(19) United States
(12) Patent Application Publication
(10) Pub. No.: US 2025/0234774 A1
(43) Pub. Date: Jul. 17, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: Yuji SUZAKI, Yokohama (JP); Yoshiro SUGITA, Yokohama (JP); Yuuki MIYAZAKI, Yokohama (JP)

(73) Assignee: Samsung Display Co., Ltd., Yongin-si (KR)

(21) Appl. No.: 18/924,001

(22) Filed: Oct. 23, 2024

(30) Foreign Application Priority Data
Jan. 17, 2024 (KR) 10-2024-0007565

(51) Int. Cl. H10K 85/60; C07F 5/02; C09K 11/02; C09K 11/06; H10K 50/11; H10K 101/20

(52) U.S. Cl. CPC H10K 85/658; C07F 5/027; C09K 11/02; C09K 11/06; H10K 85/6572; C09K 2211/1007; C09K 2211/1018; H10K 50/11; H10K 2101/20

(57) ABSTRACT

Embodiments provide a fused polycyclic compound and a light emitting element. The light emitting element includes a first electrode, a second electrode disposed on the first electrode, and a light emitting layer disposed between the first electrode and the second electrode, wherein the light emitting layer includes the fused polycyclic compound. The fused polycyclic compound is represented by Formula 1, which is explained in the specification:

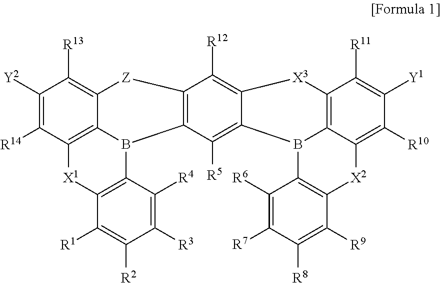

### CROSS-REFERENCE TO RELATED APPLICATION(S)

This application claims priority to and benefits of Korean Patent Application No. 10-2024-0007565 under 35 U.S.C. § 119, filed on Jan. 17, 2024, in the Korean Intellectual Property Office, the entire contents of which are incorporated herein by reference.

### BACKGROUND

### 1. Technical Field

The disclosure relates to a light emitting element, a fused polycyclic compound used for the light emitting element, and a display device including the light emitting element.

### 2. Description of the Related Art

Ongoing development continues for an organic electroluminescence display device as an image display. An organic electroluminescence display device is different from a liquid crystal display device and the like in that it is a so-called self-luminescent display device which achieves display by recombining holes and electrons respectively injected from a first electrode and a second electrode in a light emitting layer to emit light from a light emitting material that includes an organic compound.

In the application of an organic electroluminescence element to a display device, there is a constant demand for a lower driving voltage, increased luminescence efficiency, and a longer device life. Continuous development is required on materials for an organic electroluminescence element that are capable of stably achieving such characteristics.

In order to implement an organic electroluminescence element with high efficiency, technologies pertaining to phosphorescence emission that uses triplet state energy, or to fluorescence emission in which singlet excitons are generated by the collision of triplet excitons (triplet-triplet annihilation (TTA)) are being developed. Development is currently directed to thermally activated delayed fluorescence (TADF) materials that utilize delayed fluorescence phenomena.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides a light emitting element with improved luminous efficiency and element lifespan.

Another embodiment provides a fused polycyclic compound that is capable of improving luminous efficiency and element lifespan of a light emitting element.

Another embodiment provides a display device with excellent display quality by including a light emitting element with improved efficiency and lifespan.

According to an embodiment, a light emitting element may include a first electrode, a second electrode disposed on the first electrode, and a light emitting layer disposed between the first electrode and the second electrode, wherein the light emitting layer may include a first compound represented by Formula 1:

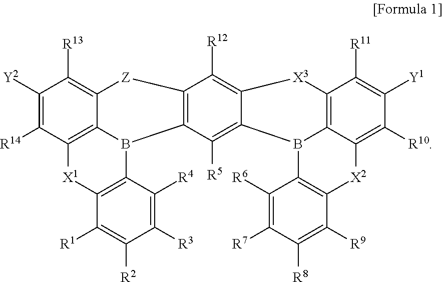

In Formula 1, X¹, X², and X³ may each independently be O, S, Se, C(R¹⁵)(R¹⁶), P(R¹⁷), Si(R¹⁸)(R¹⁹), C═O, C═S, or N(R²⁰); Y¹ and Y² may each independently be a substituted or unsubstituted alkyl group having 1 to 20 carbon atoms or a substituted or unsubstituted aryl group having 6 to 30 ring-forming carbon atoms; Z may be O, S, Se, C(R²¹)(R²²), P(R²³), Si(R²⁴)(R²⁵), C═O, or C═S; and R¹ to R²⁵ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or form a ring by being bonded to an adjacent group, except that:

if Y¹ and Y² are each an alkyl group, then R¹ to R²⁰ may not be bonded to an adjacent group to form a ring; and at least one of R¹, R², R⁸, and R⁹ may each independently be a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

In an embodiment, the first compound may be represented by one of Formula 2-1 to Formula 2-4:

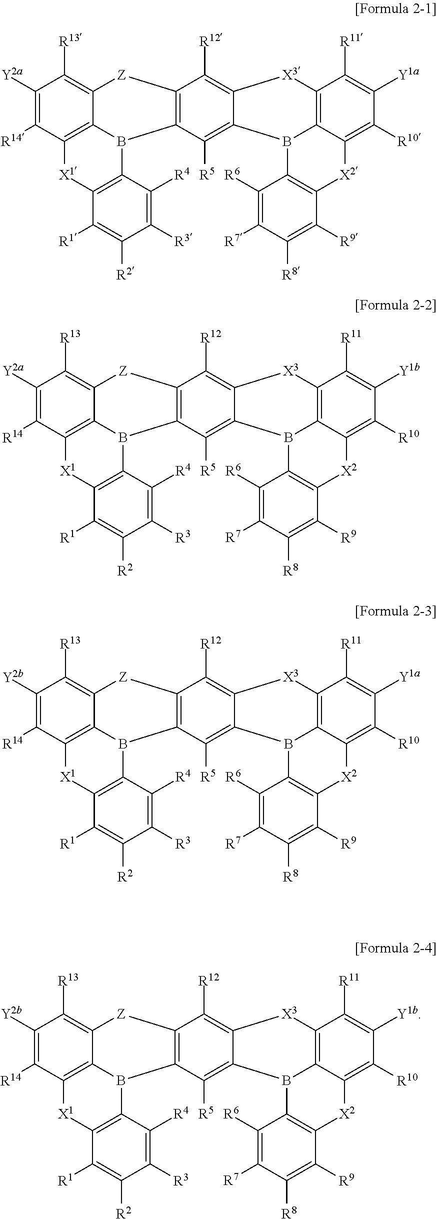

In Formula 2-1 to Formula 2-4, Y^{1a} and Y^{2a} may each independently be a substituted or unsubstituted alkyl group having 1 to 20 carbon atoms; and Y^{1b} and Y^{2b} may each independently be a substituted or unsubstituted aryl group having 6 to 30 ring-forming carbon atoms.

In Formula 2-1, X^{1′}, X^{2′}, and X^{3′} may each independently be O, S, Se, C(R^{15′})(R^{16′}), P(R^{17′}), Si(R^{18′})(R^{19′}), C═O, C═S, or N(R^{20′}); and R^{1′} to R^{20′} may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 2-1 to Formula 2-4, Z, X¹ to X³, and R¹ to R¹⁴ are the same as defined in Formula 1.

In an embodiment, the first compound may be represented by one of Formula 3-1 to Formula 3-6:

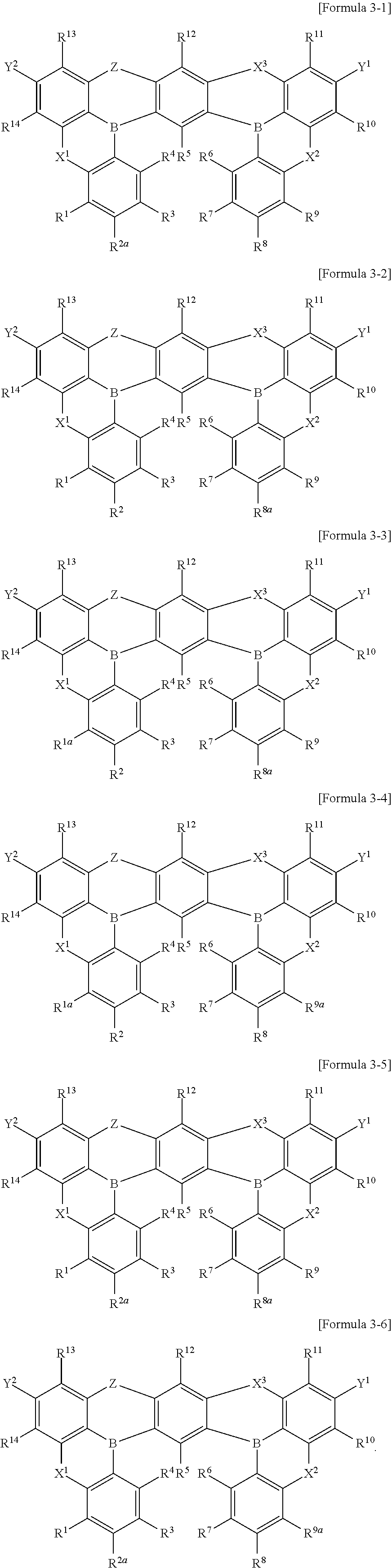

In Formula 3-1 to Formula 3-6, R^{1a}, R^{2a}, R^{8a}, and R^{9a} may each independently be a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

In Formula 3-1 to Formula 3-6, Z, X¹ to X³, Y¹, Y², and R¹ to R¹⁴ are the same as defined in Formula 1.

In an embodiment, the first compound may be represented by Formula 4:

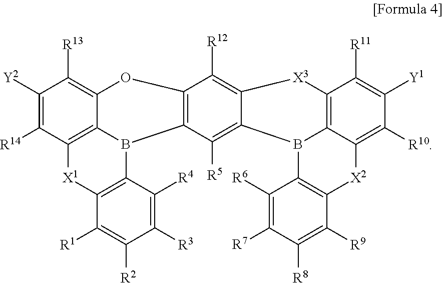

In Formula 4, X¹ to X³, Y¹, Y², and R¹ to R¹⁴ are the same as defined in Formula 1.

In an embodiment, the first compound may be represented by one of Formula 5-1 to Formula 5-3:

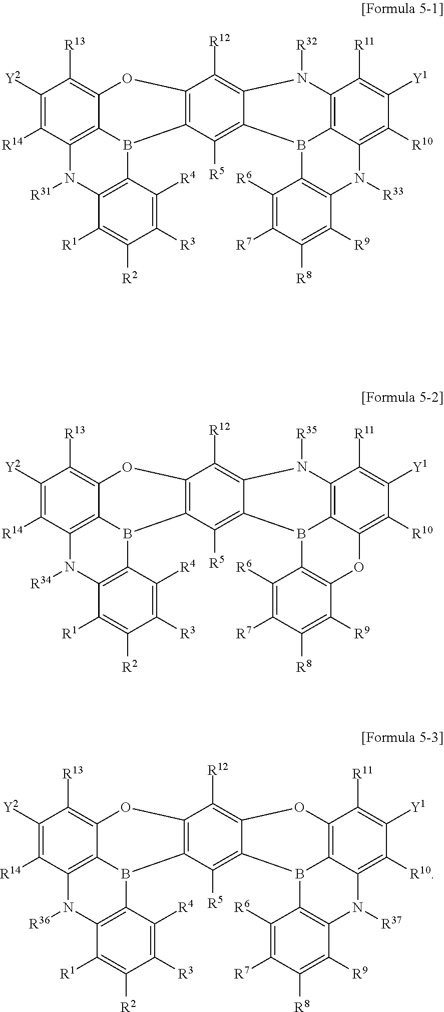

In Formula 5-1 to Formula 5-3, R³¹ to R³⁷ may each independently be a substituted or unsubstituted aryl group having 6 to 30 ring-forming carbon atoms or a substituted or unsubstituted heteroaryl group having 2 to 30 ring-forming carbon atoms.

In Formula 5-1 to Formula 5-3, Y¹, Y², and R¹ to R¹⁴ are the same as defined in Formula 1.

In an embodiment, the first compound may be represented by Formula 6:

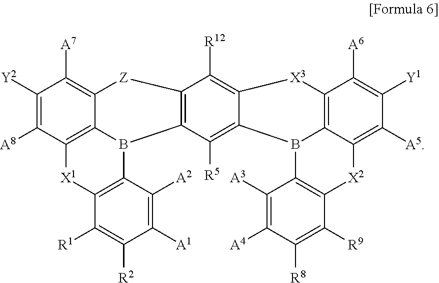

In Formula 6, A¹ to A⁸ may each independently be a hydrogen atom or a deuterium atom.

In Formula 6, Z, X¹ to X³, Y¹, Y², R¹, R², R₅, R⁸, R′, and R¹² are the same as defined in Formula 1.

In an embodiment, Y¹ and Y² may each independently be a substituted or unsubstituted alkyl group having 2 to 10 carbon atoms or a substituted or unsubstituted aryl group having 6 to 15 ring-forming carbon atoms.

In an embodiment, at least one of R¹, R², R⁸, and R⁹ may each independently be a substituted or unsubstituted arylamine group, a substituted or unsubstituted phenyl group, a substituted or unsubstituted biphenyl group, or a substituted or unsubstituted carbazole group; and the remainder of R¹, R², R⁸, and R⁹ may each independently be a hydrogen atom or a deuterium atom.

In an embodiment, the light emitting layer may further include at least one of a second compound represented by Formula HT-1, a third compound represented by Formula ET-1, and a fourth compound represented by Formula D-1:

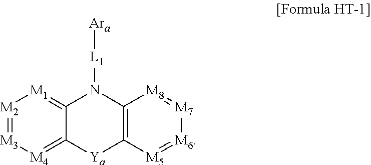

In Formula HT-1, M₁ to M₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₅₂)(R₅₃), or Si(R₅₄)(R₅₅); Arₐ may be a substituted or unsubstituted aryl group having 6 to 30 ring-forming carbon atoms or a substituted or unsubstituted heteroaryl group having 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or form a ring by being bonded to an adjacent group.

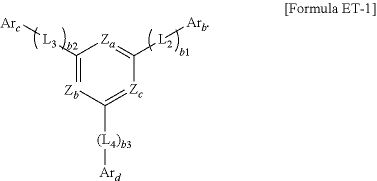

In Formula ET-1, at least one of Zₐ to Z_{c} may each be N, the remainder of Zₐ to Z_{c} may each independently be C(R₅₆); R₅₆ may be a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

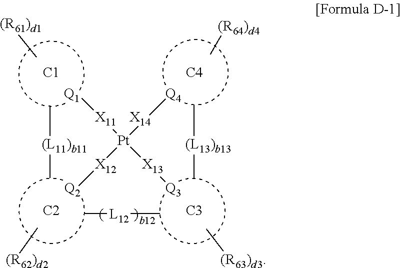

In Formula D-1, Q₁ to Q₄ may each independently be C or N; C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms; X₁₁ to X₁₄ may each independently be a direct linkage or *—O—*; L₁₁ to L₁₃ may each independently be a direct linkage,

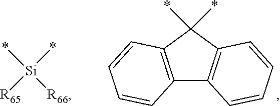

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms; and d1 to d4 may each independently be an integer from 0 to 4.

In an embodiment, the first compound may include at least one compound selected from Compound Group 1, which is explained below.

According to an embodiment, a display device may include a circuit layer disposed on a base layer, and a display element layer disposed on the circuit layer, the display element layer including a light emitting element, wherein

the light emitting element may include a first electrode, a second electrode disposed on the first electrode, and a light emitting layer disposed between the first electrode and the second electrode; and the light emitting layer may include a first compound represented by Formula 1, which is explained herein.

In an embodiment, the light emitting element may further include a capping layer disposed on the second electrode; and the capping layer may have a refractive index equal to or greater than about 1.6, with respect to light in a wavelength range of about 550 nm to about 660 nm

In an embodiment, the display device may further include a light control layer disposed on the display element layer, wherein

the light emitting element may emit a first color light; and the light control layer may include a first light control unit including a first quantum dot that converts the first color light into a second color light having a longer wavelength range than the first color light, a second light control unit including a second quantum dot that converts the first color light into a third color light having a longer wavelength range than the first color light and the second color light, and a third light control unit that transmits the first color light.

In an embodiment, the display device may further include a color filter layer disposed on the light control layer, wherein the color filter layer may include a first filter that transmits the second color light, a second filter that transmits the third color light, and a third filter that transmits the first color light.

According to an embodiment, a fused polycyclic compound may be represented by Formula 1, which is explained herein.

In an embodiment, the fused polycyclic compound represented by Formula 1 may be represented by one of Formula 2-1 to Formula 2-4, which are explained herein.

In an embodiment, the fused polycyclic compound represented by Formula 1 may be represented by one of Formula 3-1 to Formula 3-6, which are explained herein.

In an embodiment, the fused polycyclic compound represented by Formula 1 may be represented by Formula 4, which is explained herein.

In an embodiment, the fused polycyclic compound represented by Formula 1 may be represented by one of Formula 5-1 to Formula 5-3, which are explained herein.

In an embodiment, the fused polycyclic compound may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of a vehicle including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for case of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “form a ring by being bonded to an adjacent group” may refer to a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 50, 6 to40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

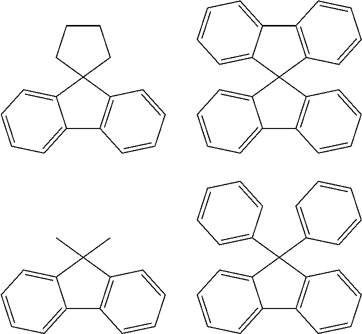

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an acyl (or carbonyl) group is not particularly limited, and may be 1 to 40, 1 to 30, 1 to 20, or 1 to 10. Examples of an acyl group may include an acetyl group, an ethylcarbonyl group, an isopropylcarbonyl group, a naphthylenecarbonyl group, a cyclopentylcarbonyl group, a cyclohexylcarbonyl group, a phenylcarbonyl group, etc., but embodiments are not limited thereto. For example, an acyl group may have the following structure, but embodiments are not limited thereto.

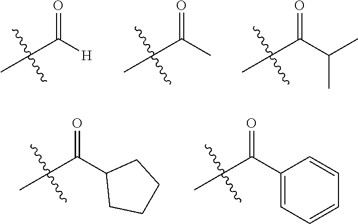

In the specification, the number of carbon atoms in a sulfinyl group or in a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an amino group may be a functional group that is represented by —NH₂.

In the specification, a thiol group may be a functional group that is represented by —SH.

In the specification, a hydroxy group may be a functional group that is represented by —OH.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols [symbol] and [symbol] each represent a bond to a neighboring atom in a corresponding formula or moiety.

Hereinafter, embodiments will be described with reference to the accompanying drawings.

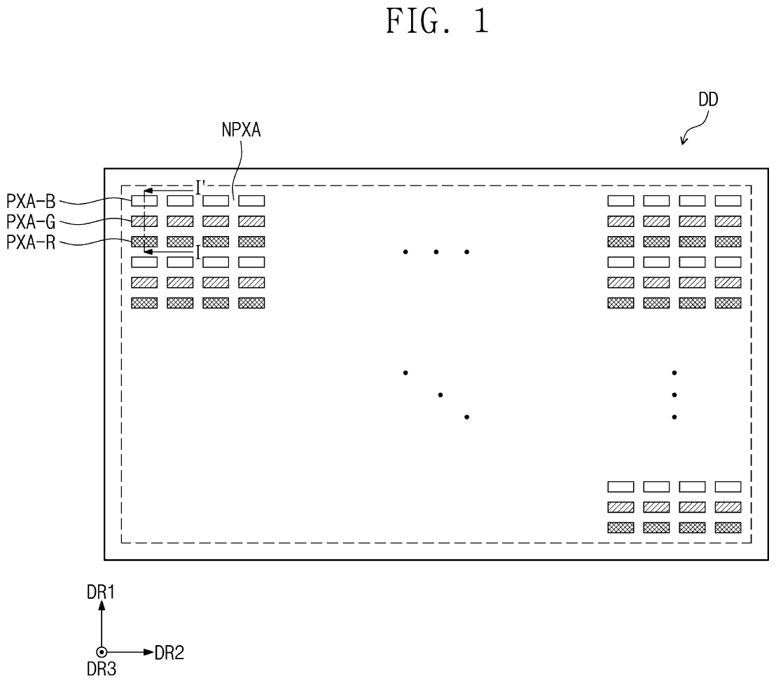

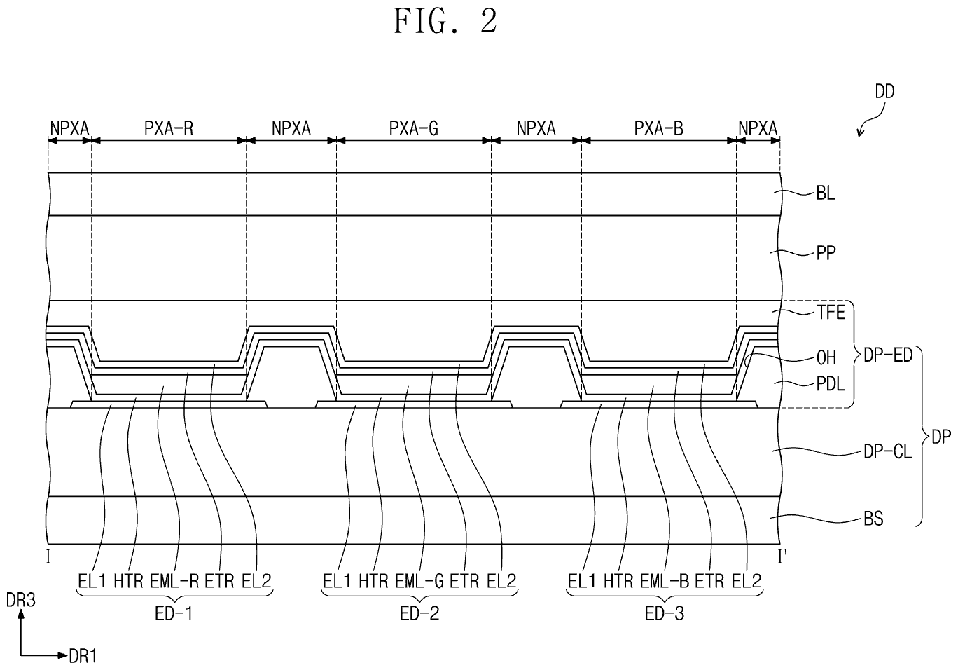

FIG. 1 is a schematic plan view of a display device DD according to an embodiment. FIG. 2 is a schematic cross-sectional view of a display device DD according to an embodiment. FIG. 2 is a schematic cross-sectional view illustrating a part taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

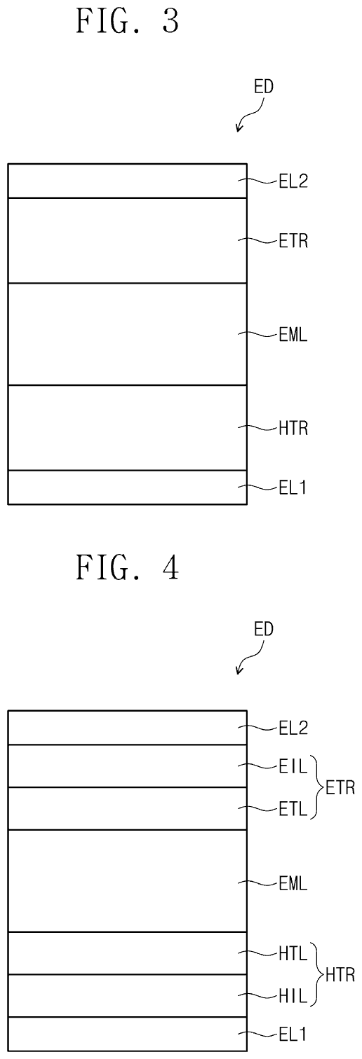

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, light emitting layers EML-R, EML-G, and EML-B, an electron transport region ETR, and a second electrode EL2.

FIG. 2 illustrates an embodiment in which the light emitting layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not shown in FIG. 2, the hole transport region HTR and the electron transport region ETR may each be provided by being patterned in the openings OH defined in the pixel defining film PDL. For example, in an embodiment, the hole transport region HTR, the light emitting layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The light emitting layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively, correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. Embodiments provide a light emitting element ED which may include a first electrode EL1, a second electrode EL2 disposed on the first electrode EL1, and at least one functional layer disposed between the first electrode EL1 and the second electrode EL2. The light emitting element ED may include a fused polycyclic compound according to an embodiment, which will be explained later, in the at least one functional layer.

In an embodiment, the light emitting element ED may include a hole transport region HTR, a light emitting layer EML, an electron transport region ETR, or the like, as the at least one functional layer. In an embodiment shown in FIG. 3, a light emitting element ED may include a first electrode EL1, a hole transport region HTR, a light emitting layer EML, an electron transport region ETR, and a second electrode EL2.

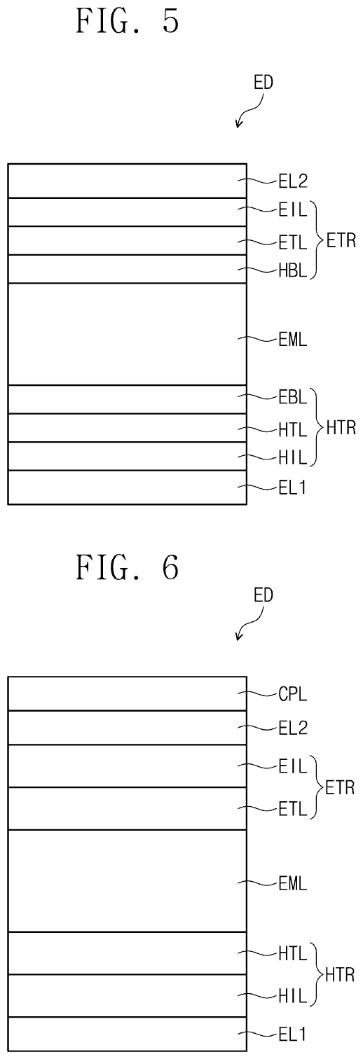

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

A light emitting element ED according to an embodiment may include a fused polycyclic compound according to an embodiment, which will be explained later, in the at least one functional layer. In the light emitting element ED, at least one of the hole transport region HTR, the light emitting layer EML, and the electron transport region ETR may include the fused polycyclic compound according to an embodiment. For example, in the light emitting element ED, the light emitting layer EML may include the fused polycyclic compound.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

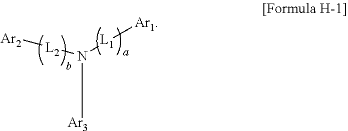

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is an integer of 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

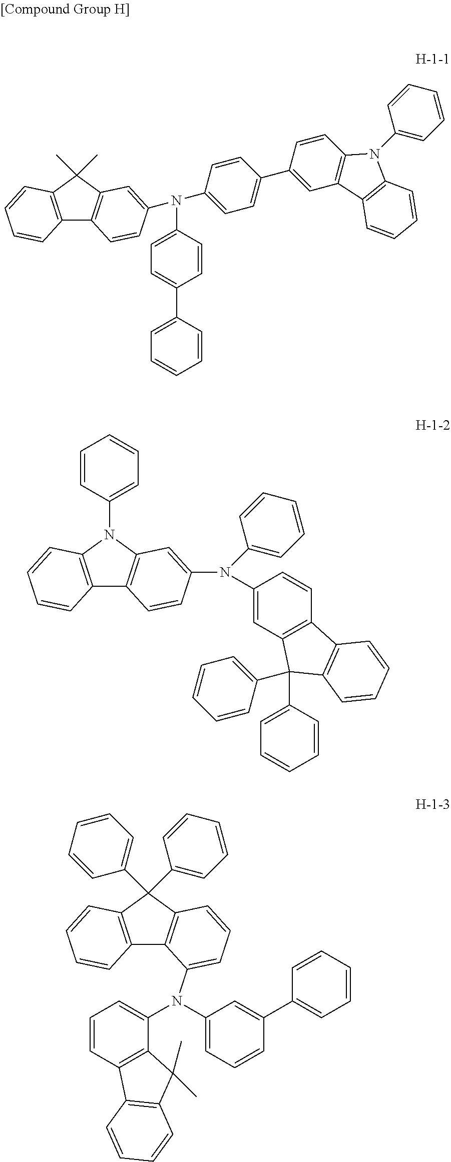 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

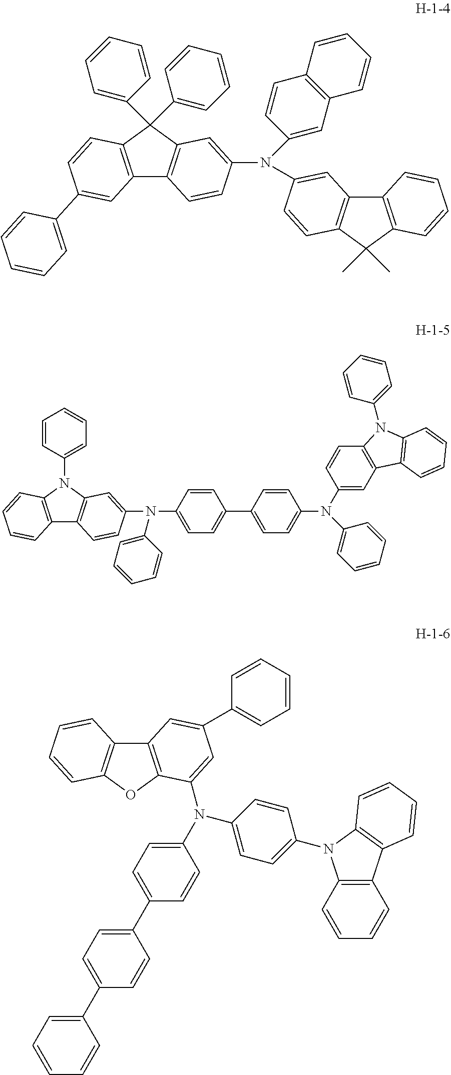 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

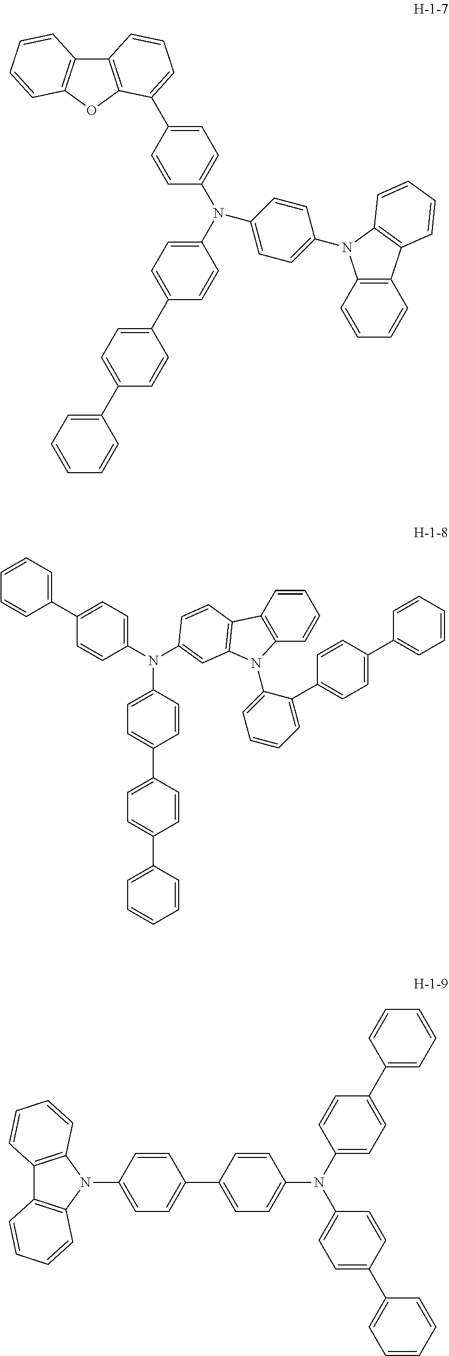 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

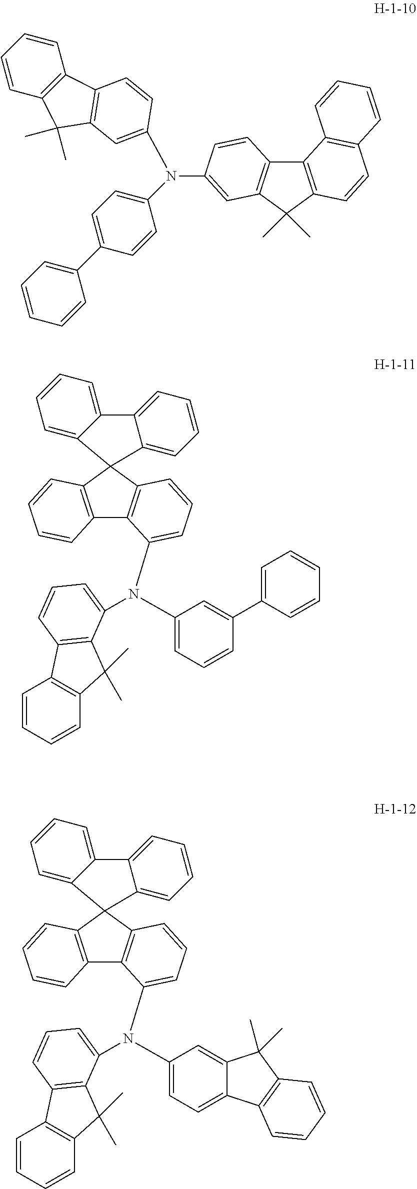 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

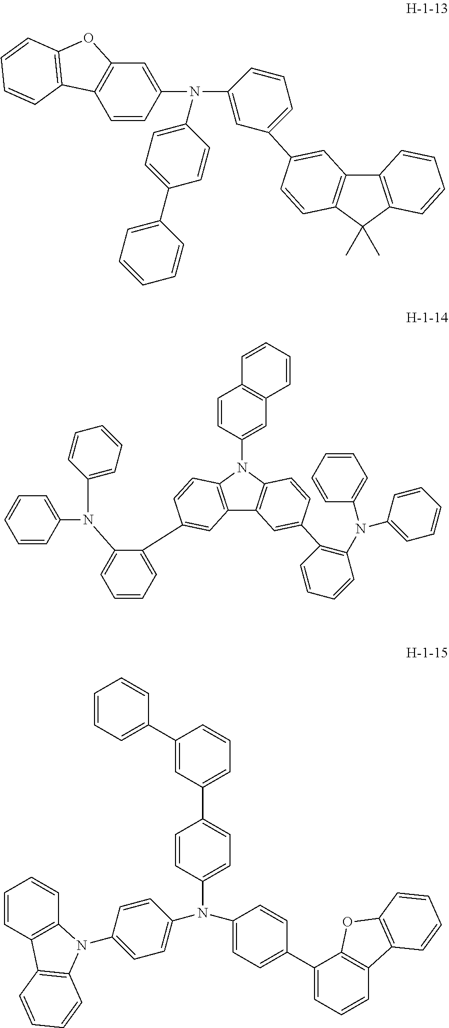 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

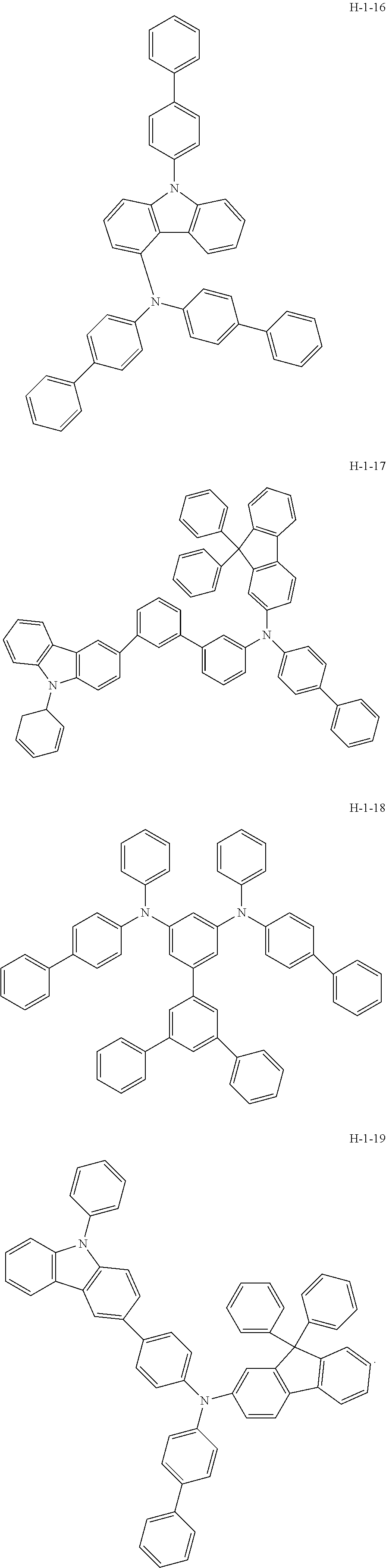 [SMILES: c1ccc(-c2ccc(N(c3ccc(-c4ccccc4)cc3)c3cccc4c3c3ccccc3n4-c3ccc(-c4ccccc4)cc3)cc2)cc1 ; C1=CCC(n2c3ccccc3c3cc(-c4cccc(-c5cccc(N(c6ccc(-c7ccccc7)cc6)c6ccc7c(c6)C(c6ccccc6)(c6ccccc6)c6ccccc6-7)c5)c4)ccc32)C=C1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl) borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to the hole injection layer HIL and the hole transport layer HTL. The buffer layer (not shown) may compensate for a resonance distance according to a wavelength of light emitted from the light emitting layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The light emitting layer EML may be provided on the hole transport region HTR. The light emitting layer EML may have a thickness in a range of about 100 Å to about 1,000 Å. For example, the light emitting layer EML may have a thickness in a range of about 100 Å to about 300 Å. The light emitting layer EML may have a structure consisting of a layer consisting of a single material, a structure consisting of a layer including different materials, or a structure including multiple layers including different materials.

The light emitting element ED according to an embodiment may include a fused polycyclic compound represented by Formula 1 in at least one functional layer disposed between the first electrode EL1 and the second electrode EL2. In the light emitting element ED, the light emitting layer EML may include the fused polycyclic compound according to an embodiment. In an embodiment, the light emitting layer EML may include the fused polycyclic compound as a dopant. The fused polycyclic compound may be a dopant material of the light emitting layer EML. In the specification, the fused polycyclic compound according to an embodiment may be referred to as a first compound.

The fused polycyclic compound may include a fused ring core in which five benzene rings are condensed together through two boron atoms and four heteroatoms, and the fused polycyclic compound has a structure in which first and second substituents are connected to the fused ring core.

In an embodiment, the fused ring core of the fused polycyclic compound may form nine rings as five substituted or unsubstituted benzene rings are condensed together through two boron atoms and four heteroatoms. Among the five benzene rings of the fused ring core, a first benzene ring and a second benzene ring may each be connected to a first boron atom, a third benzene ring and a fourth benzene ring may each be connected to a second boron atom, and a fifth benzene ring may be connected to both the first boron atom and the second boron atom.

In an embodiment, a first heteroatom may be connected between the first benzene ring and the second benzene ring, and a second heteroatom may be connected between the third benzene ring and the fourth benzene ring. Thus, the first benzene ring and the second benzene ring may be connected to each other through the first boron atom and the first heteroatom, and a six-membered first fused ring that includes the first boron atom and the first heteroatom as ring-forming atoms may be formed between the first benzene ring and the second benzene ring. The third benzene ring and the fourth benzene ring may be connected to each other through the second boron atom and the second heteroatom, and a six-membered second fused ring that includes the second boron atom and the second heteroatom as ring-forming atoms may be formed between the third benzene ring and the fourth benzene ring.

In the fused ring core, the first benzene ring and the third benzene ring may be disposed adjacent to the fifth benzene ring. In an embodiment, the first benzene ring and the third benzene ring may each be connected to the fifth benzene ring through a boron atom and a heteroatom. A third heteroatom may be connected between the third benzene ring and the fifth benzene ring, and a fourth heteroatom may be connected between the first benzene ring and the fifth benzene ring. The first benzene ring and the fifth benzene ring may be connected to each other through the first boron atom and the fourth heteroatom, and a six-membered third fused ring that includes the first boron atom and the fourth heteroatom as ring-forming atoms may be formed between the first benzene ring and the fifth benzene ring. The third benzene ring and the fifth benzene ring may be connected to each other through the second boron atom and the third heteroatom and a six-membered fourth fused ring including the second boron atom and the third heteroatom as ring-forming atoms may be formed between the third benzene ring and the fifth benzene ring.

In an embodiment, the first to third heteroatoms may each independently be an oxygen (O) atom, a sulfur(S) atom, a selenium (Sc) atom, a carbon (C) atom, a phosphorus (P) atom, a silicon (Si) atom, or a nitrogen (N) atom. The fourth heteroatom may be an oxygen (O) atom, a sulfur(S) atom, a selenium (Sc) atom, a carbon (C) atom, a phosphorus (P) atom, or a silicon (Si) atom. In an embodiment, the fourth heteroatom may not be a nitrogen (N) atom. Since the fourth heteroatom in the fused polycyclic compound is not nitrogen (N), material stability may be improved, which may contribute to high efficiency and long lifespan of the light emitting element.

The fused polycyclic compound may include a first substituent connected to the fused ring core. In an embodiment, the fused polycyclic compound may include multiple first substituents. The first substituent may be connected to each of the first benzene ring and the third benzene ring of the fused ring core. The first substituent may be directly connected to the first benzene ring and the third benzene ring, so that the first substituent may be directly connected to the first benzene ring and the third benzene ring without a linking moiety. The first substituent may be connected at a para position to a boron atom of the fused ring core. For example, the first substituent may include a first sub-substituent and a second sub-substituent, wherein the first sub-substituent may be connected to a carbon atom of the first benzene ring that is at a para position with respect to a carbon atom connected to the first boron atom, and the second sub-substituent may be connected to a carbon atom of the third benzene ring that is at a para position with respect to a carbon atom connected to the second boron atom. In an embodiment, the first substituent may be a substituted or unsubstituted alkyl group having 1 to 20 carbon atoms or a substituted or unsubstituted aryl group having 6 to 30 ring-forming carbon atoms. In the specification, the first substituent may be represented by Y¹ and Y² in Formula 1, which will be described below.

The fused polycyclic compound may include a second substituent connected to the fused ring core. The second substituent may be connected to the second benzene ring and/or the fourth benzene ring of the fused ring core. The fused polycyclic compound may include a single second substituent or multiple second substituents. In an embodiment, the second substituent may be a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. In the fused polycyclic compound, a carbon atom of the second benzene ring that is at a para position with respect to the first boron atom may be referred to as a first carbon atom, and a carbon atom of the second benzene ring that is at an ortho position with respect to the first heteroatom may be referred to as a second carbon atom. In the fused polycyclic compound, a carbon atom of the fourth benzene ring that is at a para position with respect to the second boron atom may be referred to as a third carbon atom, and a carbon atom of the fourth benzene ring that is at an ortho position with respect to the second heteroatom may be referred to as a fourth carbon atom. In the fused polycyclic compound, the second substituent may be connected to at least one of the first to fourth carbon atoms.

The light emitting element ED according to an embodiment may include the fused polycyclic compound according to an embodiment. The fused polycyclic compound according to an embodiment may be represented by Formula 1:

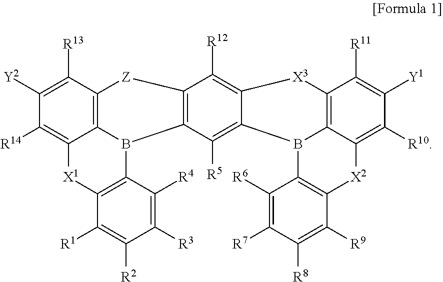

The fused polycyclic compound according to an embodiment, which may be represented by Formula 1, may include a fused ring core formed by nine rings that are condensed together with two boron atoms and four heteroatoms, and the fused polycyclic compound may include first and second substituents that are connected to the fused ring core. In the specification, in Formula 1, a benzene ring that includes Y², R¹³, and R¹⁴ may correspond to the first benzene ring as described above, a benzene ring that includes R¹ to R⁴ may correspond to the second benzene ring as described above, a benzene ring that includes Y¹, R¹⁰, and R¹¹ may correspond to the third benzene ring as described above, a benzene ring that includes R⁶ to R⁹ may correspond to the fourth benzene ring as described above, and a benzene ring that includes R⁵ and R¹² may correspond to the fifth benzene ring as described above. In Formula 1, Y¹ and Y² may correspond to the first substituent as described above.

In Formula 1, X¹, X², and X³ may each independently be O, S, Se, C(R¹⁵)(R¹⁶), P(R¹⁷), Si(R¹⁸)(R¹⁹), C═O, C═S, or N(R²⁰). For example, X¹, X², and X³ may each independently be O or N(R²⁰).

In an embodiment, at least one of X¹, X², and X³ may each independently be N(R²⁰), and the remainder of X¹, X², and X³ may each be O. For example, any one of X¹, X², and X³ may be N(R²⁰), and the remainder of X¹, X², and X³ may each be O. As another example, two of X¹, X², and X³ may each independently be N(R²⁰), and the remainder of X¹, X², and X³ may be O. As yet another example, X¹, X², and X³ may each independently be N(R²⁰).

In Formula 1, Y¹ and Y² may each independently be a substituted or unsubstituted alkyl group having 1 to 20 carbon atoms or a substituted or unsubstituted aryl group having 6 to 30 ring-forming carbon atoms. In an embodiment, Y¹ and Y² may each independently be a substituted or unsubstituted alkyl group having 2 to 10 carbon atoms or a substituted or unsubstituted aryl group having 6 to 15 ring-forming carbon atoms. For example, Y′ and Y² may each independently be a substituted or unsubstituted t-butyl group or a substituted or unsubstituted phenyl group.

For example, Y¹ and Y² may each independently be a substituted or unsubstituted alkyl group having 1 to 20 carbon atoms. As another example, Y¹ and Y² may each independently be a substituted or unsubstituted aryl group having 1 to 30 ring-forming carbon atoms. As another example, one of Y¹ and Y² may be a substituted or unsubstituted aryl group having 1 to 20 carbon atoms, and the other of Y′ and Y² may be a substituted or unsubstituted aryl group having 6 to 30 ring-forming carbon atoms. As yet another example, one of Y¹ and Y² may be a substituted or unsubstituted aryl group having 6 to 30 ring-forming carbon atoms and the other of Y¹ and Y² may be a substituted or unsubstituted alkyl group having 1 to 20 carbon atoms.

In Formula 1, Z may be O, S, Se, C(R²¹)(R²²), P(R²³), Si(R²⁴)(R²⁵), C═O, or C═S. For example, Z may be O.

In Formula 1, R¹ to R²⁵ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or form a ring by being bonded to an adjacent group. For example, R¹ to R¹⁴ may each independently be a hydrogen atom, a deuterium atom, a substituted or unsubstituted methyl group, or a substituted or unsubstituted phenyl group; and R¹⁵ to R²⁵ may each independently be a substituted or unsubstituted methyl group, a substituted or unsubstituted phenyl group, a substituted or unsubstituted biphenyl group, or a substituted or unsubstituted terphenyl group.

In the fused polycyclic compound represented by Formula 1, as an exception to the definition of R¹ to R²⁵ as described above, if Y and Y² are each an alkyl group, then R¹ to R²⁰ may not be bonded to an adjacent group to form a ring. For example, in Formula 1, if Y¹ and Y² are each an alkyl group, then R¹ to R²⁰ may not be bonded to an adjacent substituent to thereby forming an additional condensed ring. For example, if Y¹ and Y² are each an alkyl group, and X¹ and X² are each N(R²⁰), X¹ may not be bonded to R¹ or R¹⁴ to form a ring, and X² may not be bonded to R⁹ or R¹⁰ to form a ring.

In Formula 1, at least one of R¹, R², R⁸, and R⁹ may each independently be a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, at least one of R¹, R², R⁸, and R⁹ may each independently be a substituted or unsubstituted arylamine group, a substituted or unsubstituted phenyl group, a substituted or unsubstituted biphenyl group, or a substituted or unsubstituted carbazole group.

In an embodiment, in Formula 1, at least one of R¹, R², R⁸, and R⁹ may each independently be a substituted or unsubstituted arylamine group, a substituted or unsubstituted phenyl group, a substituted or unsubstituted biphenyl group, or a substituted or unsubstituted carbazole group, and the remainder of R¹, R², R⁸, and R⁹ may each independently be a hydrogen atom or a deuterium atom. For example, any one of R¹, R², R⁸, and R⁹ may be a substituted or unsubstituted diphenylamine group, a substituted or unsubstituted phenyl group, a substituted or unsubstituted biphenyl group, or a substituted or unsubstituted carbazole group, and the remainder of R¹, R², R⁸, and R⁹ may each independently be a hydrogen atom or a deuterium atom. As another example, two of R¹, R², R⁸, and R⁹ may each independently be a substituted or unsubstituted diphenylamine group, a substituted or unsubstituted phenyl group, a substituted or unsubstituted biphenyl group, or a substituted or unsubstituted carbazole group, and the remainder of R¹, R², R⁸, and R⁹ may each independently be a hydrogen atom or a deuterium atom. As yet another example, three of R¹, R², R⁸, and R⁹ may each independently be a substituted or unsubstituted diphenylamine group, a substituted or unsubstituted phenyl group, a substituted or unsubstituted biphenyl group, or a substituted or unsubstituted carbazole group, and the remainder of R¹, R², R⁸, and R⁹ may be a hydrogen atom or a deuterium atom. However, embodiments are not limited thereto, and R¹, R², R⁸, and R⁹ may each independently be a substituted or unsubstituted diphenylamine group, a substituted or unsubstituted phenyl group, a substituted or unsubstituted biphenyl group, or a substituted or unsubstituted carbazole group.

In an embodiment, the fused polycyclic compound represented by Formula 1 may be represented by one of Formula 2-1 to Formula 2-4:

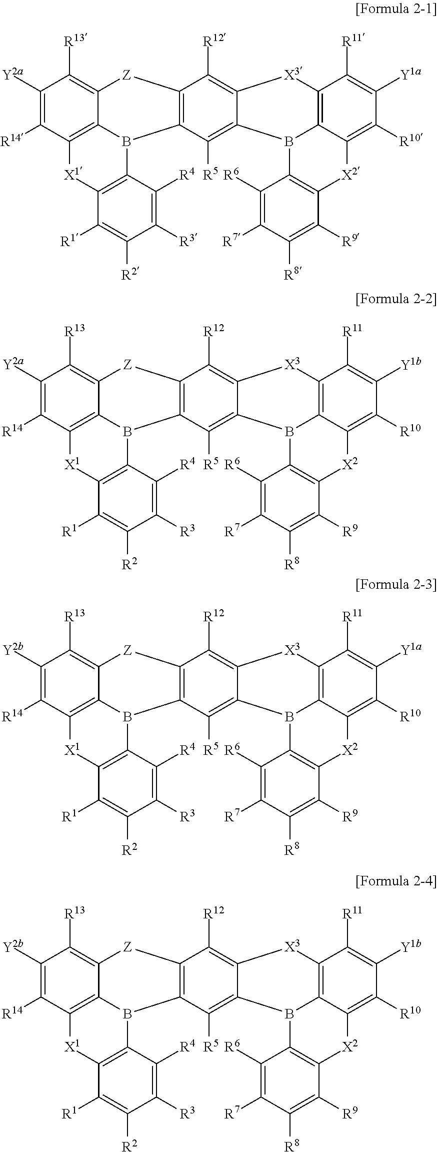

In Formula 2-1 to Formula 2-3, Y^{1a} and Y^{2a} may each independently be a substituted or unsubstituted alkyl group having 1 to 20 carbon atoms. For example, Y^{1a} and Y^{2a} may each independently be a substituted or unsubstituted t-butyl group.

In Formula 2-1 to Formula 2-4, Y^{1b} and Y^{2b} may each independently be a substituted or unsubstituted aryl group having 6 to 30 ring-forming carbon atoms. For example, Y^{1b} and Y^{2b} may each independently be a substituted or unsubstituted phenyl group.

In Formula 2-1, X¹′, X^{2′}, and X^{3′} may each independently be O, S, Se, C(R^{15′})(R^{16′}), P(R^{17′}), Si(R^{18′})(R^{19′}), C═O, C═S, or N(R^{20′}). For example, X^{1′}, X^{2′}, and X^{3′} may each independently be O or N(R^{20′}).

In an embodiment, at least one of X^{1′}, X^{2′}, and X^{3′} may each independently be N(R^{20′}), and the remainder of X^{1′}, X^{2′}, and X^{3′} may each be O. For example, one of X^{1′}, X^{2′}, and X^{3′} may be N(R^{20′}), and the remainder of X^{1′}, X^{2′}, and X^{3′} may each be O. As another example, two of X^{1′}, X^{2′}, and X^{3′} may each independently be N(R^{20′}), and the remainder of X^{1′}, X^{2′}, and X^{3′} may be O. As yet another example, X^{1′}, X^{2′}, and X^{3′} may each independently be N(R^{20′}).

In Formula 2-1, R^{1′} to R^{20′} may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R^{1′} to R^{20′} may each independently be a hydrogen atom, a deuterium atom, a substituted or unsubstituted methyl group, a substituted or unsubstituted phenyl group, a substituted or unsubstituted biphenyl group, or a substituted or unsubstituted terphenyl group.

In Formula 2-1 to Formula 2-4, Z, X¹ to X³, and R¹ to R¹⁴ are the same as defined in Formula 1.

In an embodiment, the fused polycyclic compound represented by Formula 1 may be represented by one of Formula 3-1 to Formula 3-6:

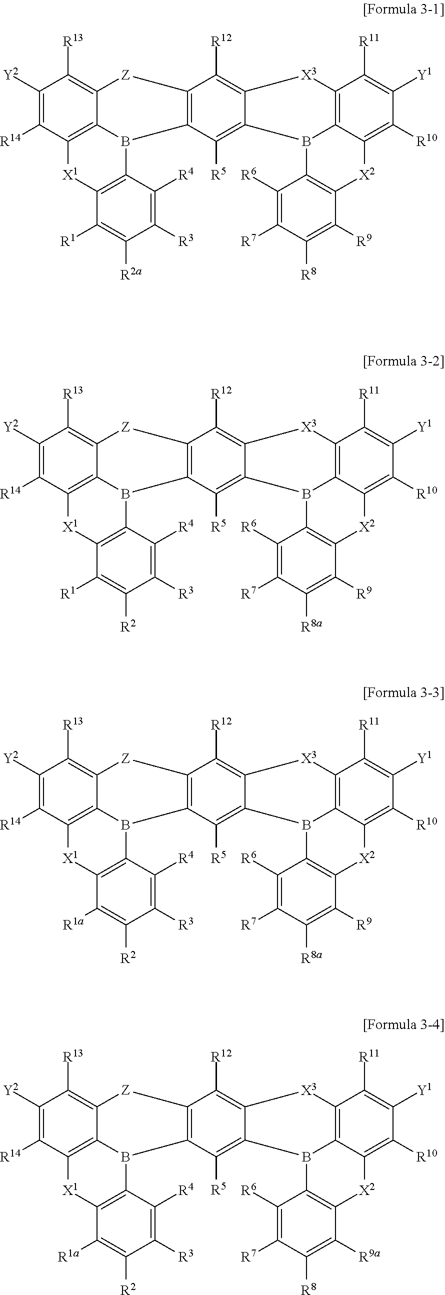

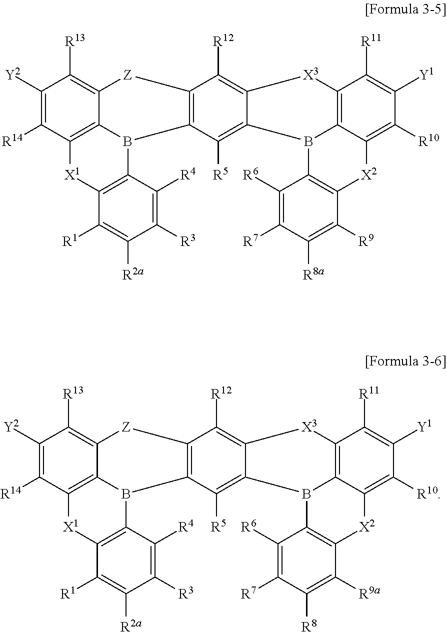

Formula 3-1 to Formula 3-6 each represent a case where R¹, R², R⁸, and R⁹ in Formula 1 are further defined.

In Formula 3-1 to Formula 3-6, R^{1a}, R^{2a}, R^{8a}, and R^{9a} may each independently be a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. For example, R^{1a}, R^{2a}, R^{8a}, and R^{9a} may each independently be a substituted or unsubstituted arylamine group, a substituted or unsubstituted phenyl group, a substituted or unsubstituted biphenyl group, or a substituted or unsubstituted carbazole group.

In Formula 3-1 to Formula 3-6, Z, X¹ to X³, Y¹, Y², and R¹ to R¹⁴ are the same as defined in Formula 1.

In an embodiment, the fused polycyclic compound represented by Formula 1 may be represented by Formula 4:

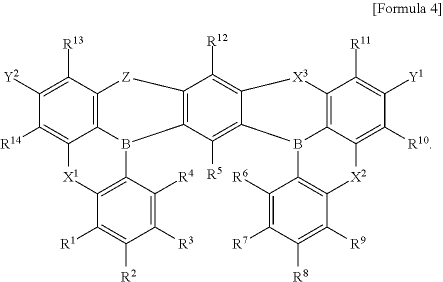

Formula 4 represents a case where Z in Formula 1 is further defined.

In Formula 4, X¹ to X³, Y¹, Y², and R¹ to R¹⁴ are the same as defined in Formula 1.

In an embodiment, the fused polycyclic compound represented by Formula 1 may be represented by one of Formula 5-1 to Formula 5-3:

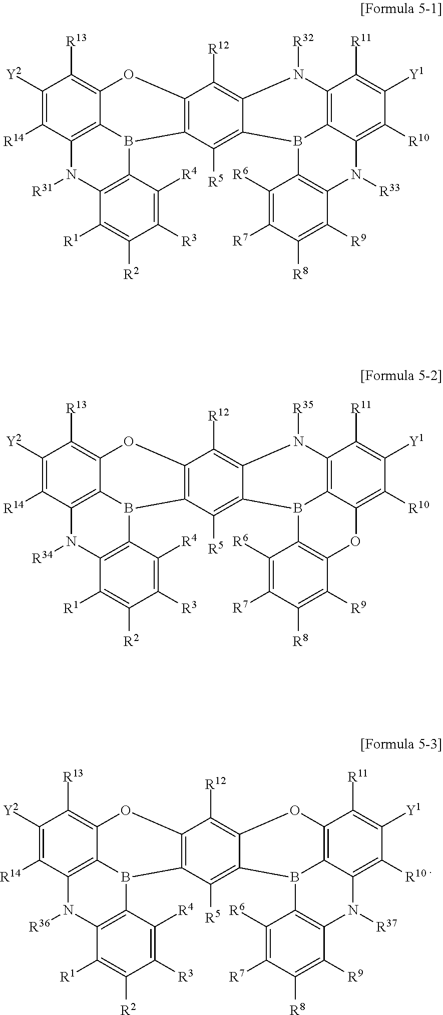

Formula 5-1 to Formula 5-3 each represent a case where Z and X¹ to X³ in Formula 1 are further defined.

In Formula 5-1 to Formula 5-3, R³¹ to R³⁷ may each independently be a substituted or unsubstituted aryl group having 6 to 30 ring-forming carbon atoms, or a substituted or unsubstituted heteroaryl group having 2 to 30 ring-forming carbon atoms. In an embodiment, R³¹ to R³⁷ may each independently be a substituted or unsubstituted aryl group having 6 to 30 ring-forming carbon atoms. For example, R³¹ to R³⁷ may each independently be a substituted or unsubstituted phenyl group, a substituted or unsubstituted biphenyl group, or a substituted or unsubstituted terphenyl group.

In Formula 5-1 to Formula 5-3, Y¹, Y², and R¹ to R¹⁴ are the same as defined in Formula 1.

In an embodiment, the fused polycyclic compound represented by Formula 1 may be represented by Formula 6:

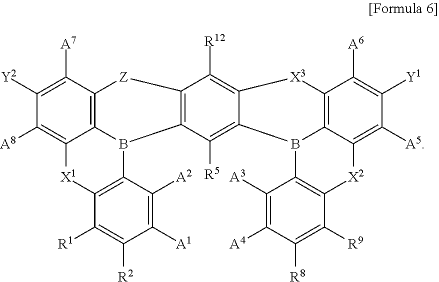

In Formula 6, A′ to A⁸ may each independently be a hydrogen atom or a deuterium atom. For example, A′ to A⁸ may each be a hydrogen atom, or A′ to A⁸ may each be a deuterium atom.

In Formula 6, Z, X¹ to X³, Y¹, Y², R¹, R², R₅, R⁸, R⁹, and R¹² are the same as defined in Formula 1.

In an embodiment, the fused polycyclic compound may include at least one deuterium atom as a substituent. The fused polycyclic compound may have a structure in which at least one hydrogen atom is each substituted by a deuterium atom.

In an embodiment, the fused polycyclic compound may be any compound selected from Compound Group 1. In an embodiment, in the light emitting element ED, the at least one functional layer (for example, a light emitting layer EML) may include at least one fused polycyclic compound selected from Compound Group 1:

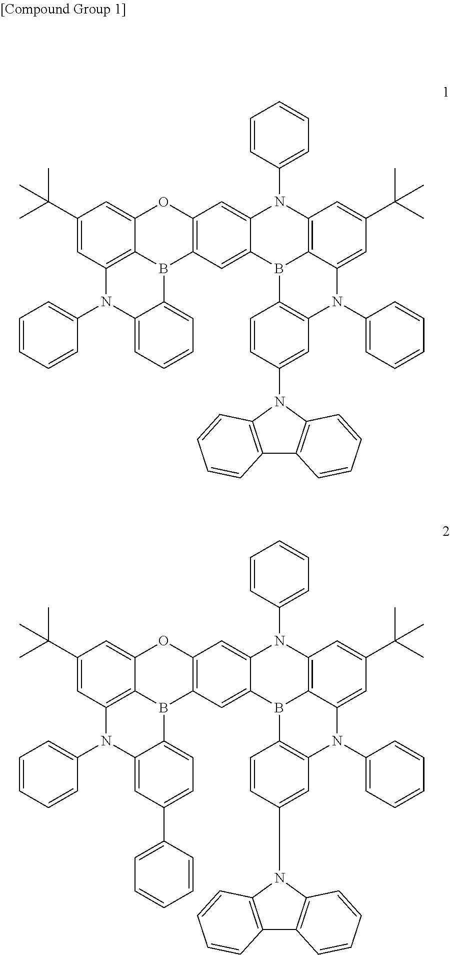 [SMILES: CC(C)(C)c1cc2c3c(c1)N(c1ccccc1)c1ccccc1B3c1cc3c(cc1O2)N(c1ccccc1)c1cc(C(C)(C)C)cc2c1B3c1ccc(-n3c4ccccc4c4ccccc43)cc1N2c1ccccc1 ; CC(C)(C)c1cc2c3c(c1)N(c1ccccc1)c1cc(-c4ccccc4)ccc1B3c1cc3c(cc1O2)N(c1ccccc1)c1cc(C(C)(C)C)cc2c1B3c1ccc(-n3c4ccccc4c4ccccc43)cc1N2c1ccccc1]

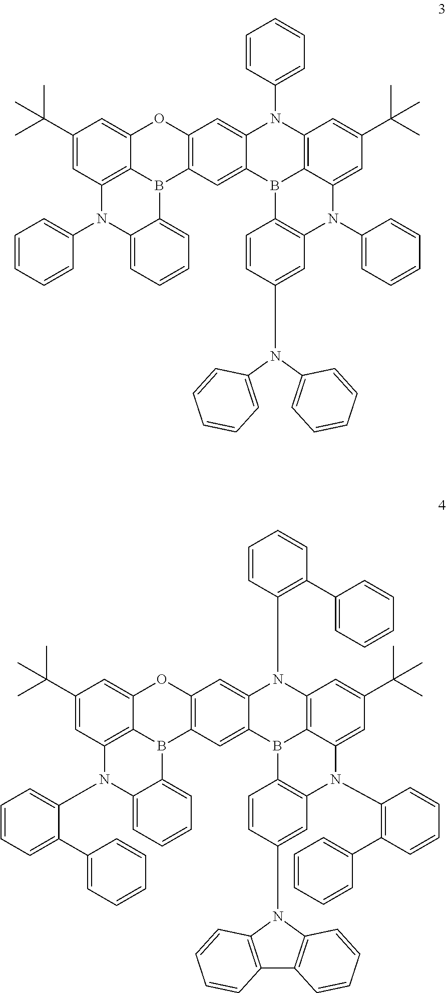 [SMILES: CC(C)(C)c1cc2c3c(c1)N(c1ccccc1)c1ccccc1B3c1cc3c(cc1O2)N(c1ccccc1)c1cc(C(C)(C)C)cc2c1B3c1ccc(N(c3ccccc3)c3ccccc3)cc1N2c1ccccc1 ; CC(C)(C)c1cc2c3c(c1)N(c1ccccc1-c1ccccc1)c1ccccc1B3c1cc3c(cc1O2)N(c1ccccc1-c1ccccc1)c1cc(C(C)(C)C)cc2c1B3c1ccc(-n3c4ccccc4c4ccccc43)cc1N2c1ccccc1-c1ccccc1]

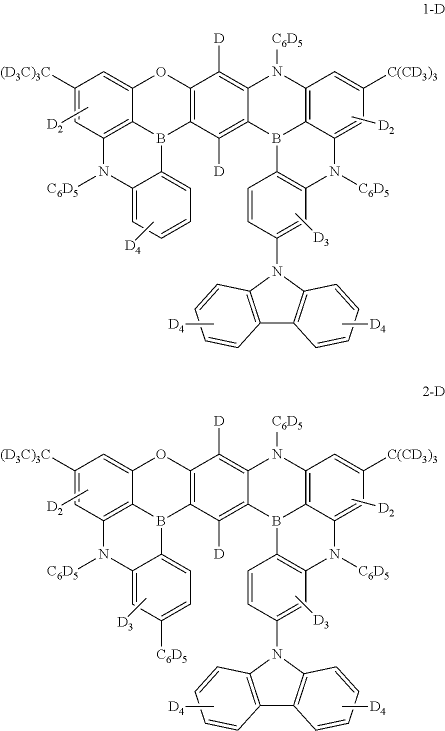

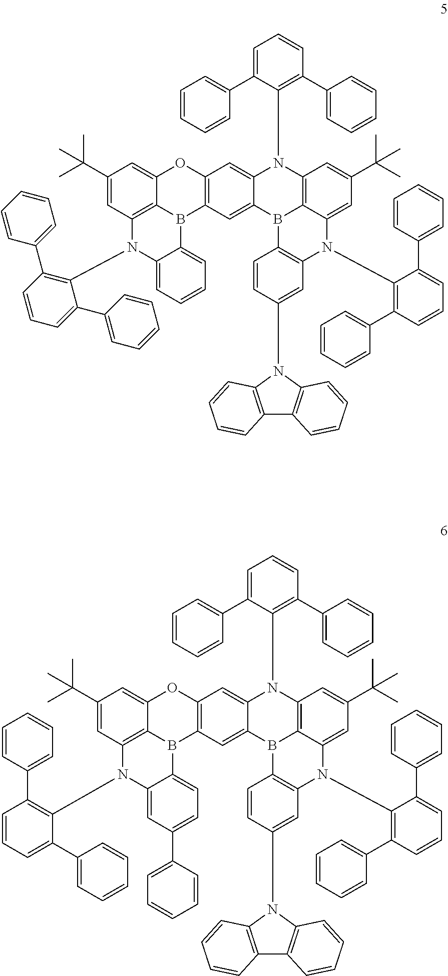 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cccc1-c1ccccc1)c1cc(C(C)(C)C)cc2c1B3c1ccc(-n3c4ccccc4c4ccccc43)cc1N2c1c(-c2ccccc2)cccc1-c1ccccc1]

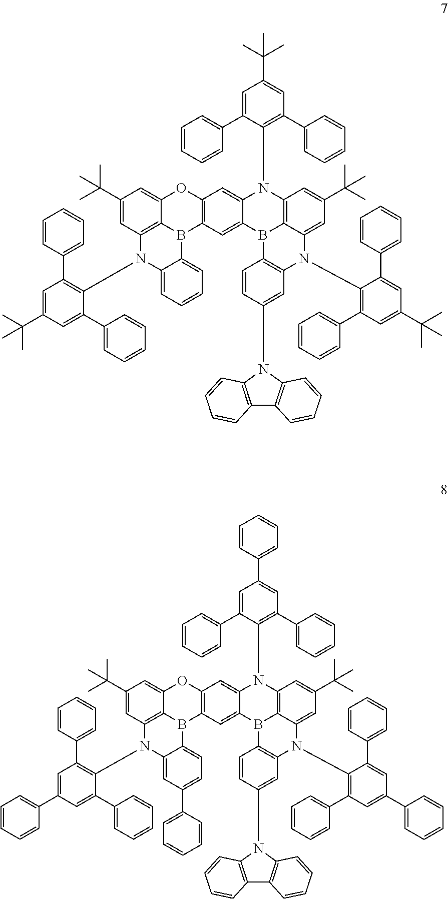 [SMILES: CC(C)(C)c1cc(-c2ccccc2)c(N2c3ccccc3B3c4cc5c(cc4Oc4cc(C(C)(C)C)cc2c43)N(c2c(-c3ccccc3)cc(C(C)(C)C)cc2-c2ccccc2)c2cc(C(C)(C)C)cc3c2B5c2ccc(-n4c5ccccc5c5ccccc54)cc2N3c2c(-c3ccccc3)cc(C(C)(C)C)cc2-c2ccccc2)c(-c2ccccc2)c1 ; CC(C)(C)c1cc2c3c(c1)N(c1c(-c4ccccc4)cc(-c4ccccc4)cc1-c1ccccc1)c1cc(-c4ccccc4)ccc1B3c1cc3c(cc1O2)N(c1c(-c2ccccc2)cc(-c2ccccc2)cc1-c1ccccc1)c1cc(C(C)(C)C)cc2c1B3c1ccc(-n3c4ccccc4c4ccccc43)cc1N2c1c(-c2ccccc2)cc(-c2ccccc2)cc1-c1ccccc1]

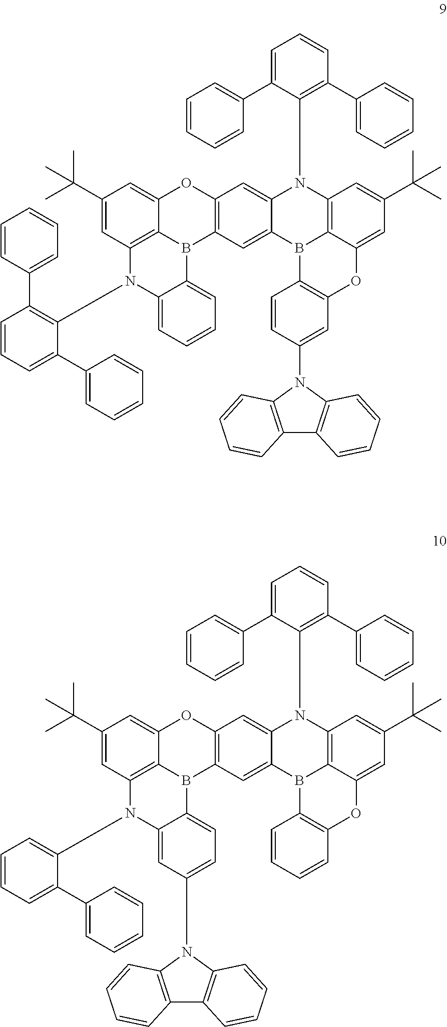 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(-n3c4ccccc4c4ccccc43)cc1O2 ; CC(C)(C)c1cc2c3c(c1)N(c1ccccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccccc1O2]

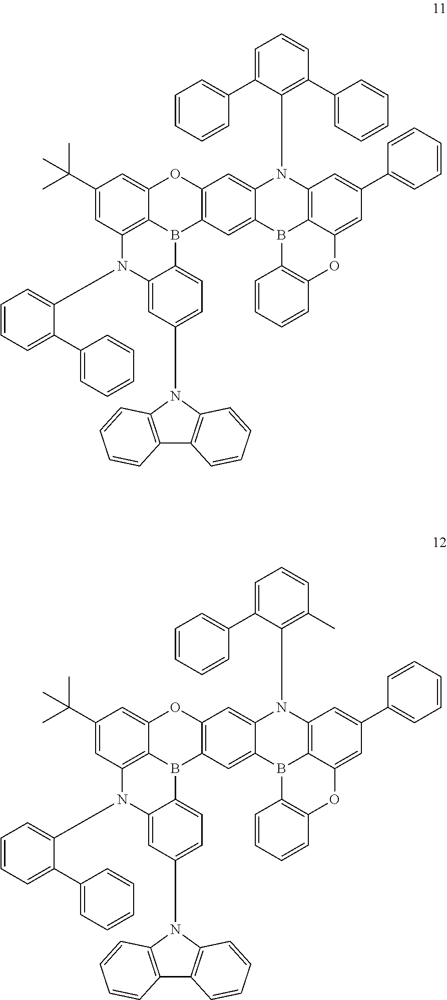 [SMILES: CC(C)(C)c1cc2c3c(c1)N(c1ccccc1-c1ccccc1)c1cc(-n4c5ccccc5c5ccccc54)ccc1B3c1cc3c(cc1O2)N(c1c(-c2ccccc2)cccc1-c1ccccc1)c1cc(-c2ccccc2)cc2c1B3c1ccccc1O2 ; Cc1cccc(-c2ccccc2)c1N1c2cc3c(cc2B2c4ccccc4Oc4cc(-c5ccccc5)cc1c42)B1c2ccc(-n4c5ccccc5c5ccccc54)cc2N(c2ccccc2-c2ccccc2)c2cc(C(C)(C)C)cc(c21)O3]

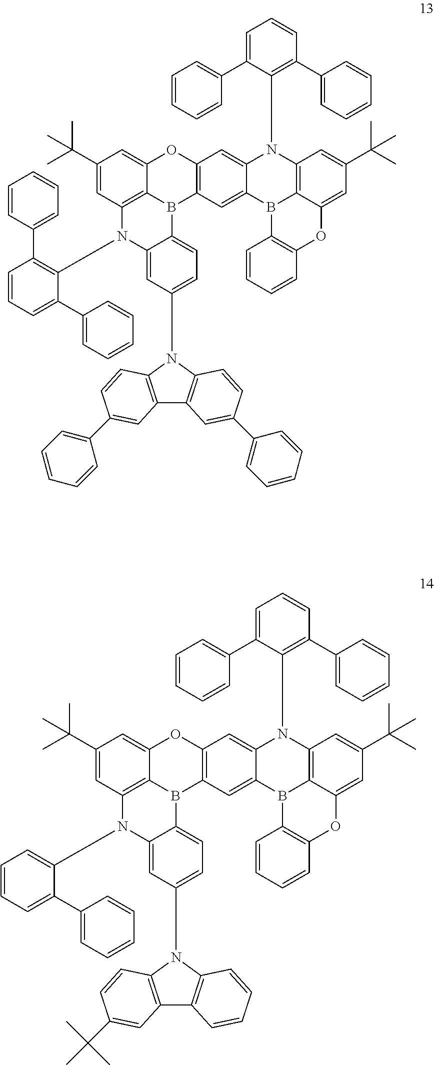 [SMILES: CC(C)(C)c1cc2c3c(c1)N(c1c(-c4ccccc4)cccc1-c1ccccc1)c1cc(-n4c5ccc(-c6ccccc6)cc5c5cc(-c6ccccc6)ccc54)ccc1B3c1cc3c(cc1O2)N(c1c(-c2ccccc2)cccc1-c1ccccc1)c1cc(C(C)(C)C)cc2c1B3c1ccccc1O2 ; CC(C)(C)c1cc2c3c(c1)N(c1ccccc1-c1ccccc1)c1cc(-n4c5ccccc5c5cc(C(C)(C)C)ccc54)ccc1B3c1cc3c(cc1O2)N(c1c(-c2ccccc2)cccc1-c1ccccc1)c1cc(C(C)(C)C)cc2c1B3c1ccccc1O2]

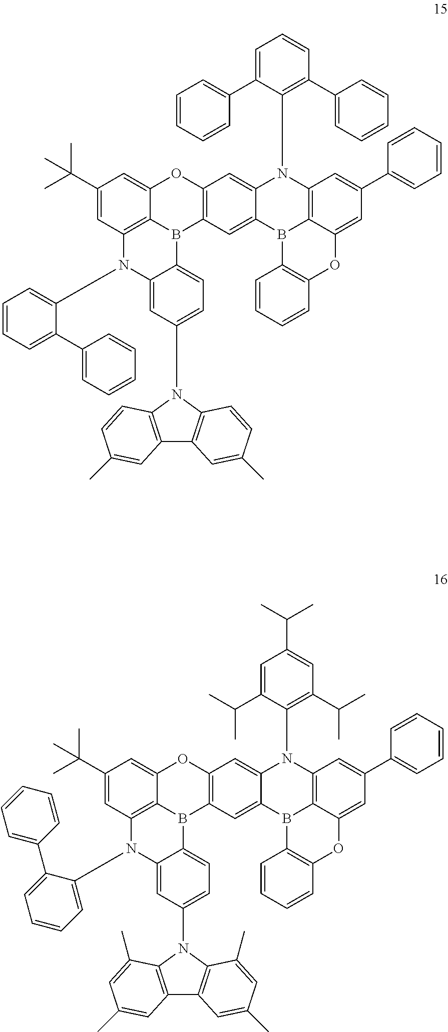 [SMILES: Cc1ccc2c(c1)c1cc(C)ccc1n2-c1ccc2c(c1)N(c1ccccc1-c1ccccc1)c1cc(C(C)(C)C)cc3c1B2c1cc2c(cc1O3)N(c1c(-c3ccccc3)cccc1-c1ccccc1)c1cc(-c3ccccc3)cc3c1B2c1ccccc1O3 ; Cc1cc(C)c2c(c1)c1cc(C)cc(C)c1n2-c1ccc2c(c1)N(c1ccccc1-c1ccccc1)c1cc(C(C)(C)C)cc3c1B2c1cc2c(cc1O3)N(c1c(C(C)C)cc(C(C)C)cc1C(C)C)c1cc(-c3ccccc3)cc3c1B2c1ccccc1O3]

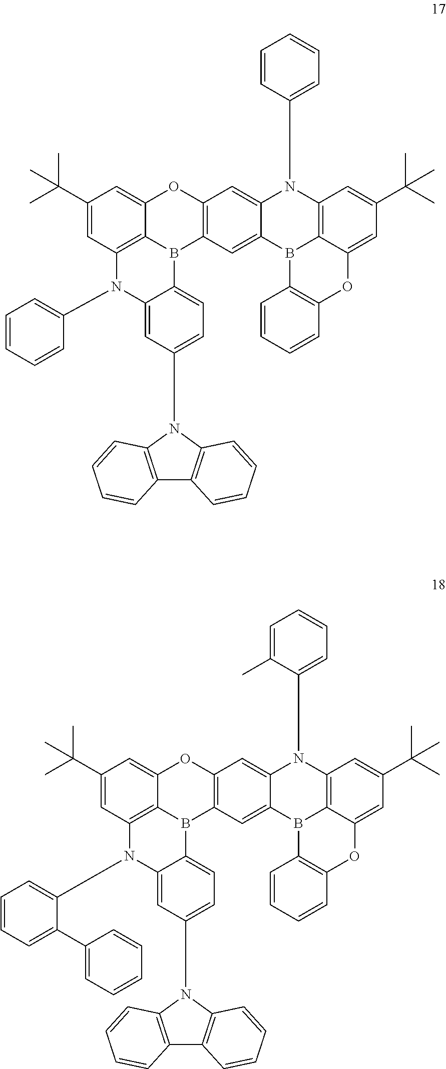 [SMILES: CC(C)(C)c1cc2c3c(c1)N(c1ccccc1)c1cc(-n4c5ccccc5c5ccccc54)ccc1B3c1cc3c(cc1O2)N(c1ccccc1)c1cc(C(C)(C)C)cc2c1B3c1ccccc1O2 ; Cc1ccccc1N1c2cc3c(cc2B2c4ccccc4Oc4cc(C(C)(C)C)cc1c42)B1c2ccc(-n4c5ccccc5c5ccccc54)cc2N(c2ccccc2-c2ccccc2)c2cc(C(C)(C)C)cc(c21)O3]

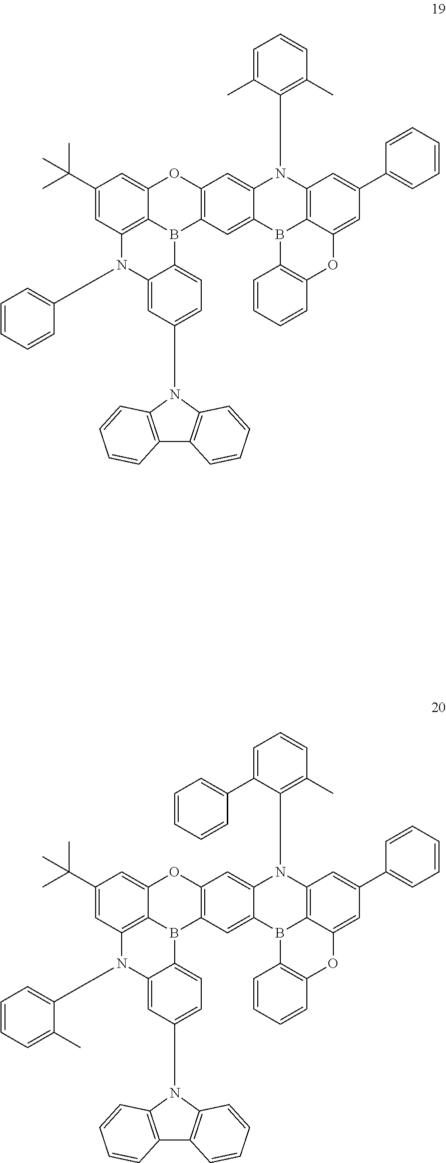 [SMILES: Cc1cccc(C)c1N1c2cc3c(cc2B2c4ccccc4Oc4cc(-c5ccccc5)cc1c42)B1c2ccc(-n4c5ccccc5c5ccccc54)cc2N(c2ccccc2)c2cc(C(C)(C)C)cc(c21)O3 ; Cc1ccccc1N1c2cc(-n3c4ccccc4c4ccccc43)ccc2B2c3cc4c(cc3Oc3cc(C(C)(C)C)cc1c32)N(c1c(C)cccc1-c1ccccc1)c1cc(-c2ccccc2)cc2c1B4c1ccccc1O2]

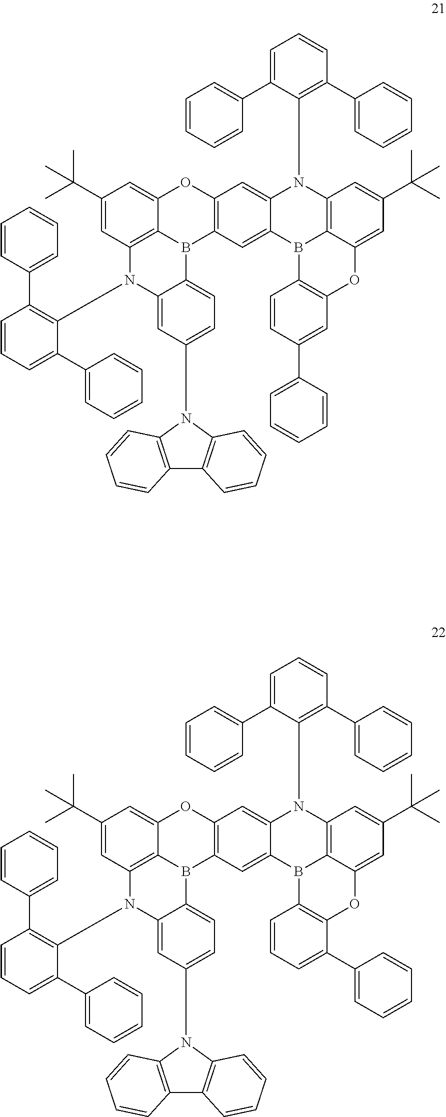 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccc(-c3ccccc3)cc1O2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1cccc(-c3ccccc3)c1O2]

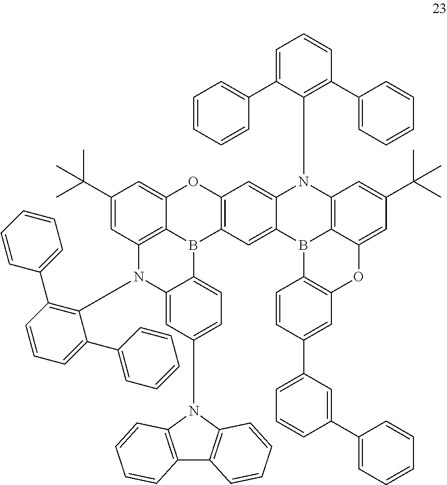 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccc(-c3cccc(-c4ccccc4)c3)cc1O2]

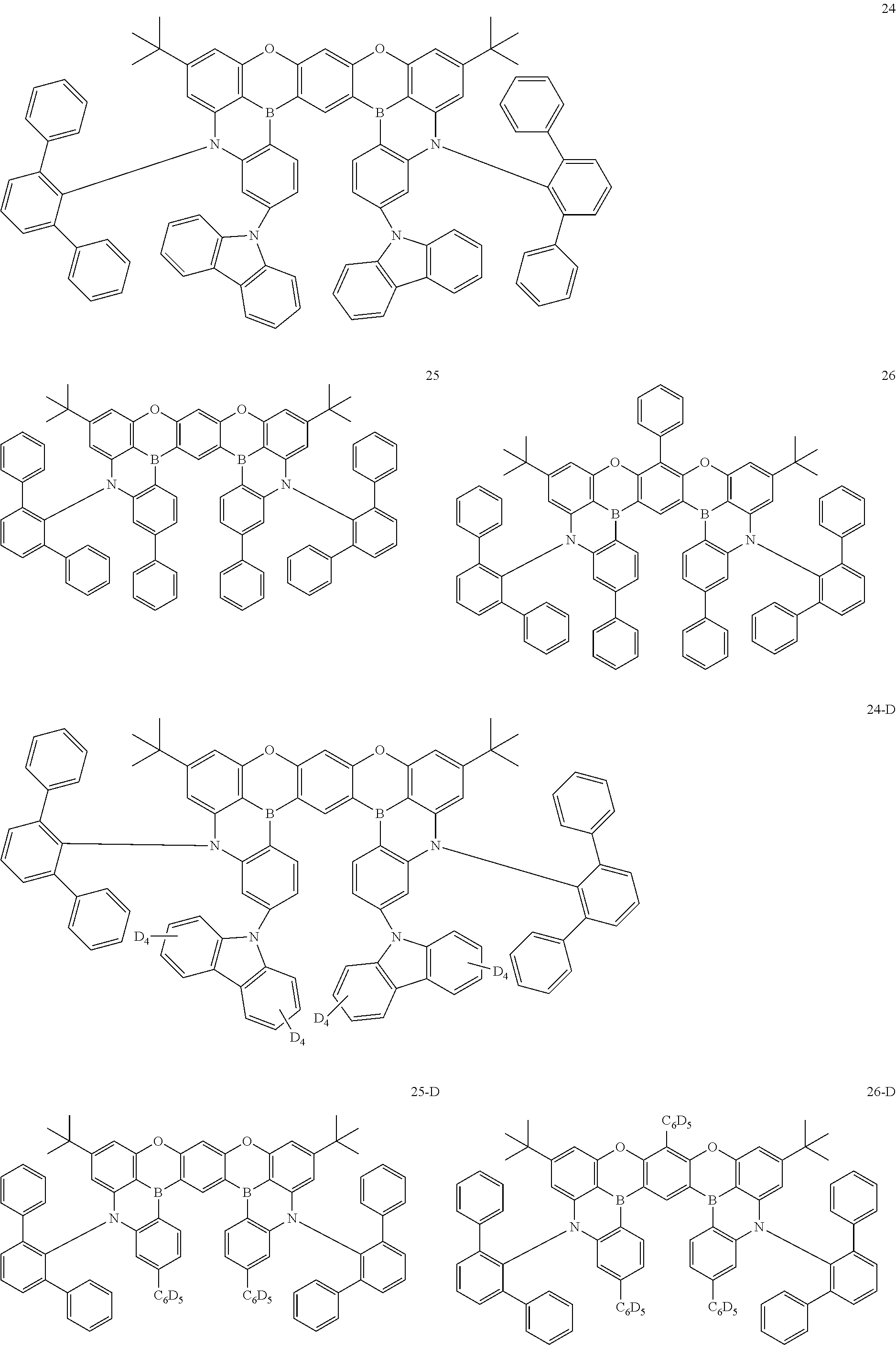

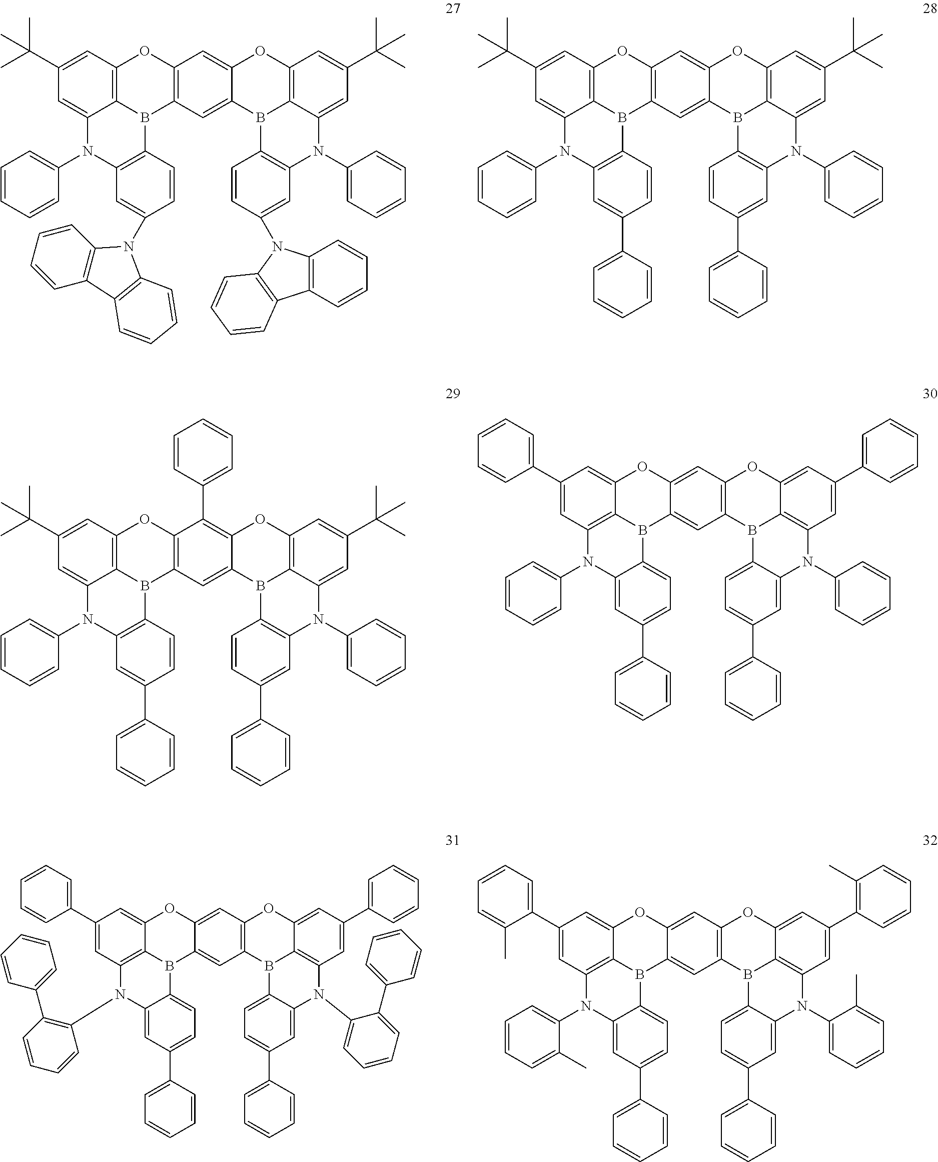

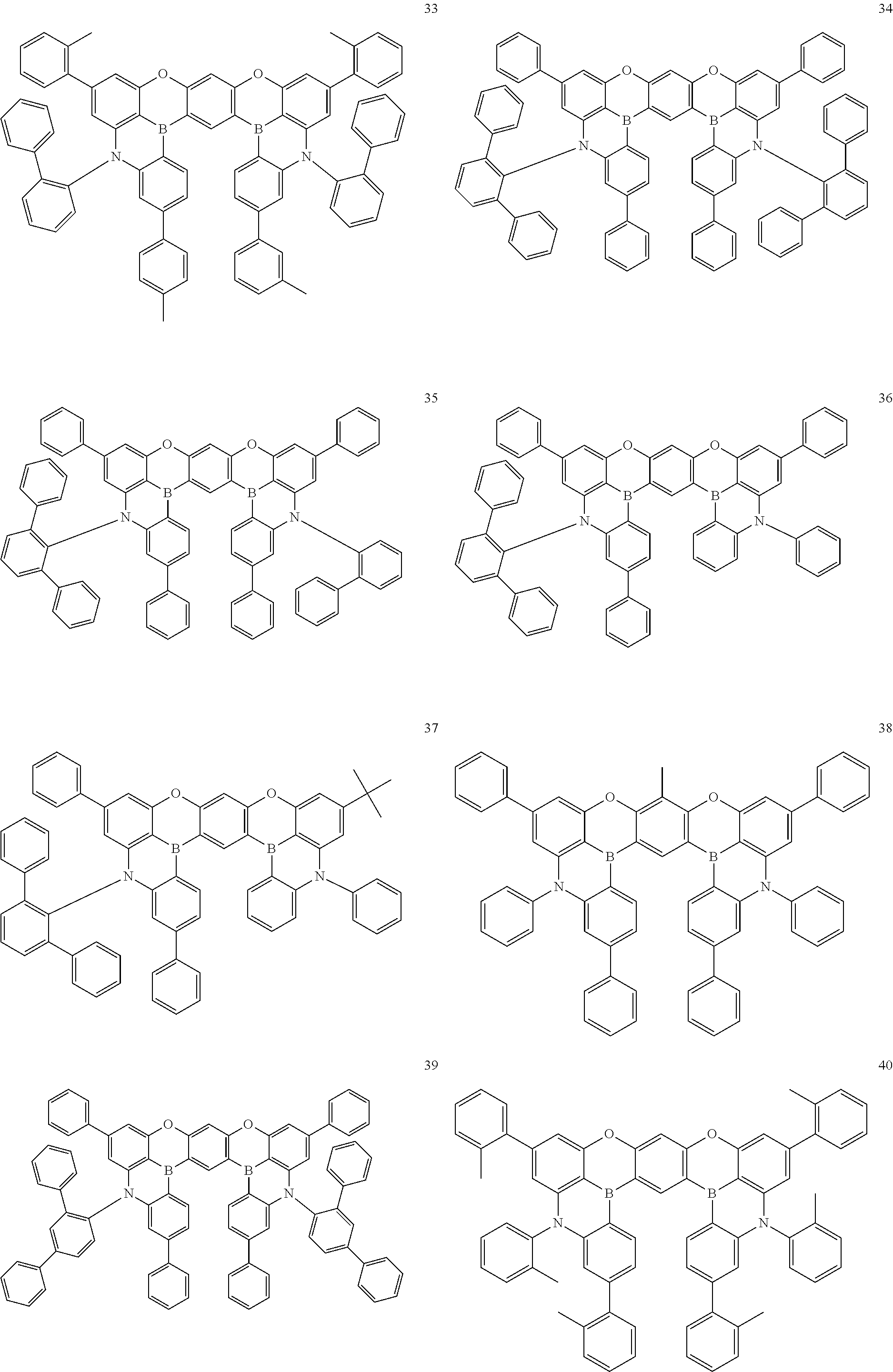

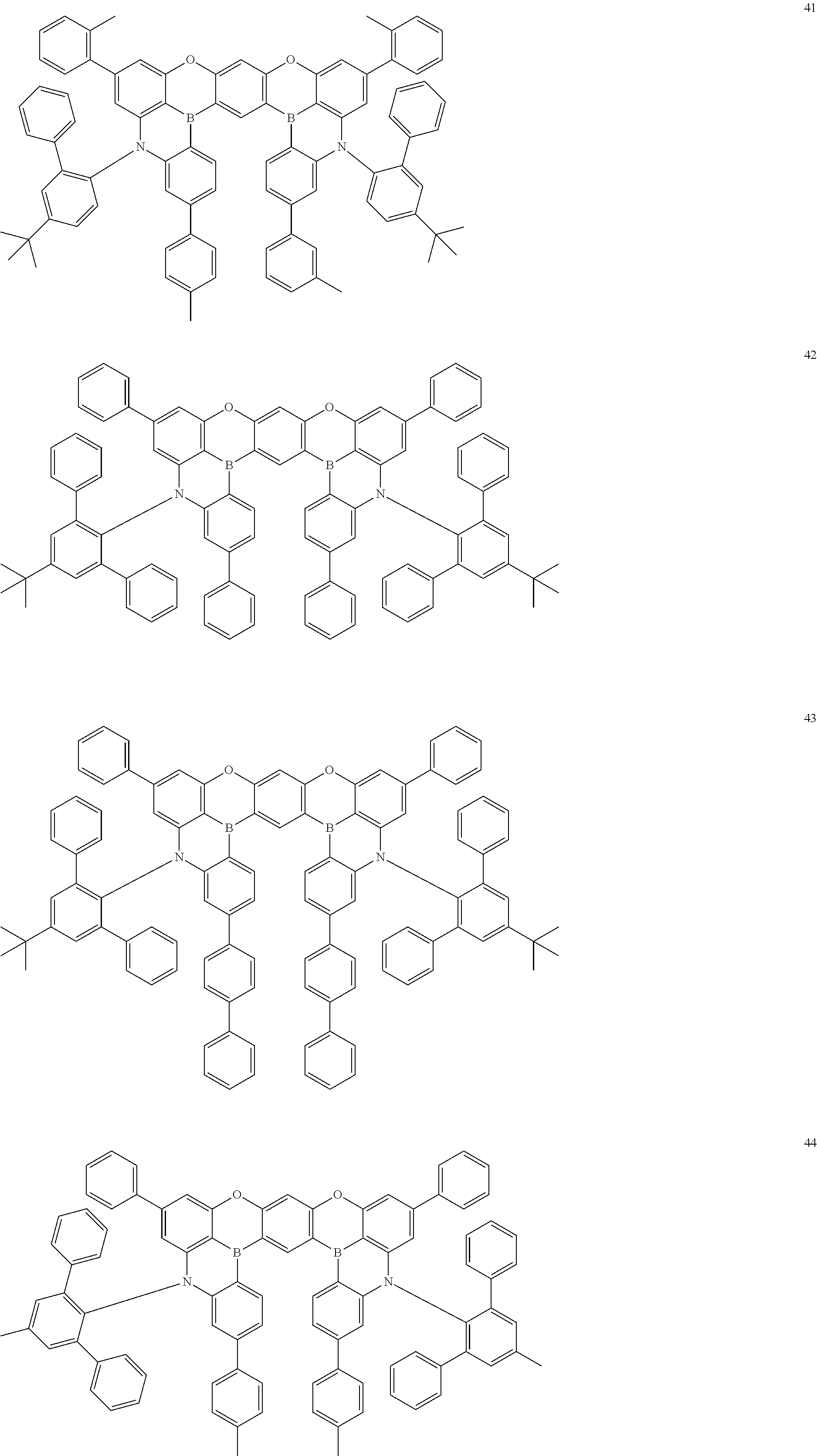

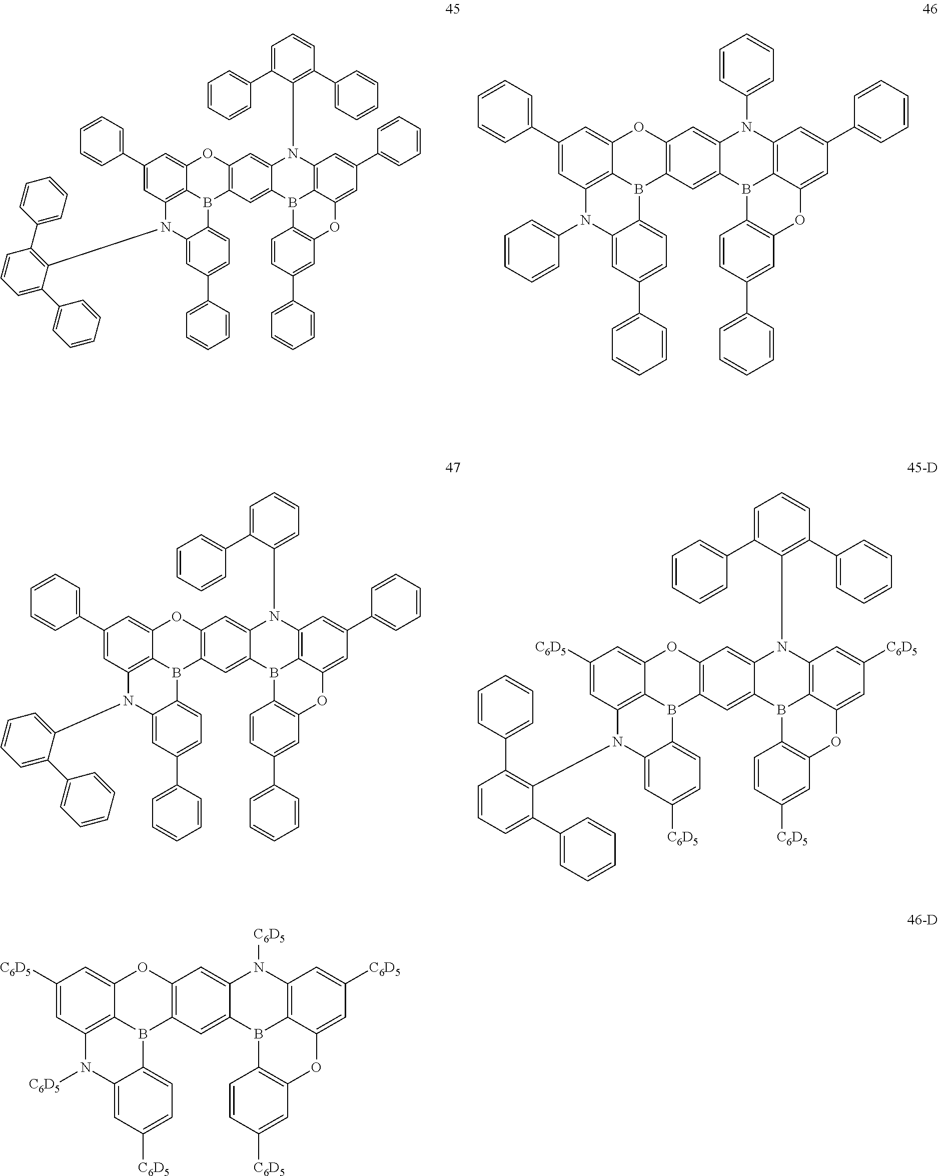

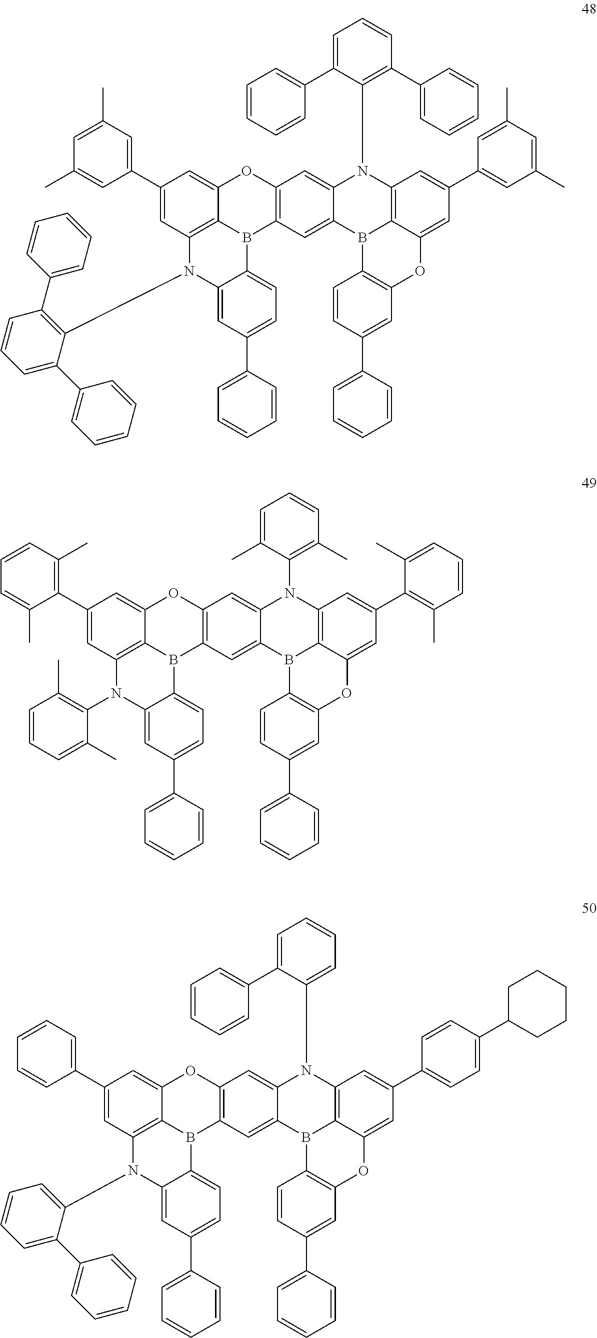 [SMILES: Cc1cc(C)cc(-c2cc3c4c(c2)N(c2c(-c5ccccc5)cccc2-c2ccccc2)c2cc(-c5ccccc5)ccc2B4c2cc4c(cc2O3)N(c2c(-c3ccccc3)cccc2-c2ccccc2)c2cc(-c3cc(C)cc(C)c3)cc3c2B4c2ccc(-c4ccccc4)cc2O3)c1 ; Cc1cccc(C)c1-c1cc2c3c(c1)N(c1c(C)cccc1C)c1cc(-c4ccccc4)ccc1B3c1cc3c(cc1O2)N(c1c(C)cccc1C)c1cc(-c2c(C)cccc2C)cc2c1B3c1ccc(-c3ccccc3)cc1O2 ; c1ccc(-c2ccc3c(c2)Oc2cc(-c4ccc(C5CCCCC5)cc4)cc4c2B3c2cc3c(cc2N4c2ccccc2-c2ccccc2)Oc2cc(-c4ccccc4)cc4c2B3c2ccc(-c3ccccc3)cc2N4c2ccccc2-c2ccccc2)cc1]

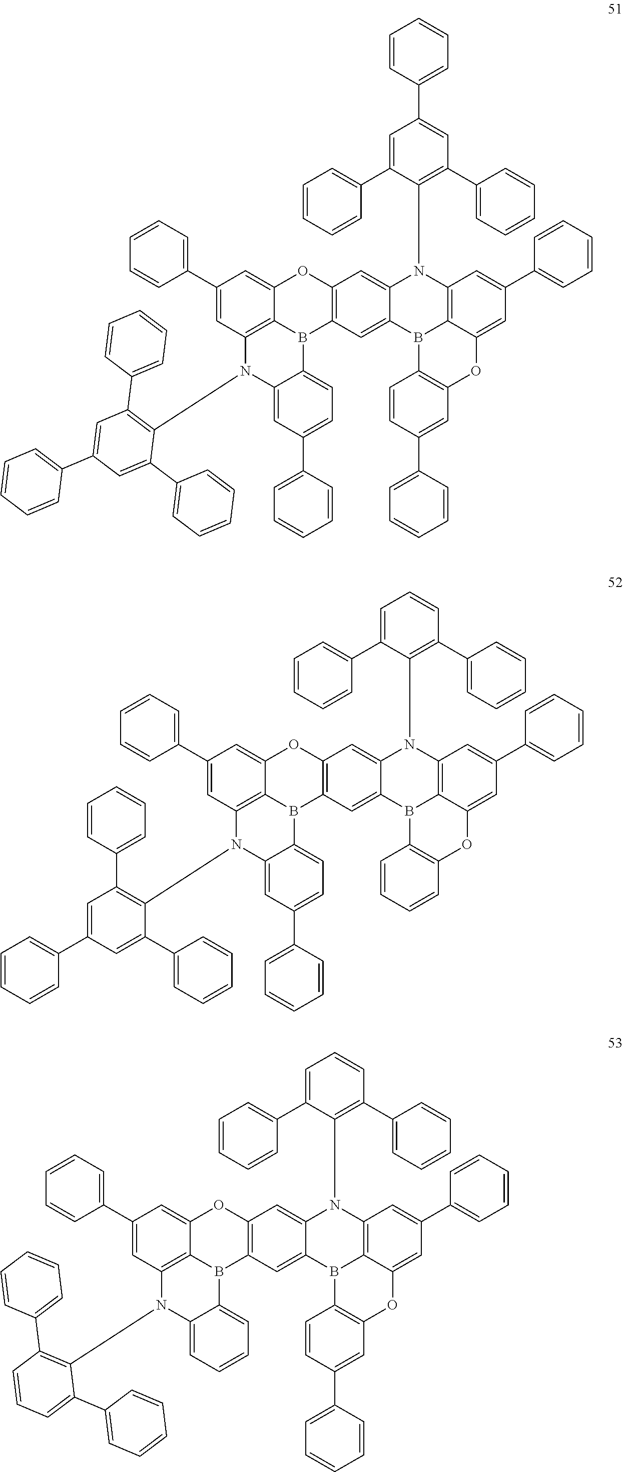 [SMILES: c1ccc(-c2ccc3c(c2)Oc2cc(-c4ccccc4)cc4c2B3c2cc3c(cc2N4c2c(-c4ccccc4)cc(-c4ccccc4)cc2-c2ccccc2)Oc2cc(-c4ccccc4)cc4c2B3c2ccc(-c3ccccc3)cc2N4c2c(-c3ccccc3)cc(-c3ccccc3)cc2-c2ccccc2)cc1 ; c1ccc(-c2cc(-c3ccccc3)c(N3c4cc(-c5ccccc5)ccc4B4c5cc6c(cc5Oc5cc(-c7ccccc7)cc3c54)N(c3c(-c4ccccc4)cccc3-c3ccccc3)c3cc(-c4ccccc4)cc4c3B6c3ccccc3O4)c(-c3ccccc3)c2)cc1 ; c1ccc(-c2ccc3c(c2)Oc2cc(-c4ccccc4)cc4c2B3c2cc3c(cc2N4c2c(-c4ccccc4)cccc2-c2ccccc2)Oc2cc(-c4ccccc4)cc4c2B3c2ccccc2N4c2c(-c3ccccc3)cccc2-c2ccccc2)cc1]

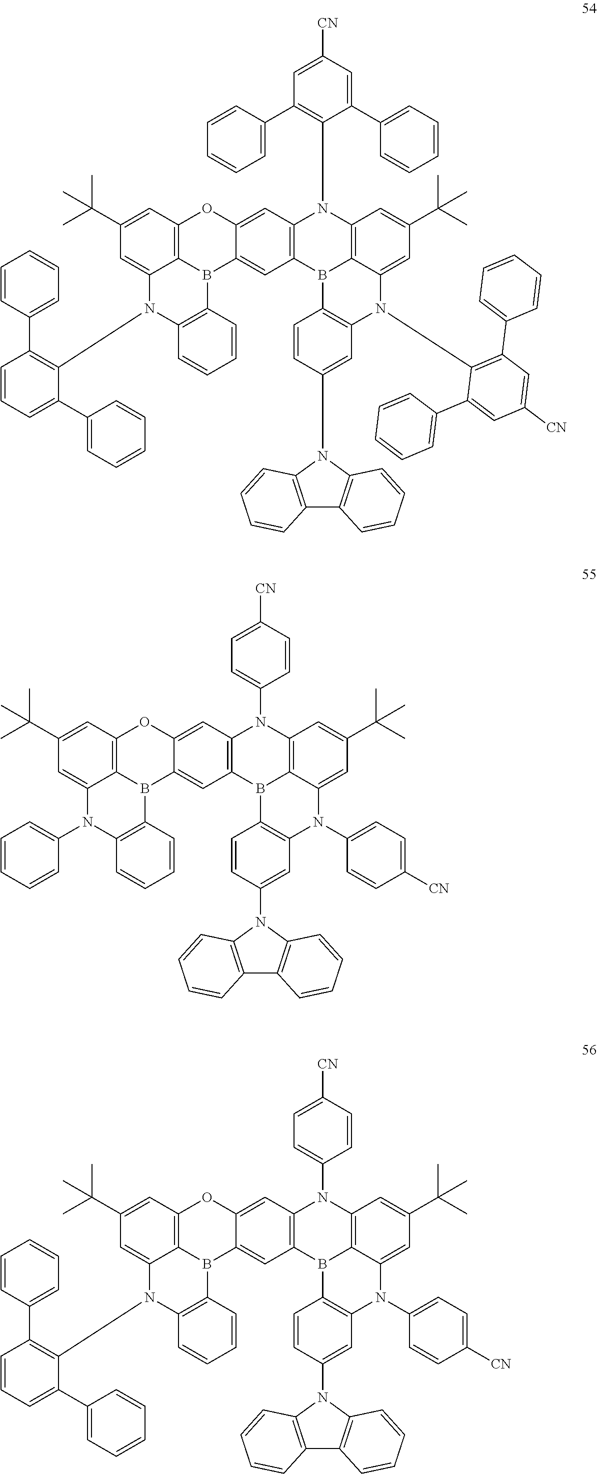 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccc(-n3c4ccccc4c4ccccc43)cc1N2c1c(-c2ccccc2)cc(C#N)cc1-c1ccccc1 ; CC(C)(C)c1cc2c3c(c1)N(c1ccccc1)c1ccccc1B3c1cc3c(cc1O2)N(c1ccc(C#N)cc1)c1cc(C(C)(C)C)cc2c1B3c1ccc(-n3c4ccccc4c4ccccc43)cc1N2c1ccc(C#N)cc1 ; CC(C)(C)c1cc2c3c(c1)N(c1c(-c4ccccc4)cccc1-c1ccccc1)c1ccccc1B3c1cc3c(cc1O2)N(c1ccc(C#N)cc1)c1cc(C(C)(C)C)cc2c1B3c1ccc(-n3c4ccccc4c4ccccc43)cc1N2c1ccc(C#N)cc1]

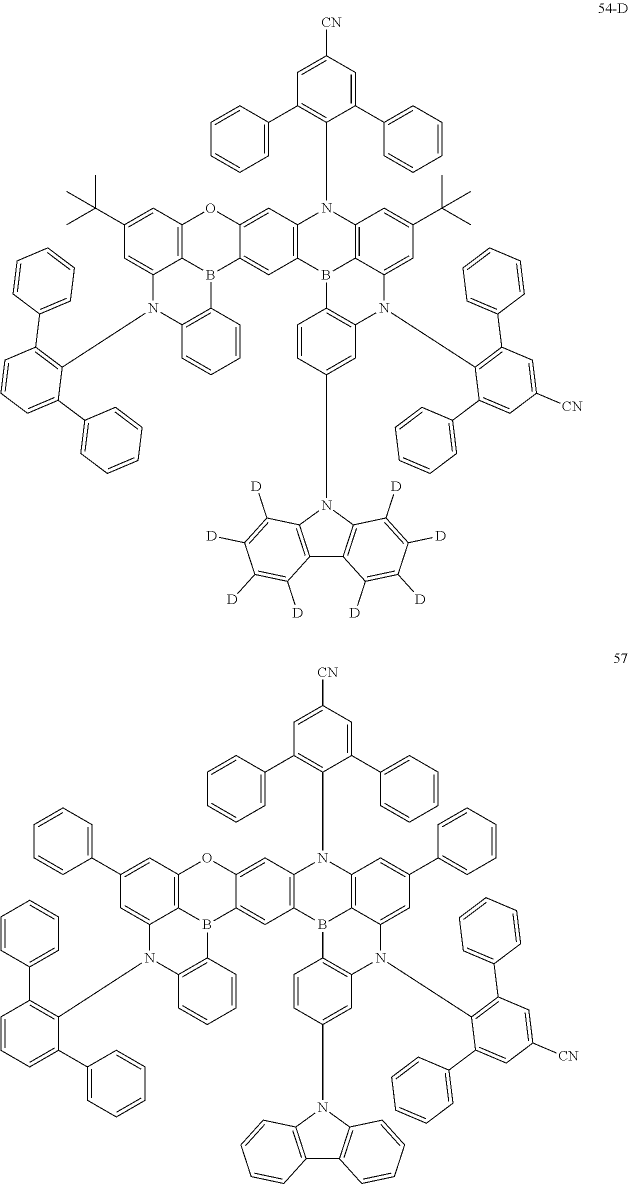 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C#N)cc1-c1ccccc1)c1cc(C(C)(C)C)cc3c1B2c1cc2c(cc1N3c1c(-c3ccccc3)cc(C#N)cc1-c1ccccc1)Oc1cc(C(C)(C)C)cc3c1B2c1ccccc1N3c1c(-c2ccccc2)cccc1-c1ccccc1 ; N#Cc1cc(-c2ccccc2)c(N2c3cc(-n4c5ccccc5c5ccccc54)ccc3B3c4cc5c(cc4N(c4c(-c6ccccc6)cc(C#N)cc4-c4ccccc4)c4cc(-c6ccccc6)cc2c43)Oc2cc(-c3ccccc3)cc3c2B5c2ccccc2N3c2c(-c3ccccc3)cccc2-c2ccccc2)c(-c2ccccc2)c1]

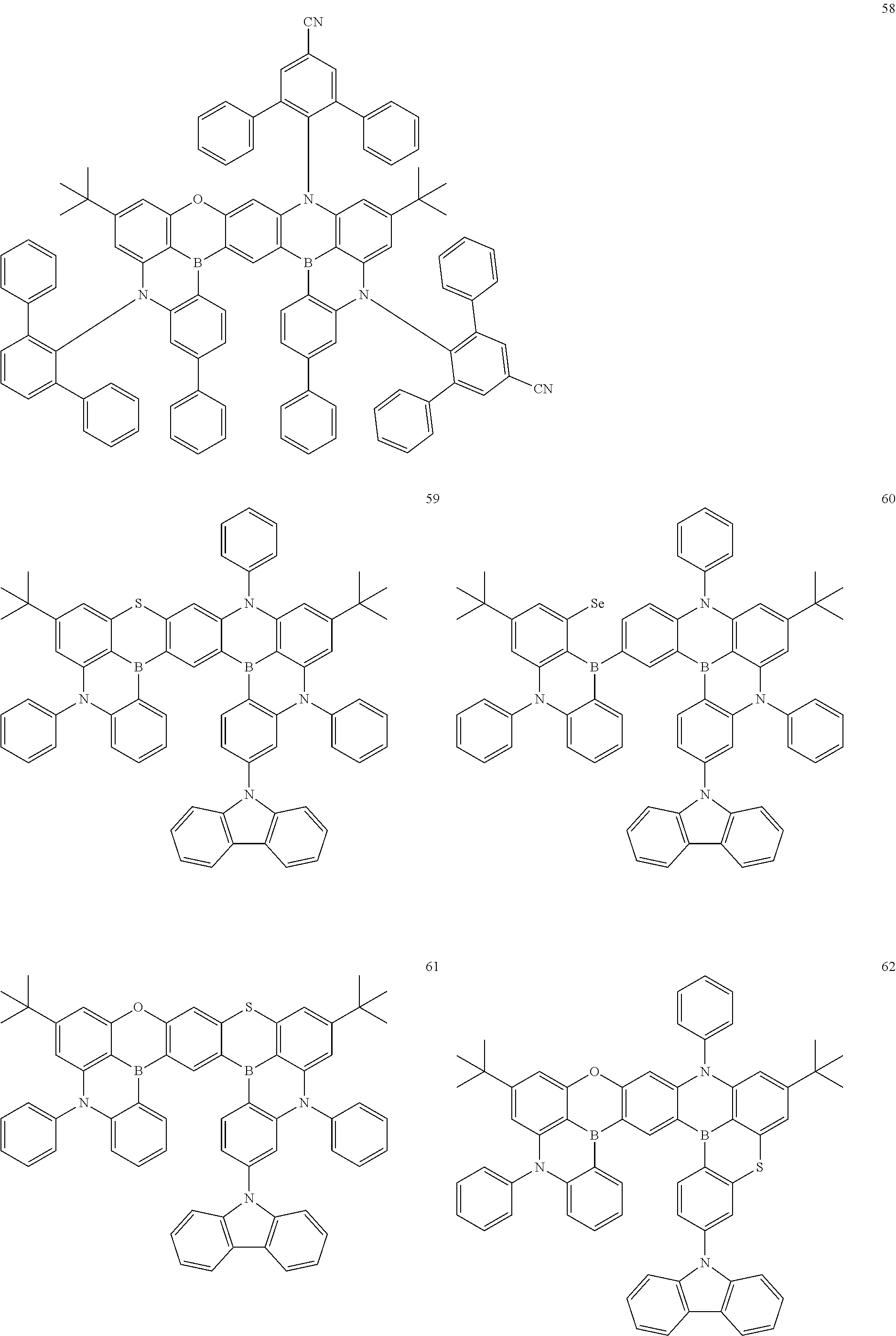

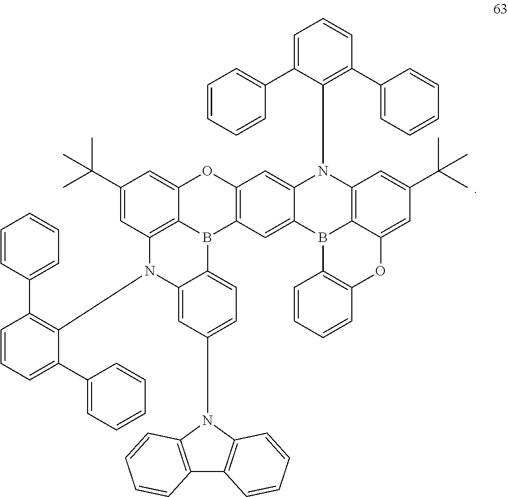 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccccc1O2]

In Compound Group 1. D represents a deuterium atom.

The fused polycyclic compound may contribute to high efficiency and long lifespan in the light emitting element ED by having a structure in which the first substituent and the second substituent are connected to positions of the fused ring core as described herein.

The fused polycyclic compound according to an embodiment may include a fused ring core formed by nine rings that are condensed together with two boron atoms and four heteroatoms, and the fused polycyclic compound may include first and second substituents that are connected to positions of the fused ring core as described herein. The fused polycyclic compound according to an embodiment may exhibit excellent molecular stability due to the structure and connection position of the first and second substituents, which may contribute to high efficiency and long lifespan of the light emitting element ED.

The fused polycyclic compound may effectively maintain a trigonal planar structure of a boron atom through a steric hindrance effect of the first and second substituents. A boron atom has electron-deficiency properties due to an empty p-orbital, and thus, may form a bond with another nucleophile that would change the trigonal planar structure into a tetrahedral structure, thereby contributing to deterioration of the light emitting element. Since the fused polycyclic compound represented by Formula 1 includes the first and second substituents, the empty p-orbital of the boron atoms may be effectively protected, thereby preventing deterioration due to structural deformation.

The fused polycyclic compound may control or limit the formation of excimers and exciplexes by suppressing intermolecular interactions due to the introduction of the first and second substituents, so that luminous efficiency may be increased. The fused polycyclic compound represented by Formula 1 includes the first and second substituents, which increases intermolecular distance, thereby reducing the occurrence of Dexter energy transfer. Dexter energy transfer is a phenomenon in which a triplet exciton is transferred between molecules, which increases when intermolecular distance is short, and may be a factor for increasing quenching caused by an increase in triplet concentration. According to embodiments, the fused polycyclic compound has a structure with high steric hindrance, which increases intermolecular distance between adjacent molecules, thereby suppressing Dexter energy transfer, and thus, may suppress deterioration of lifespan caused by increased triplet concentration. Therefore, when the fused polycyclic compound is applied to a light emitting layer EML of the light emitting element ED, luminous efficiency may be increased, and the lifespan of the element may also be improved.

The emission spectrum of the fused polycyclic compound represented by Formula 1 may have a full width at half maximum (FWHM) in a range of about 10 nm to about 50 nm. For example, the emission spectrum of the fused polycyclic compound may have a full width at half maximum in a range of about 20 nm to about 40 nm. As the emission spectrum of the fused polycyclic compound represented by Formula 1 has a full width at half maximum in the above-described range, and luminous efficiency may be improved in a light emitting element that includes the fused polycyclic compound. When the fused polycyclic compound is used as a material for a blue light emitting element, the lifespan of the element may be improved.

In an embodiment, the fused polycyclic compound represented by Formula 1 may be a thermally activated delayed fluorescence (TADF) light emitting material. The fused polycyclic compound represented by Formula 1 may be a thermally activated delayed fluorescence dopant having a difference (ΔE_{ST}) between a lowest triplet excitation energy level (T1) and a lowest singlet excitation energy level (S1) equal to or less than about 0.6 eV. In an embodiment, the fused polycyclic compound represented by Formula 1 may be a thermally activated delayed fluorescence dopant having a difference (ΔE_{ST}) between a lowest triplet excitation energy level T1 and a lowest singlet excitation energy level (S1) equal to or less than about 0.2 eV. However, embodiments are not limited thereto.

In an embodiment, the fused polycyclic compound may include the first substituent and the second substituent. By controlling the number and bonding position of the first substituent and the second substituent, the overall singlet energy level and triplet energy level of the compound may be suitably controlled. Accordingly, the fused polycyclic compound may exhibit improved thermally activated delayed fluorescence properties.

The fused polycyclic compound represented by Formula 1 may be a light emitting material that emits light having a central wavelength in a range of about 430 nm to about 490 nm. For example, the fused polycyclic compound represented by Formula 1 may be used as a blue thermally activated delayed fluorescence (TADF) dopant. However, embodiments are not limited thereto, and when the fused polycyclic compound of an embodiment is used as a light emitting material, the fused polycyclic compound may be used as a dopant material for emitting light in various wavelength regions, such as a red light emitting dopant, a green light emitting dopant, or the like.

In the light emitting element ED, the light emitting layer EML may emit delayed fluorescence. For example, the light emitting layer EML may emit thermally activated delayed fluorescence (TADF).

The light emitting layer EML of the light emitting element ED may emit blue light. For example, the light emitting layer EML of the light emitting element ED of an embodiment may emit blue light having a wavelength equal to or less than about 490 nm. However, embodiments are not limited thereto, and the light emitting layer EML may emit green light or red light.

In an embodiment, the light emitting layer EML may include the fused polycyclic compound according to an embodiment. The fused polycyclic compound may be included in the light emitting layer EML as a dopant material. The fused polycyclic compound may be a thermally activated delayed fluorescence material. The fused polycyclic compound may be used as a thermally activated delayed fluorescence dopant. For example, in the light emitting element ED, the light emitting layer EML may include at least one fused polycyclic compound selected from Compound Group 1 as a thermally activated delayed fluorescence dopant. However, the use of the fused polycyclic compound is not limited thereto.

In an embodiment, the light emitting layer EML may include multiple compounds. In an embodiment, the light emitting layer EML may include the fused polycyclic compound represented by Formula 1 as a first compound, and at least one of a second compound represented by Formula HT-1, a third compound represented by Formula ET-1 and a fourth compound represented by Formula D-1.

In an embodiment, the light emitting layer EML may include the first compound represented by Formula 1, and may further include at least one of a second compound represented by Formula HT-1 and a third compound represented by Formula ET-1.

In an embodiment, the light emitting layer EML may further include a second compound represented by Formula HT-1. In an embodiment, the second compound may be used as a hole transport host material in the light emitting layer EML:

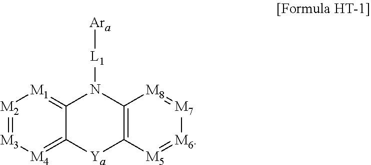

In Formula HT-1, M₁ to Ms may each independently be N or C(R₅₁). For example, M₁ to M₈ may each independently be C(R₅₁). As another example, any one of M₁ to M₈ may be N, and the remainder of M₁ to Ms may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom of Formula HT-1 may be connected to each other via a direct linkage,

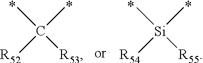

In Formula HT-1, if Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or form a ring by being bonded to an adjacent group. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2:

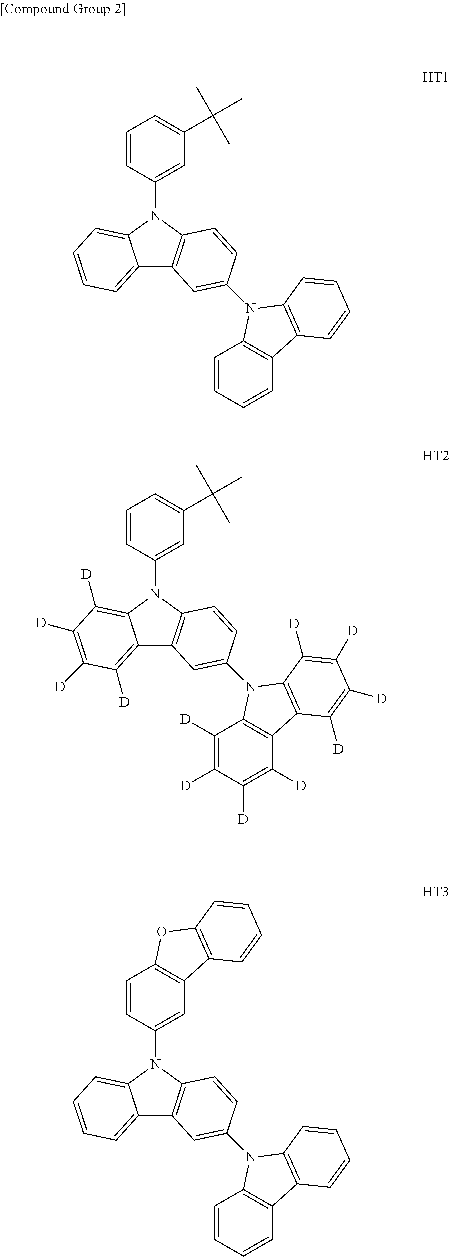 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

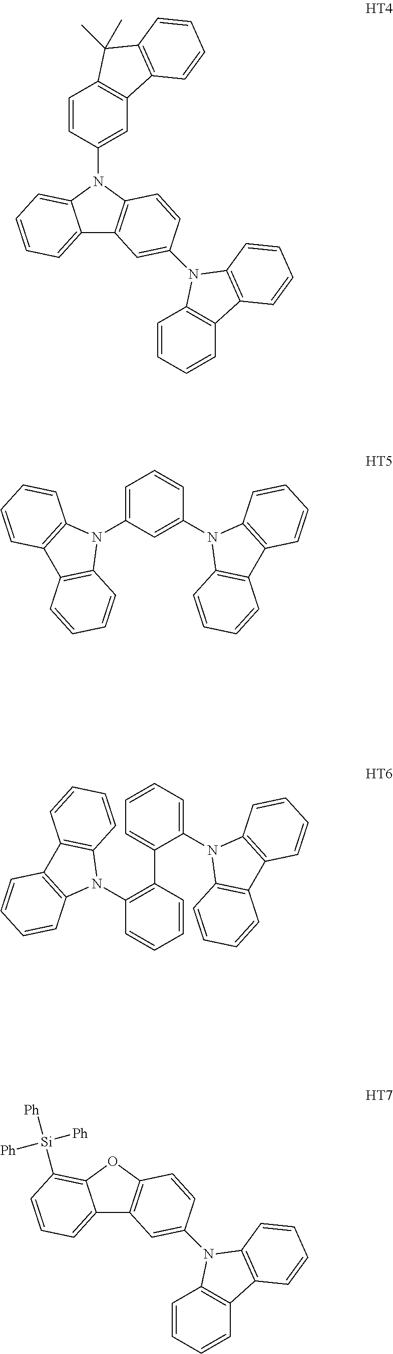 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

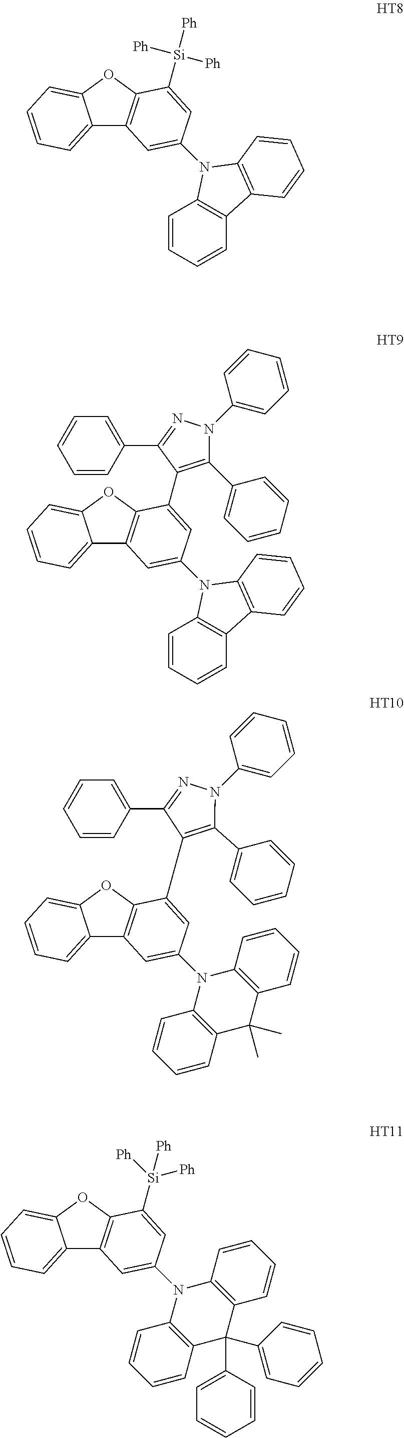 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

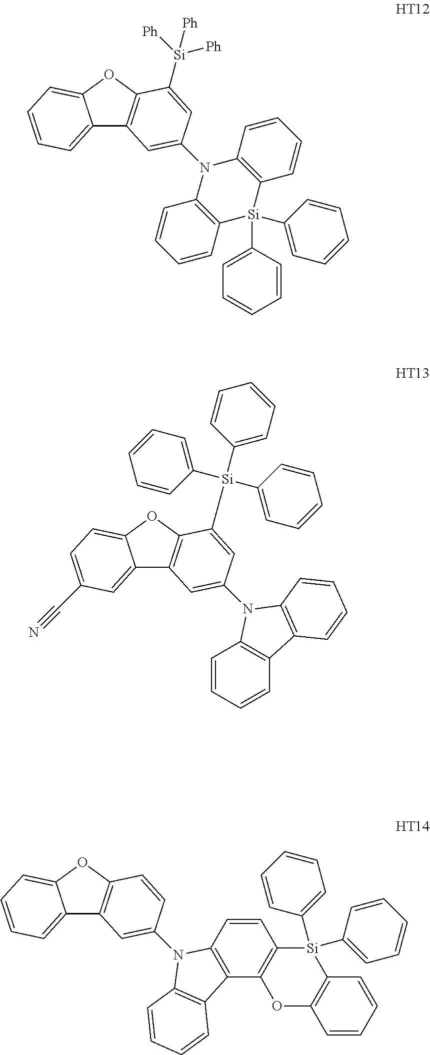 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

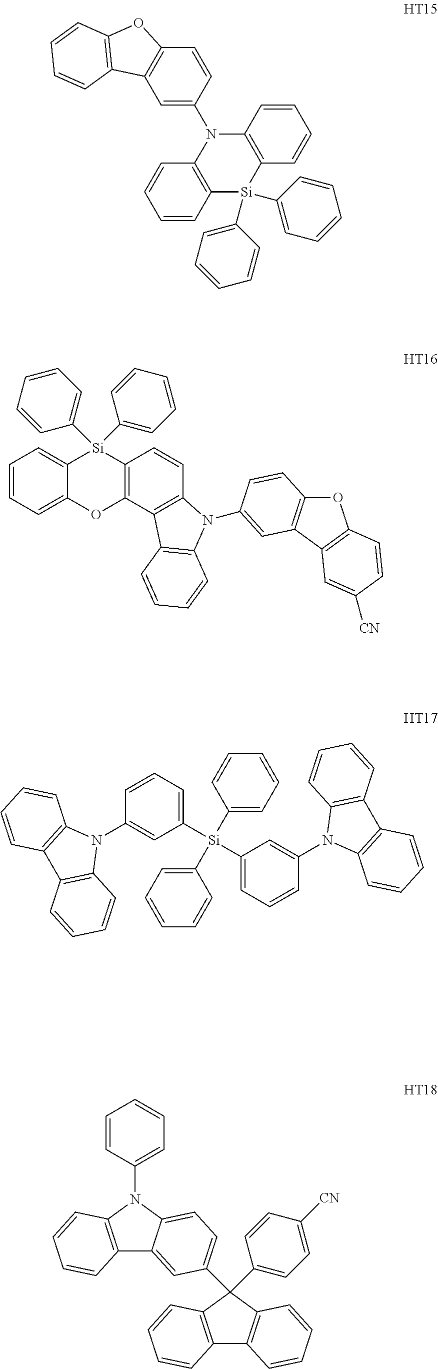 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

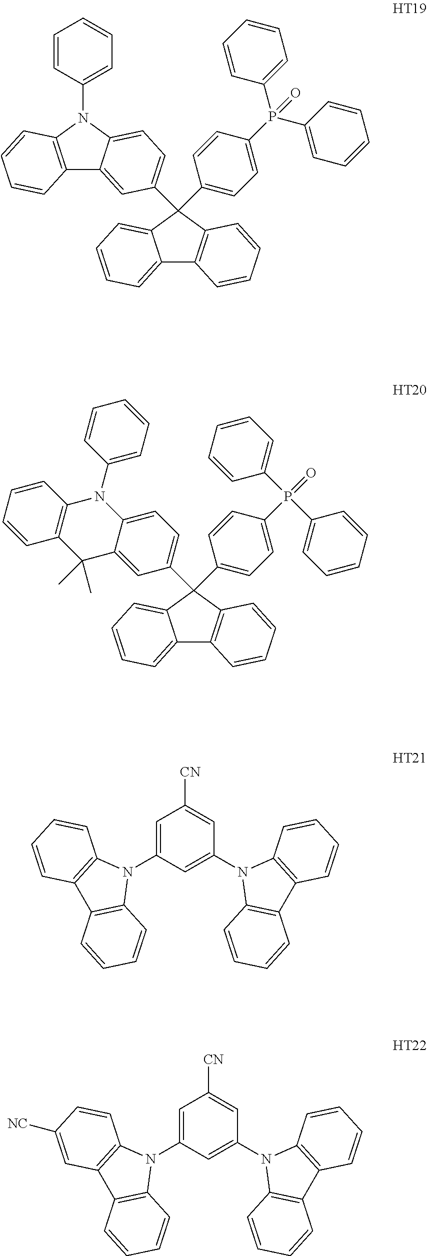 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

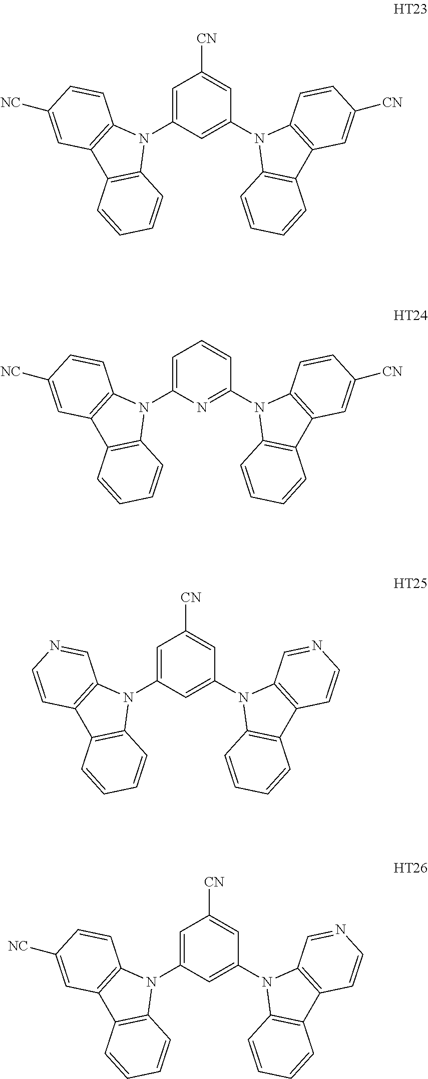 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

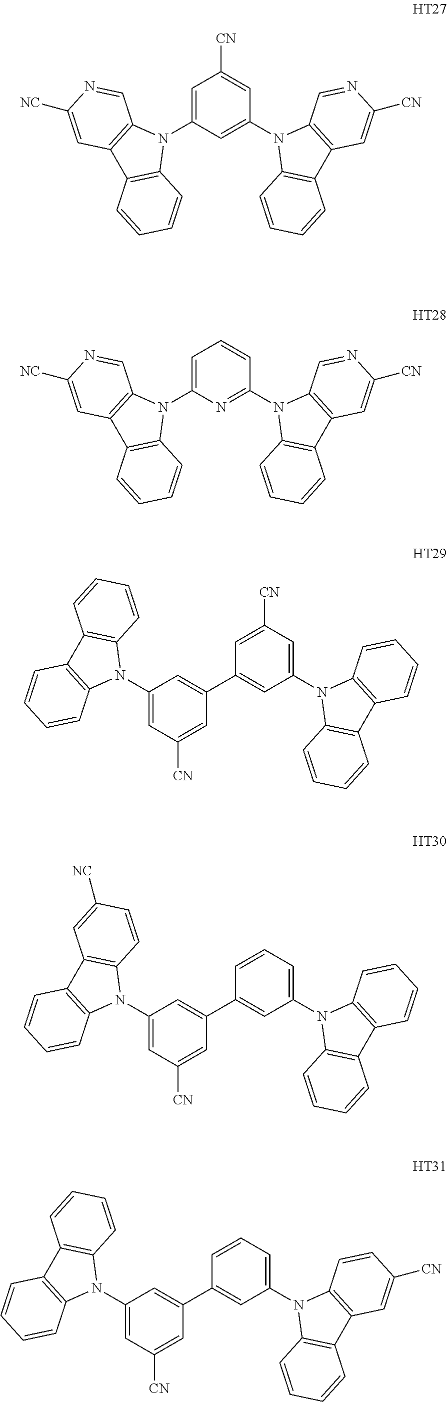 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

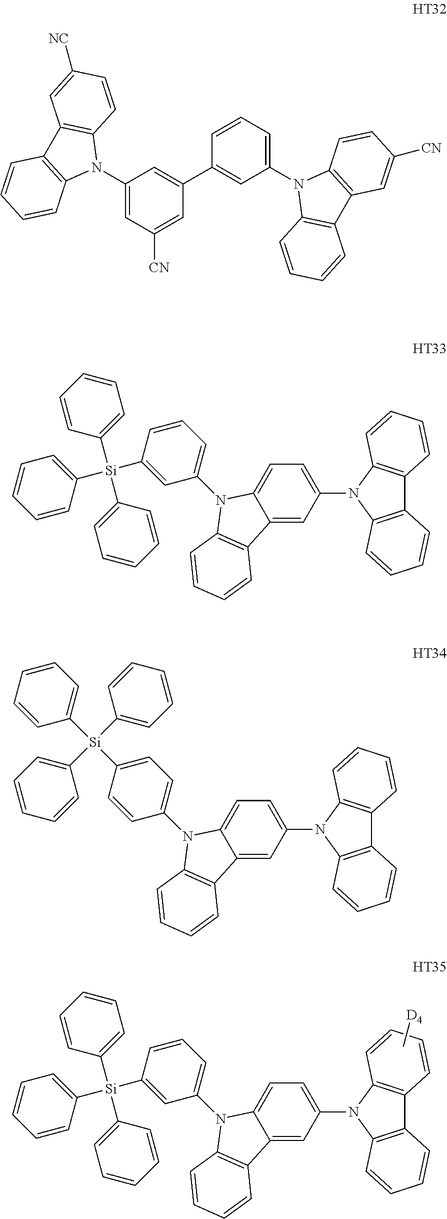

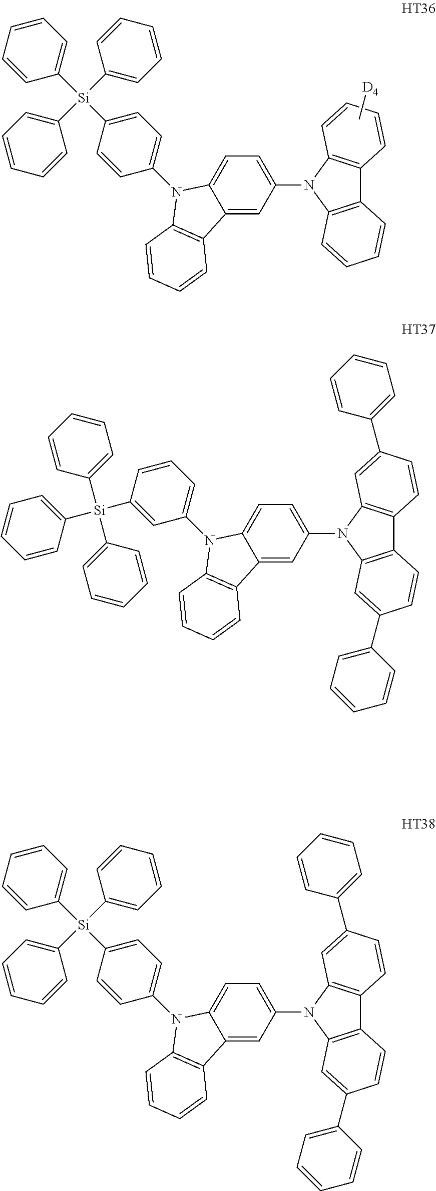

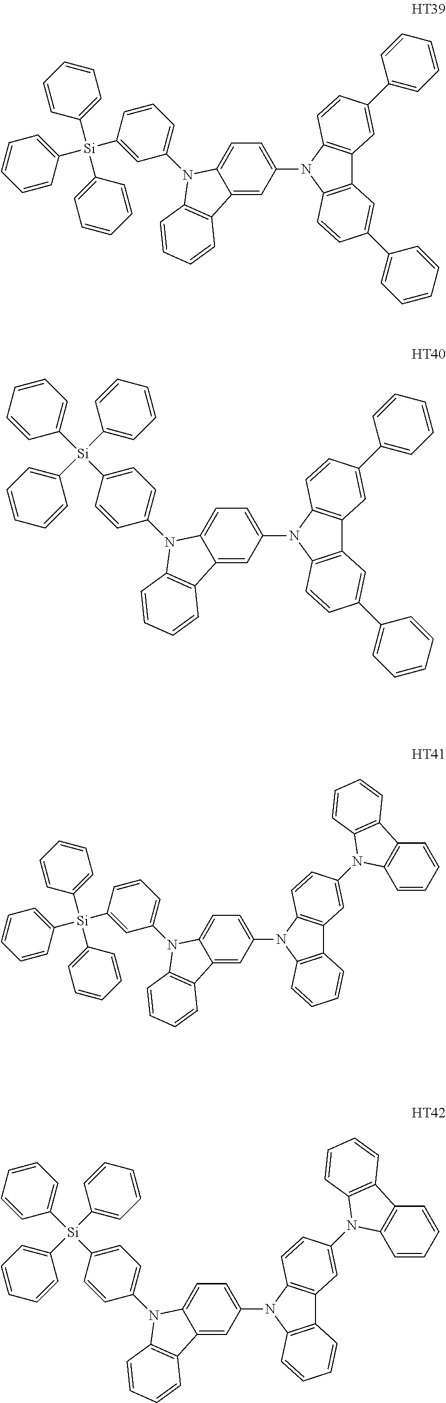 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

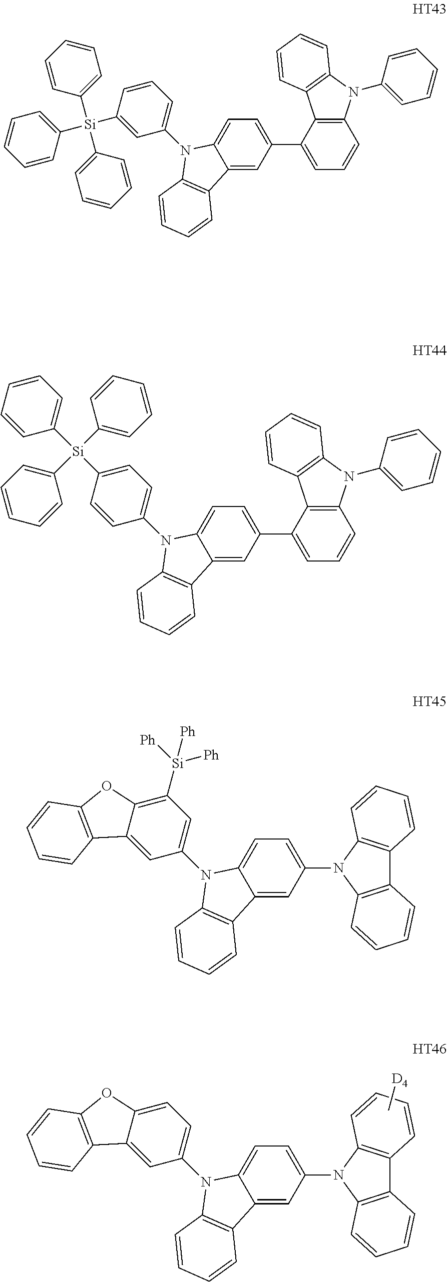

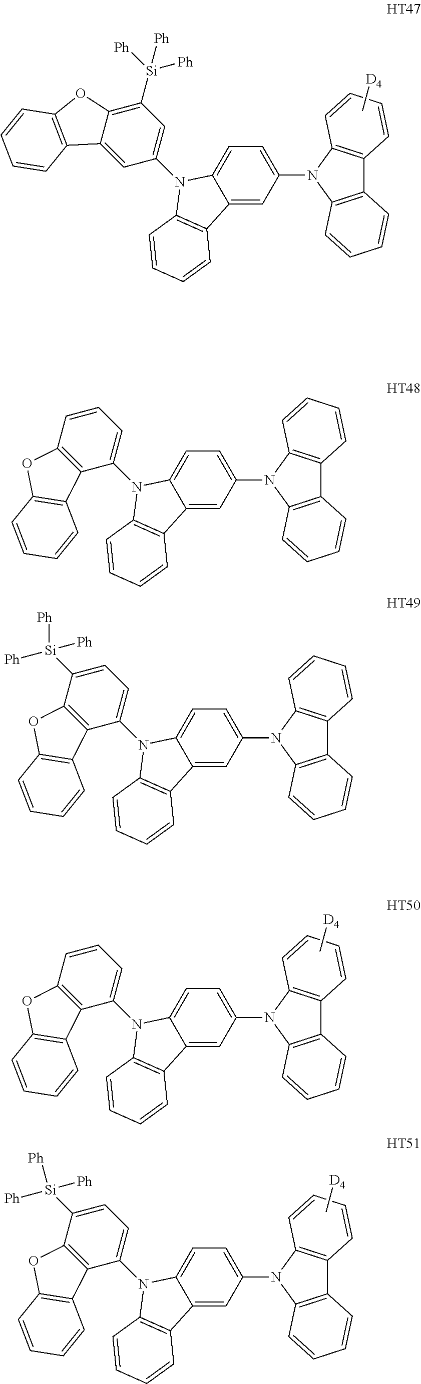

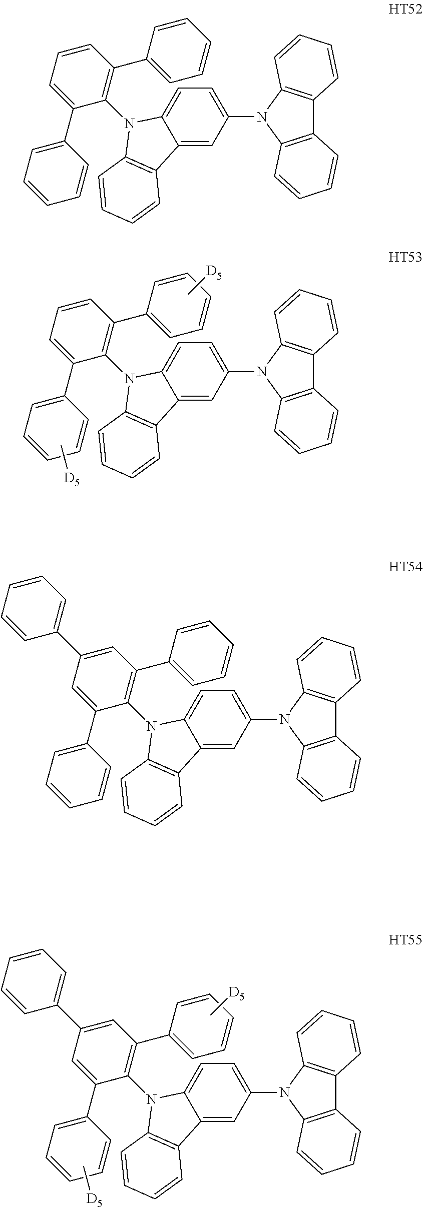

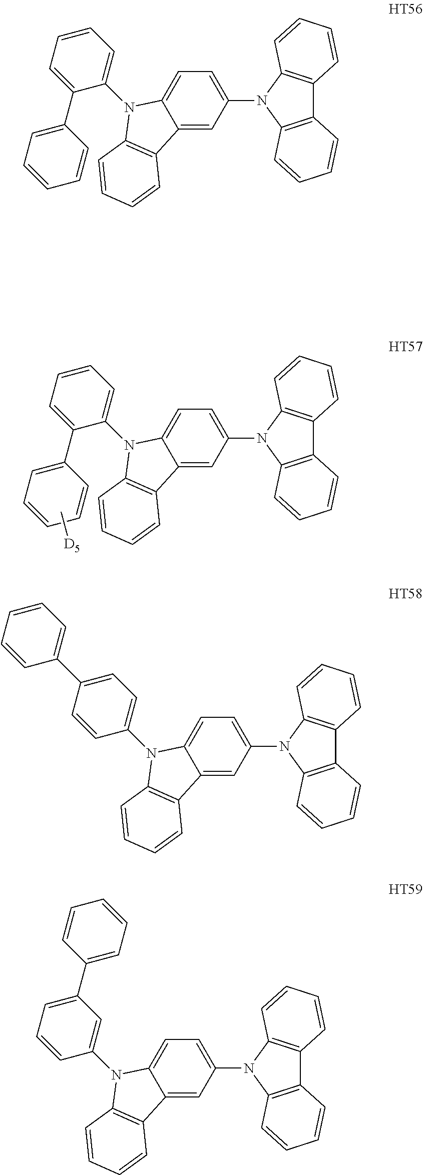

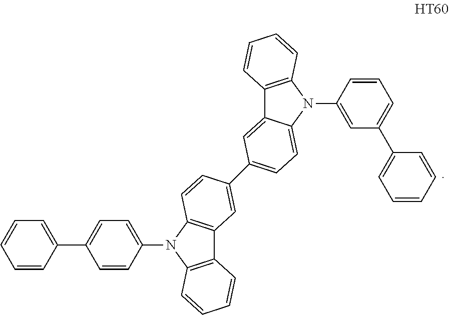 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In Compound Group 2, D represents a deuterium atom, and Ph represents an unsubstituted phenyl group.

In an embodiment, the light emitting layer EML may further include a third compound represented by Formula ET-1. In an embodiment, the third compound may be used as an electron transport host material in the light emitting layer EML:

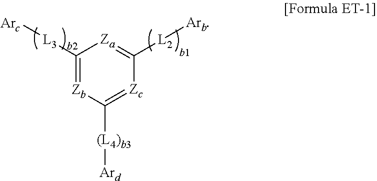

In Formula ET-1, at least one of Zₐ to Z_{c} may each be N, and the remainder of Zₐ to Z_{c} may each independently be C(R₅₆). For example, one of Zₐ to Z_{c} may be N, and the remainder of Zₐ to Z_{c} may each independently be C(R₅₆). Thus, the third compound represented by Formula ET-1 may include a pyridine moiety. As another example, two of Zₐ to Z_{c} may each be N, and the remainder of Zₐ to Z_{c} may be C(R₅₆). Thus, the third compound represented by Formula ET-1 may include a pyrimidine moiety. As yet another example, Zₐ to Z_{c} may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar_{b} to Ar_{d} may each independently be a substituted or unsubstituted phenyl group or a substituted or unsubstituted carbazole group.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, multiple groups of each of L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

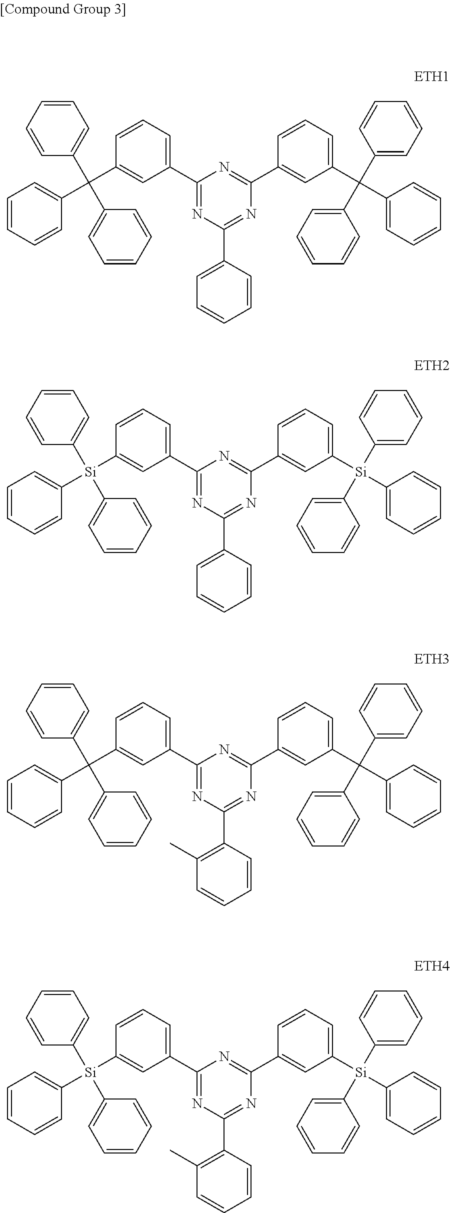 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

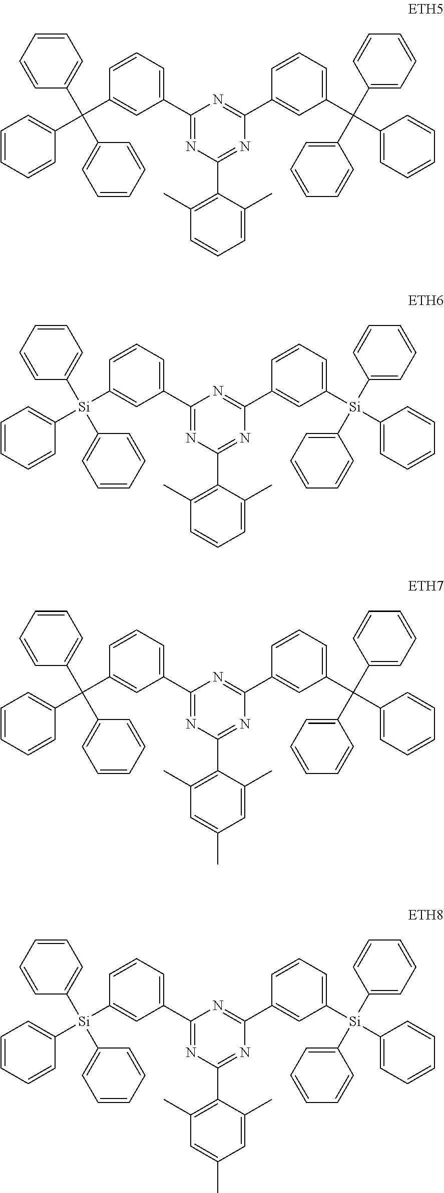 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

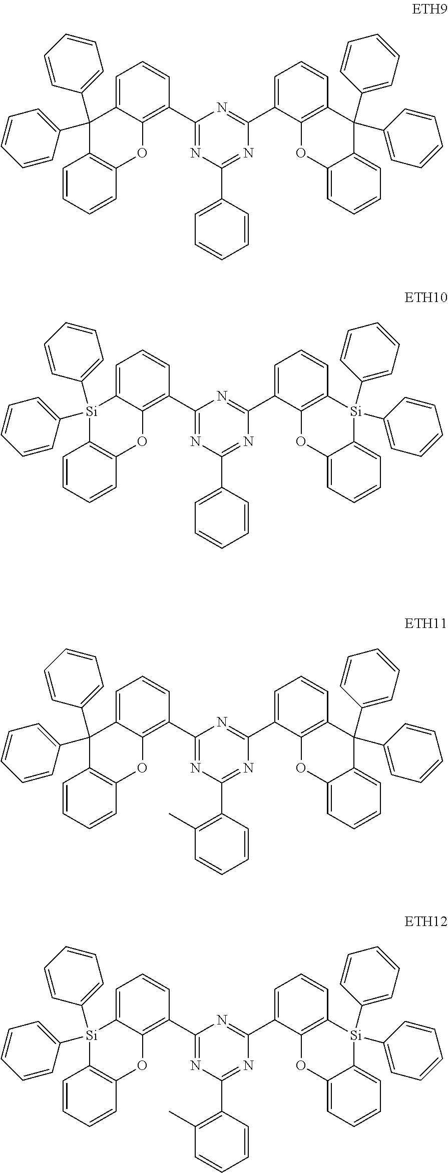 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

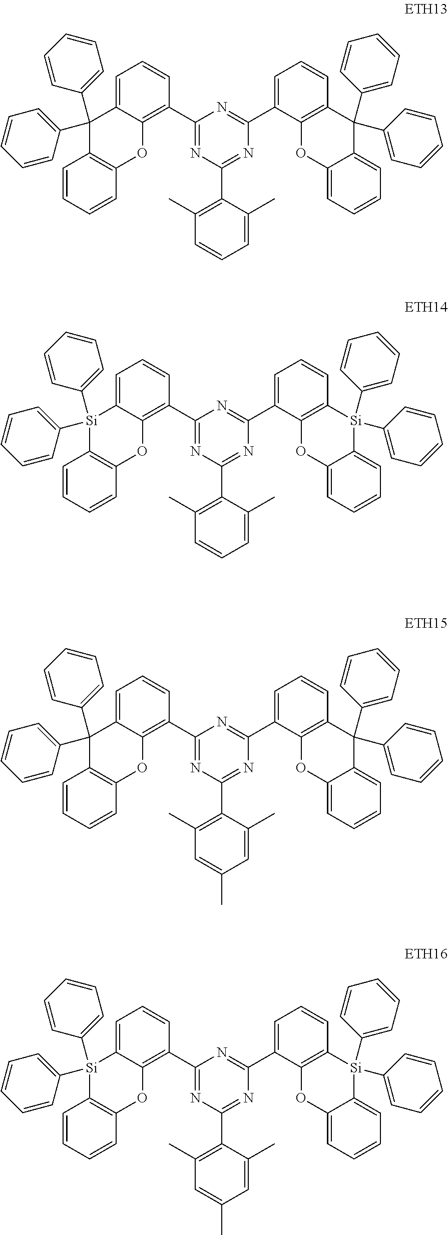 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

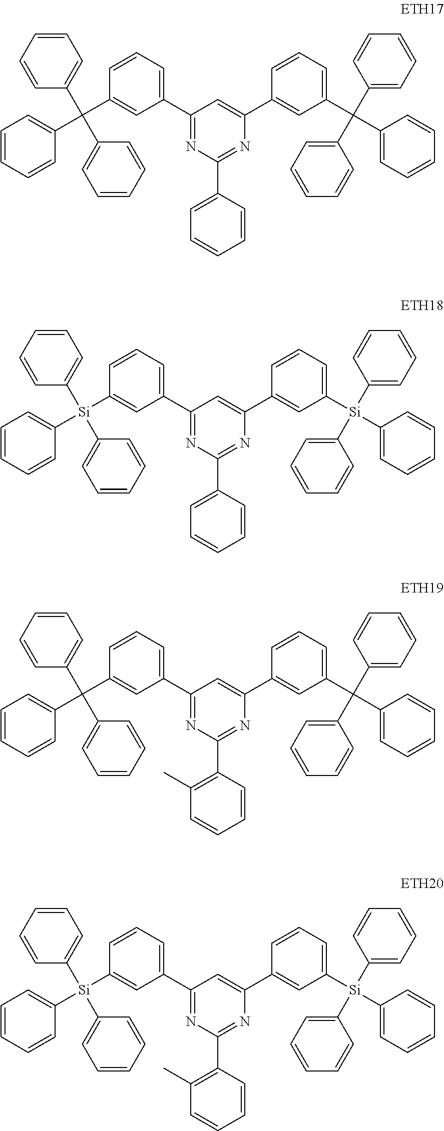 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

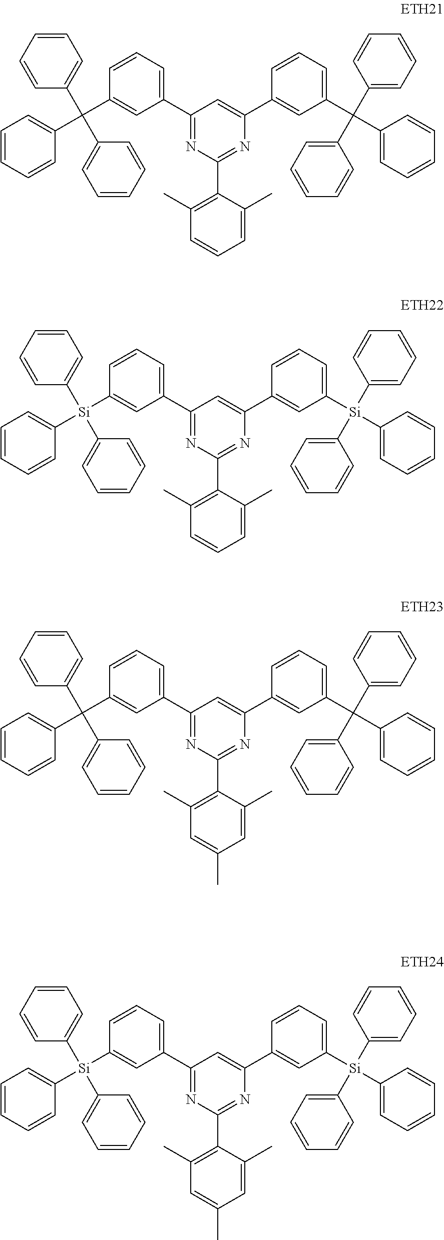 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

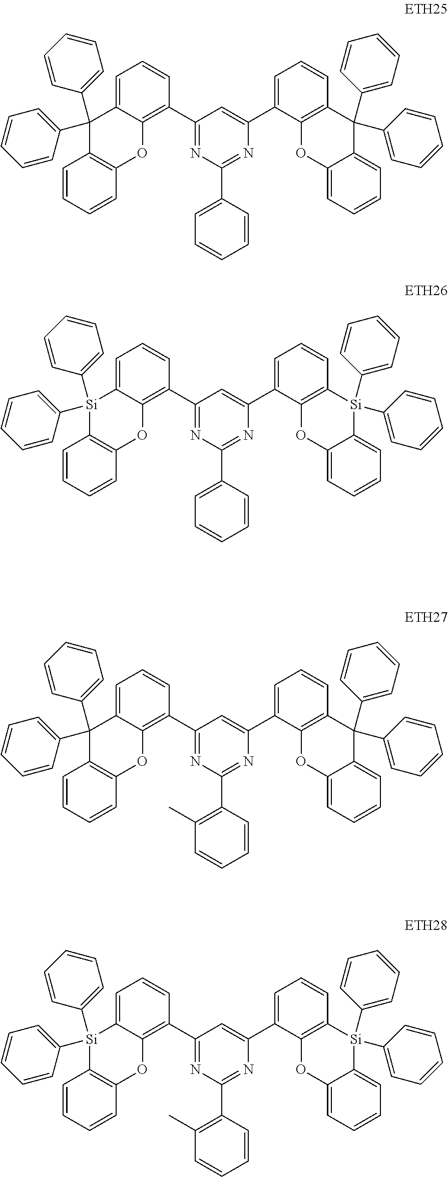 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

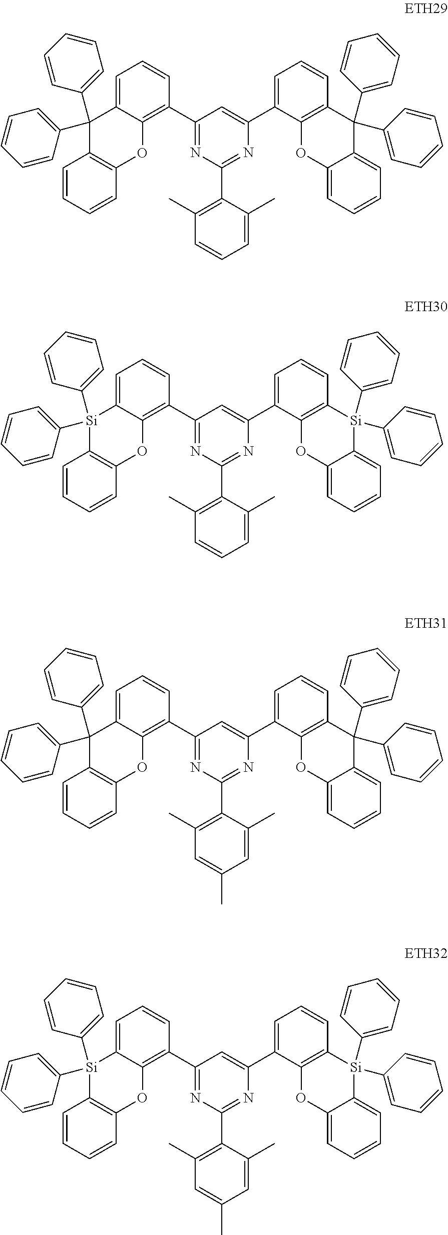 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

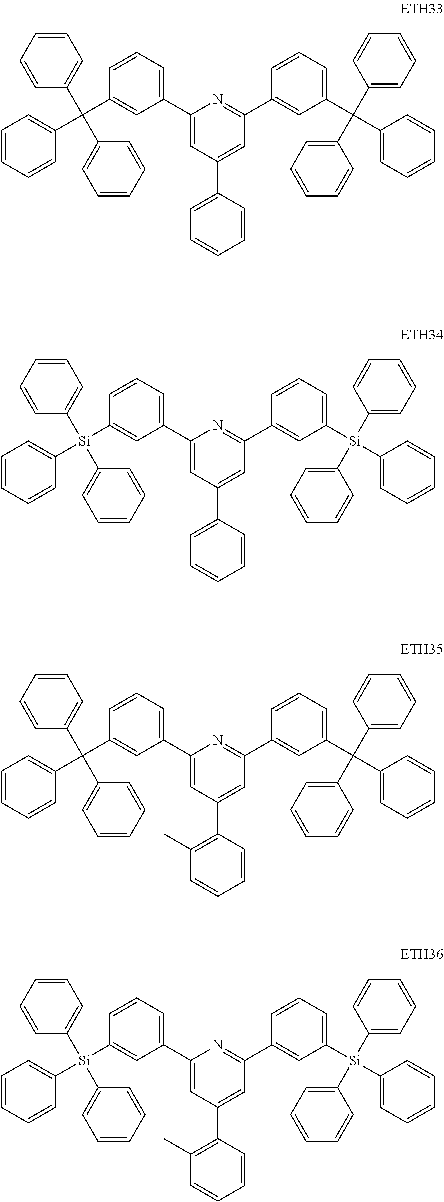 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

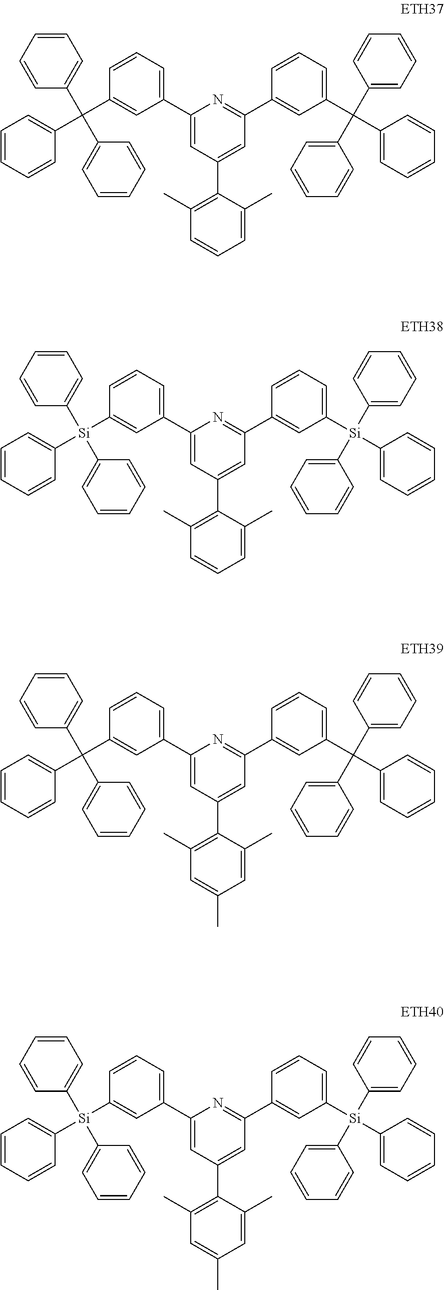 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

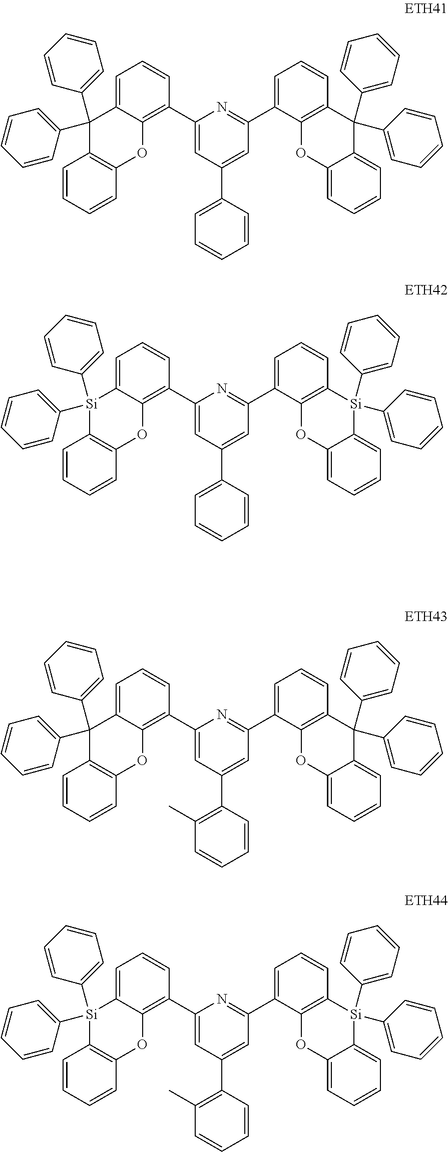 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

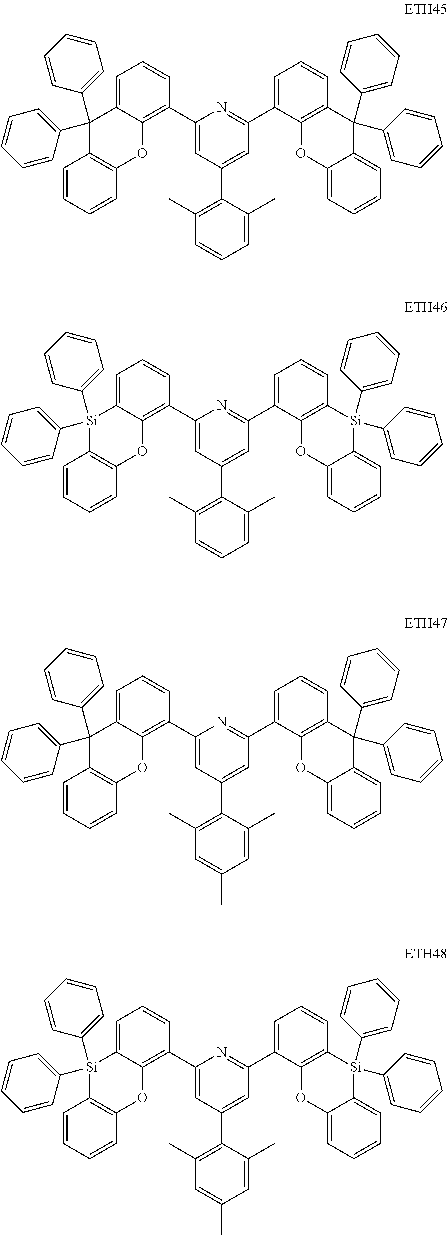 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

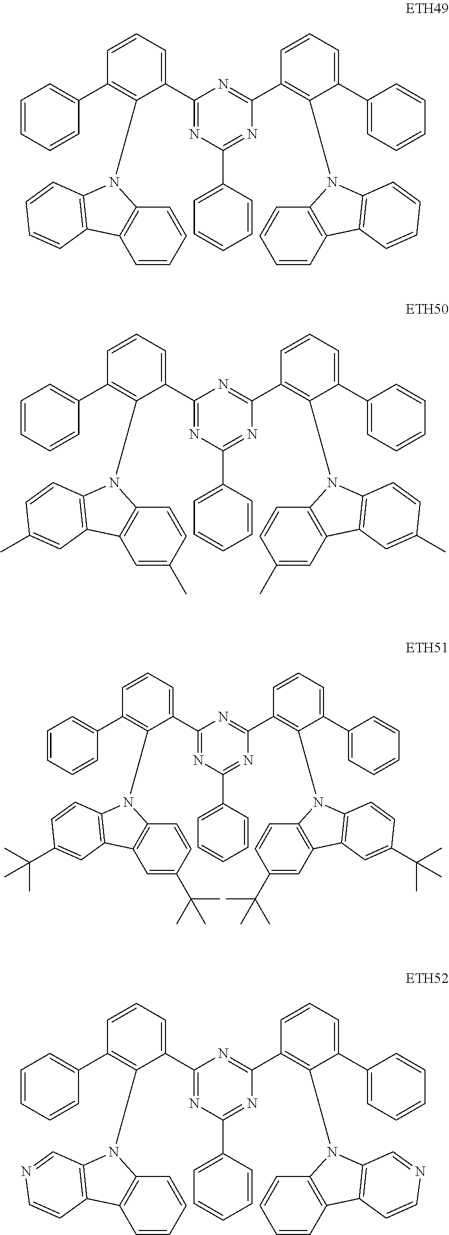

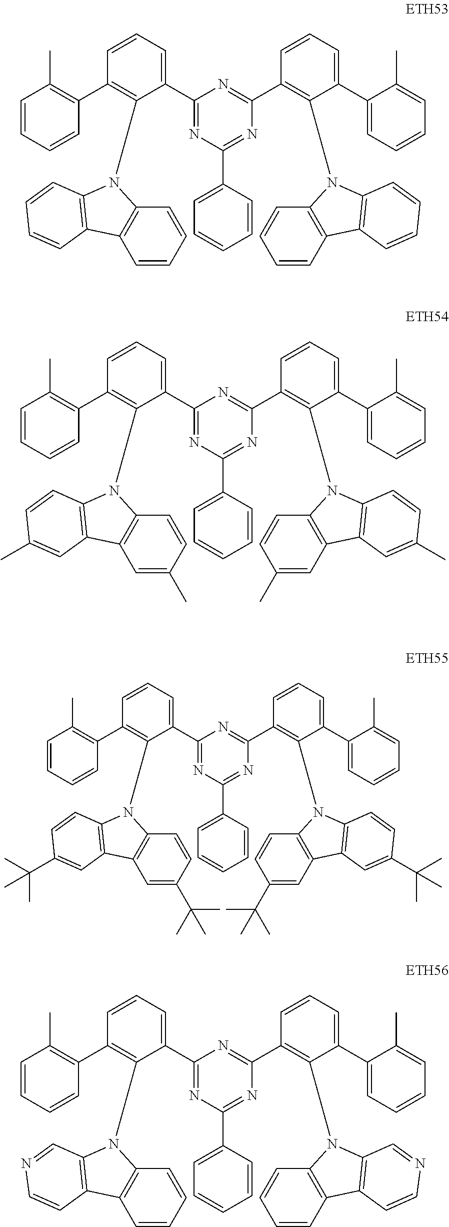

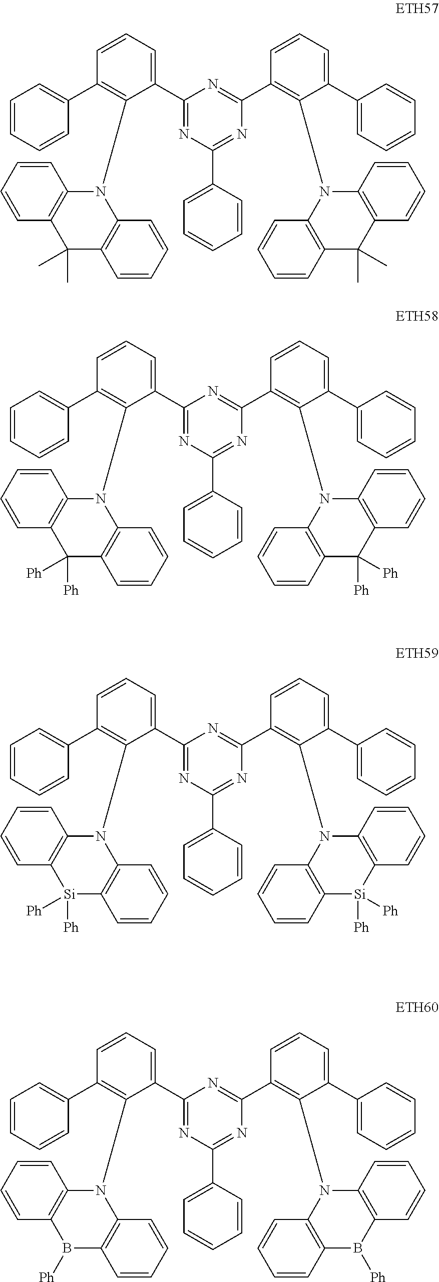

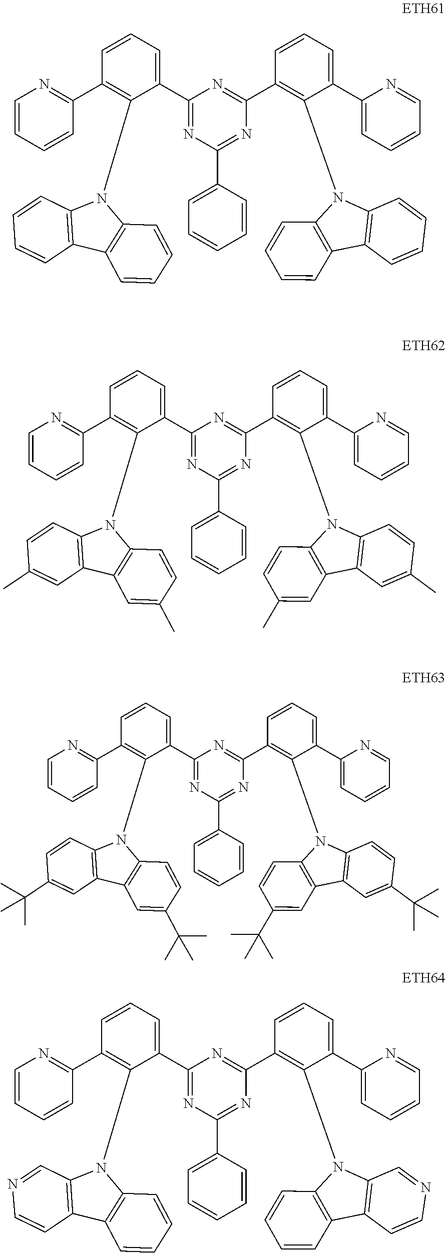

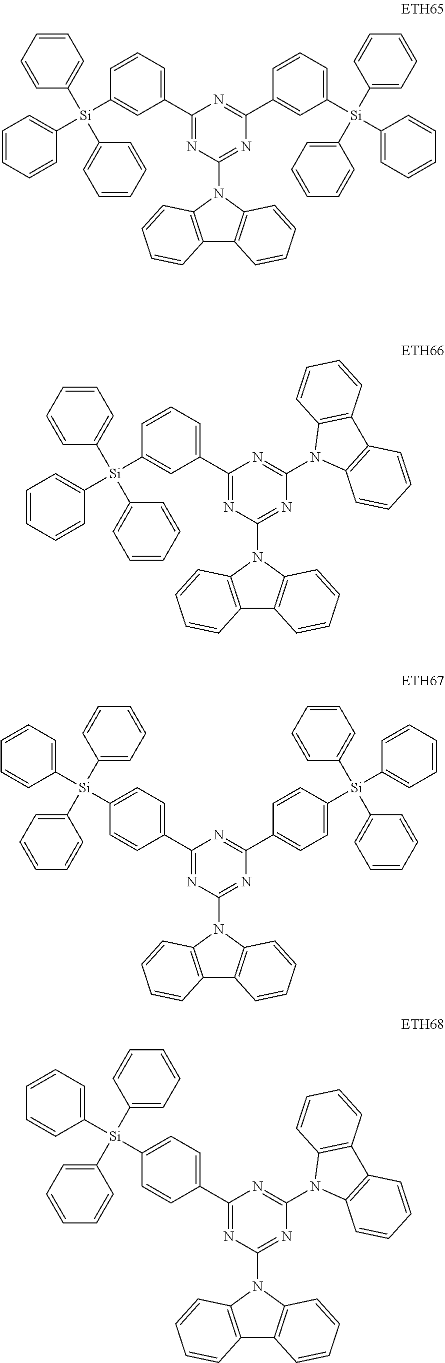 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

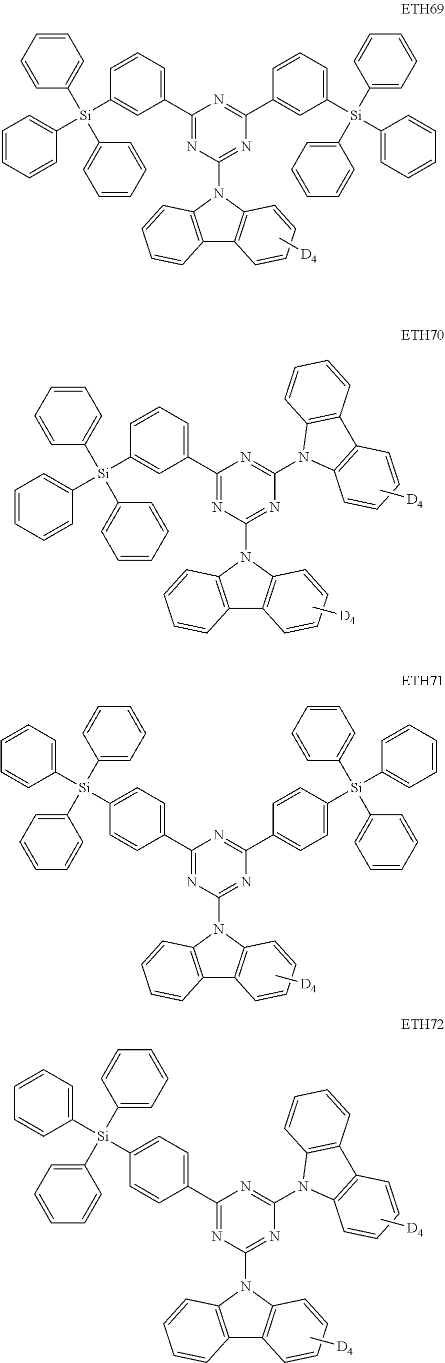

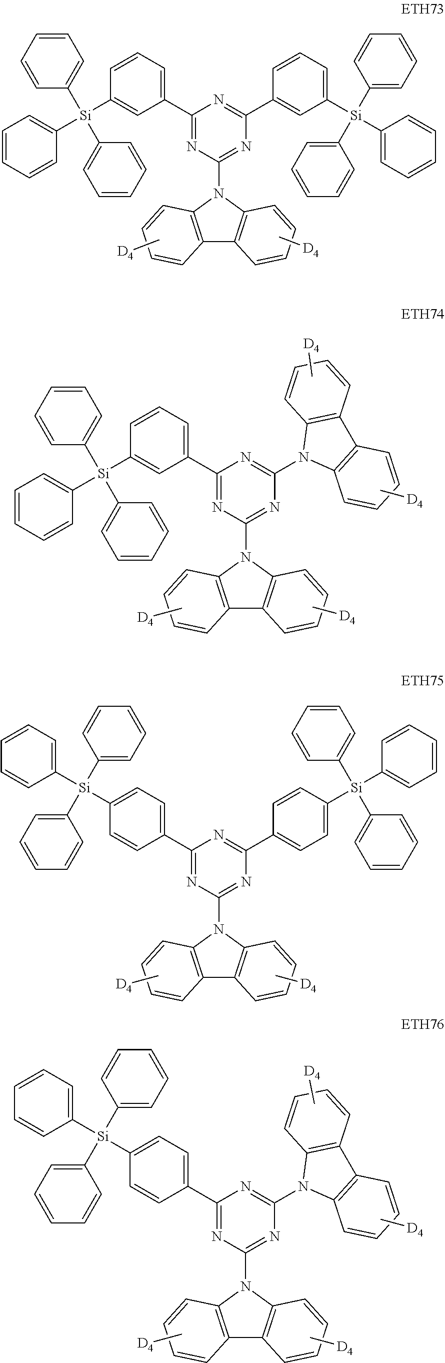

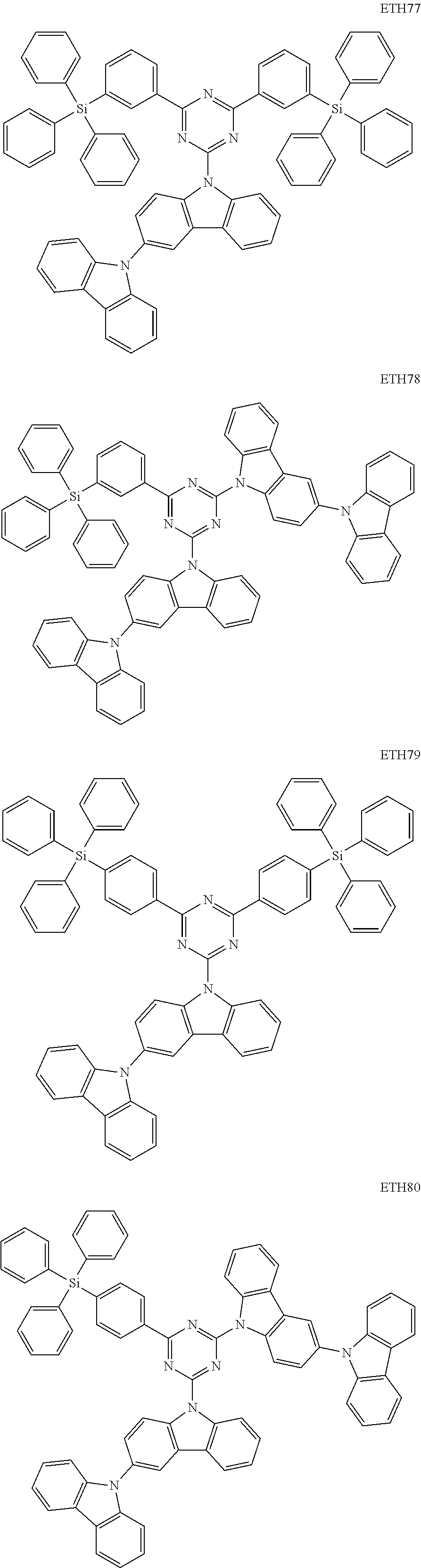

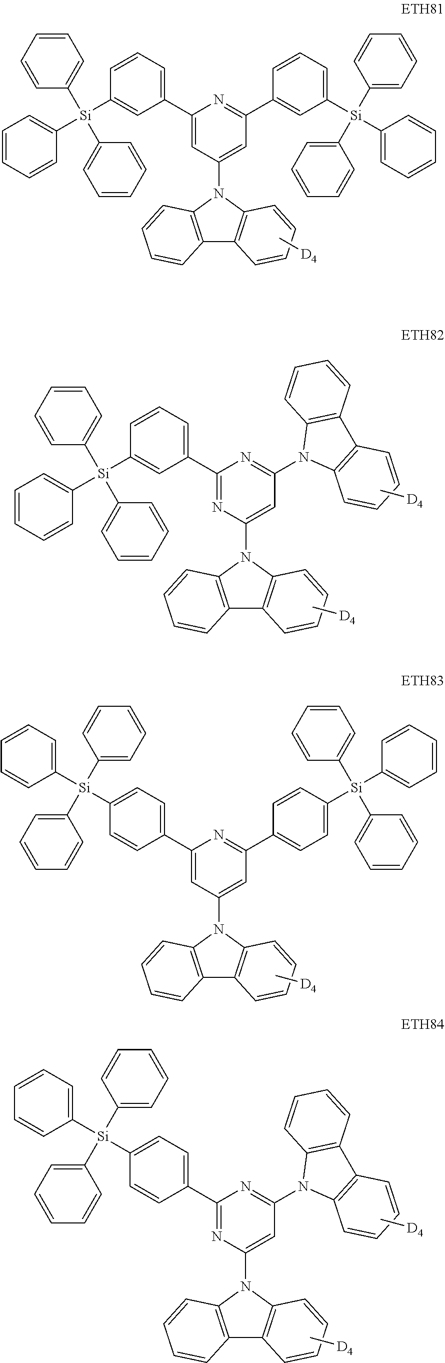

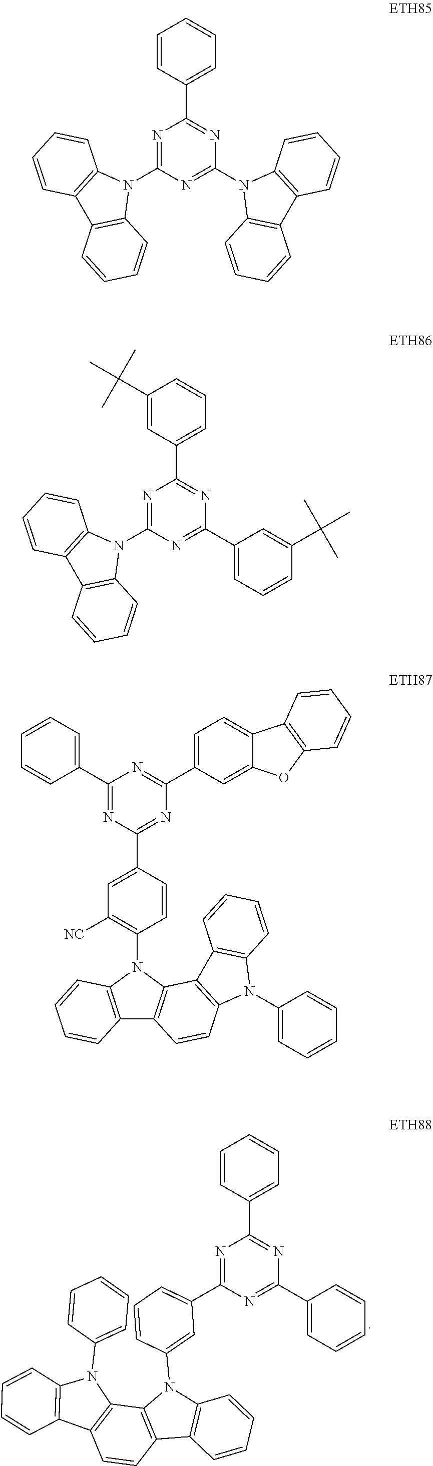 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1 ; N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In Compound Group 3, D represents a deuterium atom, and Ph represents an unsubstituted phenyl group.

In an embodiment, the light emitting layer EML may include the second compound and the third compound, and the second compound and the third compound may form an exciplex. In the light emitting layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy of the exciplex may have a value that is smaller than an energy gap of each host material. The exciplex may have a triplet energy level equal to or less than about 3.0 eV, which is an energy gap between the hole transport host and the electron transport host.

In an embodiment, the light emitting layer EML may include a fourth compound, in addition to the first compound, the second compound, and the third compound. The fourth compound may be used as a phosphorescent sensitizer in the light emitting layer EML. Energy may be transferred from the fourth compound to the first compound, thereby effecting light emission.

In an embodiment, the light emitting layer EML may include an organometallic complex that includes platinum (Pt) as a central metal atom and ligands bonded to the central metal atom, as a fourth compound. In an embodiment, the light emitting layer EML may further include a fourth compound represented by Formula D-1:

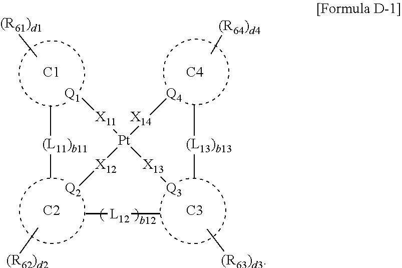

In Formula D-1, Q₁ to Q₄ may be each independently C or N.

In Formula D-1, C1 to C4 may each independently be a substituted or unsubstituted hydrocarbon ring of 5 to 30 ring-forming carbon atoms, a substituted or unsubstituted aryl group having 6 to 30 ring-forming carbon atoms, or a substituted or unsubstituted heterocycle of 2 to 30 ring-forming carbon atoms.

In Formula D-1, X₁₁ to X₁₄ may each independently be a direct linkage or *—O—* For example, one of X₁₁ to X₁₄ may be *—O—*, and the remainder of X₁₁ to X₁₄ may each be a direct linkage.

In Formula D-1, L₁ to L₁₃ may each independently be a direct linkage, *—O—*, *—S—*,

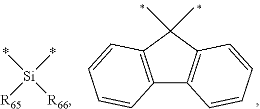

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, [symbol] represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b3 is 0, C3 and C4 may not be directly bonded to each other.

In Formula D-1, R⁶¹ to R⁶⁶ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or form a ring by being bonded to an adjacent group. For example, R⁶¹ to R⁶⁶ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R⁶¹ to R⁶⁴, respectively. A case where d1 to d4 are each 4 and four groups of each of R⁶¹ to R⁶⁴ are all hydrogen atoms may be the same as a case where d1 to d4 are each 0. If d1 to d4 are each 2 or more, multiple groups of each of R⁶¹ to R⁶⁴ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-5:

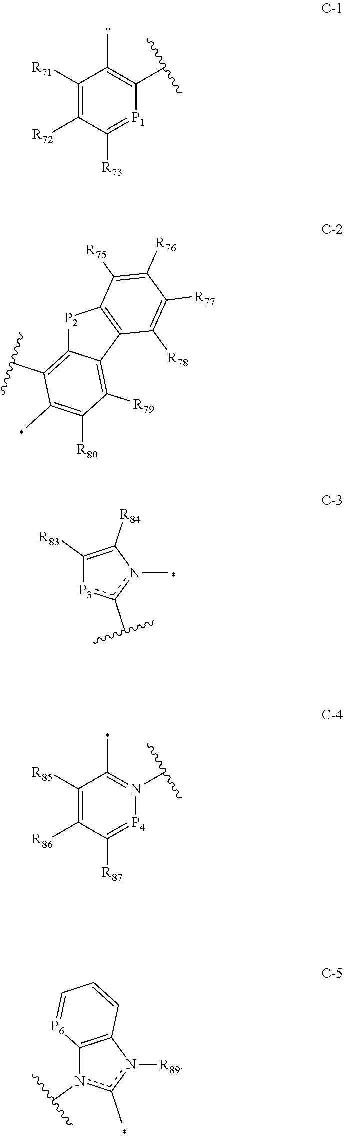

In Formula C-1 to Formula C-5, P₁ may be C—* or C(R₇₄), P₂ may be N—* or N(R₈₁), P₃ may be N—* or N(R₈₂), P₄ may be C—* or C(R₈₈), and P₆ may be C—* or C(R₉₀).

In Formula C-1 to Formula C-5, R₇₁ to R₉₀ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group.

In Formula C-1 to Formula C-5, [symbol] represents a bond to Pt, which is a central metal atom, and [symbol] represents a bond to an adjacent ring group (C1 to C4) or to a linking moiety (L₁ to L₁₃).

In an embodiment, the light emitting layer EML may include the first compound represented by Formula 1, and at least one of the second compound, the third compound, and the fourth compound. In an embodiment, the light emitting layer EML may include the first compound, the second compound, and the third compound. In the light emitting layer EML, the second compound and the third compound may form an exciplex, and energy may be transferred from the exciplex to the first compound, thereby effecting light emission.

In another embodiment, the light emitting layer EML may include the first compound, the second compound, the third compound, and the fourth compound. In the light emitting layer EML, the second compound and the third compound may form an exciplex, and energy may be transferred from the exciplex to the fourth compound and the first compound, thereby effecting light emission. In an embodiment, the fourth compound may be a sensitizer. In the light emitting element ED, the fourth compound included in the light emitting layer EML may serve as a sensitizer that transfers energy from a host (for example, an exciplex host) to the first compound, which is a light-emitting dopant. For example, the fourth compound, which serves as an auxiliary dopant, may accelerate energy transfer to the first compound, which serves as a light emitting dopant, thereby increasing an emission ratio of the first compound. Accordingly, the light emitting layer EML may exhibit improved emission efficiency. If energy transfer to the first compound increases, excitons formed in the light emitting layer EML may not accumulate and may rapidly emit light, so that deterioration of the light emitting element ED may be reduced. Accordingly, the lifetime of the light emitting element ED may increase.

The light emitting element ED may include the first compound, the second compound, the third compound, and the fourth compound, and the light emitting layer EML may include the combination of two host materials and two dopant materials. In the light emitting element ED, the light emitting layer EML may include the second compound and the third compound, which are two different hosts, the first compound which emits delayed fluorescence, and the fourth compound including an organometallic complex, and thus the light emitting element ED may exhibit excellent emission efficiency properties.

In an embodiment, the fourth compound represented by Formula D-1 may be selected from Compound Group 4. In an embodiment, in the light emitting element ED, the fourth compound may include at least one compound selected from Compound Group 4:

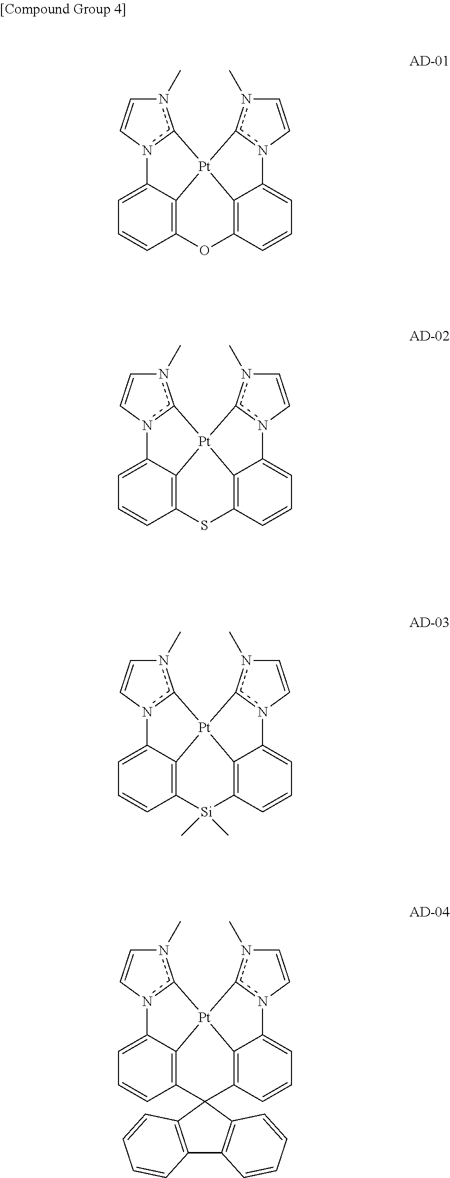

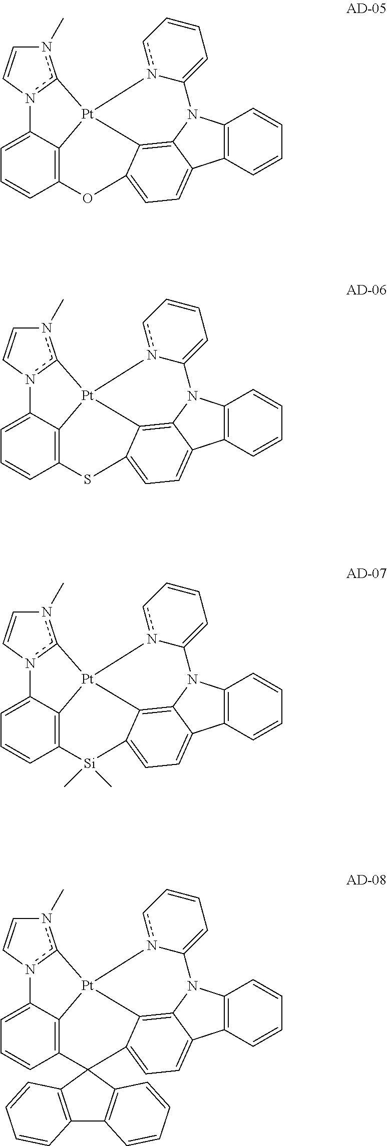

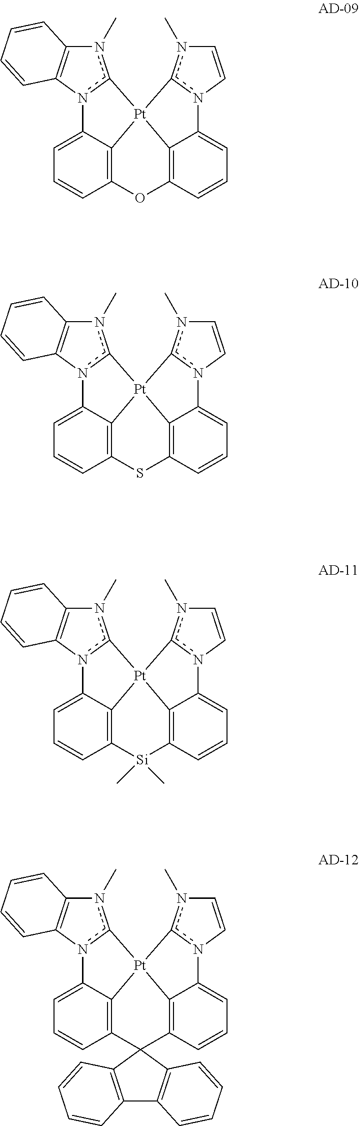

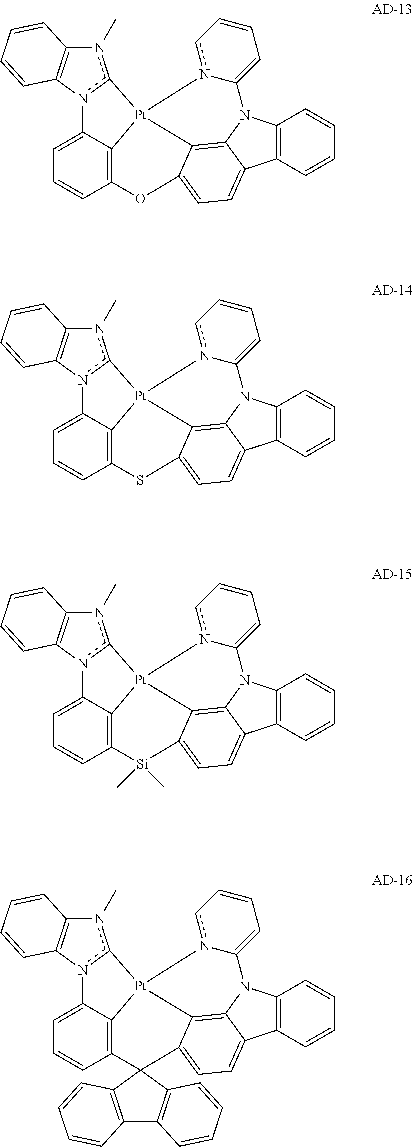

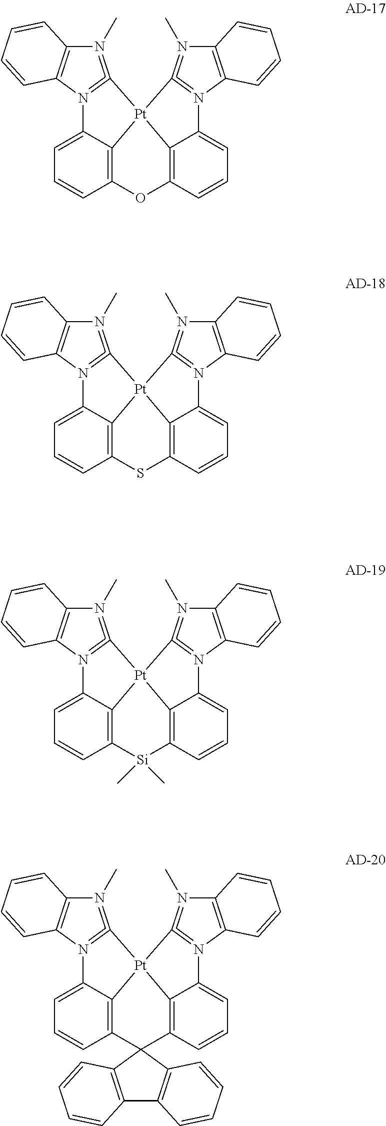

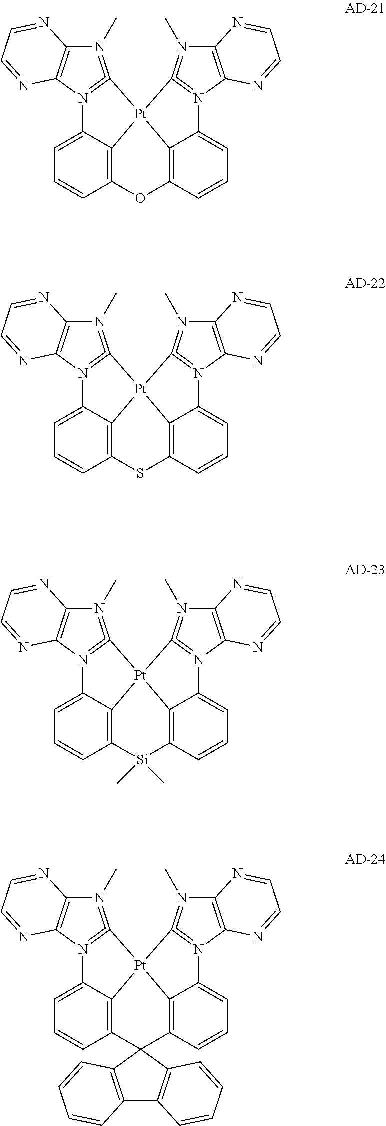

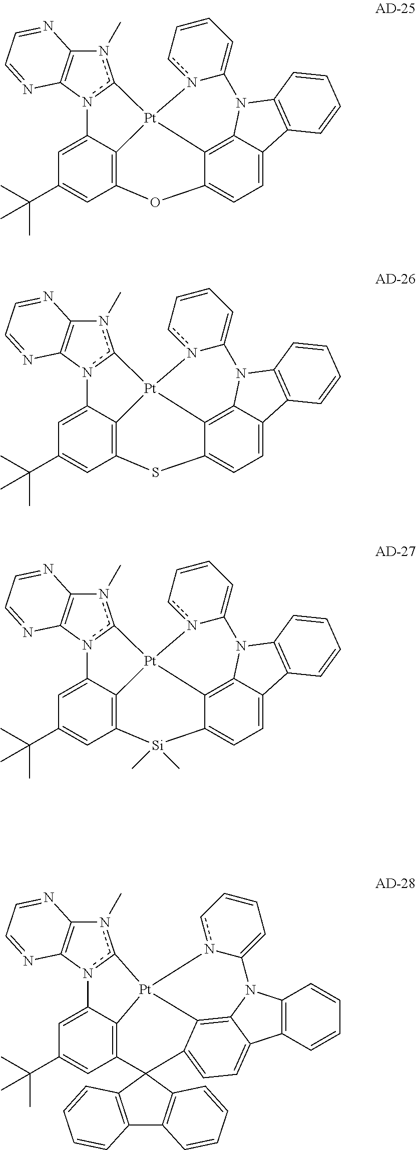

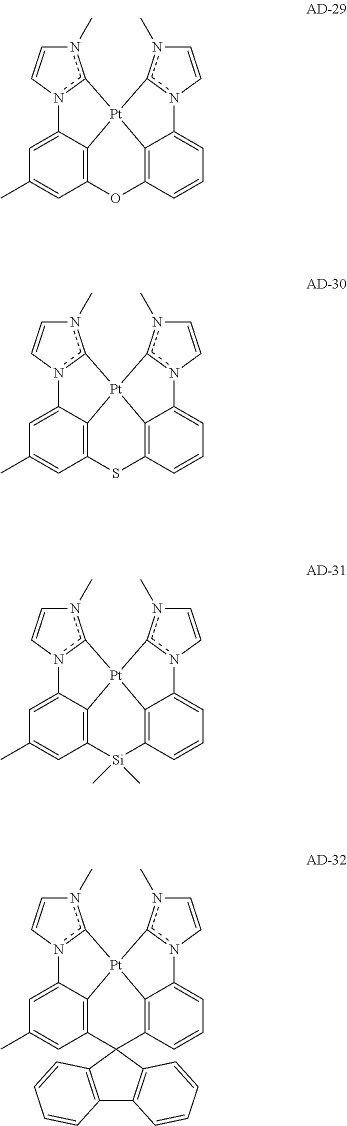

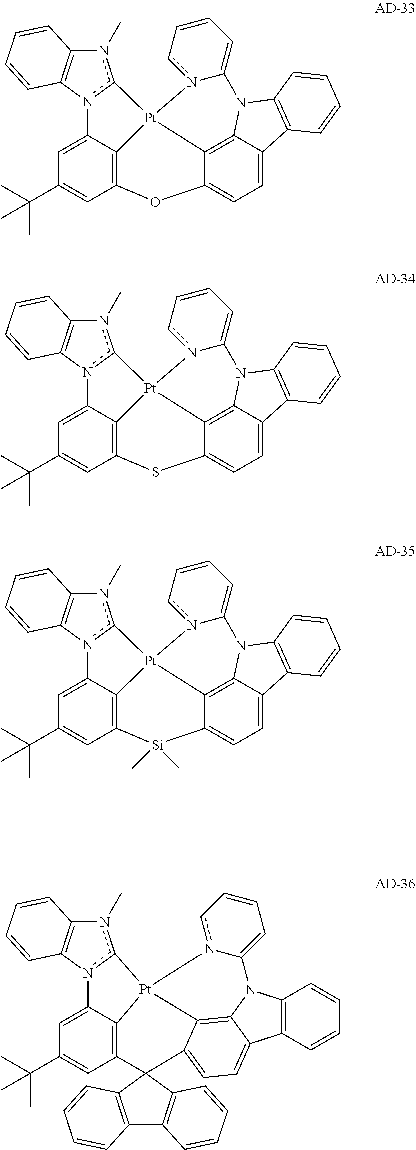

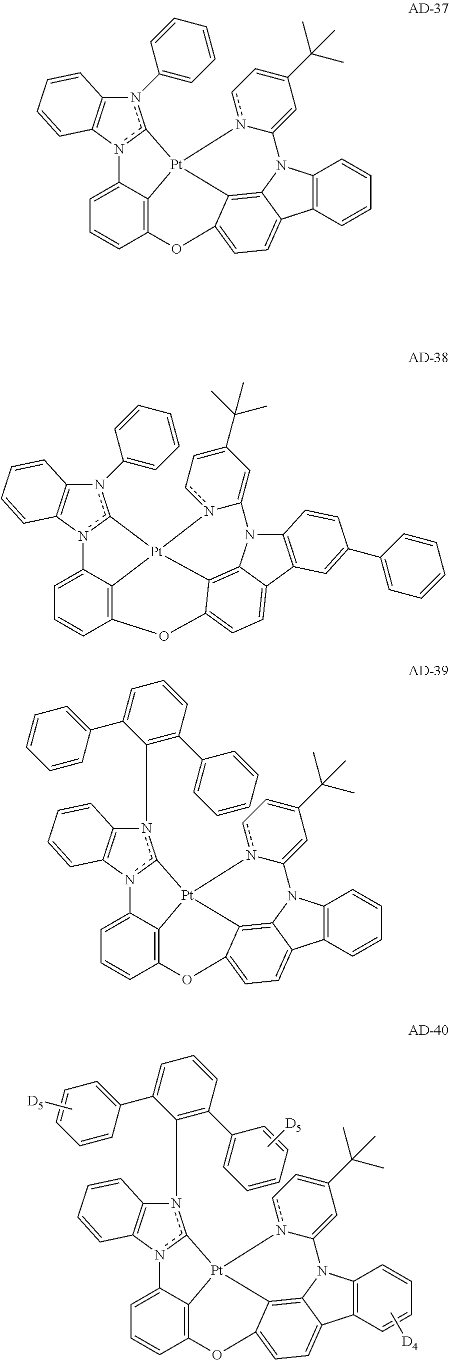

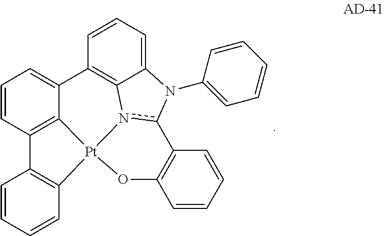

In Compound Group 4, D represents a deuterium atom.

In an embodiment, the light emitting element ED may include multiple light emitting layers. Multiple light emitting layers may be provided as a stack, so that a light emitting element ED including multiple light emitting layers may emit white light. The light emitting element ED including multiple light emitting layers may be a light emitting element having a tandem structure. If the light emitting element ED includes multiple light emitting layers, at least one light emitting layer EML may include the first compound represented by Formula 1. For example, if the light emitting element ED includes multiple light emitting layers, at least one light emitting layer EML may include the first compound, the second compound, the third compound, and the fourth compound.

In the light emitting element ED, if the light emitting layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the above-described range, energy transfer from the second compound and the third compound to the first compound may increase, and accordingly, emission efficiency and element lifetime may increase.

In the light emitting layer EML, a total amount of the second compound and the third compound may be the remainder of the total weight of the first compound, the second compound, the third compound, and the fourth compound, excluding the amount of the first compound and the fourth compound. For example, a combined amount of the second compound and the third compound may be in a range of about 65 wt % to about 95 wt %, based on a total weight of the first compound, the second compound, the third compound, and the fourth compound.

Within the combined amount of the second compound and the third compound in the light emitting layer EML, a weight ratio of the second compound to the third compound may be in a range of about 3:7 to about 7:3.

If the amounts of the second compound and the third compound satisfy the above-described ranges and ratios, charge balance properties in the light emitting layer EML may be improved, and emission efficiency and element lifetime may be improved. If the amounts of the second compound and the third compound deviate from the above-described ranges and ratios, charge balance in the light emitting layer EML may not be achieved, so that emission efficiency may be reduced, and the element may readily deteriorate.

If the light emitting layer EML includes the fourth compound, an amount of the fourth compound in the light emitting layer EML may be in a range of about 4 wt % to about 30 wt %, based on a total weight of the first compound, the second compound, the third compound, and the fourth compound. However, embodiments are not limited thereto. If an amount of the fourth compound satisfies the above-described range, energy transfer from a host (for example, an exciplex host) to the first compound, which is a light emitting dopant, may increase so that an emission ratio may improve. Accordingly, emission efficiency of the light emitting layer EML may improve. If the amounts of the first compound, the second compound, the third compound, and the fourth compound included in the light emitting layer EML satisfy the above-described ranges and ratios, excellent emission efficiency and long lifetime may be achieved.

In the light emitting element ED, the light emitting layer EML may further include an anthracene derivative, a pyrene derivative, a fluoranthene derivative, a chrysene derivative, a dihydrobenzanthracene derivative, or a triphenylene derivative. For example, the light emitting layer EML may include an anthracene derivative or a pyrene derivative.

In the light emitting elements ED according to embodiments as shown in each of FIG. 3 to FIG. 6, the light emitting layer EML may further include hosts and dopants of the related art, in addition to the above-described host and dopant.

In an embodiment, the light emitting layer EML may include a compound represented by Formula E-1. The compound represented by Formula E-1 may be used as a fluorescence host material:

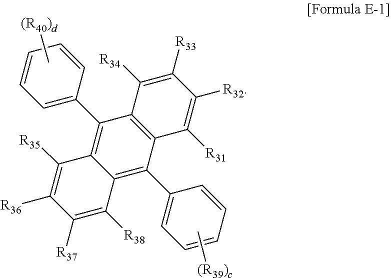

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group. For example, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

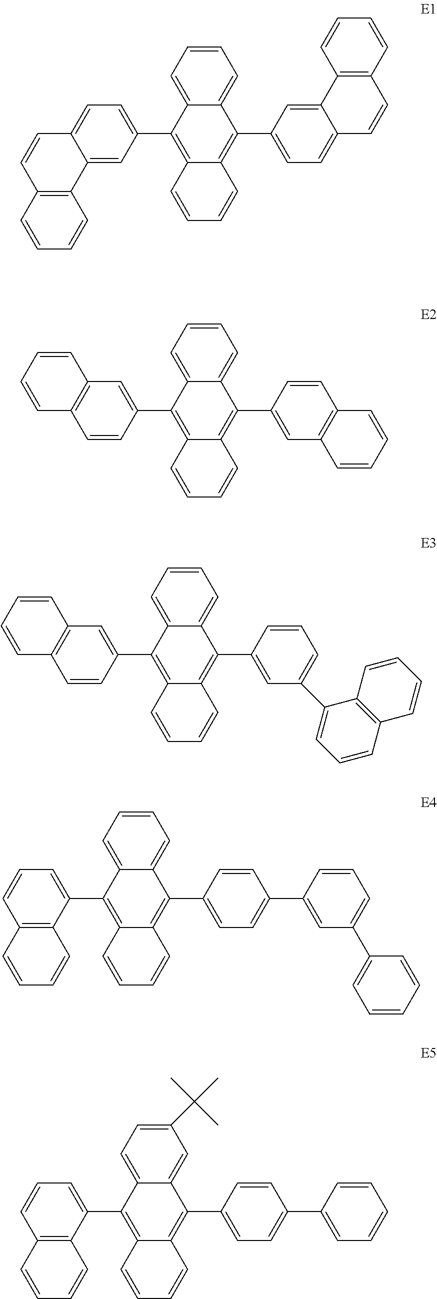

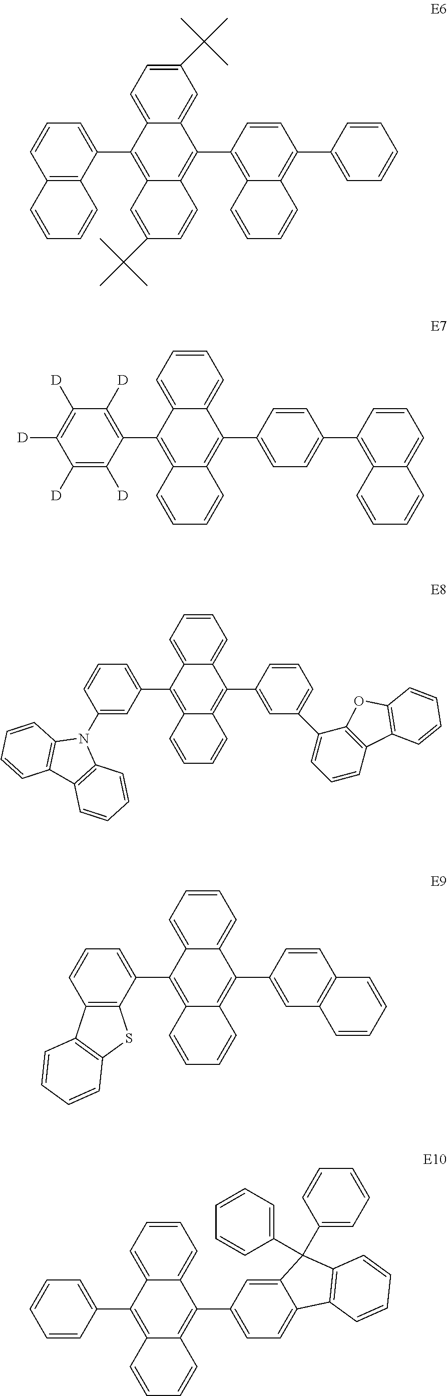

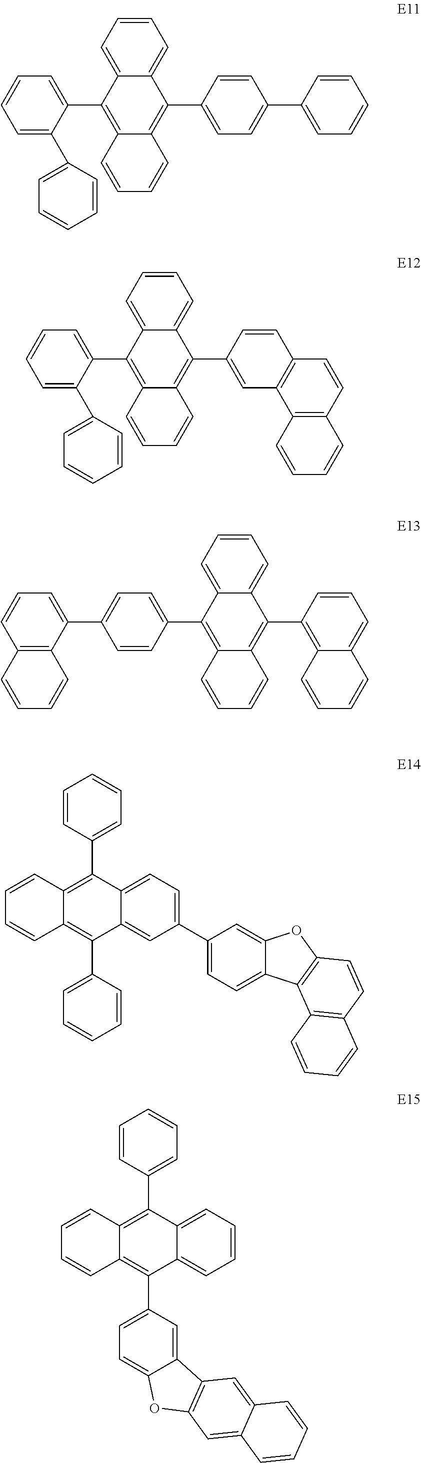

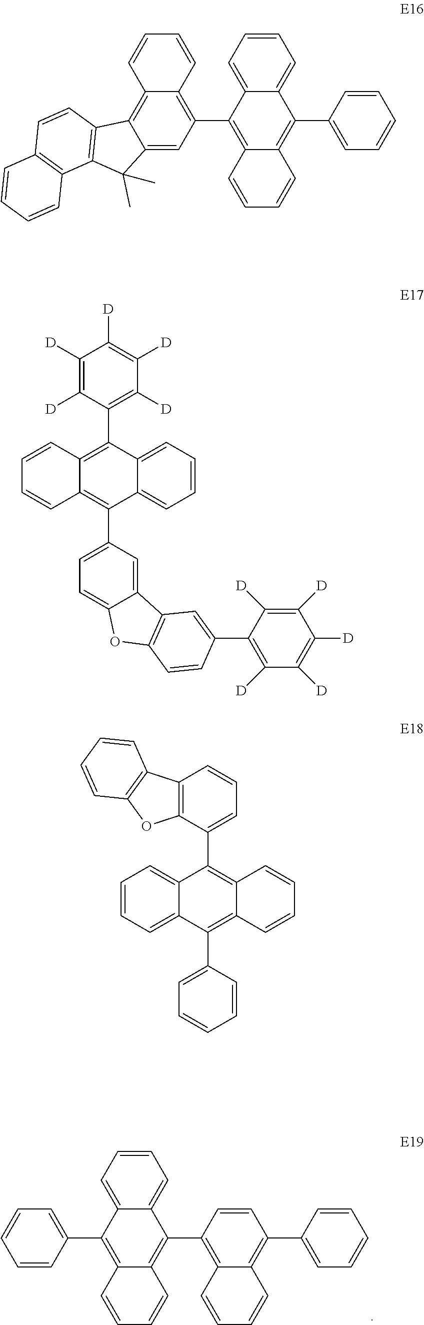

In an embodiment, the light emitting layer EML may include a compound represented by Formula E-2a or Formula E-2b. The compound represented by Formula E-2a or Formula E-2b may be used as a phosphorescence host material.

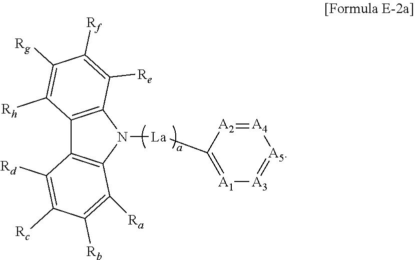

In Formula E-2a, a may be an integer from 0 to 10; and La may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple La groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

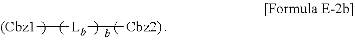

In Formula E-2b, Cbz1 and Cbz2 may each independently be an unsubstituted carbazole group or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10. If b is 2 or more, multiple L_{b} groups may each independently be a substituted or unsubstituted arylene group of 6 to 30 ring-forming carbon atoms or a substituted or unsubstituted heteroarylene group of 2 to 30 ring-forming carbon atoms.

In an embodiment, the compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2:

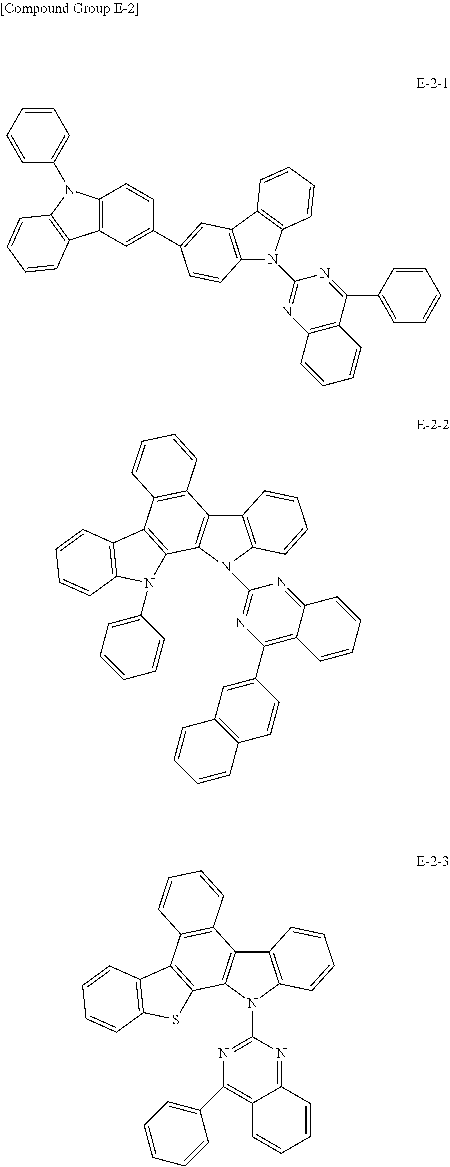 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

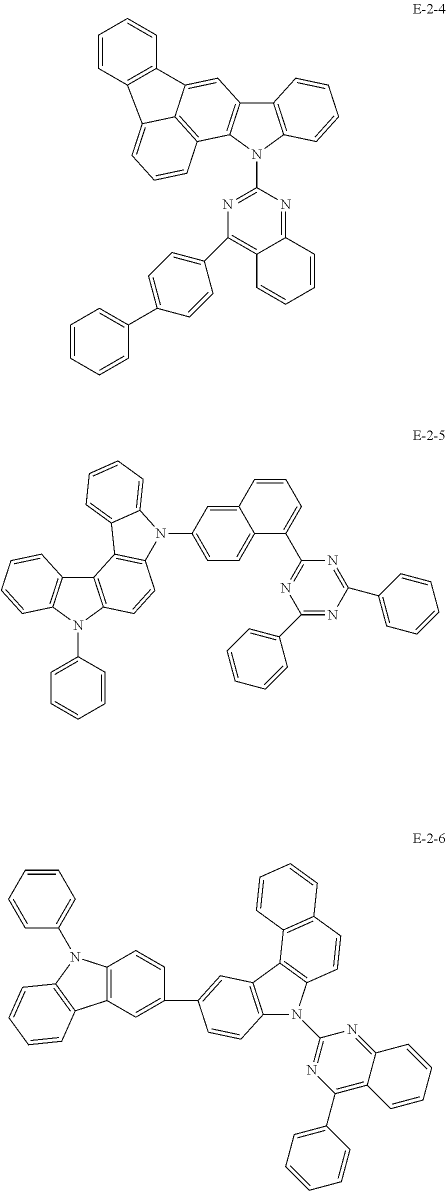 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

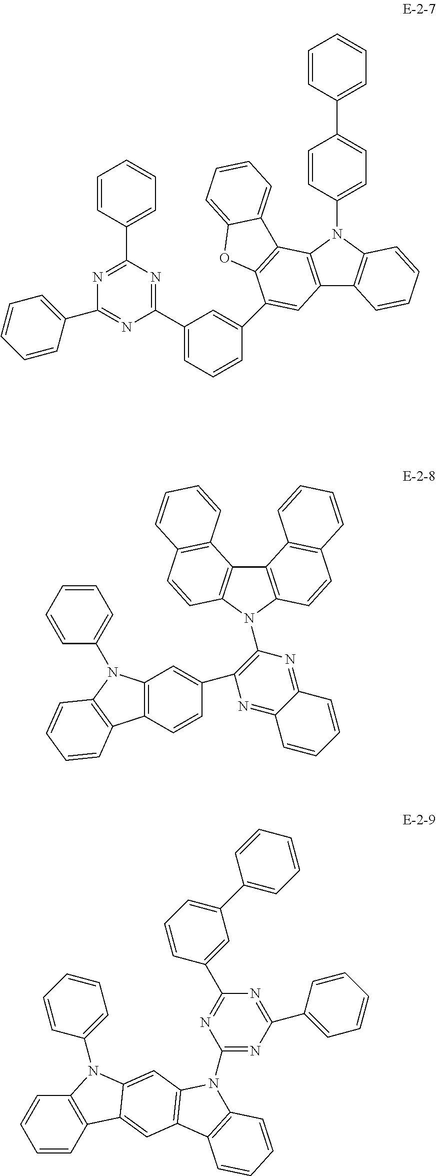 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

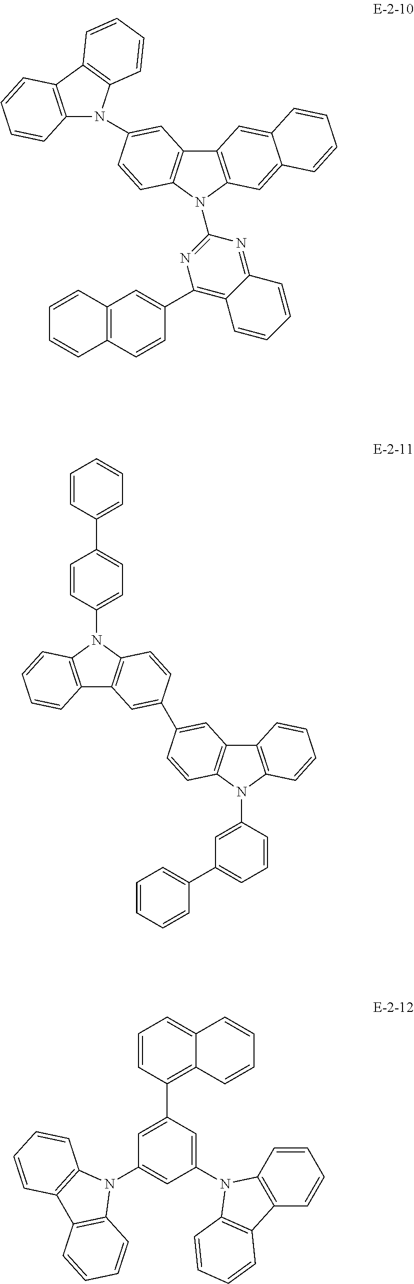 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

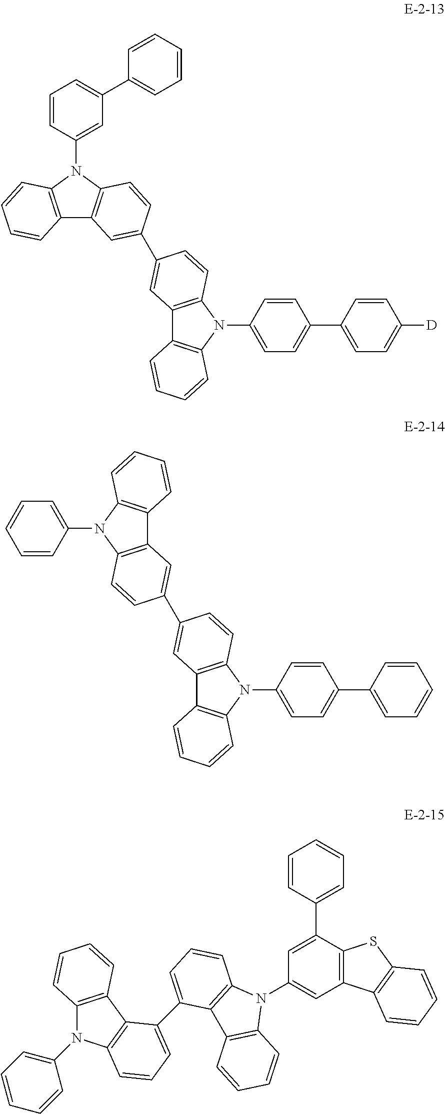 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

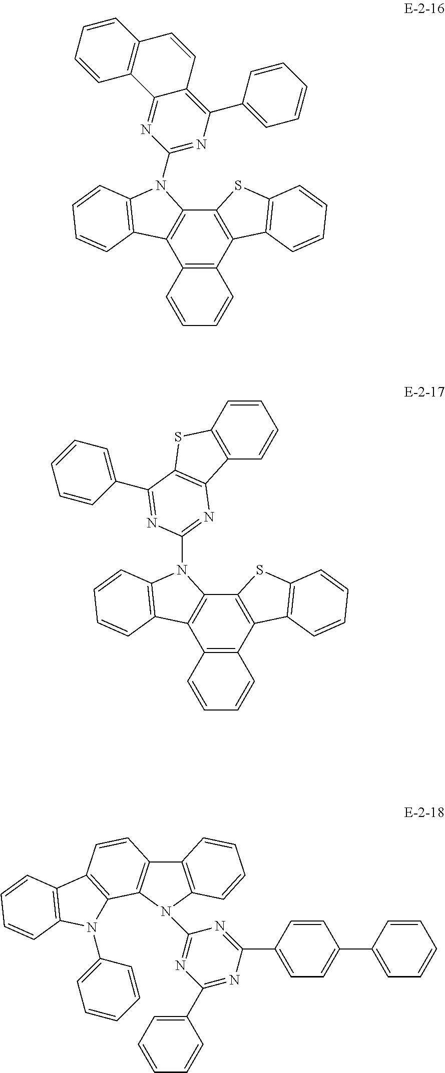 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

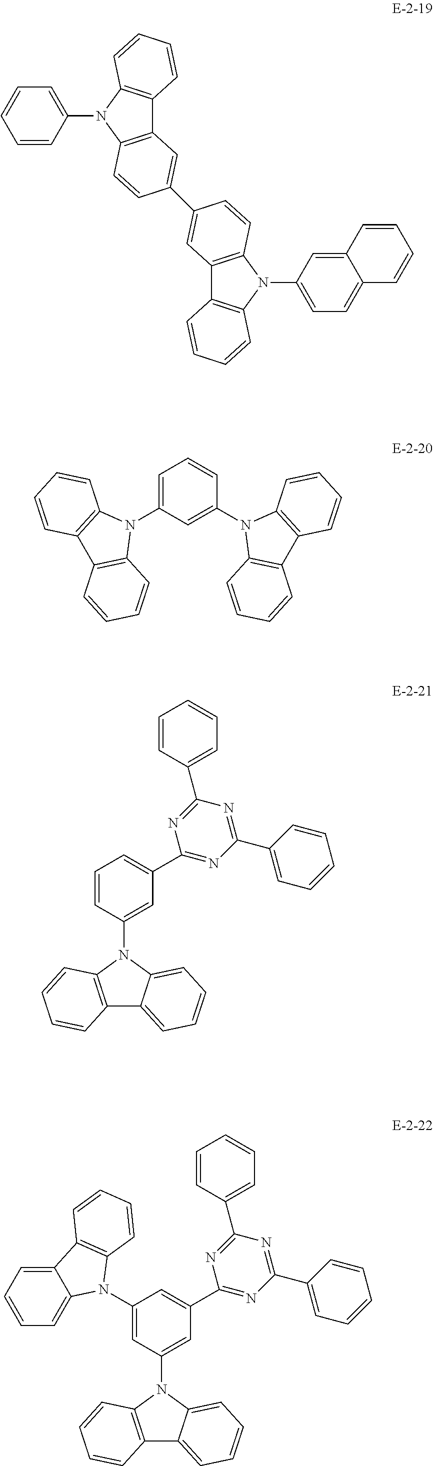 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

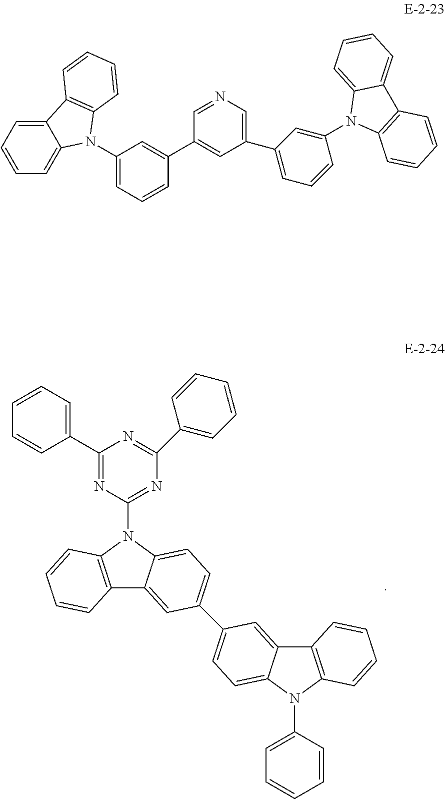 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The light emitting layer EML may further include a material of the related art as a host material. For example, the light emitting layer EML may include, as a host material, at least one of bis (4-(9H-carbazol-9-yl)phenyl) diphenylsilane (BCPDS), (4-(1-(4-(diphenylamino)phenyl) cyclohexyl)phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the light emitting layer EML may include a compound represented by Formula M-a. The compound represented by Formula M-a may be used as a phosphorescence dopant material.

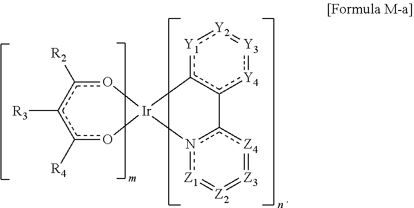

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group. In Formula M-a, m may be 0 or 1, and n may be 2 or 3. In Formula M-a, if m is 0, n may be 3, and if m is 1, n may be 2.

In an embodiment, the compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

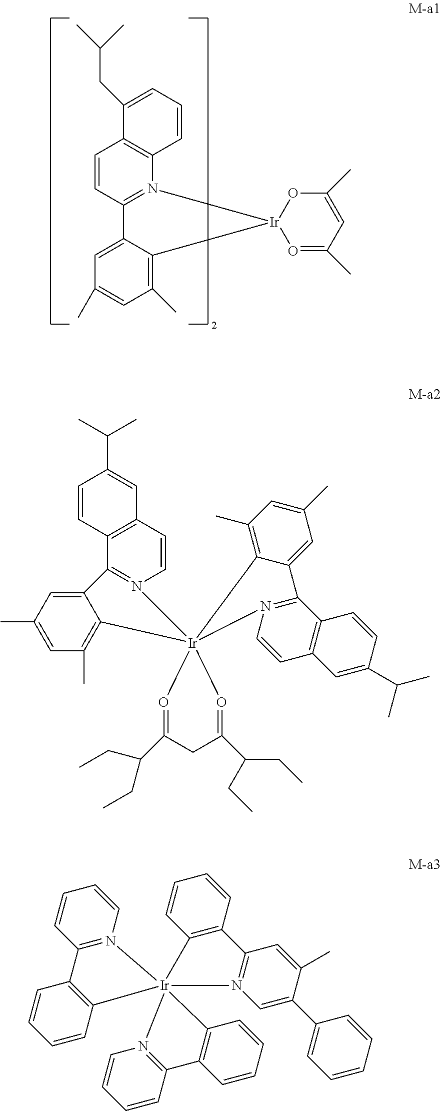

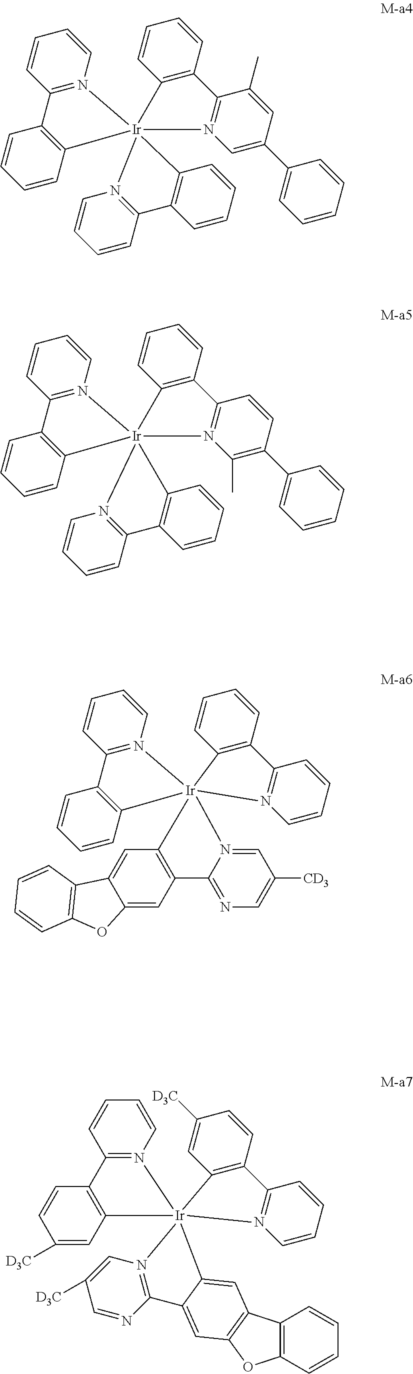

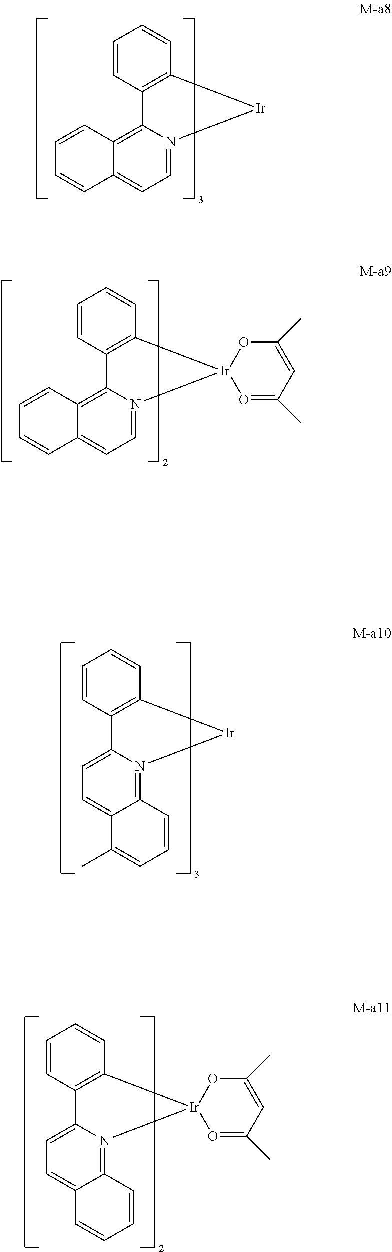

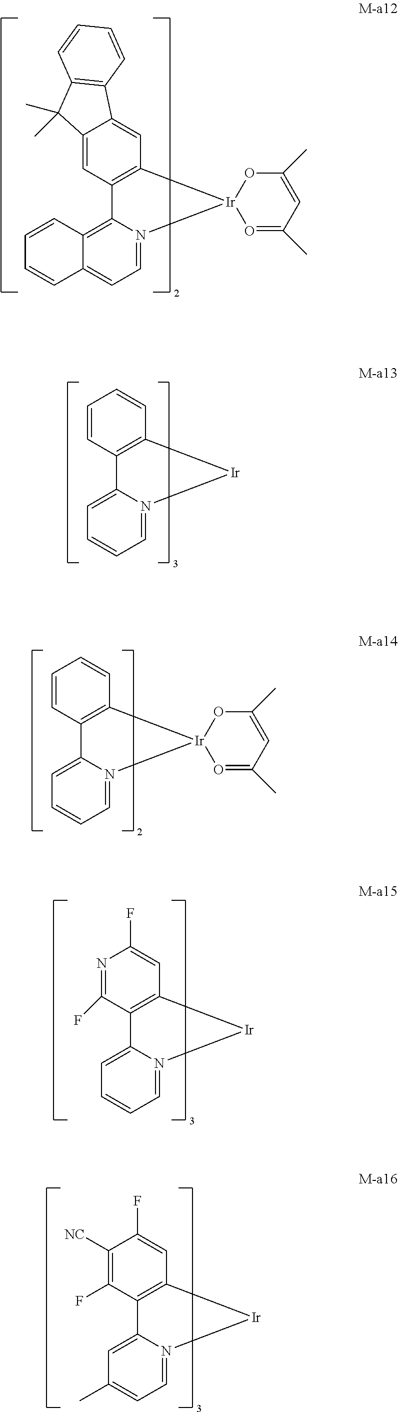

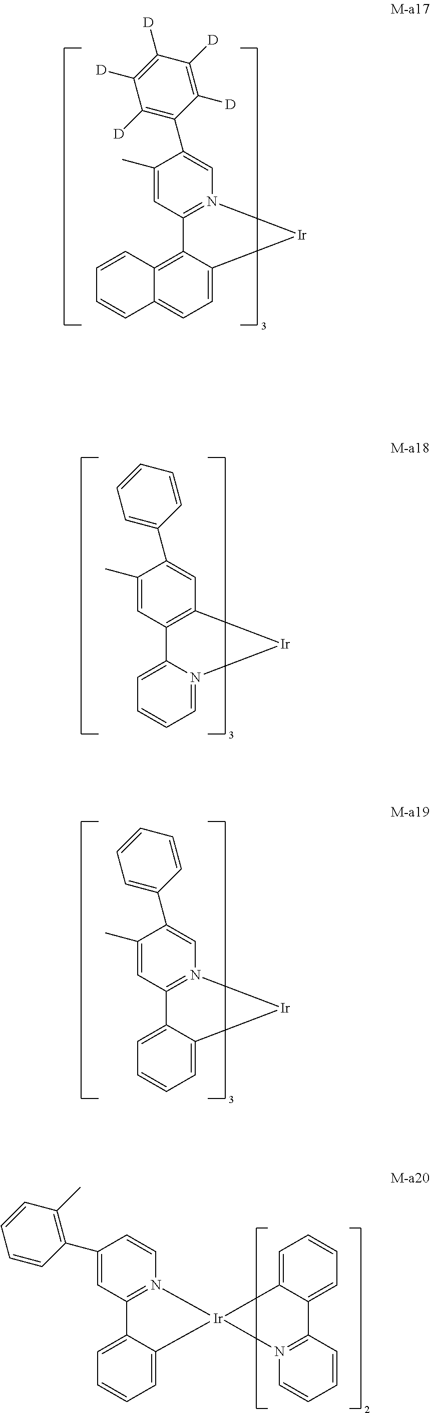

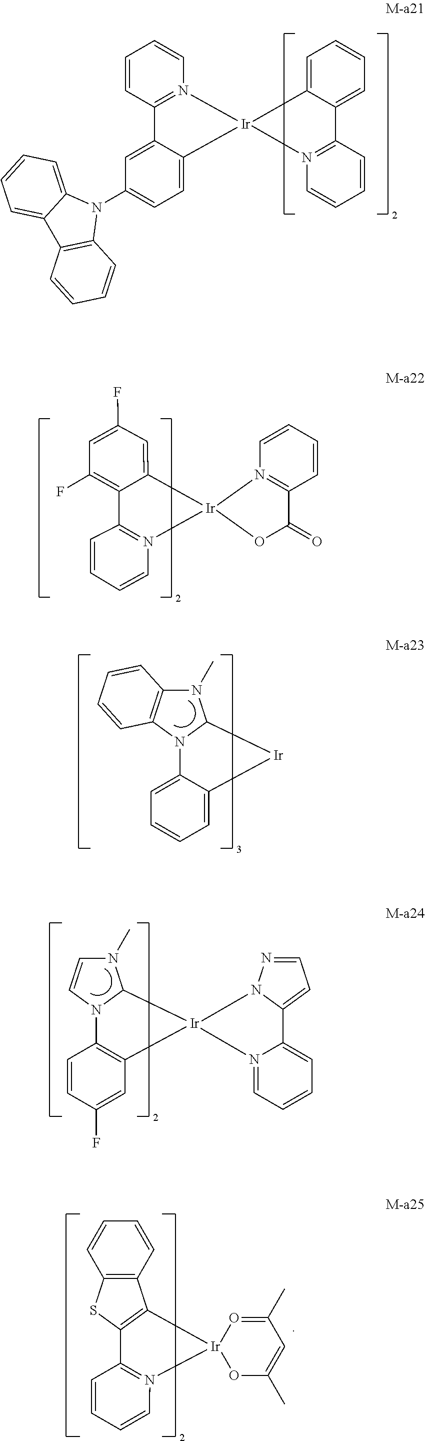

In an embodiment, the light emitting layer EML may further include a compound represented by one of Formula F-a to Formula F-c. The compound represented by one of Formula F-a to Formula F-c may be used as a fluorescence dopant material.

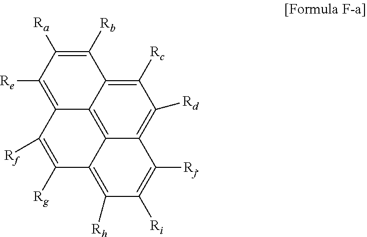

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may each independently be a heteroaryl group including O or S as a ring-forming atom.

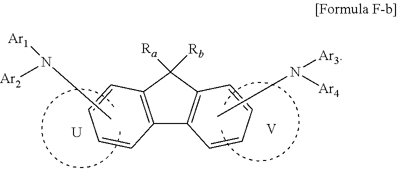

In Formula F-b, Rₐ and Rb may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the part indicated by U or V, respectively, and if the number of U or V is 0, a fused ring may not be present at the part indicated by U or V, respectively. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number U and V is each 1, a fused ring having the fluorene core of Formula F-b may be a cyclic compound with five rings.

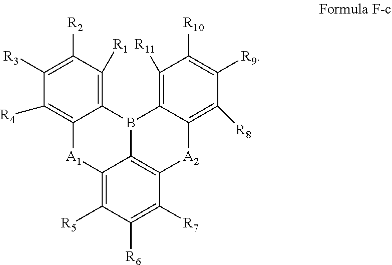

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or form a ring by being bonded to an adjacent group.

In Formula F-c, A₁ and A₂ may each independently be combined with a substituent of an adjacent ring to form a fused ring. For example, if A₁ and A₂ are each independently N(Rₘ), A₁ may be combined with R₄ or R⁵ to form a fused ring. For example, A₂ may be combined with R₇ or R₈ to form a fused ring.

In an embodiment, the light emitting layer EML may include, as a dopant material of the related art, a styryl derivative (for example, 1,4-bis[2-(3-N-ethylcarbazoryl) vinyl]benzene (BCzVB), 4-(di-p-tolylamino)-4′-[(di-p-tolylamino) styryl]stilbene (DPAVB), N-(4-((E)-2-(6-((E)-4-(diphenylamino) styryl) naphthalen-2-yl) vinyl)phenyl)-N-phenylbenzenamine (N-BDAVBi), and 4,4′-bis[2-(4-(N,N-diphenylamino)phenyl) vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino) pyrene), etc.

The light emitting layer EML may include a phosphorescence dopant material of the related art. For example, the phosphorescence dopant may include a metal complex that includes iridium (Ir), platinum (Pt), osmium (Os), gold (Au), titanium (Ti), zirconium (Zr), hafnium (Hf), europium (Eu), terbium (Tb), or thulium (Tm). For example, iridium (III) bis(4,6-difluorophenylpyridinato-N,C2′) picolinate (FIrpic), bis(2,4-difluorophenylpyridinato)-tetrakis(1-pyrazolyl) borate iridium (III) (Fir6), or platinum octaethyl porphyrin (PtOEP) may be used as a phosphorescence dopant. However, embodiments are not limited thereto.

In an embodiment, the light emitting layer may include a quantum dot.

In the specification, a quantum dot may be a crystal of a semiconductor compound. The quantum dot may emit light in various emission wavelengths according to a size of the crystal. The quantum dot may emit light in various emission wavelengths by controlling an elemental ratio of a quantum dot compound.

A diameter of the quantum dot may be, for example, in a range of about 1 nm to about 10 nm.

A quantum dot may be synthesized by chemical bath deposition, metal organic chemical vapor deposition, molecular beam epitaxy, or by a similar process.

Chemical bath deposition is a method of mixing an organic solvent and a precursor material and growing a quantum dot particle crystal. While growing the crystal, the organic solvent may serve as a dispersant that is coordinated on a surface of the quantum dot crystal and may control the growth of the crystal. Accordingly, chemical bath deposition may be more advantageous as compared to a vapor deposition method such as metal organic chemical vapor deposition (MOCVD) and molecular beam epitaxy (MBE), and the growth of a quantum dot particle may be controlled through a low-cost process.

In an embodiment, the light emitting layer EML may include a quantum dot material. The quantum dot may be a Group II-VI compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; and a combination thereof.

In an embodiment, a Group II-VI compound may further include a Group I metal and/or a Group IV element. Examples of a Group I-II-VI compound may include: CuSnS and CuZnS. Examples of a Group II-IV-VI compound may include ZnSnS and the like. Examples of a Group I-II-IV-VI compound may include a quaternary compound selected from the group consisting of Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃, and In₂Se₃; a ternary compound such as InGaS₃ and InGaSe₃; and a combination thereof.

Examples of a Group I-III-VI compound may include: a ternary compound selected from the group consisting of AgInS, AgInS₂, CuInS, CuInS₂, AgGaS₂, CuGaS₂, CuGaO₂, AgGaO₂, AgAIO₂, and a mixture thereof; a quaternary compound such as AgInGaS₂, and CuInGaS₂; and a combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GalnNP, GaInNAs, GalnNSb, GalnPAs, GalnPSb, InAlNP, InAlNAs, InAlNSb, InAlPAs, InAlPSb, and a mixture thereof; and a combination thereof. In an embodiment, a Group III-V compound may further include a Group II element. Examples of a Group III-II-V compound may include InZnP, etc.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; and a combination thereof.

Examples of a Group II-IV-V compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

Examples of a Group IV element may include Si, Ge, and a mixture thereof. Examples of a Group IV compound may include a binary compound selected from the group consisting of SiC, SiGe, and a mixture thereof.

Each element included in a compound, such as a binary compound, a ternary compound, or a quaternary compound, may be present in a particle at a uniform concentration or at a non-uniform concentration. For example, a formula may indicate the elements that are included in a compound, but an elemental ratio of the compound may vary. For example, AgInGaS₂ may indicate AgInₓGa₁₋ₓS₂ (where x is a real number between 0 and 1).

A binary compound, a ternary compound, or a quaternary compound may be present in a particle at uniform concentration or at a partially different concentration distribution state. In an embodiment, a quantum dot may have a core/shell structure in which a quantum dot surrounds another quantum dot. An interface between the core and the shell may have a concentration gradient in which the concentration of an element that is present in the shell decreases toward the core.

In embodiments, the quantum dot may have the above-described core-shell structure including a nanocrystal core and a shell that surrounds the core. The shell of a quantum dot may serve as a protection layer that prevents chemical deformation of the core to maintain semiconductor properties and/or may serve as a charging layer that imparts the quantum dot with electrophoretic properties. The shell may have a single layer structure or a multilayer structure. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; or a ternary compound such as MgAl₂O₄, CoFc₂O₄, NiFe₂O₄, and CoMn₂O₄. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Within any of the above ranges, color purity or color reproducibility may be improved. Light that is emitted through a quantum dot may be emitted in all directions, so that light viewing angle properties may be improved.

The shape of a quantum dot may be any shape that is used in the related art. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

As a size of a quantum dot or an elemental ratio of the quantum dot compound is adjusted, the energy band gap may be changed accordingly to produce light of various wavelengths from a quantum dot light emitting layer. Therefore, by using quantum dots as described above (for example, using quantum dots of different sizes or having different elemental ratios of the quantum dot compound), a light emitting element that emits light of various wavelengths may be achieved. For example, the size of the quantum dots or the elemental ratio of the quantum dot compound may be adjusted to emit red light, green light, and/or blue light. For example, the quantum dots may be configured to emit white light by combining light of various colors.

In the light emitting elements ED according to embodiments, as shown in each of FIG. 3 to FIG. 6, the electron transport region ETR may be provided on the light emitting layer EML. The electron transport region ETR may include at least one of an electron blocking layer HBL, an electron transport layer ETL, and an electron injection layer EIL. However, embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In an embodiment, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the light emitting layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

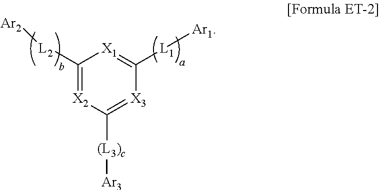

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl) anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl) naphthalen-1-yl)-[1,1′-biphenyl]-4-carbonitrile), or a mixture thereof, without limitation.

In an embodiment, the electron transport region ETR may include a compound selected from Compound Group 3.

In an embodiment, the electron transport region ETR may include at least one compound selected from Compounds ET1 to ET36:

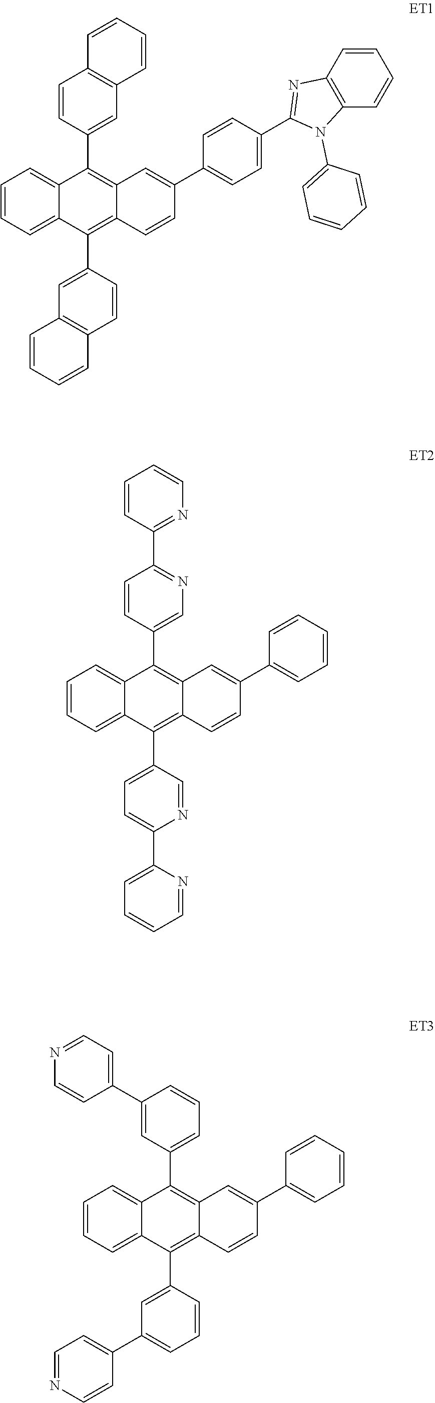 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

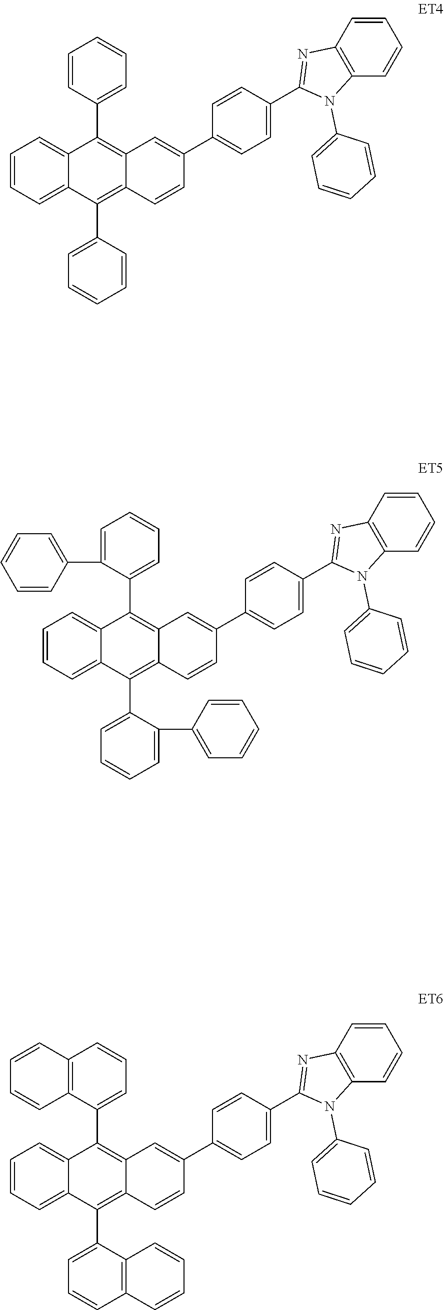 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

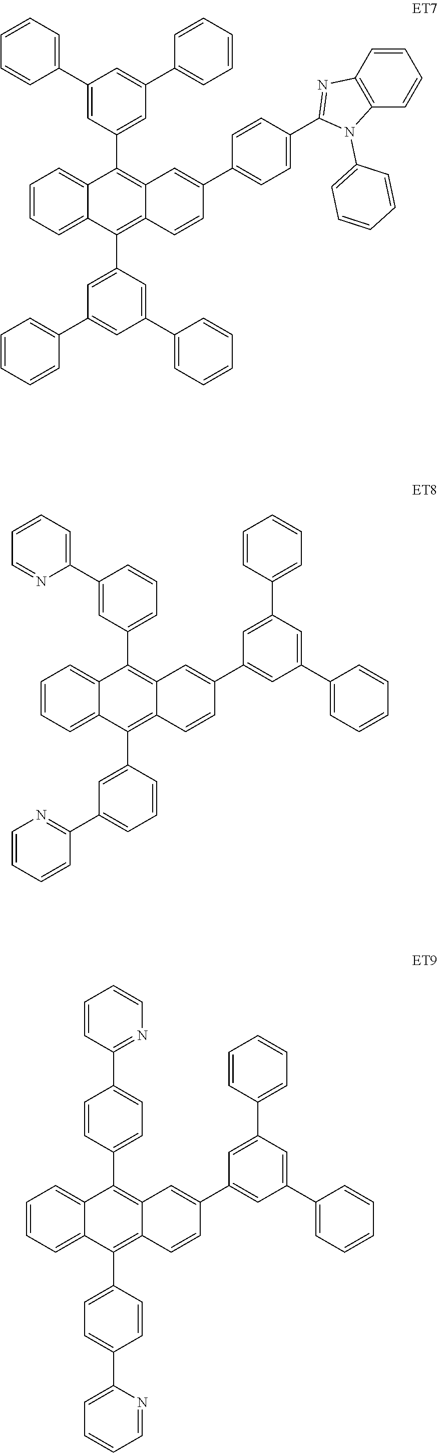 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

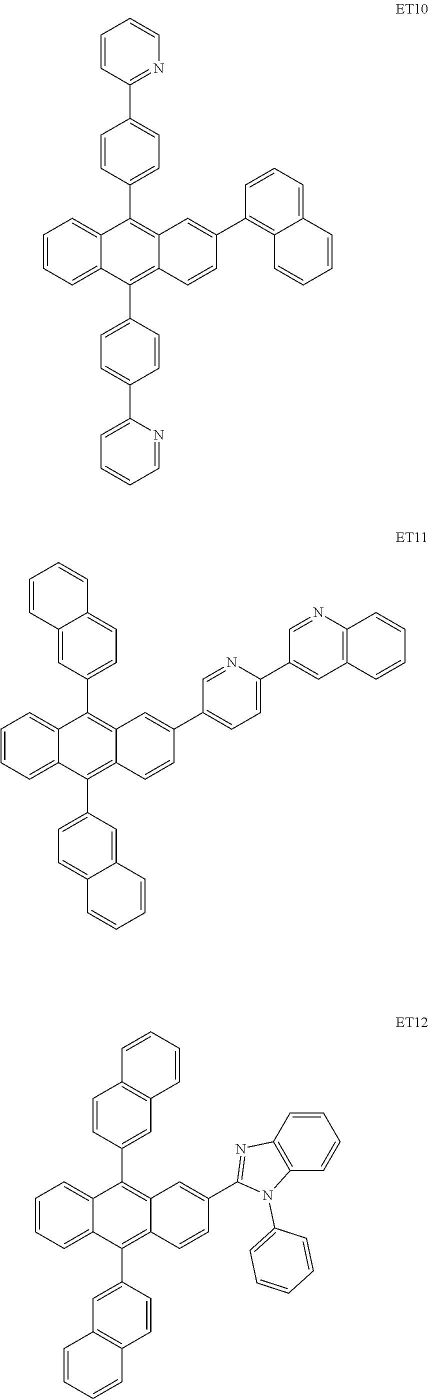 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

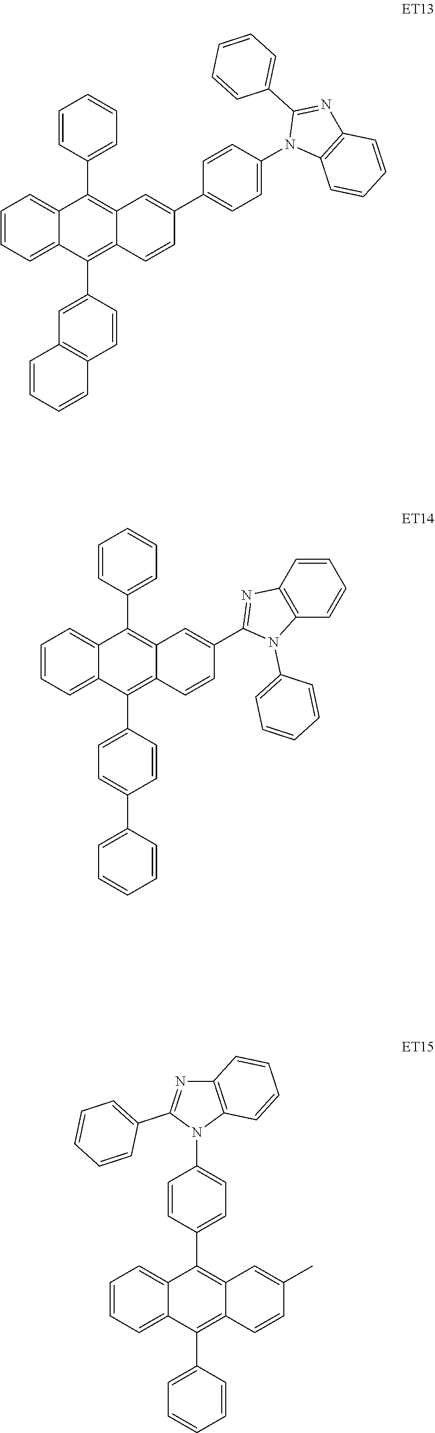 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

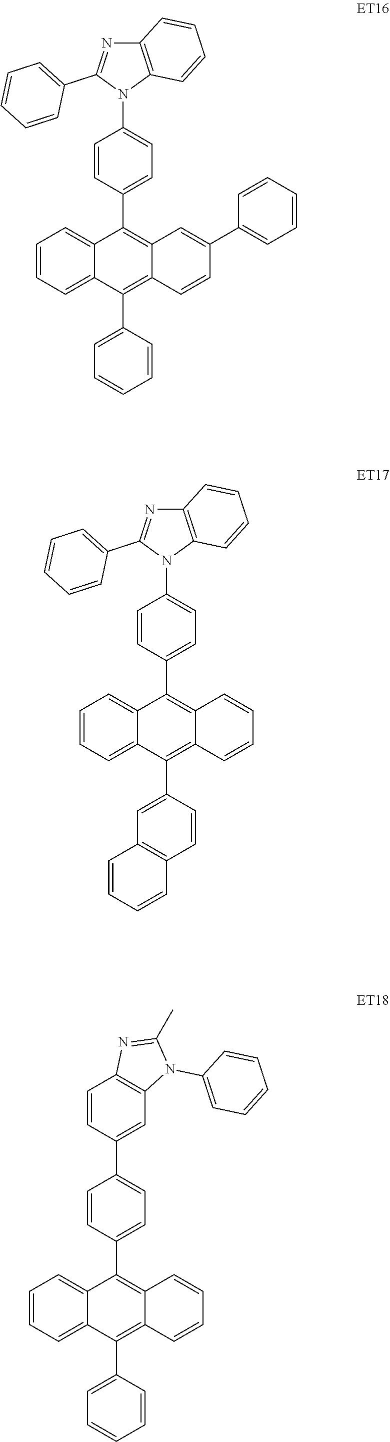 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

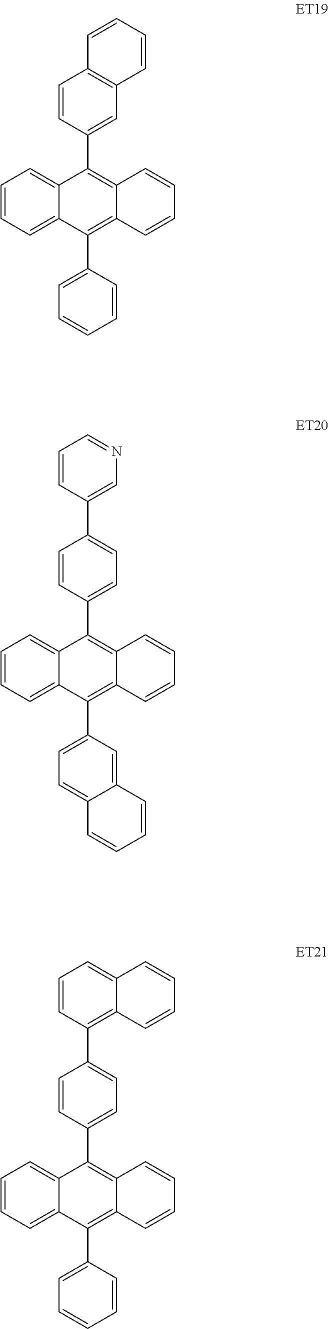

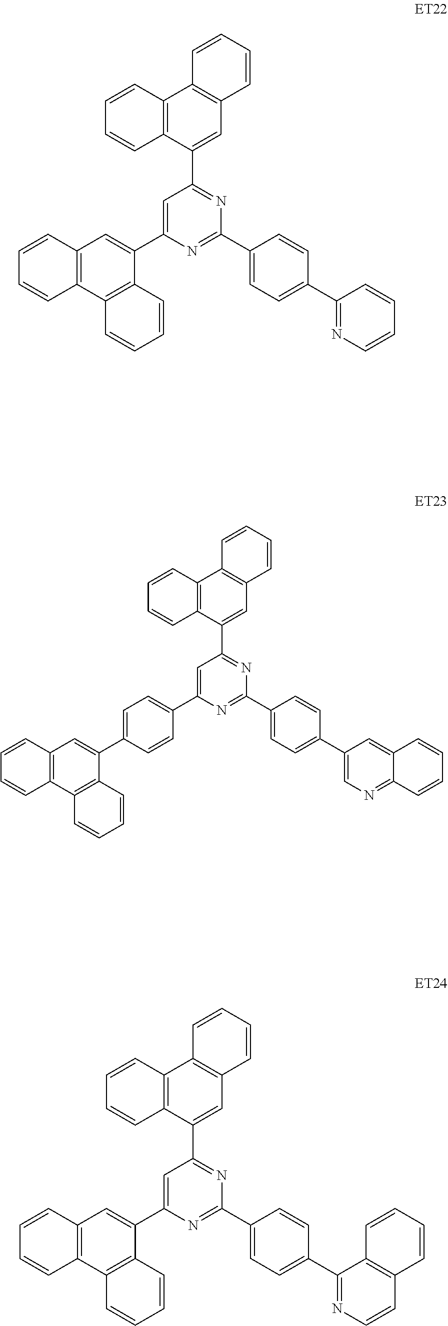 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

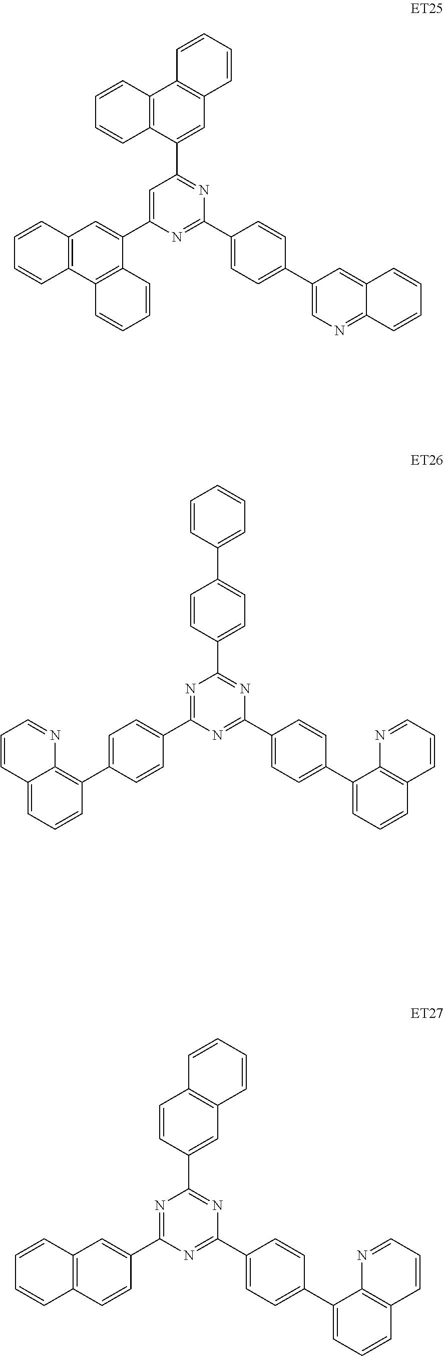 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

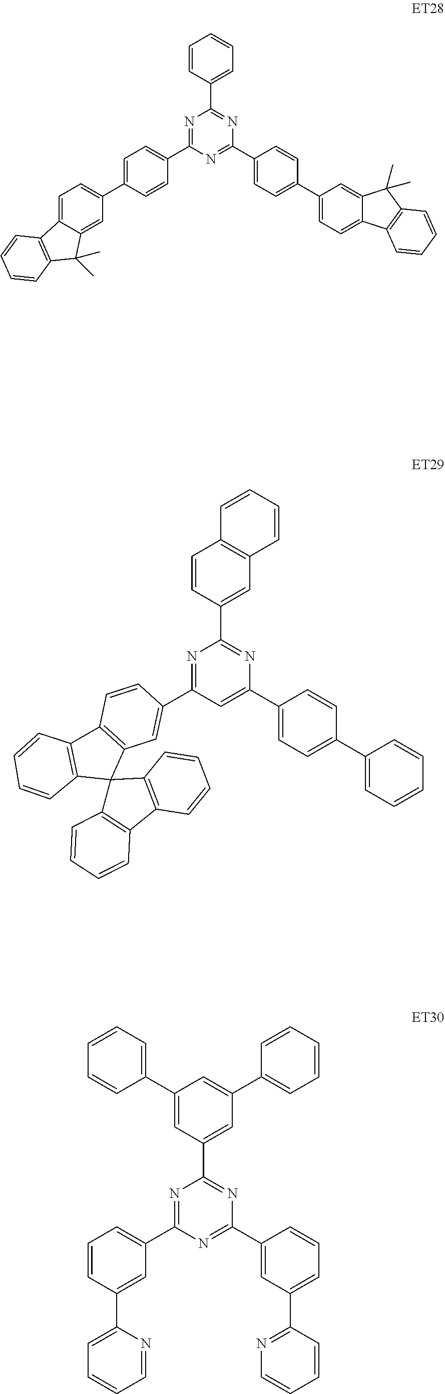 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

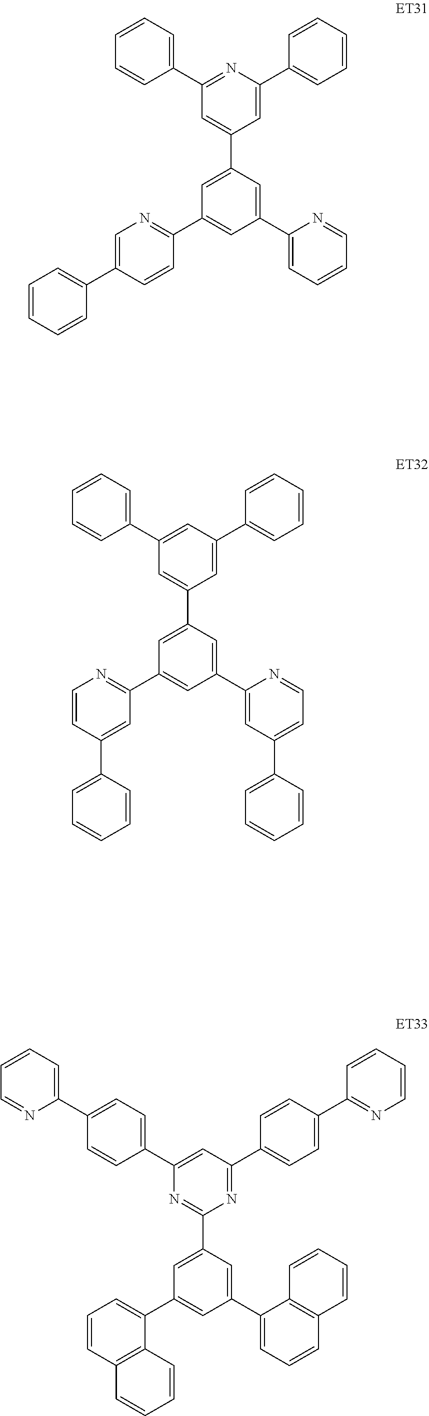 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2cc(-c3ccccc3)cc(-c3cc(-c4cc(-c5ccccc5)ccn4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

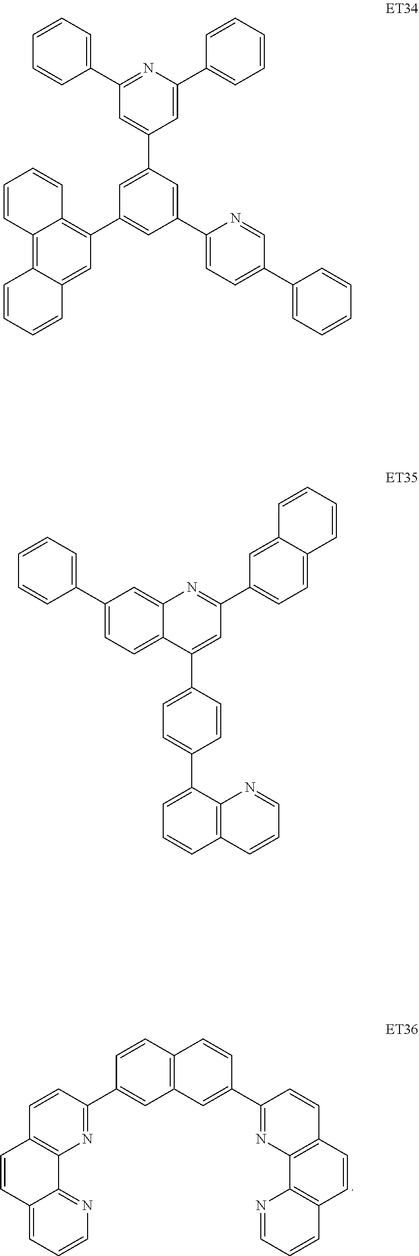 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI and KI, a lanthanide such as Yb, or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR may also be formed of a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen), in addition to the aforementioned materials. However, embodiments are not limited thereto.

The electron transport region ETR may include the compounds of the electron transport region ETR in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, L₁, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more of the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayer structure or a single layer structure.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), etc., or may include an epoxy resin, or an acrylate such as methacrylate. In an embodiment, the capping layer CPL may include at least one of Compounds P1 to P5, but embodiments are not limited thereto.

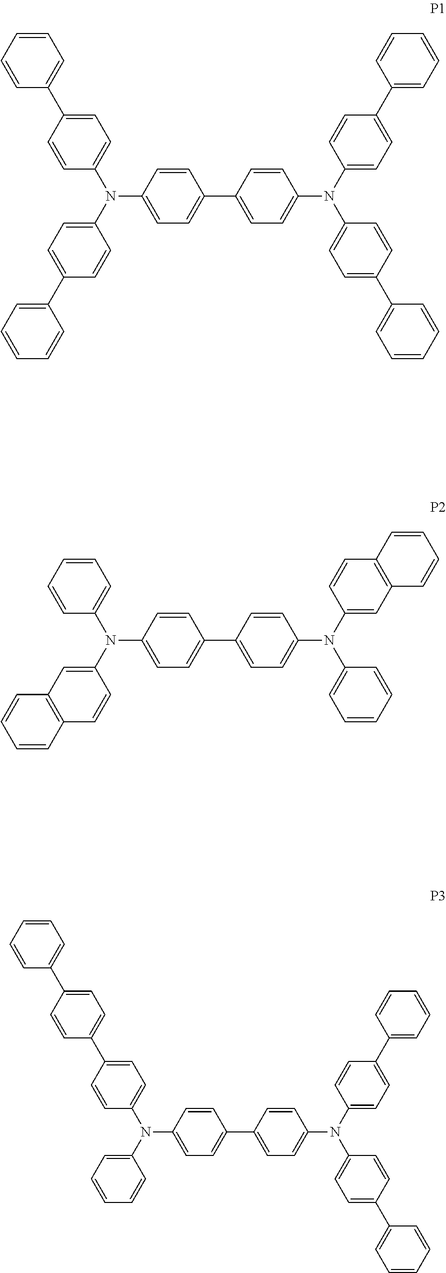 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

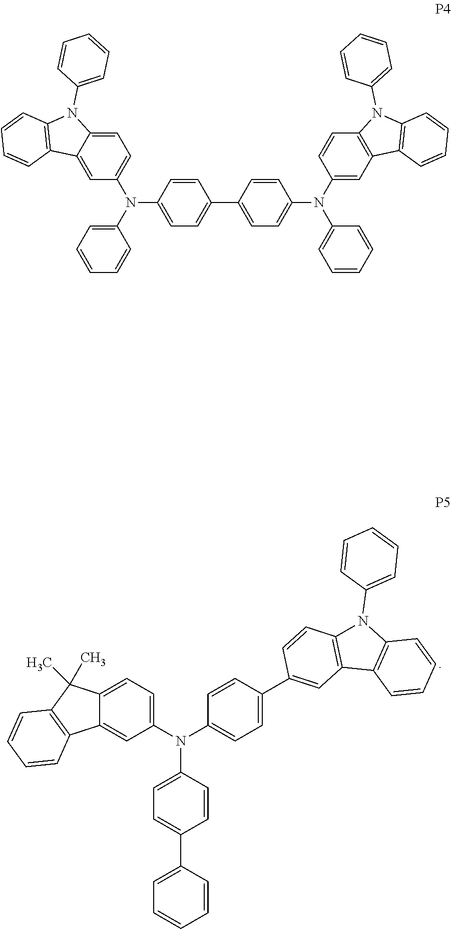 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

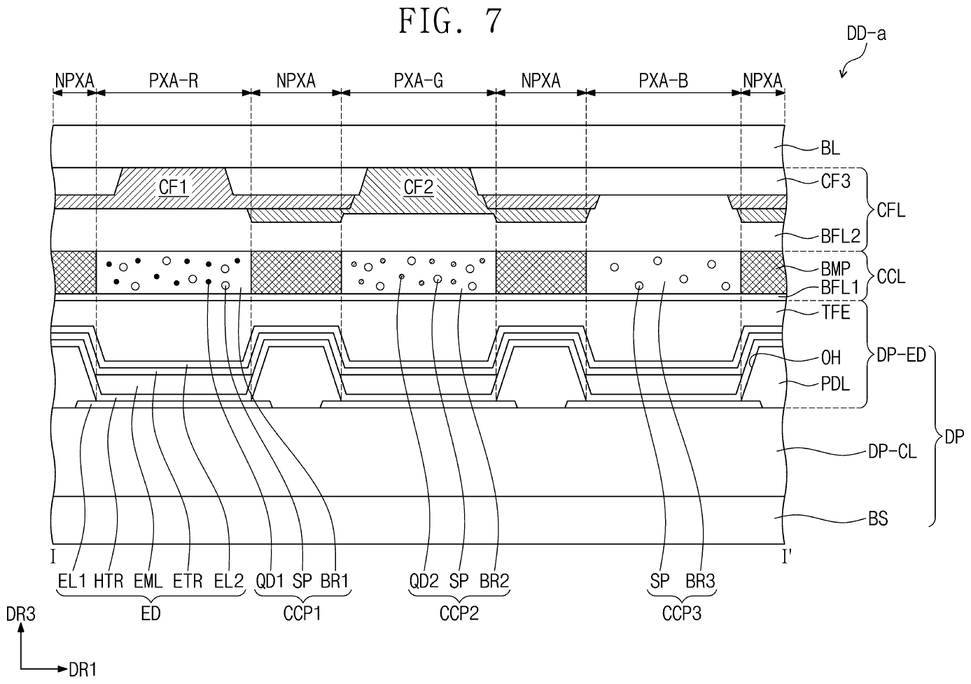

FIG. 7 to FIG. 10 are each a schematic cross-sectional view of a display device according to an embodiment. In the descriptions of the display devices according to embodiments as shown in FIG. 7 to FIG. 10, the features which have been described above with respect to FIG. 1 to FIG. 6 will not be explained again, and the differing features will be explained.

Referring to FIG. 7, the display device DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED, and the display device layer DP-ED may include a light emitting element ED.

The light emitting element ED may include a first electrode EL1, a hole transport region HTR disposed on the first electrode EL1, a light emitting layer EML disposed on the hole transport region HTR, an electron transport region ETR disposed on the light emitting layer EML, and a second electrode EL2 disposed on the electron transport region ETR. In embodiments, a structure of the light emitting element ED shown in FIG. 7 may be the same as a structure of a light emitting element according to one of FIG. 3 to FIG. 6 as described above.

The light emitting layer EML of the light emitting element ED included in the display device DD-a according to an embodiment may include the fused polycyclic compound according to an embodiment as described above.

Referring to FIG. 7, the light emitting layer EML may be disposed in an opening OH defined in a pixel defining film PDL. For example, the light emitting layer EML, which is separated by the pixel defining film PDL and correspondingly provided to each of the light emitting regions PXA-R, PXA-G, and PXA-B, may emit light in a same wavelength range. In the display device DD-a, the light emitting layer EML may emit blue light. Although not shown in the drawings, in an embodiment, the light emitting layer EML may be provided as a common layer for each of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and emit the resulting light. For example, the light controlling layer CCL may be a layer that includes a quantum dot or a layer that includes a phosphor.

The light controlling layer CCL may include light controlling parts CCP1, CCP2, and CCP3. The light controlling parts CCP1, CCP2, and CCP3 may be spaced apart from one another.

Referring to FIG. 7, a partition pattern BMP may be disposed between the light controlling parts CCP1, CCP2, and CCP3, that are spaced apart from one another, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light.

In an embodiment, the first light controlling part CCP1 may provide red light, which is the second color light, and the second light controlling part CCP2 may provide green light, which is the third color light. The third color controlling part CCP3 may provide blue light by transmitting the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are mediums in which the quantum dots QD1 and QD2 and the scatterer SP are dispersed, and may include various resin compositions, which may be referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. In an embodiment, a color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film that secures light transmittance. The barrier layers BFL1 and BFL2 may each independently further include an organic material. The barrier layers BFL1 and BFL2 may be composed of a single layer or of multiple layers.

In the display device DD-a, the color filter layer CFL may be disposed on the light controlling layer CCL. In an embodiment, the color filter layer CFL may be directly disposed on the light controlling layer CCL. For example, the barrier layer BFL2 may be omitted.

The color filter layer CFL may include filters CF1, CF2, and CF3. The first filter CF1, the second filter CF2, and the third filter CF3 may be disposed to respectively correspond to a red light emitting region PXA-R, a green light emitting region PXA-G, and a blue light emitting region PXA-B.

The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, the color filter layer CFL may further include a light blocking part (not shown). The light blocking part (not shown) may be a black matrix. The light blocking part (not shown) may include an organic light blocking material or an inorganic light blocking material, each including a black pigment or a black dye. The light blocking part (not shown) may prevent light leakage, and may separate the boundaries between adjacent filters CF1, CF2, and CF3.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

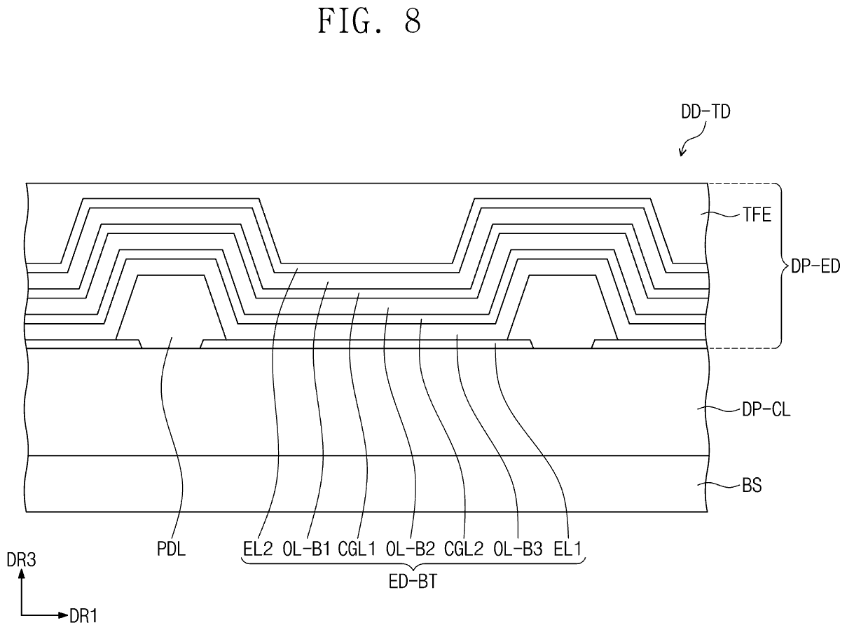

FIG. 8 is a schematic cross-sectional view of a portion of a display device according to an embodiment. In a display device DD-TD according to an embodiment, the light emitting element ED-BT may include light emitting structures OL-B1, OL-B2, and OL-B3. The light emitting element ED-BT may include a first electrode EL1 and a second electrode EL2 that are disposed opposite each other, and the light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, a light emitting layer EML (FIG. 7), and an electron transport region ETR, which may be disposed in that order between the first electrode EL1 and the second electrode EL2.

For example, the light emitting element ED-BT included in the display device DD-TD may be a light emitting element having a tandem structure that includes multiple light emitting layers.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light in different wavelength ranges, may emit white light.

Charge generating layers CGL1 and CGL2 may each be disposed between two adjacent light emitting structures among the light emitting structures OL-B1, OL-B2, and OL-B3. Charge generating layers CGL1 and CGL2 may each independently include a p-type charge generating layer and/or an n-type charge generating layer.

At least one of the light emitting structures OL-B1, OL-B2, and OL-B3 may each independently include the fused polycyclic compound according to an embodiment. For example, at least one of the light emitting layers that are included in the light emitting element ED-BT may each independently include the fused polycyclic compound according to an embodiment.

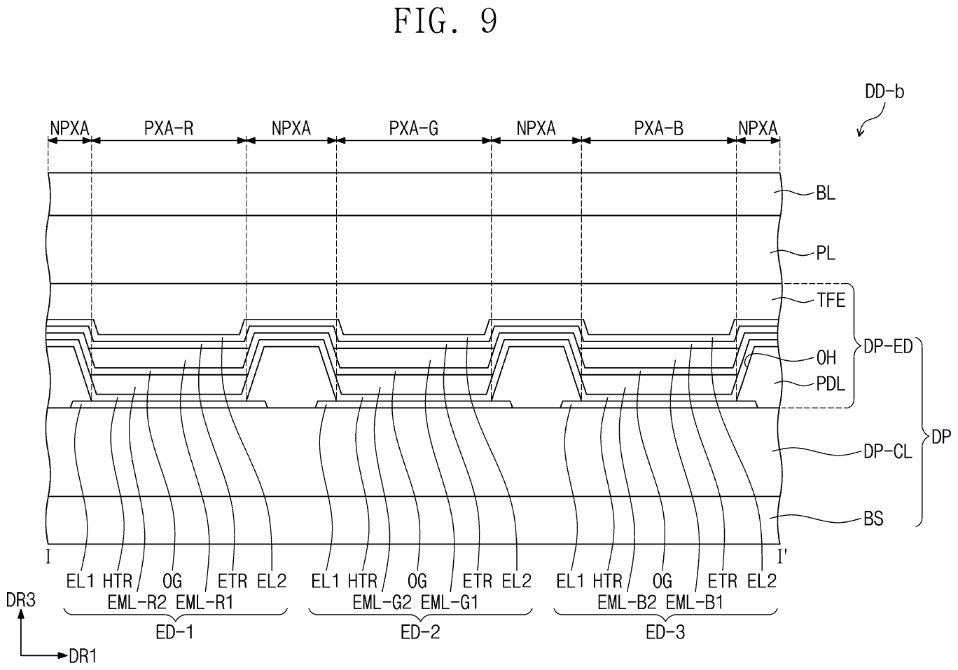

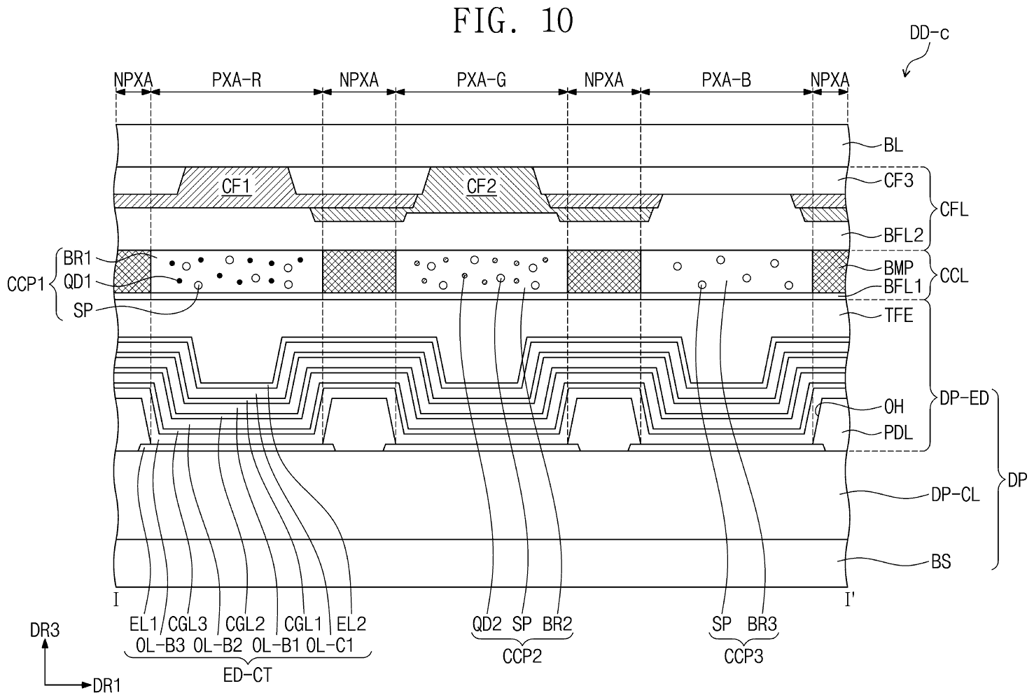

FIG. 9 is a schematic cross-sectional view of a display device DD-b according to an embodiment. FIG. 10 is a schematic cross-sectional view of a display device DD-c according to an embodiment.

Referring to FIG. 9, a display device DD-b according to an embodiment may include light emitting elements ED-1, ED-2, and ED-3 in which two light emitting layers are stacked. In comparison to the display device DD shown in FIG. 2, the embodiment shown in FIG. 9 is different at least in that the first to third light emitting elements ED-1, ED-2, and ED-3 each include two light emitting layers that are stacked in a thickness direction. In each of the first to third light emitting elements ED-1, ED-2, and ED-3, the two light emitting layers may emit light in a same wavelength range.

The first light emitting element ED-1 may include a first red light emitting layer EML-R1 and a second red light emitting layer EML-R2. The second light emitting element ED-2 may include a first green light emitting layer EML-G1 and a second green light emitting layer EML-G2. The third light emitting element ED-3 may include a first blue light emitting layer EML-B1 and a second blue light emitting layer EML-B2. An emission auxiliary part OG may be disposed between the first red light emitting layer EML-R1 and the second red light emitting layer EML-R2, between the first green light emitting layer EML-G1 and the second green light emitting layer EML-G2, and between the first blue light emitting layer EML-B1 and the second blue light emitting layer EML-B2.

The emission auxiliary part OG may have a single layer structure or a multilayer structure. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned in the openings OH defined in the pixel defining film PDL.

The first red light emitting layer EML-R1, the first green light emitting layer EML-G1, and the first blue light emitting layer EML-B1 may each be disposed between the electron transport region ETR and the emission auxiliary part OG. The second red light emitting layer EML-R2, the second green light emitting layer EML-G2, and the second blue light emitting layer EML-B2 may each be disposed between the emission auxiliary part OG and the hole transport region HTR.

For example, the first light emitting element ED-1 may include a first electrode EL1, a hole transport region HTR, a second red light emitting layer EML-R2, an emission auxiliary part OG, a first red light emitting layer EML-R1, an electron transport region ETR, and a second electrode EL2, which are stacked in that order. The second light emitting element ED-2 may include a first electrode EL1, a hole transport region HTR, a second green light emitting layer EML-G2, an emission auxiliary part OG, a first green light emitting layer EML-G1, an electron transport region ETR, and a second electrode EL2, which are stacked in that order. The third light emitting element ED-3 may include a first electrode EL1, a hole transport region HTR, a second blue light emitting layer EML-B2, an emission auxiliary part OG, a first blue light emitting layer EML-B1, an electron transport region ETR, and a second electrode EL2, which are stacked in that order.

An optical auxiliary layer PL may be disposed on the display device layer DP-ED. The optical auxiliary layer PL may include a polarization layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one light emitting layer included in the display device DD-b shown in FIG. 9 may include the fused polycyclic compound according to an embodiment. For example, in an embodiment, at least one of a first blue light emitting layer EML-B1 and a second blue light emitting layer EML-B2 may include the fused polycyclic compound.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 that are disposed opposite each other, and first to fourth light emitting structures OL-B1, OL-B2, OL-B3, and OL-C1 that are stacked in a thickness direction between the first electrode EL1 and the second electrode EL2. In an embodiment, the third light emitting structure OL-B3, the second light emitting structure OL-B2, the first light emitting structure OL-B1, and the fourth light emitting structure OL-C1 may be stacked in the stated order in a thickness direction.

Charge generating layers CGL1, CGL2, and CGL3 may each be disposed between two adjacent light emitting structures among the first to fourth light emitting structures OL-B1, OL-B2, OL-B3, and OL-C1. For example, a first charge generating layer CGL1 may be disposed between the first light emitting structure OL-B1 and the fourth light emitting structure OL-C1. For example, a second charge generating layer CGL2 may be disposed between the first light emitting structure OL-B1 and the second light emitting structure OL-B2. For example, a third charge generating layer CGL3 may be disposed between the second light emitting structure OL-B2 and the third light emitting structure OL-B3.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength ranges that are different from each other.

The charge generating layers CGL1, CGL2, and CGL3 that are disposed between adjacent light emitting structures among the first to fourth light emitting structures OL-B1, OL-B2, OL-B3, and OL-C1 may each independently include a p-type charge generating layer and/or an n-type charge generating layer.

At least one of the light emitting structures OL-B1, OL-B2, OL-B3, and OL-C1 included in the display device DD-c may each independently include the fused polycyclic compound according to an embodiment. For example, at least one of the first to third light emitting structures OL-B1, OL-B2, and OL-B3 may each independently include the fused polycyclic compound.

The light emitting element ED according to an embodiment may include the fused polycyclic compound represented by Formula 1 in at least one functional layer disposed between the first electrode EL1 and the second electrode EL2, and thus, may exhibit excellent luminous efficiency and improved lifespan properties. For example, the light emitting layer EML of the light emitting element ED may include the fused polycyclic compound according to an embodiment, and the light emitting element ED may exhibit long lifespan properties.

In an embodiment, an electronic apparatus may include a display device that includes multiple light emitting elements and a control part that controls the display device. The electronic apparatus may be an apparatus that is activated by an electrical signal. The electronic apparatus may include display devices according to various embodiments as described herein. Examples of an electronic apparatus may include large, medium-sized, and small apparatuses, such as a television, a monitor, a billboard, a personal computer, a laptop computer, a personal digital terminal, a display device for a vehicle, a game console, a portable electronic device, and a camera.

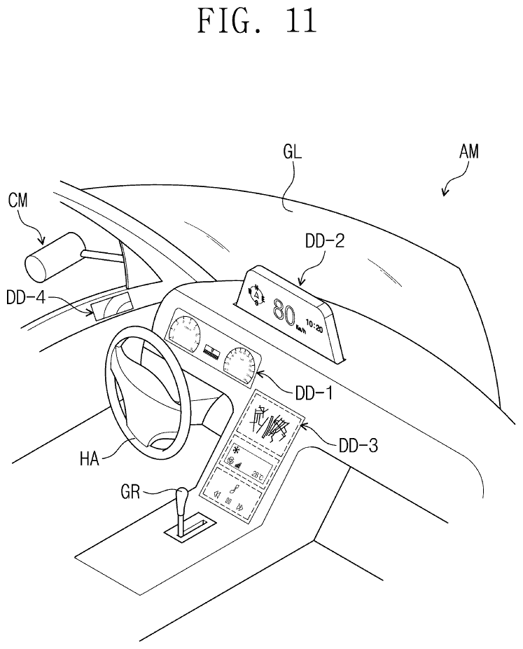

FIG. 11 is a schematic perspective view of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c, as explained above with reference to FIGS. 1, 2, and 7 to 10.

In FIG. 11, a vehicle AM is shown as an automobile, but this is only an example, and the first to fourth display devices DD-1, DD-2, DD-3, and DD-4 may be disposed in various transportation means such as a bicycle, a motorcycle, a train, a ships, or an airplane. In an embodiment, at least one of the first to fourth display devices DD-1, DD-2, DD-3, and DD-4, each having a structure according to one of display devices DD, DD-TD, DD-a, DD-b, and DD-c, may be included in a personal computer, a laptop computer, a personal digital terminal, a game console, a portable electronic device, a television, a monitor, a billboard, or the like. However, these are merely listed as examples, and the display device may be included in other electronic apparatuses.

At least one of the first to fourth display devices DD-1, DD-2, DD-3, and DD-4 may each independently include a light emitting element ED according to an embodiment as described with reference to any of FIGS. 3 to 6. The light emitting element ED may include a fused polycyclic compound according to an embodiment. At least one of the first to fourth display devices DD-1, DD-2, DD-3, and DD-4 may each independently include a light emitting element ED that includes the fused polycyclic compound, thereby exhibiting an improved display service life.

Referring to FIG. 11, a vehicle AM may include a steering wheel HA and a gearshift GR for operating the vehicle AM. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), and an image that represents a fuel gauge. The first scale and the second scale may each be represented by a digital image.

A second display device DD-2 may be disposed in a second region facing a driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed of the vehicle AM and may further include information such as the current time. Although not shown in the drawings, in an embodiment, the second information of the second display device DD-2 may be displayed by being projected onto the front window GL.

A third display device DD-3 may be disposed in a third region that is adjacent to the gearshift GR. For example, the third display device DD-3 may be disposed between the driver's seat and a passenger seat, and may be a center information display (CID) for the vehicle AM that displays third information. The passenger seat may be a seat that is spaced apart from the driver's seat, and the gearshift GR may be disposed between the driver's seat and the passenger seat. The third information may include information about traffic or road conditions (for example, navigation information), information about music or radio that is playing, a dynamic image (or video) that is being displayed, information about the temperature in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM disposed at an exterior of the vehicle AM. The fourth information may include an exterior image of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, a fused polycyclic compound according to an embodiment and a light emitting element according to an embodiment will be described with reference to the Examples and the Comparative Examples. The Examples described below are only provided to assist in understanding the disclosure, and the scope thereof is not limited thereto.

### Examples

### 1. Synthesis of Fused Polycyclic Compound

A method for synthesizing a fused polycyclic compound according to embodiments will be described in detail with reference to a synthesis method for Compounds 1, 5, 9, 24, 30, 34, 45, and 54. The synthesis method for the fused polycyclic compounds described below is only provided as an example, and the synthesis method for the fused polycyclic compound according to an embodiment is not limited to the Examples below.

### (1) Synthesis of Compound 1

Compound 1 according to an embodiment may be synthesized by, for example, the following reaction.

### Synthesis of Intermediate 2a

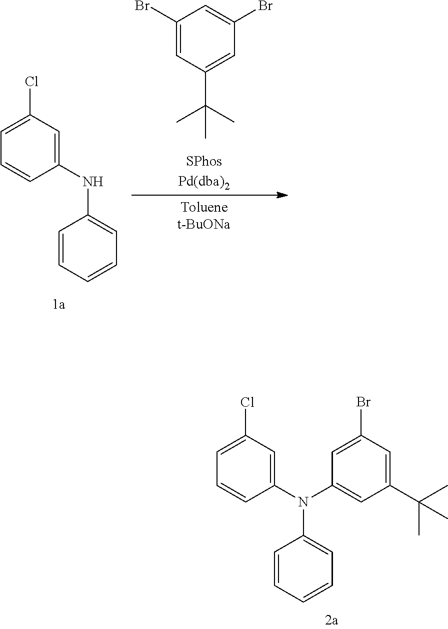 [SMILES: Clc1cccc(Nc2ccccc2)c1 ; CC(C)(C)c1cc(Br)cc(Br)c1 ; CC(C)(C)c1cc(Br)cc(N(c2ccccc2)c2cccc(Cl)c2)c1]

Under an Ar atmosphere, 1,3-dibromo-5-tert-butylbenzene (33.5 g), Intermediate 1a (23.4 g), Pd(dba)₂ (2.2 g) (dba=dibenzylidene acetone), SPhos (1.7 g) (SPhos=2-Dicyclohexylphosphino-2′,6′-dimethoxybiphenyl), and NaOtBu (6.9 g) were placed in a 2,000 mL three-necked flask, dissolved in toluene (850 mL), and heated and refluxed for 1 hour. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 30.4 g of Intermediate 2a (yield 64%). The mass number of Intermediate 2a measured by FAB-MS measurement was 413.

### Synthesis of Intermediate 4a

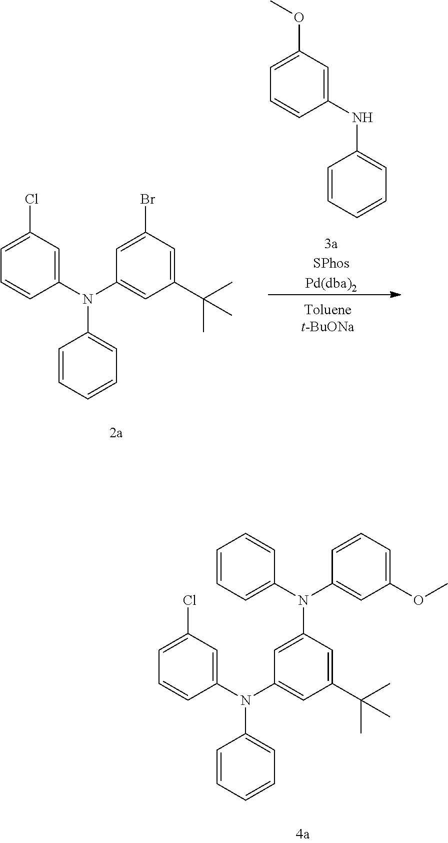 [SMILES: CC(C)(C)c1cc(Br)cc(N(c2ccccc2)c2cccc(Cl)c2)c1 ; COc1cccc(Nc2ccccc2)c1 ; COc1cccc(N(c2ccccc2)c2cc(N(c3ccccc3)c3cccc(Cl)c3)cc(C(C)(C)C)c2)c1]

Under an Ar atmosphere, Intermediate 2a (30.4 g), Intermediate 3a (14.6 g), Pd(dba)₂ (2.1 g), SPhos (1.6 g), and NaOtBu (6.8 g) were placed in a 2,000 mL three-necked flask, dissolved in toluene (900 mL), and heated and refluxed for 2 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 27.7 g of Intermediate 4a (yield 71%). The mass number of Intermediate 4a measured by FAB-MS measurement was 532.

### Synthesis of Intermediate 5a

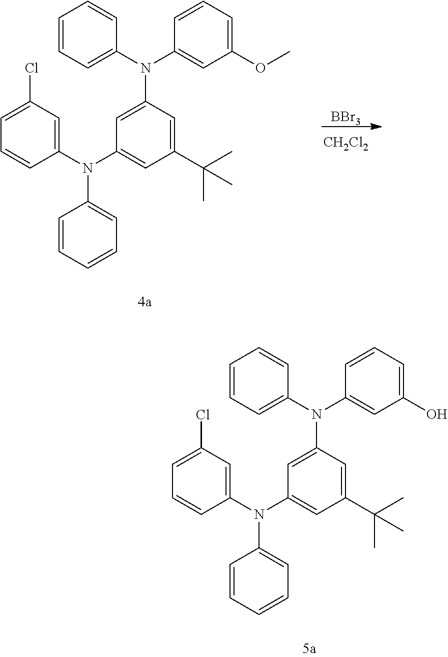 [SMILES: COc1cccc(N(c2ccccc2)c2cc(N(c3ccccc3)c3cccc(Cl)c3)cc(C(C)(C)C)c2)c1 ; "BBr3" ; "CH2Cl2" ; CC(C)(C)c1cc(N(c2ccccc2)c2cccc(O)c2)cc(N(c2ccccc2)c2cccc(Cl)c2)c1]

Under an Ar atmosphere, CH₂Cl₂ (52 mL) and Intermediate 4a (27.7 g) were added to a 500 mL three-necked flask, and the solution was cooled to 0° C. using an ice bath. BBr₃ (39 g in CH₂Cl₂ (100 mL)) was added dropwise to the cooled solution for 30 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 21.1 g of Intermediate 5a (yield 78%). The mass number of Intermediate 5a measured by FAB-MS measurement was 518.

### Synthesis of Intermediate 7a

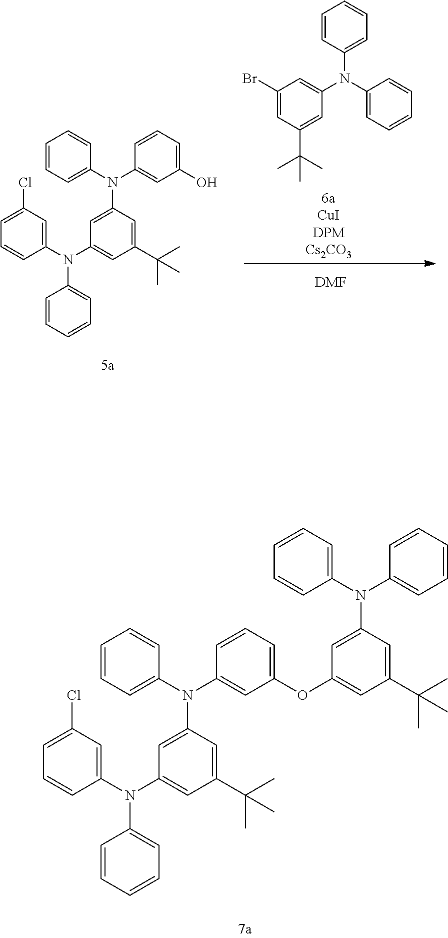

Under an Ar atmosphere, Intermediate 5a (21.1 g), Intermediate 6a (15.0 g), CuI (1.2 g), dipivaloylmethane (DPM) (2.0 g), and Cs₂CO₃ (26 g) were placed in a 1,000 mL three-necked flask, dissolved in DMF (40 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 20.9 g of Intermediate 7a (yield 63%). The mass number of Intermediate 7a measured by FAB-MS measurement was 817.

### Synthesis of Intermediate 8a

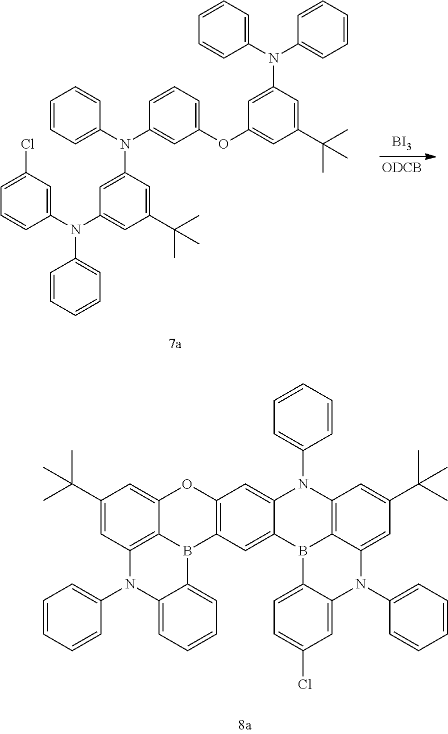

Under an Ar atmosphere, Intermediate 7a (20.9 g) was placed in a 500 mL three-necked flask, dissolved in o-Dichlorobenzene (70 mL), cooled to 0° C. in an ice bath, and added with boron triiodide (60.1 g), and the mixture was heated and stirred at 170° C. for 18 hours, cooled to 0° C. in an ice bath, and added with triethylamine (100 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 4.9 g of Intermediate 8a (yield 23%). The mass number of Intermediate 8a measured by FAB-MS measurement was 833.

### Synthesis of Compound 1

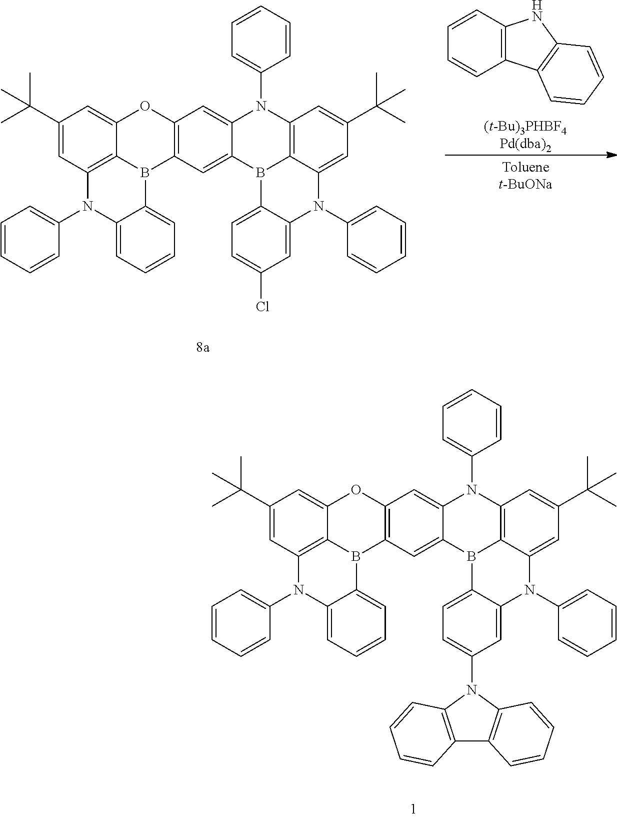

Under an Ar atmosphere, Intermediate 8a (4.9 g), carbazole (2.0 g), Pd(dba)₂ (0.4 g), tri-tert-butylphosphonium tetrafluoroborate ([P(tBu)₃H]BF₄, 0.4 g), and NaOtBu (1.1 g) were placed in a 500 mL three-necked flask, dissolved in toluene (20 mL), and heated and refluxed for 16 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 2.1 g of Compound 1 (yield 37%). The mass number of Compound 1 measured by FAB-MS measurement was 965.

### (2) Synthesis of Compound 5

Compound 5 according to an embodiment may be synthesized by, for example, the following reaction.

### Synthesis of Intermediate 10a

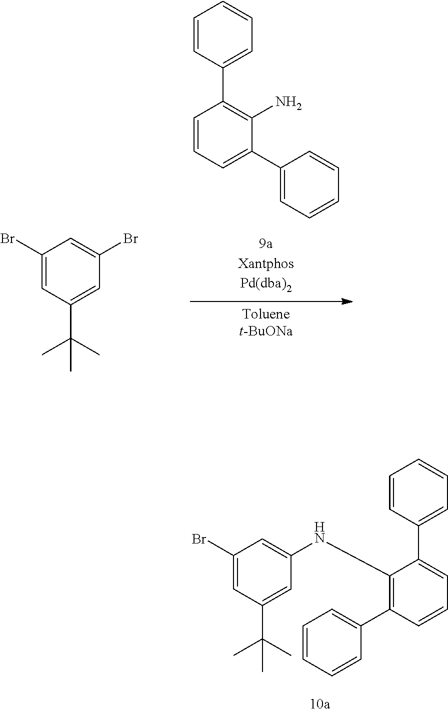 [SMILES: Nc1c(-c2ccccc2)cccc1-c1ccccc1 ; CC(C)(C)c1cc(Br)cc(Br)c1 ; CC(C)(C)c1cc(Br)cc(Nc2c(-c3ccccc3)cccc2-c2ccccc2)c1]

Under an Ar atmosphere, 1,3-dibromo-5-tert-butylbenzene (376 g), Intermediate 9a (316 g), Pd(dba)₂ (39 g), 4,5-Bis(diphenylphosphino)-9,9-dimethylxanthene (Xantphos) (79 g), and NaOtBu (263 g) were placed in a 5,000 mL three-necked flask, dissolved in toluene (2700 mL), and heated and refluxed for 7 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 359 g of Intermediate 10a (yield 61%). The mass number of Intermediate 10a measured by FAB-MS measurement was 455.

### Synthesis of Intermediate 11a

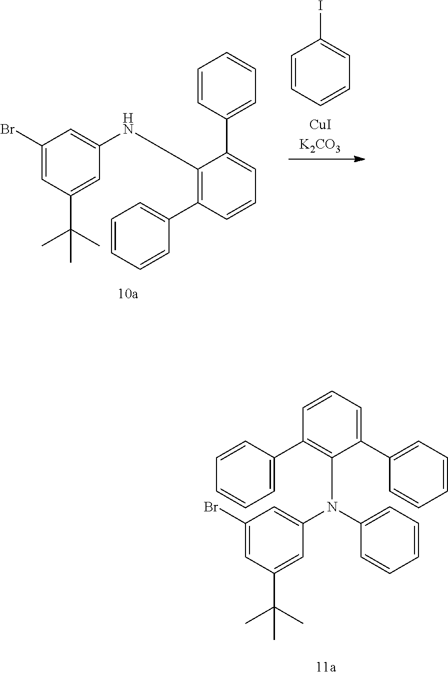

Under an Ar atmosphere, Intermediate 10a (359 g), I-C₆H₅ (800 g), CuI (161 g), and K₂CO₃ (138 g) were added to a 2,000 mL three-necked flask and heated and stirred at 190° C. for 96 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 285 g of Intermediate 11a (yield 68%). The mass number of Intermediate 11a measured by FAB-MS measurement was 531.

### Synthesis of Intermediate 13a

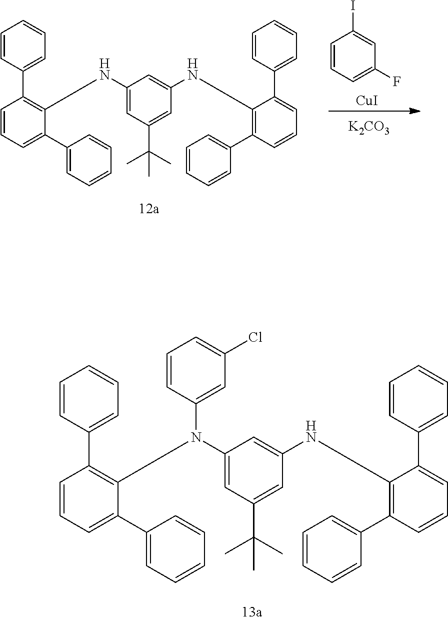

Under an Ar atmosphere, Intermediate 12a (307 g), 1-Chloro-3-iodobenzene (471 g), CuI (376 g), and K₂CO₃ (273 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 217 g of Intermediate 13a (yield 60%). The mass number of Intermediate 13a measured by FAB-MS measurement was 730.

### Synthesis of Intermediate 15a

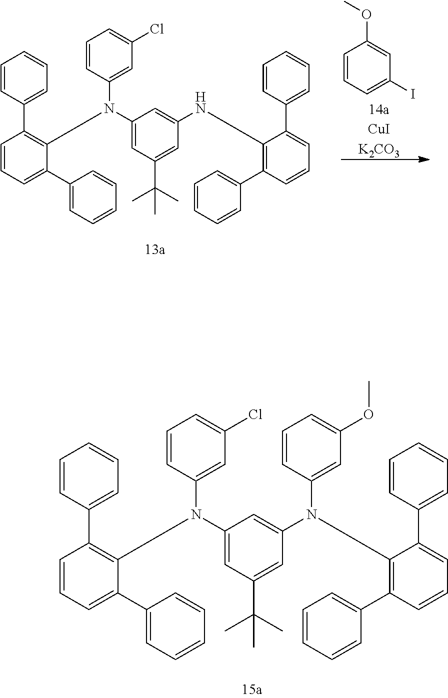

Under an Ar atmosphere, Intermediate 13a (217 g), Intermediate 14a (277 g), CuI (225 g), and K₂CO₃ (184 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 169 g of Intermediate 15a (yield 68%). The mass number of Intermediate 15a measured by FAB-MS measurement was 836.

### Synthesis of Intermediate 16a

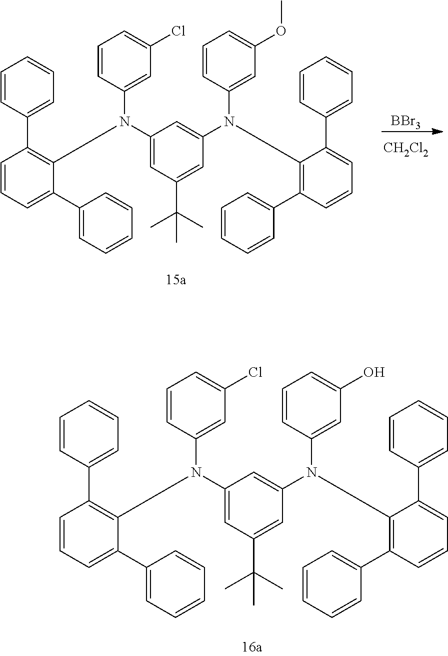

Under an Ar atmosphere, CH₂Cl₂ (300 mL) and Intermediate 15a (169 g) were added to a 1,000 mL three-necked flask, and the solution was cooled to 0° C. using an ice bath. BBr₃ (150 g in CH₂Cl₂ (300 mL)) was added dropwise to the cooled solution for 60 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 120 g of Intermediate 16a (yield 72%). The mass number of Intermediate 16a measured by FAB-MS was 822.

### Synthesis of Intermediate 17a

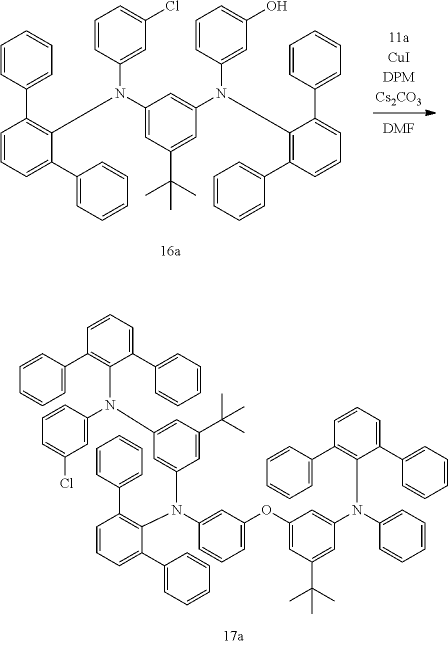

Under an Ar atmosphere, Intermediate 16a (120 g), Intermediate 11a (85.2 g), CuI (7.2 g), dipivaloylmethane (DPM) (12.0 g), and Cs₂CO₃ (160 g) were placed in a 1,000 mL three-necked flask, dissolved in DMF (100 mL), and heated and refluxed for 11 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 38.9 g of Intermediate 17a (yield 21%). The mass number of Intermediate 17a measured by FAB-MS measurement was 1274.

### Synthesis of Intermediate 18a

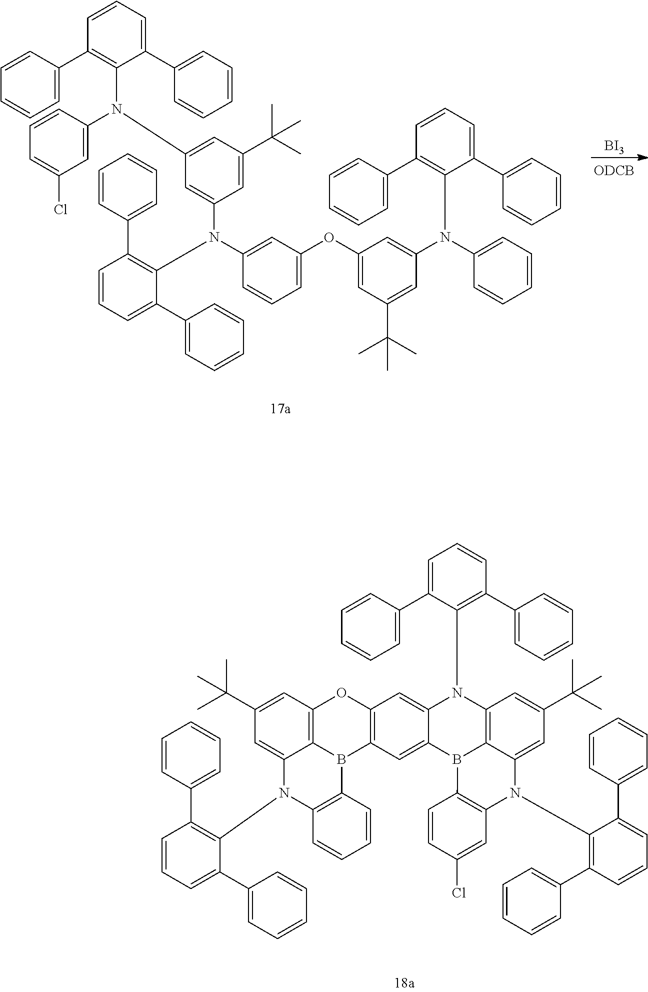

Under an Ar atmosphere, Intermediate 17a (38.9 g) was placed in a 500 mL three-necked flask, dissolved in o-Dichlorobenzene (85 mL), cooled to 0° C. in an ice bath, and added with boron triiodide (47.8 g), and the mixture was heated and stirred at 180° C. for 16 hours, cooled to 0° C. in an ice bath, and added with triethylamine (120 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 7.1 g of Intermediate 18a (yield 18%). The mass number of Intermediate 18a measured by FAB-MS measurement was 1290.

### Synthesis of Compound 5

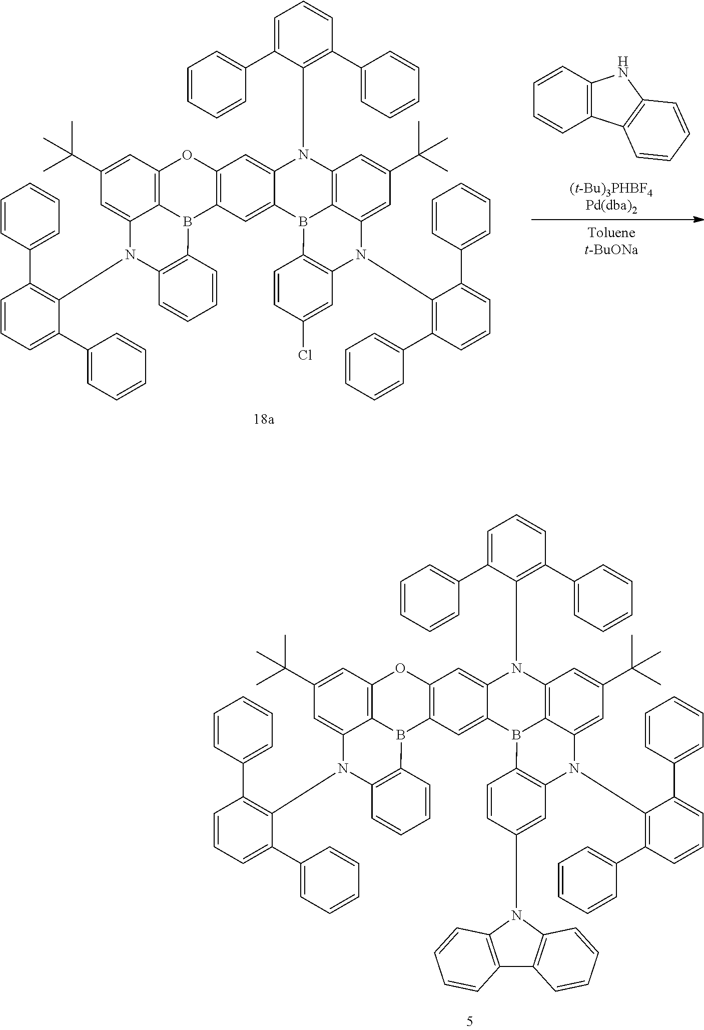 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(Cl)cc1N2c1c(-c2ccccc2)cccc1-c1ccccc1 ; c1ccc2c(c1)[nH]c1ccccc12 ; CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(-n3c4ccccc4c4ccccc43)cc1N2c1c(-c2ccccc2)cccc1-c1ccccc1]

Under an Ar atmosphere, Intermediate 18a (7.1 g), carbazole (1.1 g), Pd(dba)₂ (0.8 g), tri-tert-butylphosphonium tetrafluoroborate ([P(tBu)₃H]BF₄, 0.8 g), and NaOtBu (2.2 g) were placed in a 500 mL three-necked flask, dissolved in toluene (25 mL), and heated and refluxed for 24 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 3.2 g of Compound 5 (yield 41%). The mass number of Compound 5 measured by FAB-MS measurement was 1421.

### (3) Synthesis of Compound 9

Compound 9 according to an embodiment may be synthesized by, for example, the following reaction.

### Synthesis of Intermediate 19a

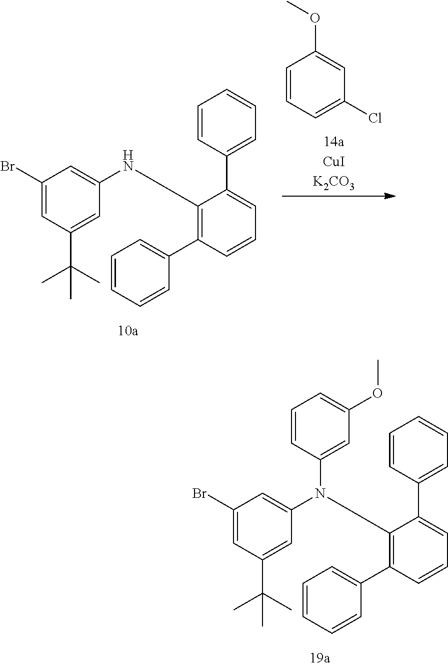

Under an Ar atmosphere, Intermediate 10a (318 g), Intermediate 14a (655 g), CuI (532 g), and K₂CO₃ (386 g) were added to a 3,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 244 g of Intermediate 19a (yield 62%). The mass number of Intermediate 19a measured by FAB-MS measurement was 561.

### Synthesis of Intermediate 21a

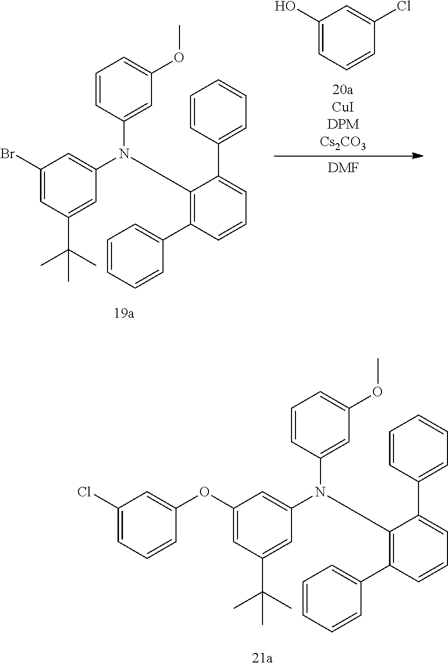

Under an Ar atmosphere, Intermediate 19a (244 g), Intermediate 20a (58.5 g), CuI (15.4 g), dipivaloylmethane (DPM) (24.0 g), and Cs₂CO₃ (320 g) were placed in a 3,000 mL three-necked flask, dissolved in DMF (150 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 108 g of Intermediate 21a (yield 41%). The mass number of Intermediate 21a measured by FAB-MS measurement was 609.

### Synthesis of Intermediate 22a

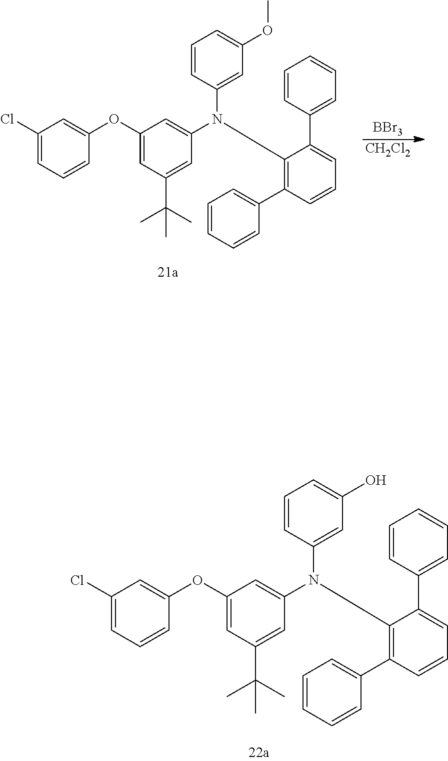

Under an Ar atmosphere, CH₂Cl₂ (300 mL) and Intermediate 21a (108 g) were added to a 2,000 mL three-necked flask, and the solution was cooled to 0° C. using an ice bath. BBr₃ (150 g in CH₂Cl₂ (300 mL)) was added dropwise to the cooled solution for 60 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 84.9 g of Intermediate 22a (yield 80%). The mass number of Intermediate 22a measured by FAB-MS measurement was 595.

### Synthesis of Intermediate 23a

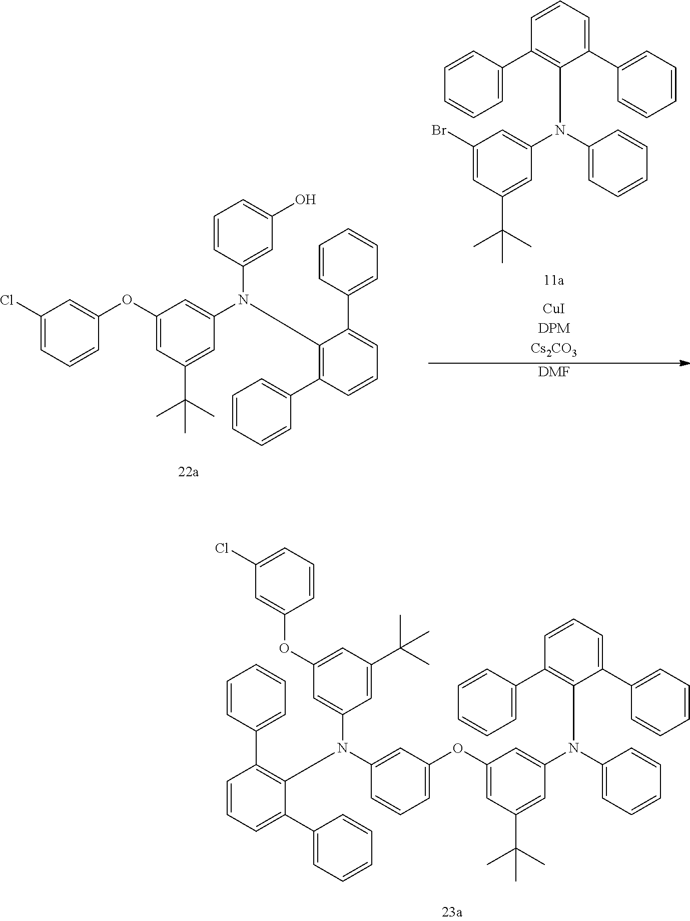

Under an Ar atmosphere, Intermediate 22a (84.9 g), Intermediate 11a (79.8 g), CuI (10.2 g), dipivaloylmethane (DPM) (16.1 g), and Cs₂CO₃ (220 g) were placed in a 2,000 mL three-necked flask, dissolved in DMF (120 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 43.3 g of Intermediate 23a (yield 29%). The mass number of Intermediate 23a measured by FAB-MS measurement was 1047.

### Synthesis of Intermediate 24a

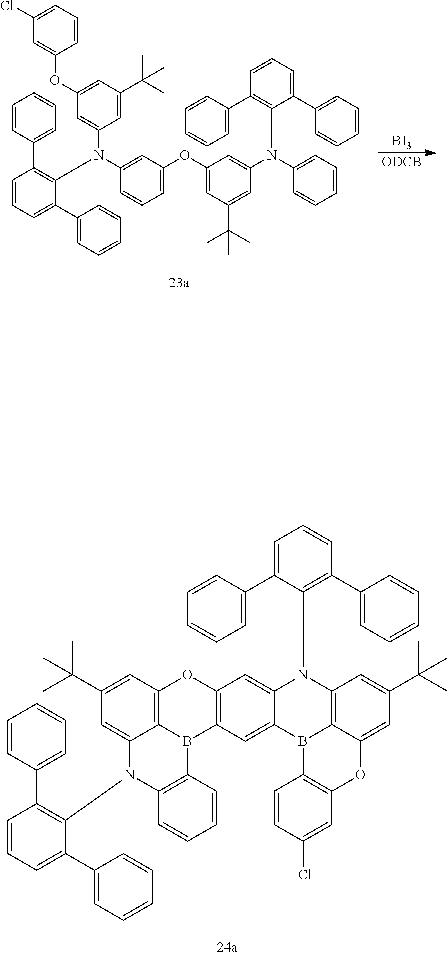

Under an Ar atmosphere, Intermediate 23a (43.3 g) was placed in a 500 mL three-necked flask, dissolved in o-Dichlorobenzene (80 mL), cooled to 0° C. in an ice bath, and added with boron triiodide (64.8 g), and the mixture was heated and stirred at 180° C. for 24 hours, cooled to 0° C. in an ice bath, and added with triethylamine (150 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 6.6 g of Intermediate 24a (yield 15%). The mass number of Intermediate 24a measured by FAB-MS measurement was 1063.

### Synthesis of Compound 9

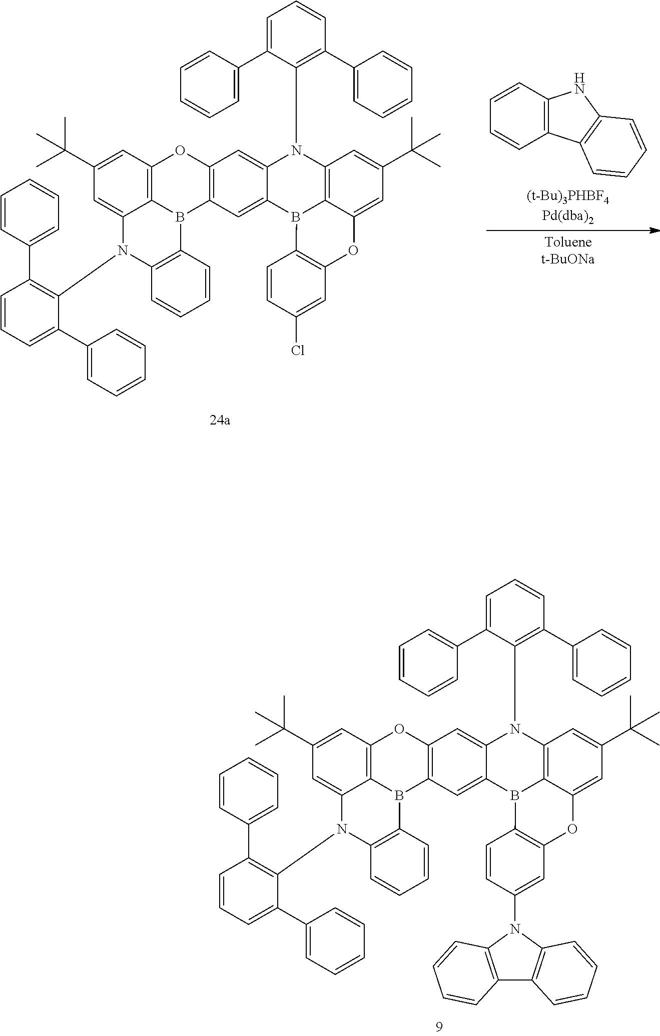 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(Cl)cc1O2 ; c1ccc2c(c1)[nH]c1ccccc12 ; CC(C)(C)c1cc2c3c(c1)N(c1c(-c4ccccc4)cccc1-c1ccccc1)c1ccccc1B3c1cc3c(cc1O2)N(c1c(-c2ccccc2)cccc1-c1ccccc1)c1cc(C(C)(C)C)cc2c1B3c1ccc(-n3c4ccccc4c4ccccc43)cc1O2]

Under an Ar atmosphere, Intermediate 24a (6.6 g), carbazole (2.1 g), Pd(dba)₂ (1.6 g), tri-tert-butylphosphonium tetrafluoroborate ([P(tBu)₃H]BF₄, 1.6 g), and NaOtBu (4.2 g) were placed in a 500 mL three-necked flask, dissolved in toluene (30 mL), and heated and refluxed for 24 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 2.9 g of Compound 9 (yield 39%). The mass number of Compound 9 measured by FAB-MS measurement was 1194.

### (4) Synthesis of Compound 24

Compound 24 according to an embodiment may be synthesized by, for example, the following reaction.

### Synthesis of Intermediate 25a

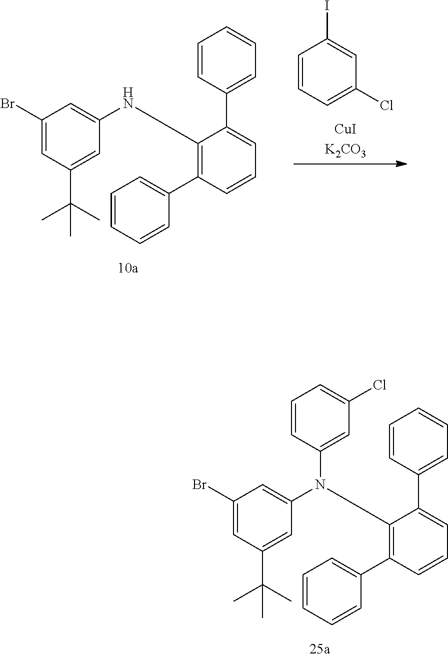

Under an Ar atmosphere, Intermediate 10a (227 g), 1-Chloro-3-iodobenzene (256 g), CuI (380 g), and K₂CO₃ (276 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 244 g of Intermediate 25a (yield 72%). The mass number of Intermediate 25a measured by FAB-MS measurement was 567.

### Synthesis of Intermediate 26a

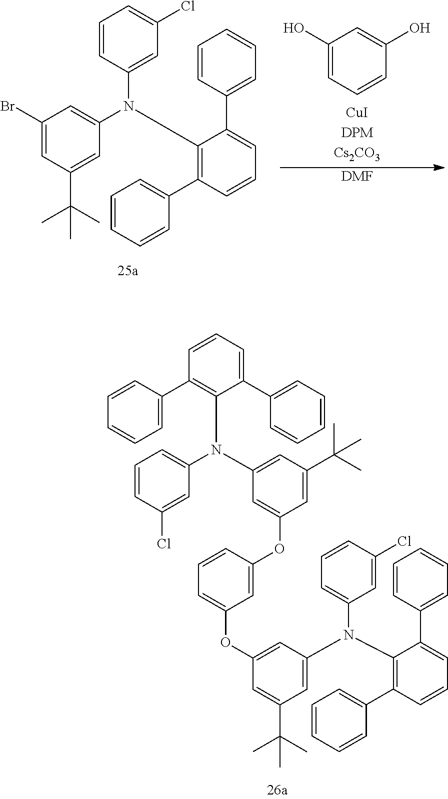

Under an Ar atmosphere, Intermediate 25a (244 g), C₆H₄-1,3-(OH) 2 (19.7 g), CuI (30.1 g), dipivaloylmethane (DPM) (48.5 g), and Cs₂CO₃ (400 g) were placed in a 2,000 mL three-necked flask, dissolved in DMF (270 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 96.7 g of Intermediate 26a (yield 25%). The mass number of Intermediate 26a measured by FAB-MS measurement was 1080.

### Synthesis of Intermediate 27a

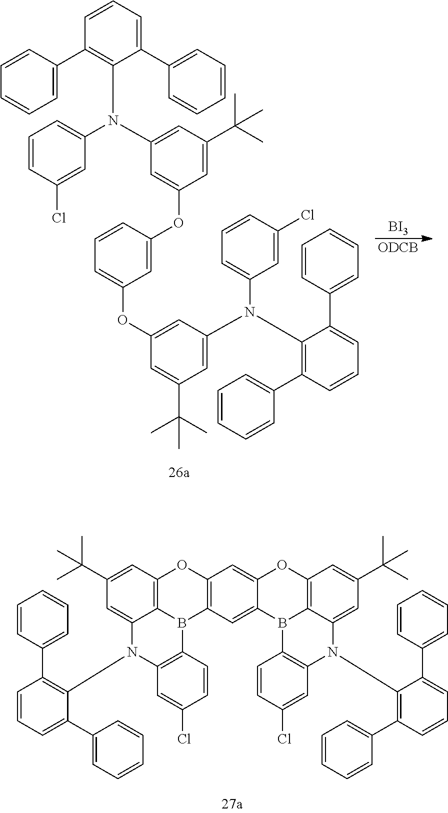

Under an Ar atmosphere, Intermediate 26a (96.7 g) was placed in a 500 mL three-necked flask, dissolved in o-Dichlorobenzene (120 mL), cooled to 0° C. in an ice bath, and added with boron triiodide (140.2 g), and the mixture was heated and stirred at 200° C. for 24 hours, cooled to 0° C. in an ice bath, and added with triethylamine (120 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 13.7 g of Intermediate 27a (yield 14%). The mass number of Intermediate 27a measured by FAB-MS measurement was 1096.

### Synthesis of Compound 24

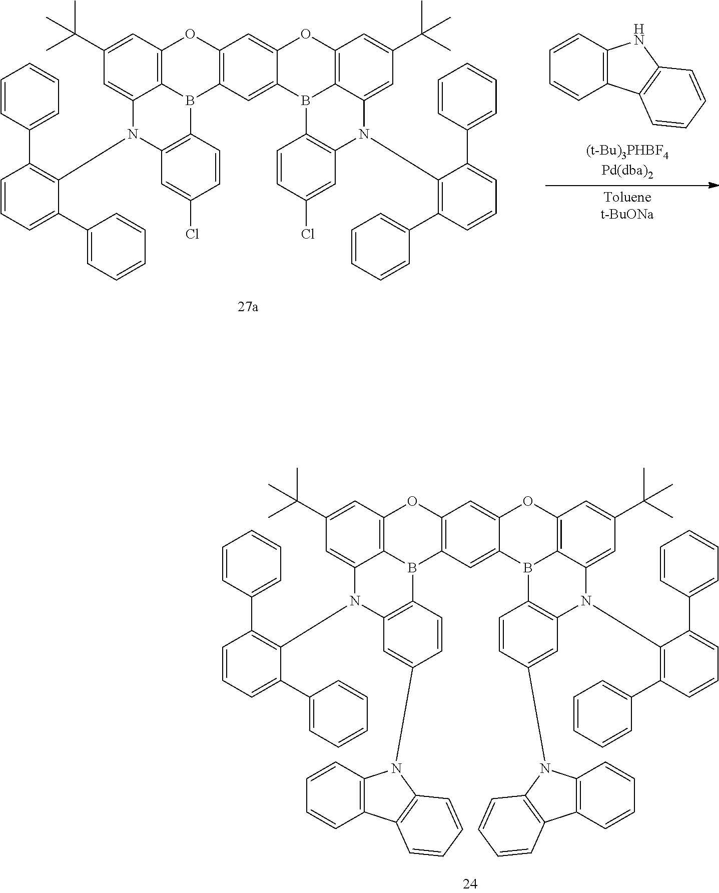 [SMILES: CC(C)(C)c1cc2c3c(c1)N(c1c(-c4ccccc4)cccc1-c1ccccc1)c1cc(Cl)ccc1B3c1cc3c(cc1O2)Oc1cc(C(C)(C)C)cc2c1B3c1ccc(Cl)cc1N2c1c(-c2ccccc2)cccc1-c1ccccc1 ; c1ccc2c(c1)[nH]c1ccccc12 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)Oc1cc(C(C)(C)C)cc2c1B3c1ccc(-n3c4ccccc4c4ccccc43)cc1N2c1c(-c2ccccc2)cccc1-c1ccccc1]

Under an Ar atmosphere, Intermediate 27a (13.7 g), carbazole (8.4 g), Pd(dba)₂ (5.0 g), tri-tert-butylphosphonium tetrafluoroborate ([P(tBu)₃H]BF₄, 5.0 g), and NaOtBu (5.6 g) were placed in a 500 mL three-necked flask, dissolved in toluene (80 mL), and heated and refluxed for 24 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 4.6 g of Intermediate 24 (yield 37%). The mass number of Intermediate 24 measured by FAB-MS measurement was 1359.

### (5) Synthesis of Compound 30

Compound 30 according to an embodiment may be synthesized by, for example, the following reaction.

### Synthesis of Intermediate 29a

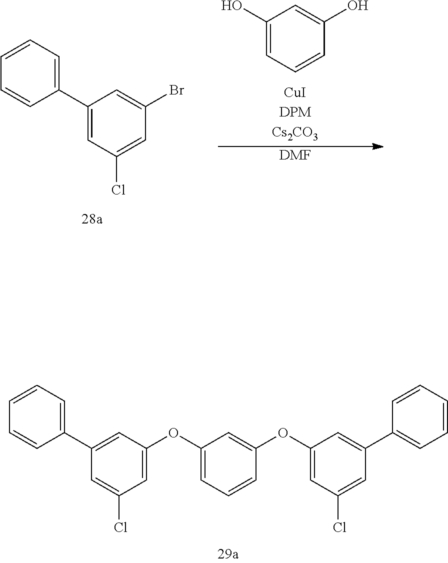

Under an Ar atmosphere, Intermediate 28a (26.8 g), C₆H₄-1,3-(OH) 2 (7.4 g), CuI (20.8 g), dipivaloylmethane (DPM) (32.9 g), and Cs₂CO₃ (350 g) were placed in a 1,000 mL three-necked flask, dissolved in DMF (180 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 18.1 g of Intermediate 29a (yield 56%). The mass number of Intermediate 29a measured by FAB-MS measurement was 482.

### Synthesis of Intermediate 31a

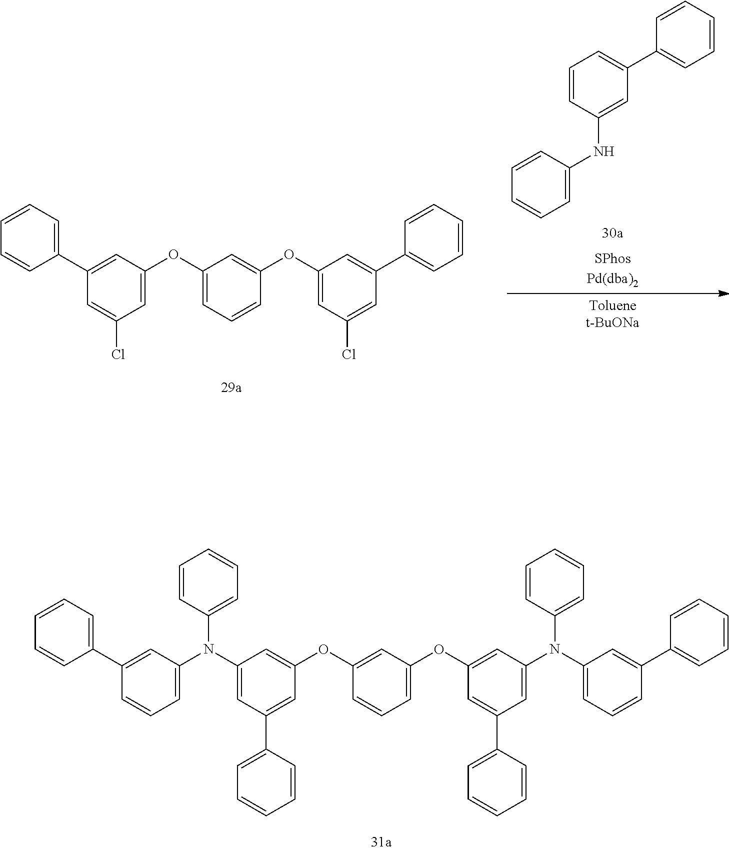 [SMILES: Clc1cc(Oc2cccc(Oc3cc(Cl)cc(-c4ccccc4)c3)c2)cc(-c2ccccc2)c1 ; c1ccc(Nc2cccc(-c3ccccc3)c2)cc1 ; c1ccc(-c2cccc(N(c3ccccc3)c3cc(Oc4cccc(Oc5cc(-c6ccccc6)cc(N(c6ccccc6)c6cccc(-c7ccccc7)c6)c5)c4)cc(-c4ccccc4)c3)c2)cc1]

Under an Ar atmosphere, Intermediate 29a (18.1 g), Intermediate 30a (20.4 g), Pd(dba)₂ (3.1 g), SPhos (2.4 g), and NaOtBu (8.8 g) were placed in a 2,000 mL three-necked flask, dissolved in toluene (400 mL), and heated and refluxed for 2 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 23.3 g of Intermediate 31a (yield 69%). The mass number of Intermediate 31a measured by FAB-MS measurement was 900.

### Synthesis of Compound 30

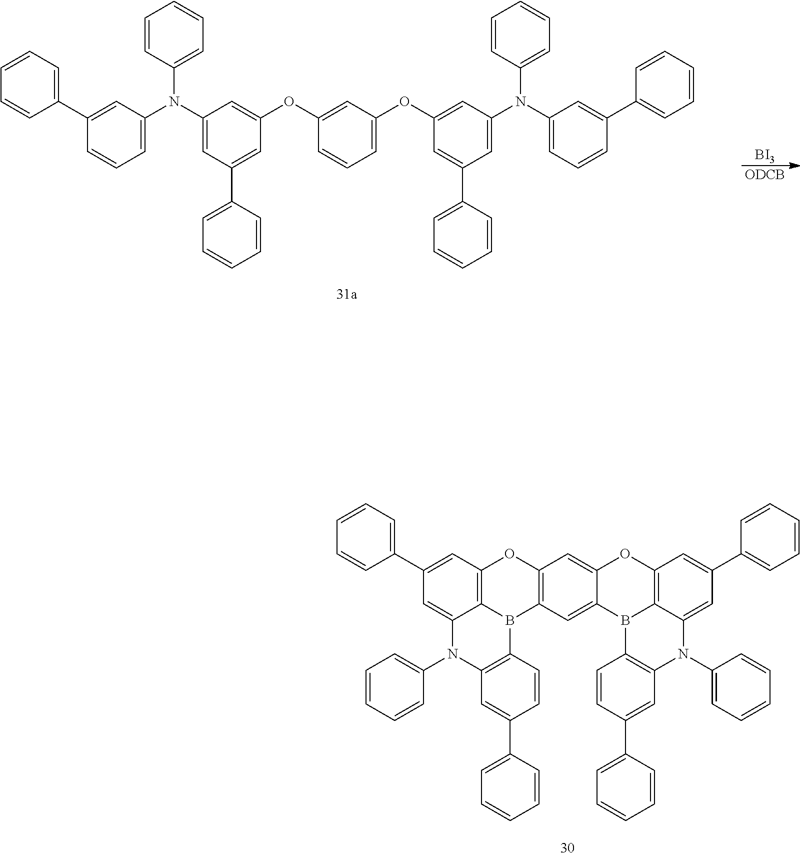 [SMILES: c1ccc(-c2cccc(N(c3ccccc3)c3cc(Oc4cccc(Oc5cc(-c6ccccc6)cc(N(c6ccccc6)c6cccc(-c7ccccc7)c6)c5)c4)cc(-c4ccccc4)c3)c2)cc1 ; "ODCB" ; "BI3" ; c1ccc(-c2ccc3c(c2)N(c2ccccc2)c2cc(-c4ccccc4)cc4c2B3c2cc3c(cc2O4)Oc2cc(-c4ccccc4)cc4c2B3c2ccc(-c3ccccc3)cc2N4c2ccccc2)cc1]

Under an Ar atmosphere, Intermediate 31a (23.3 g) was placed in a 300 mL three-necked flask, dissolved in o-Dichlorobenzene (25 mL), cooled to 0° C. in an ice bath, and added with boron triiodide (41.8 g), and the mixture was heated and stirred at 200° C. for 24 hours, cooled to 0° C. in an ice bath, and added with triethylamine (40 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 5.7 g of Compound 30 (yield 24%). The mass number of Compound 30 measured by FAB-MS measurement was 916.

### (6) Synthesis of Compound 34

Compound 34 according to an embodiment may be synthesized by, for example, the following reaction.

### Synthesis of Intermediate 32a

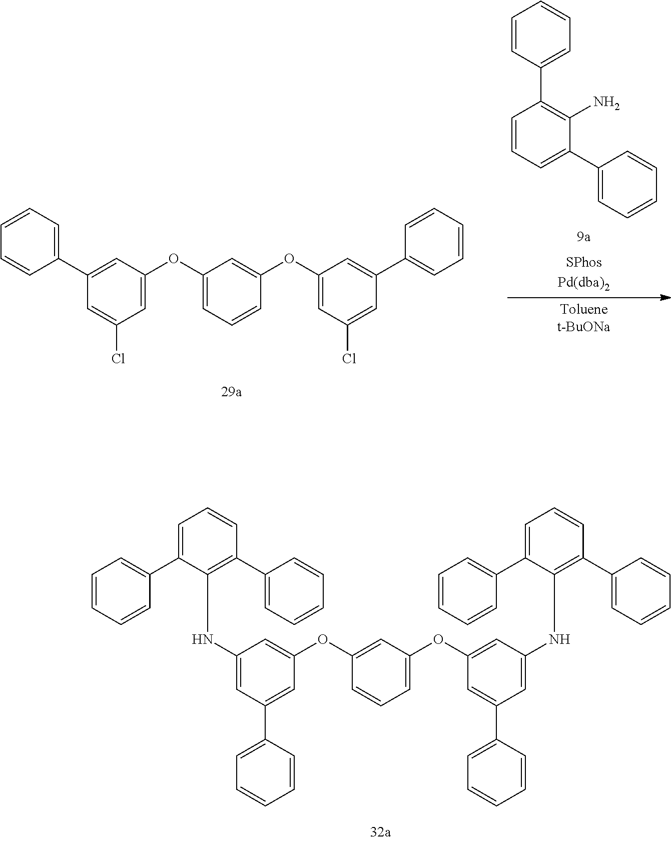 [SMILES: Clc1cc(Oc2cccc(Oc3cc(Cl)cc(-c4ccccc4)c3)c2)cc(-c2ccccc2)c1 ; Nc1c(-c2ccccc2)cccc1-c1ccccc1 ; c1ccc(-c2cc(Nc3c(-c4ccccc4)cccc3-c3ccccc3)cc(Oc3cccc(Oc4cc(Nc5c(-c6ccccc6)cccc5-c5ccccc5)cc(-c5ccccc5)c4)c3)c2)cc1]

Under an Ar atmosphere, Intermediate 29a (44.8 g), Intermediate 9a (49 g), Pd(dba)₂ (6.2 g), SPhos (4.8 g), and NaOtBu (19.9 g) were placed in a 2,000 mL three-necked flask, dissolved in toluene (700 mL), and heated and refluxed for 6 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 65.1 g of Intermediate 32a (yield 78%). The mass number of Intermediate 32a measured by FAB-MS measurement was 900.

### Synthesis of Intermediate 34a

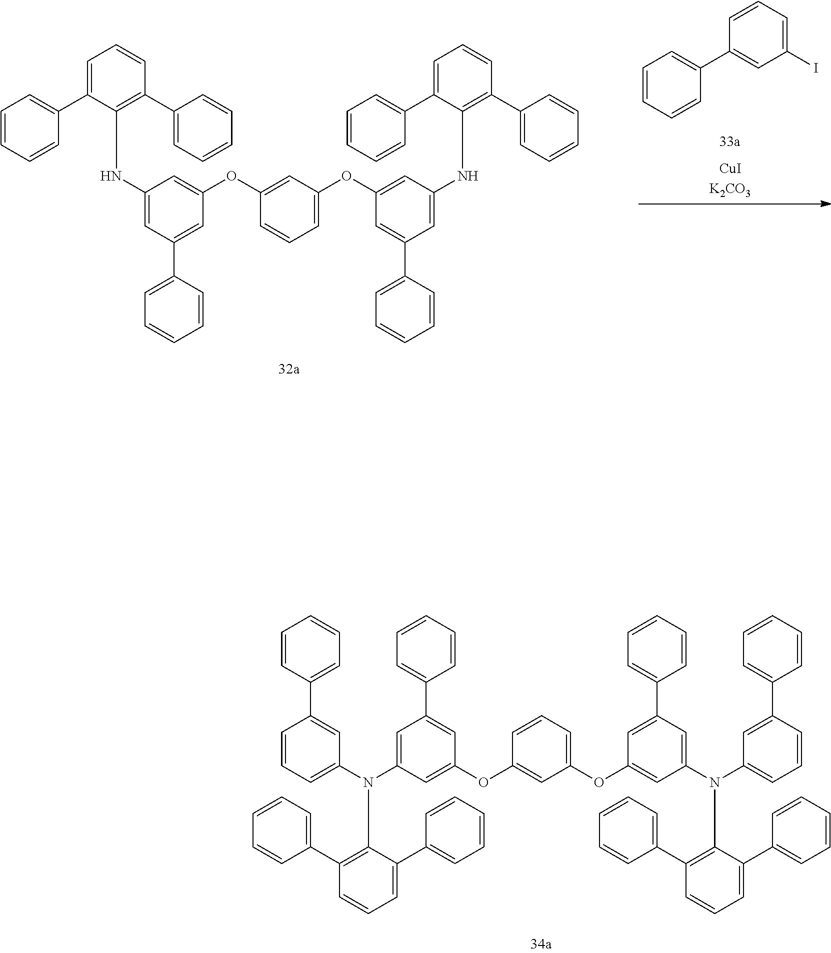 [SMILES: c1ccc(-c2cc(Nc3c(-c4ccccc4)cccc3-c3ccccc3)cc(Oc3cccc(Oc4cc(Nc5c(-c6ccccc6)cccc5-c5ccccc5)cc(-c5ccccc5)c4)c3)c2)cc1 ; Ic1cccc(-c2ccccc2)c1 ; c1ccc(-c2cccc(N(c3cc(Oc4cccc(Oc5cc(-c6ccccc6)cc(N(c6cccc(-c7ccccc7)c6)c6c(-c7ccccc7)cccc6-c6ccccc6)c5)c4)cc(-c4ccccc4)c3)c3c(-c4ccccc4)cccc3-c3ccccc3)c2)cc1]

Under an Ar atmosphere, Intermediate 32a (65.1 g), Intermediate 33a (121 g), CuI (82.4 g), and K₂CO₃ (59.9 g) were added to a 2,000 mL three-necked flask and heated and stirred at 200° C. for 105 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 33.9 g of Intermediate 34a (yield 29%). The mass number of Intermediate 34a measured by FAB-MS measurement was 1205.

### Synthesis of Compound 34

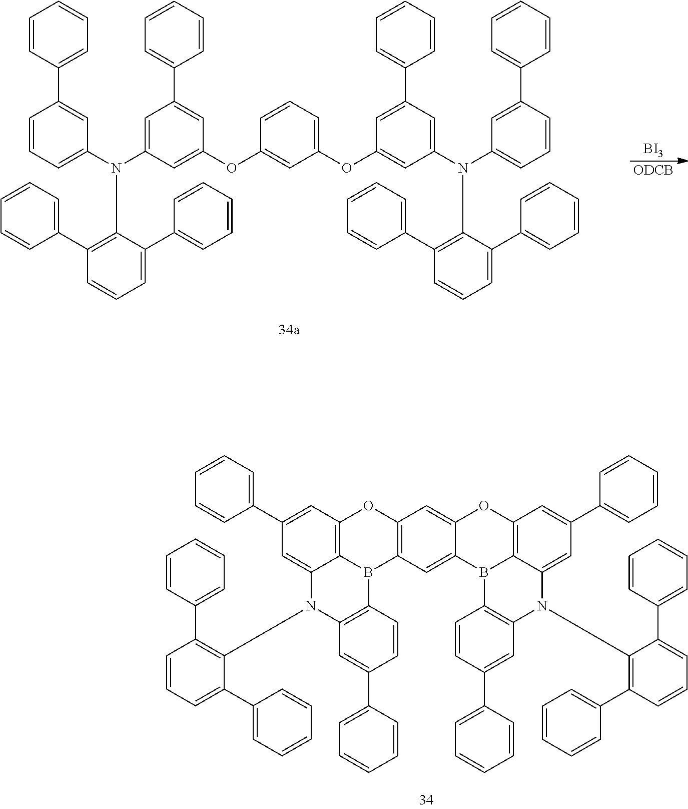

Under an Ar atmosphere, Intermediate 34a (33.9 g) was placed in a 300 mL three-necked flask, dissolved in o-Dichlorobenzene (30 mL), cooled to 0° C. in an ice bath, and added with boron triiodide (44.8 g), and the mixture was heated and stirred at 200° C. for 24 hours, cooled to 0° C. in an ice bath, and added with triethylamine (60 mL). After the temperature was returned to room temperature, the reaction solution was filtered with silica gel, and the filtrate solvent was removed by evaporation under reduced pressure. The obtained crude product was purified by repurification by silica gel column chromatography and preparative HPLC (eluent: CHCl₃), and toluene to obtain 5.5 g of Compound 34 (yield 16%). The mass number of Compound 34 measured by FAB-MS measurement was 1221.

### (7) Synthesis of Compound 45

Compound 45 according to an embodiment may be synthesized by, for example, the following reaction.

### Synthesis of Intermediate 36a

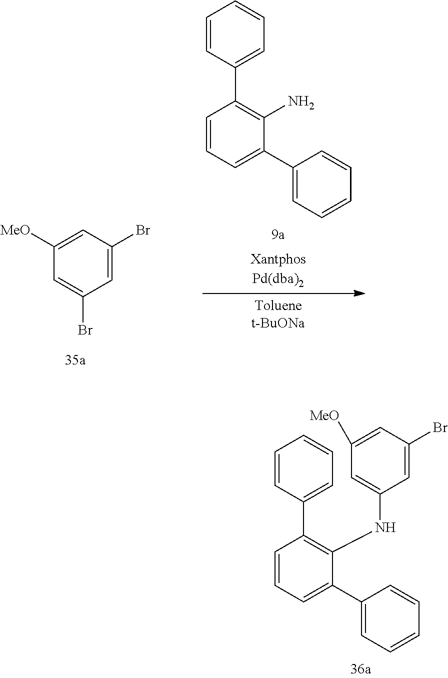 [SMILES: Nc1c(-c2ccccc2)cccc1-c1ccccc1 ; COc1cc(Br)cc(Br)c1 ; COc1cc(Br)cc(Nc2c(-c3ccccc3)cccc2-c2ccccc2)c1]

Under an Ar atmosphere, Intermediate 35a (376 g), Intermediate 9a (132 g), Pd(dba)₂ (19 g), 4,5-Bis(diphenylphosphino)-9,9-dimethylxanthene (Xantphos) (39 g), and NaOtBu (143 g) were placed in a 5,000 mL three-necked flask, dissolved in toluene (1200 mL), and heated and refluxed for 6 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 183 g of Intermediate 36a (yield 81%). The mass number of Intermediate 36a measured by FAB-MS measurement was 430.

### Synthesis of Intermediate 37a

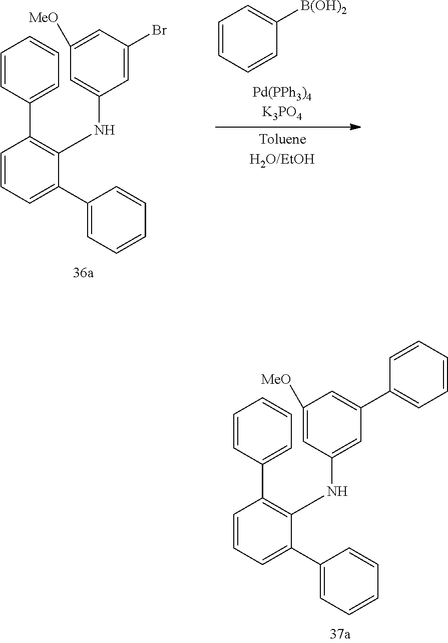 [SMILES: COc1cc(Br)cc(Nc2c(-c3ccccc3)cccc2-c2ccccc2)c1 ; OB(O)c1ccccc1 ; COc1cc(Nc2c(-c3ccccc3)cccc2-c2ccccc2)cc(-c2ccccc2)c1]

Under an Ar atmosphere, Intermediate 36a (183 g), PhB(OH)₂ (57.2 g), Pd(PPh₃)₄ (19.7 g), and K₃PO₄ (181 g) were placed in a 5,000 mL three-necked flask, dissolved in a mixed solvent of toluene (1200 mL), EtOH (300 mL), and H₂O (300 mL), and heated and refluxed for 6 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 182 g of Intermediate 37a (yield 78%). The mass number of Intermediate 37a measured by FAB-MS measurement was 427.

### Synthesis of Intermediate 38a

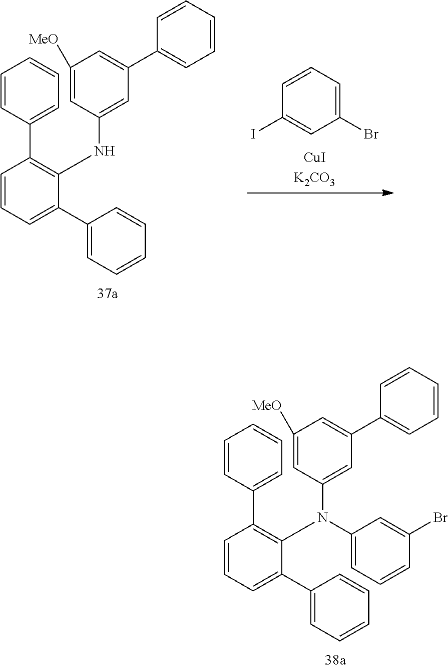 [SMILES: COc1cc(Nc2c(-c3ccccc3)cccc2-c2ccccc2)cc(-c2ccccc2)c1 ; Brc1cccc(I)c1 ; COc1cc(-c2ccccc2)cc(N(c2cccc(Br)c2)c2c(-c3ccccc3)cccc2-c2ccccc2)c1]

Under an Ar atmosphere, Intermediate 37a (100 g), 1-Bromo-3-iodobenzene (265 g), CuI (178 g), and K₂CO₃ (258 g) were added to a 3,000 mL three-necked flask and heated and stirred at 200° C. for 28 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 94.0 g of Intermediate 38a (yield 69%). The mass number of Intermediate 38a measured by FAB-MS measurement was 581.

### Synthesis of Intermediate 39a

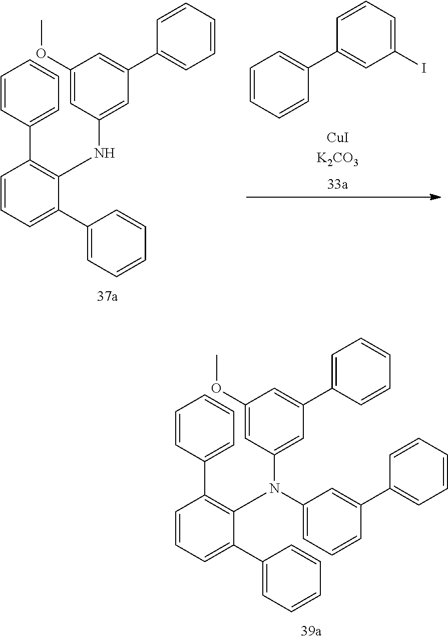

Under an Ar atmosphere, Intermediate 37a (79.1 g), Intermediate 33a (310 g), CuI (71.3 g), and K₂CO₃ (102.9 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 63.3 g of Intermediate 39a (yield 59%). The mass number of Intermediate 39a measured by FAB-MS measurement was 579.

### Synthesis of Intermediate 40a

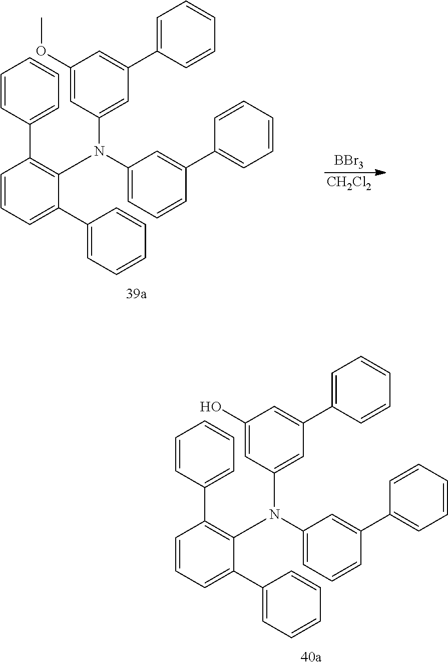

Under an Ar atmosphere, CH₂Cl₂ (300 mL) and Intermediate 39a (63.3 g) were added to a 1,000 mL three-necked flask, and the solution was cooled to 0° C. using an ice bath. BBr₃ (100 g in CH₂Cl₂ (300 mL)) was added dropwise to the cooled solution for 60 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 47.0 g of Intermediate 40a (yield 76%). The mass number of Intermediate 40a measured by FAB-MS measurement was 565.

### Synthesis of Intermediate 41a

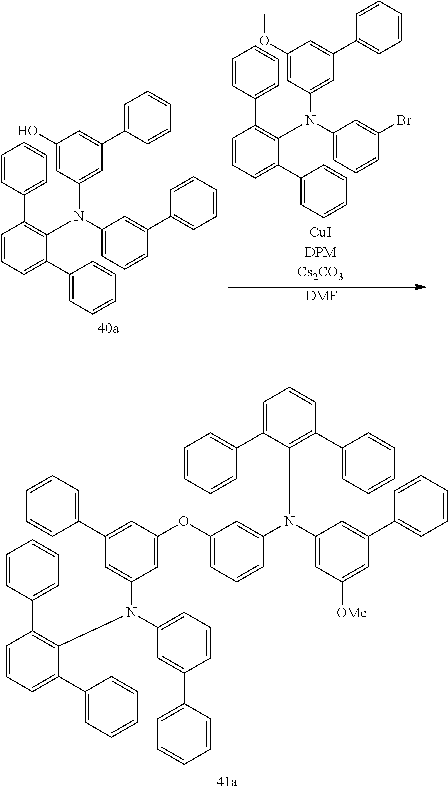

Under an Ar atmosphere, Intermediate 40a (47.0 g), Intermediate 38a (48.4 g), CuI (1.8 g), dipivaloylmethane (DPM) (3.3 g), and Cs₂CO₃ (120 g) were placed in a 1,000 mL three-necked flask, dissolved in DMF (38 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 41.6 g of Intermediate 41a (yield 47%). The mass number of Intermediate 41a measured by FAB-MS measurement was 1066.

### Synthesis of Intermediate 42a

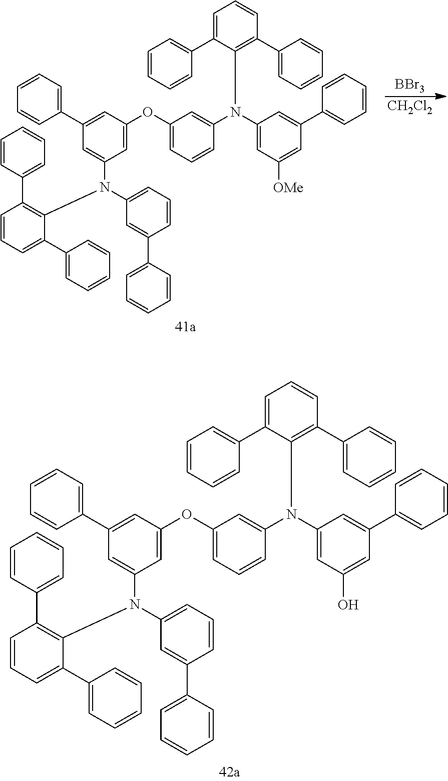

Under an Ar atmosphere, CH₂Cl₂ (200 mL) and Intermediate 41a (41.6 g) were added to a 1,000 mL three-necked flask, and the solution was cooled to 0° C. using an ice bath. BBr₃ (50 g in CH₂Cl₂ (200 mL)) was added dropwise to the cooled solution for 30 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 23.8 g of Intermediate 42a (yield 58%). The mass number of Intermediate 42a measured by FAB-MS measurement was 1221.

### Synthesis of Intermediate 43a

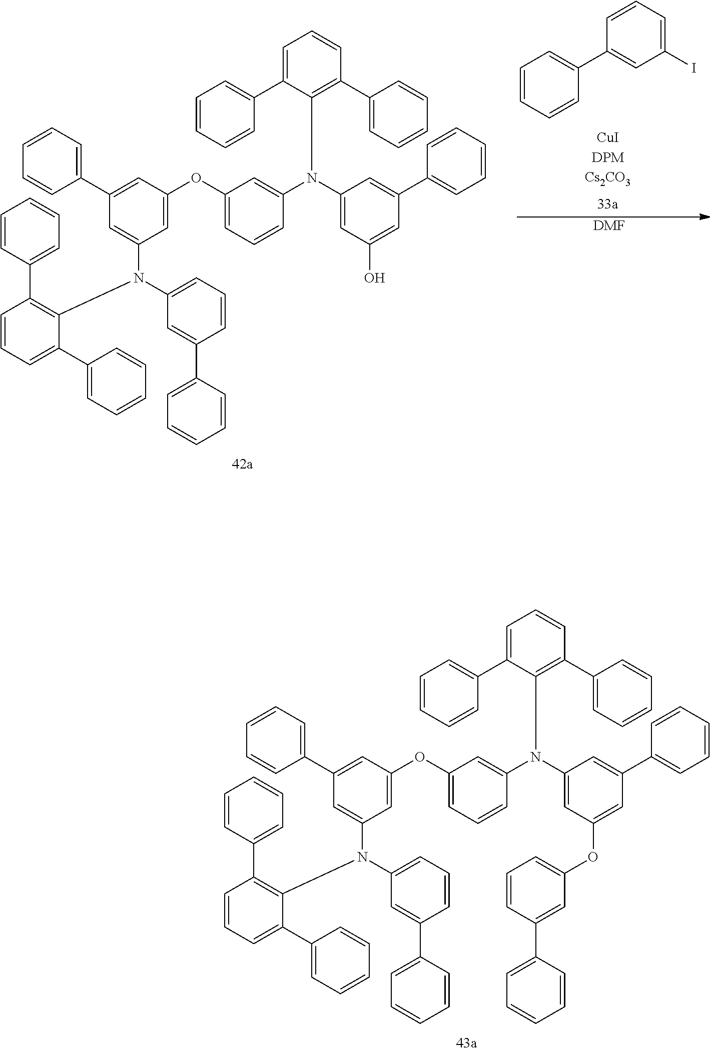

Under an Ar atmosphere, Intermediate 42a (23.8 g), Intermediate 33a (19.5 g), CuI (0.3 g), dipivaloylmethane (DPM) (0.6 g), and Cs₂CO₃ (16.0 g) were placed in a 1,000 mL three-necked flask, dissolved in DMF (20 mL), and heated and refluxed for 12 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 13.9 g of Intermediate 43a (yield 51%). The mass number of Intermediate 43a measured by FAB-MS measurement was 1205.

### Synthesis of Compound 45

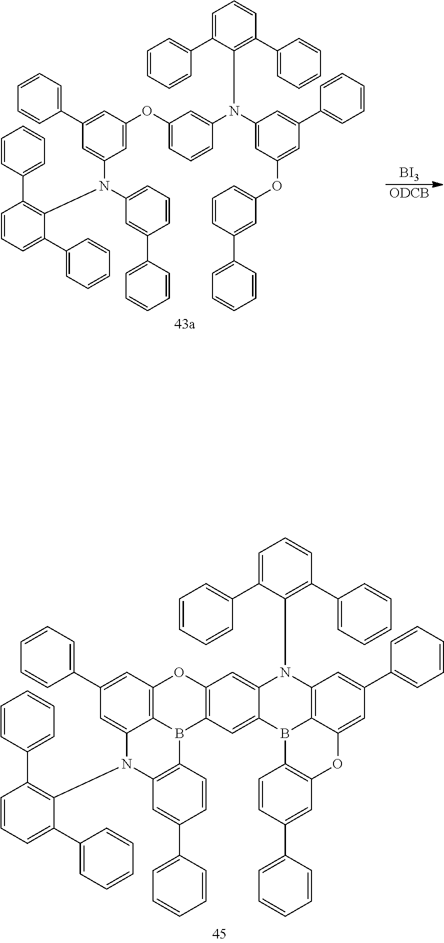

Under an Ar atmosphere, Intermediate 43a (13.9 g) was placed in a 300 mL three-necked flask, dissolved in o-Dichlorobenzene (20 mL), cooled to 0° C. in an ice bath, and added with boron triiodide (46.3 g), and the mixture was heated and stirred at 195° C. for 24 hours, cooled to 0° C. in an ice bath, and added with triethylamine (40 mL). After the temperature was returned to room temperature, the reaction solution was filtered with silica gel, and the filtrate solvent was removed by evaporation under reduced pressure. The obtained crude product was purified by repurification by silica gel column chromatography and preparative HPLC (eluent: CHCl₃), and toluene to obtain 3.1 g of Compound 45 (yield 22%). The mass number of Compound 45 measured by FAB-MS measurement was 1221.

### (8) Synthesis of Compound 54

### Synthesis of Intermediate 45a

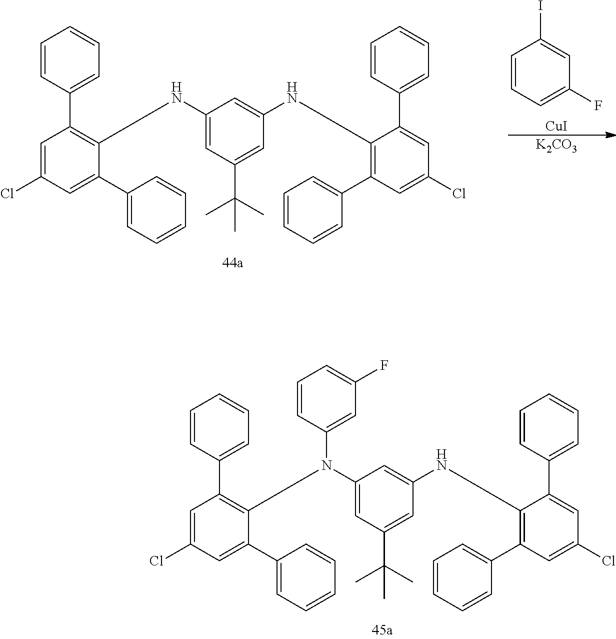

Under an Ar atmosphere, Intermediate 44a (340 g), 1-Chloro-3-fluorobenzene (450 g), CuI (360 g), and K₂CO₃ (260 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 232 g of Intermediate 45a (yield 60%). The mass number of Intermediate 45a measured by FAB-MS measurement was 784.

### Synthesis of Intermediate 46a

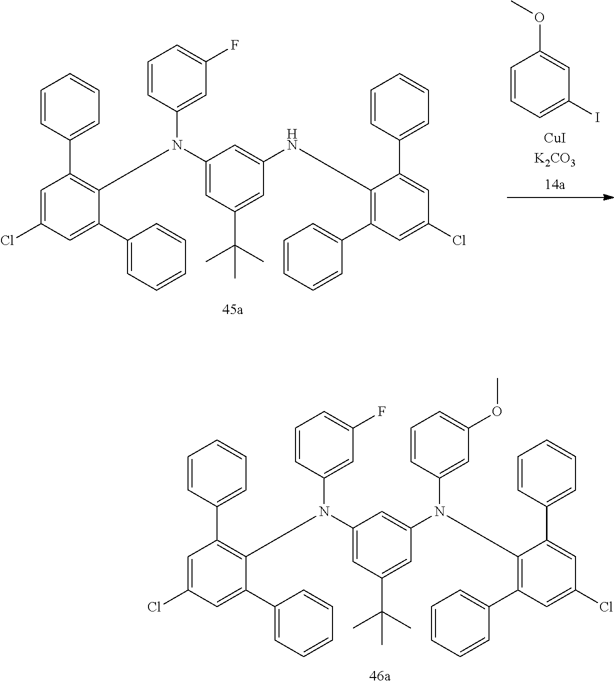

Under an Ar atmosphere, Intermediate 45a (232 g), Intermediate 14a (277 g), CuI (225 g), and K₂CO₃ (184 g) were added to a 2,000 mL three-necked flask and heated and stirred at 200° C. for 90 hours. After the temperature was returned to room temperature, water was added thereto to perform extraction with CH₂Cl₂, and an organic layer was collected and dried with MgSO₄, followed by removing the solvent by evaporation under reduced pressure. Purification was performed by silica gel column chromatography to obtain 190 g of Intermediate 46a (yield 72%). The mass number of Intermediate 46a measured by FAB-MS measurement was 890.

### Synthesis of Intermediate 47a

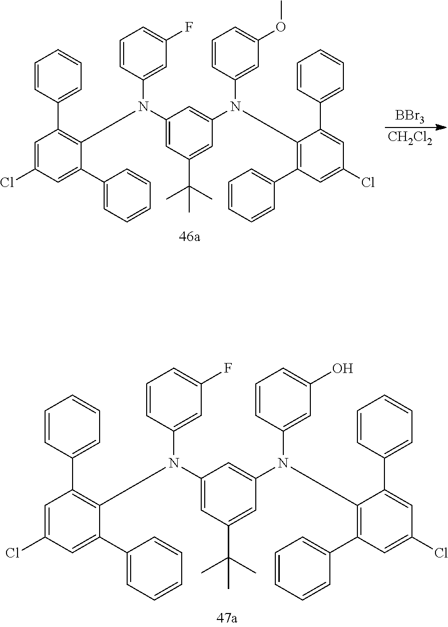

Under an Ar atmosphere, CH₂Cl₂ (300 mL) and Intermediate 46a (190 g) were added to a 1,000 mL three-necked flask, and the solution was cooled to 0° C. using an ice bath. BBr₃ (150 g in CH₂Cl₂ (300 mL)) was added dropwise to the cooled solution for 60 minutes. After dropwise addition was completed, the temperature of the reaction solution was raised to room temperature, and stirred for 6 hours. The obtained reaction solution was poured into iced water, and the product was extracted with CH₂Cl₂, and an organic layer was collected and dried with MgSO₄, followed by removing the solvent by evaporation under reduced pressure. The obtained crude product was purified by silica gel column chromatography to obtain 112 g of Intermediate 47a (yield 60%). The mass number of Intermediate 47a measured by FAB-MS measurement was 876.

### Synthesis of Intermediate 48a

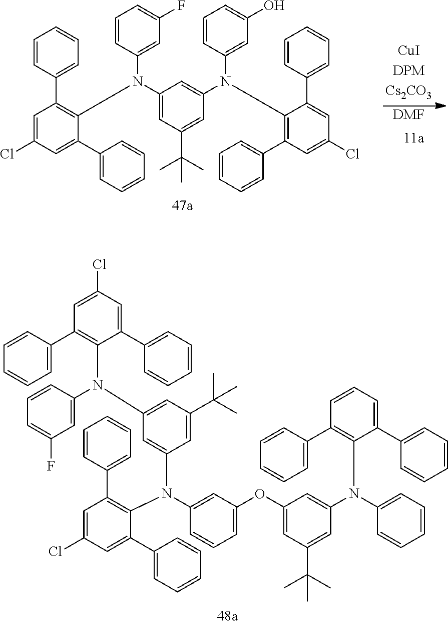

Under an Ar atmosphere, Intermediate 47a (112 g), Intermediate 11a (80 g), CuI (7.2 g), dipivaloylmethane (DPM) (12.0 g), and Cs₂CO₃ (160 g) were placed in a 1,000 mL three-necked flask, dissolved in DMF (100 mL), and heated and refluxed for 11 hours. After the temperature was returned to room temperature, water was added thereto to extract a product with CH₂Cl₂, and an organic layer was collected and dried with MgSO₄, followed by removing the solvent by evaporation under reduced pressure. The obtained crude product was purified by silica gel column chromatography to obtain 40.7 g of Intermediate 48a (yield 24%). The mass number of Intermediate 48a measured by FAB-MS measurement was 1328.

### Synthesis of Intermediate 49a

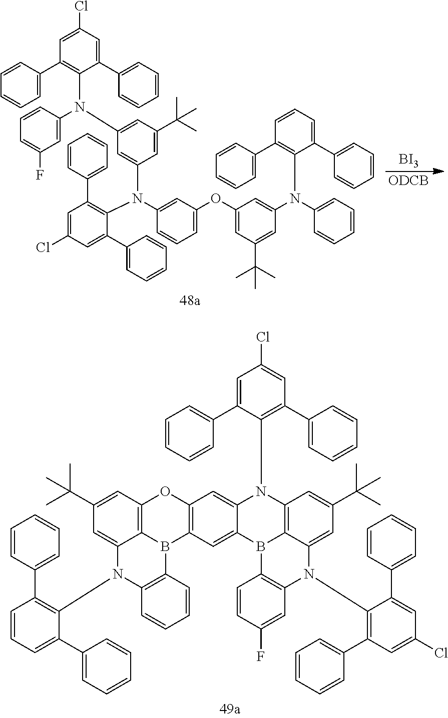

Under an Ar atmosphere, Intermediate 48a (40.7 g) was placed in a 500 mL three-necked flask, dissolved in o-Dichlorobenzene (85 mL), cooled to 0° C. in an ice bath, and added with boron triiodide (52.3 g), and the mixture was heated and stirred at 180° C. for 16 hours, cooled to 0° C. in an ice bath, and added with triethylamine (120 mL). After the temperature was returned to room temperature, the reaction solution was filtered with silica gel, and the filtrate solvent was removed by evaporation under reduced pressure. The obtained crude product was purified by repurification by silica gel column chromatography, preparative HPLC (eluent: CHCl₃), and toluene to obtain 9.5 g of Intermediate 49a (yield 23%). The mass number of Intermediate 49a measured by FAB-MS measurement was 1343.

### Synthesis of Intermediate 50a

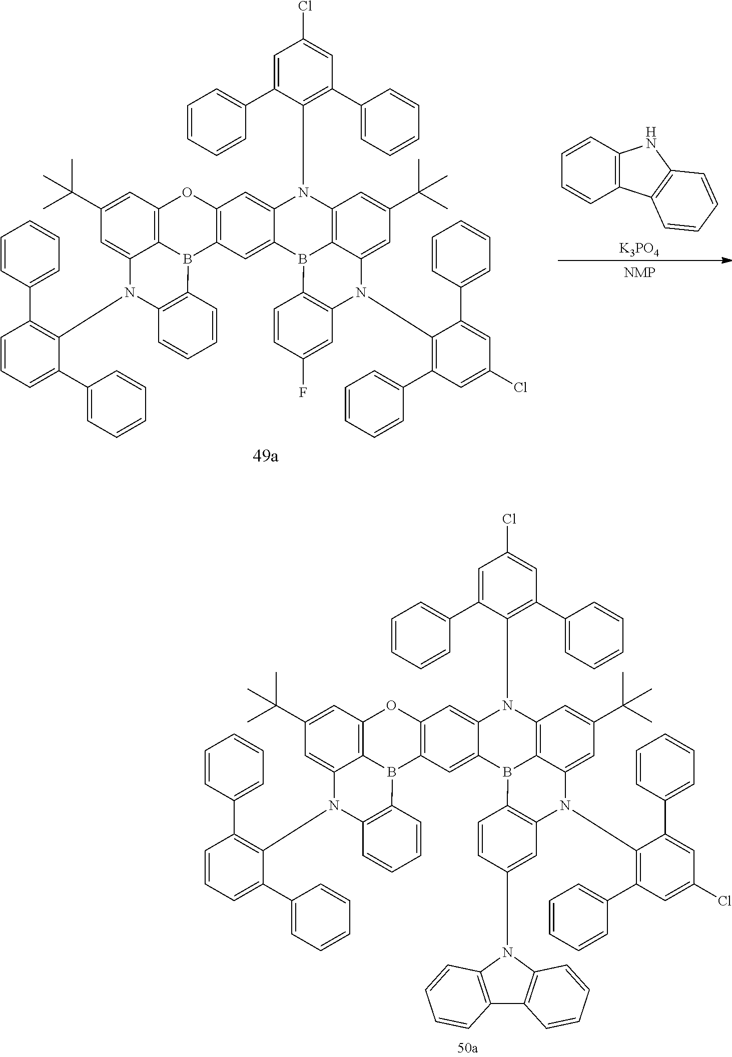

Under an Ar atmosphere, Intermediate 49a (9.5 g), Carbazole (2.7 g), and K₃PO₄ (3.0 g) were placed in a 500 mL three-necked flask, dissolved in NMP (25 mL), and heated and stirred at 160° C. for 24 hours. After the temperature was returned to room temperature, water was added thereto to extract a product with toluene, and an organic layer was collected and dried with MgSO₄, followed by removing the solvent by evaporation under reduced pressure. The obtained crude product was purified by silica gel column chromatography to obtain 4.3 g of Intermediate 50a (yield 41%). The mass number of Intermediate 50a measured by FAB-MS measurement was 1490.

### Synthesis of Compound 54

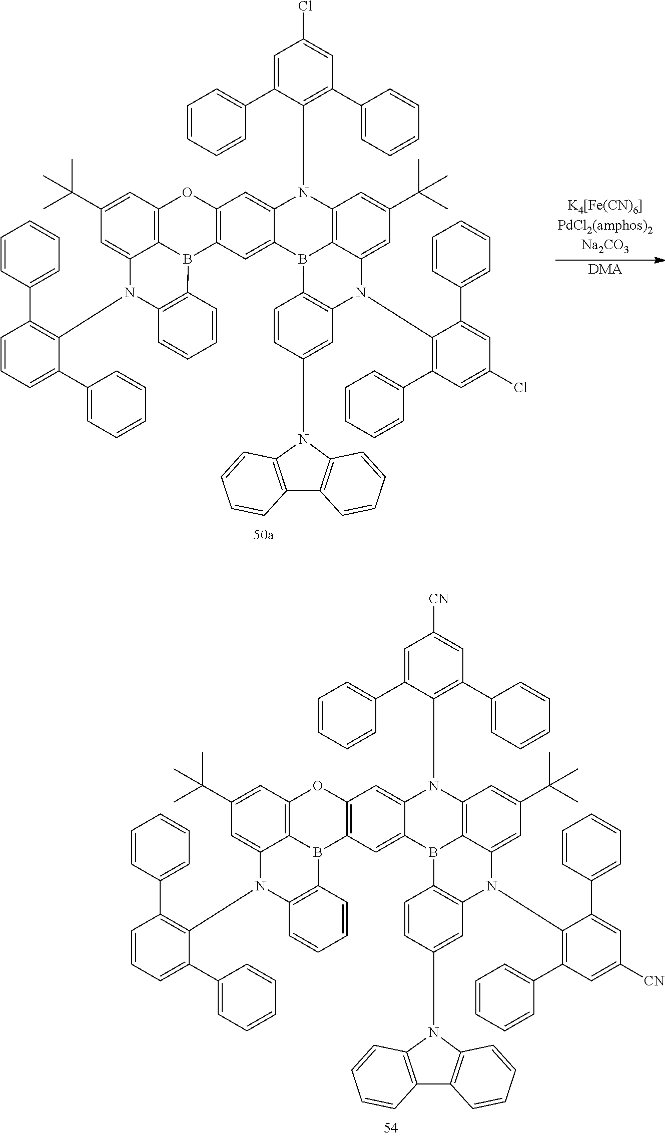

Under an Ar atmosphere, Intermediate 50a (4.3 g), K₄[Fe(CN6)] (3.8 g), Na₂CO₃ (4.9 g), and PdCl₂(amphos)₂ (0.20 g) were placed in a 500 mL three-necked flask, dissolved in DMA (30 mL), and heated and stirred at 140° C. for 24 hours. After the temperature was returned to room temperature, water was added thereto to extract a product with toluene, and an organic layer was collected and dried with MgSO₄, followed by removing the solvent by evaporation under reduced pressure. The obtained crude product was purified by silica gel column chromatography to obtain 3.0 g of Compound 54 (yield 71%). The mass number of Compound 54 measured by FAB-MS measurement was 1471.

### 2. Manufacturing and Evaluation of Light Emitting Element

A light emitting element according to an embodiment including the fused polycyclic compound according to an embodiment in a light emitting layer was manufactured in the following manner. Light emitting elements of Example 1 to Example 8 were manufactured using Compounds 1, 5, 9, 24, 30, 34, 45, and 54, respectively, which are the above-described Example Compounds, as light emitting layer dopant materials. Comparative Example 1 to Comparative Example 9 correspond to light emitting elements manufactured by using Comparative Example Compound X-1 to Comparative Example Compound X-9, respectively, as light emitting layer dopant materials.

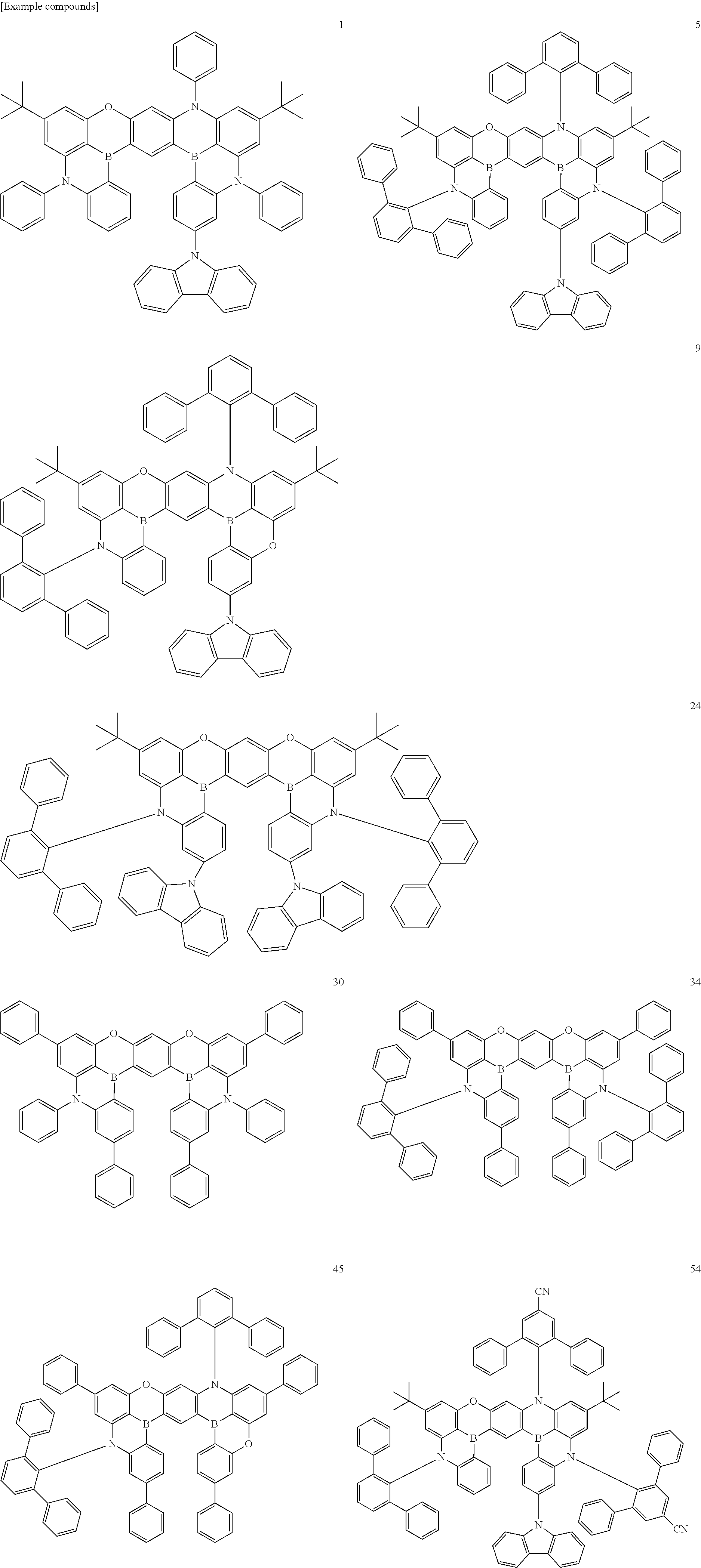

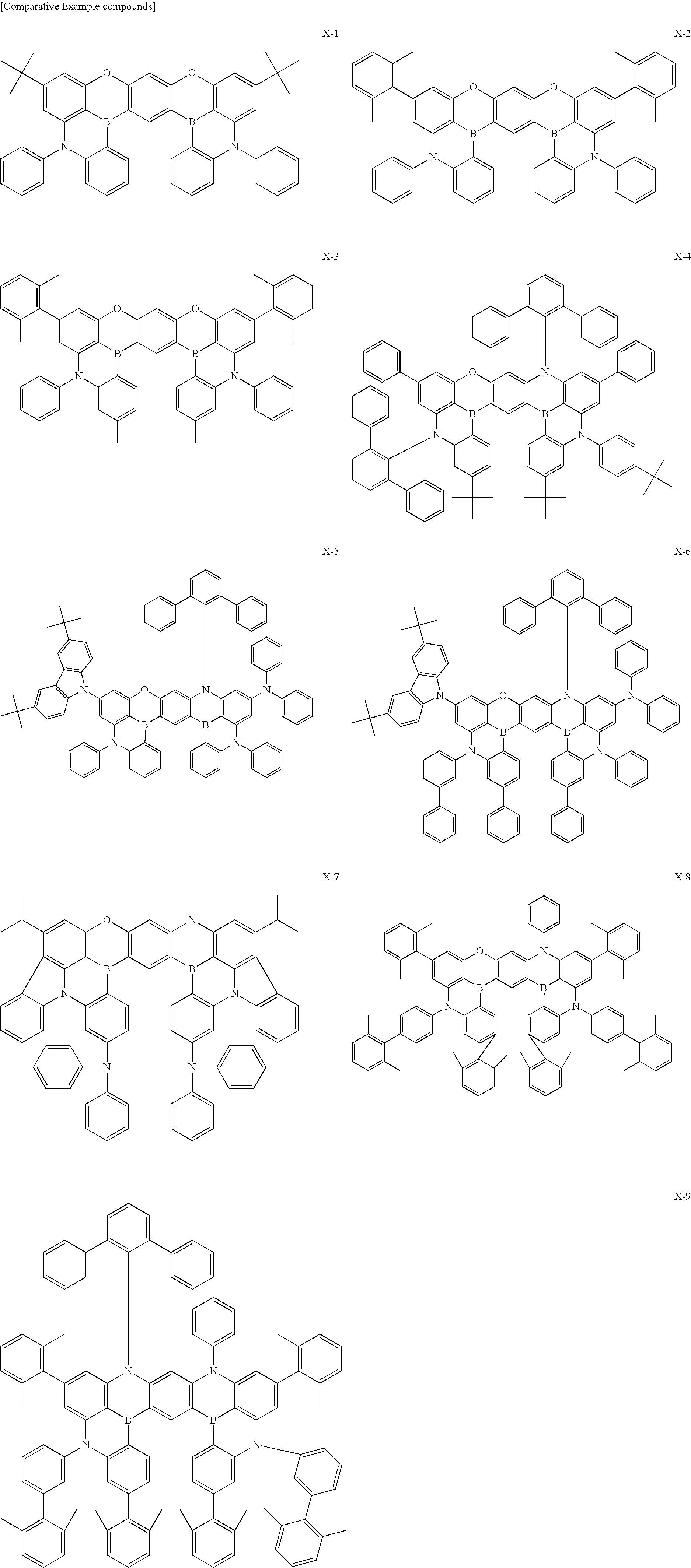

### (Manufacturing of Light Emitting Element)

A 150 nm-thick first electrode was formed with ITO, a 10 nm-thick hole injection layer was formed with dipyrazino[2,3-f: 2′,3′-h] quinoxaline-2,3,6,7,10,11-hexacarbonitrile (HATCN) on the first electrode, an 80 nm-thick hole transport layer was formed with N,N′-Di(1-naphthyl)-N,N′-diphenyl-(1,1″-biphenyl)-4,4″-diamine (NPD) on the hole injection layer, and a 5 nm-thick light emitting auxiliary layer was formed with 1,3-Bis(N-carbazolyl)benzene (mCP) on the hole transport layer. A 20 nm-thick light emitting layer in which 3,3′-Di(9H-carbazol-9-yl)-1,1′-biphenyl (mCBP) was doped with 1% of an Example Compound or a Comparative Example Compound, was formed on the light emitting auxiliary layer, a 30 nm-thick electron transport layer was formed with 2,2′,2″-(1,3,5-Benzinetriyl)-tris(1-phenyl-1-H-benzimidazole) (TPBi) on the light emitting layer, a 0.5 nm-thick electron injection layer was formed with LiF on the electron transport layer, and a 100 nm-thick second electrode was formed with A1 on the electron injection layer. Each layer was formed by a deposition method under a vacuum.

Compounds used in the manufacture of light emitting elements of the Examples and the Comparative Examples are disclosed below. The following materials were used for the manufacture of the elements by purifying commercially available products by sublimation.

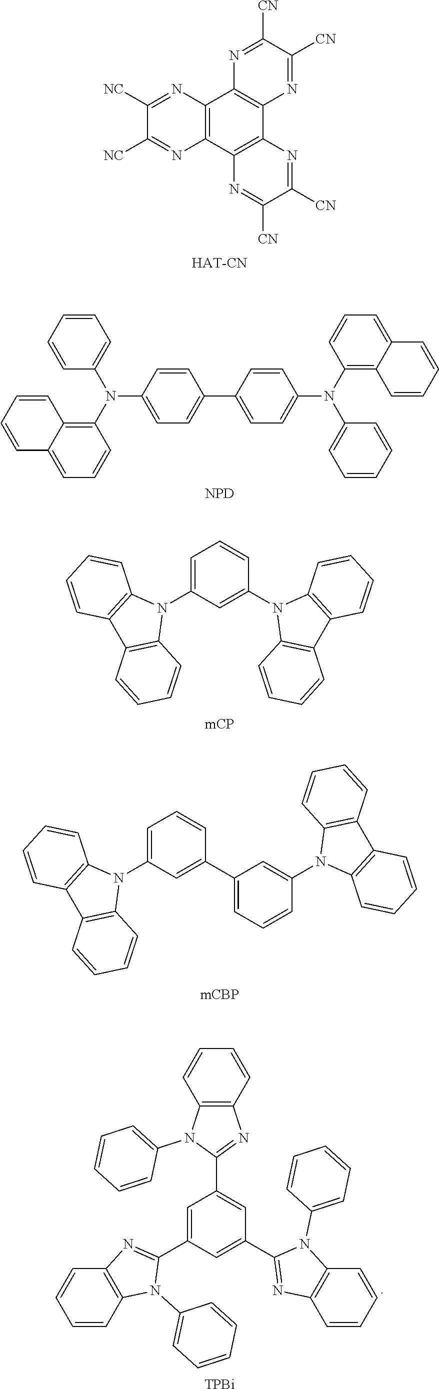

### (Evaluation of Properties of Light Emitting Element)

Table 1 shows the evaluation results of the light emitting elements of Example 1 to Example 8, and Comparative Example 1 to Comparative Example 9. Table 1 shows the comparison of external quantum efficiency EQE₈₀₀ₙᵢₜ and lifespan LT50 of the manufactured light emitting elements.

In the evaluation results of the properties of the Examples and the Comparative Examples shown in Table 1, the external quantum efficiency EQE₈₀₀ₙᵢₜ and the lifespan LT50 were measured by using an external quantum efficiency measuring device C9920-12 by Hamamatsu Photonics Company. The external quantum efficiency EQE₈₀₀ₙᵢₜ represents the external quantum efficiency at a luminance of 800 cd/m². The lifespan LT50 is represented by evaluating a luminance halving time at an initial luminance of 800 cd/m². The external quantum efficiency is a relative measurement that was calculated on the basis of the value of Comparative Example 1.

TABLE 1

| Element | | | |
|---|---|---|---|
| manufacturing | | | LT50 |
| example | Dopant | EQE₈₀₀ₙᵢₜ | (hr) |
| Example 1 | Compound 1 | 1.9 | 3.1 |
| Example 2 | Compound 5 | 2.0 | 4.4 |
| Example 3 | Compound 9 | 2.3 | 2.5 |
| Example 4 | Compound 24 | 2.9 | 4.6 |
| Example 5 | Compound 30 | 2.6 | 3.1 |
| Example 6 | Compound 34 | 2.4 | 3.8 |
| Example 7 | Compound 45 | 3.9 | 4.6 |
| Example 8 | Compound 54 | 4.0 | 4.9 |
| Comparative | Comparative Example | 1.0 | 0.5 |
| Example 1 | Compound X-1 | | |
| Comparative | Comparative Example | 1.2 | 1.7 |
| Example 2 | Compound X-2 | | |
| Comparative | Comparative Example | 1.3 | 1.2 |
| Example 3 | Compound X-3 | | |
| Comparative | Comparative Example | 1.4 | 1.2 |
| Example 4 | Compound X-4 | | |
| Comparative | Comparative Example | 1.3 | 1.6 |
| Example 5 | Compound X-5 | | |
| Comparative | Comparative Example | 1.4 | 1.6 |
| Example 6 | Compound X-6 | | |
| Comparative | Comparative Example | 1.3 | 0.2 |
| Example 7 | Compound X-7 | | |
| Comparative | Comparative Example | 1.5 | 0.9 |
| Example 8 | Compound X-8 | | |
| Comparative | Comparative Example | 1.5 | 2.0 |
| Example 9 | Compound X-9 | | |

Referring to the results of Table 1, it can be confirmed that external quantum efficiency and lifespan properties of the light emitting elements of the Examples, in which the fused polycyclic compound according to an embodiment was used as a light emitting material, are improved as compared to those of the Comparative Examples. The Examples Compounds include a fused ring core in which nine rings are condensed together through two boron atoms and four heteroatoms, and with first and second substituents that are connected to positions of the fused ring core as described herein, and thus, may exhibit high efficiency and long lifespan. The Examples Compounds may exhibit excellent molecular stability due to their structure and the bonding positions of the first and second substituents, and thus, may contribute to high efficiency and long lifespan of the light emitting element. The Example Compounds include the first and second substituents, so that boron atoms may be effectively protected, and intermolecular interaction is suppressed, thereby controlling or limiting the formation of excimers or exciplexes, so that luminous efficiency and lifespan may be increased. The Example Compounds are capable of suppressing Dexter energy transfer by increasing intermolecular distance due to the first and second substituents, and thus, may suppress lifespan deterioration caused by an increase in triplet concentration.

The light emitting element according to an embodiment includes the fused polycyclic compound according to an embodiment as a light emitting dopant of a thermally activated delayed fluorescence (TADF) light emitting element, and thus, may achieve high element efficiency and improved lifespan properties in a blue light wavelength range.

By comparing Examples 1 to 8 with Comparative Examples 1 to 9, long lifespan and high efficiency of the light emitting elements were achieved in the Examples. Improved luminous efficiency and lifetime properties are thought to be attributed to suppressed intermolecular interaction within the elements due to the influence of the first and second substituents Example Compounds used in Examples 1 to 8, thereby limiting the loss of luminescence activity through phenomena such as quenching. Due to the first and second substituents of the Example Compounds, the boron atoms in the molecular structure therein may be effectively protected, and accordingly, deterioration caused by a reaction with minute amounts of water molecules and oxygen molecules present in the elements may be prevented. In the Example Compounds, the positions at which the first and second substituents are connected correspond to positions with high chemical reactivity, and in the Comparative Example Compounds, such corresponding positions are not substituted with the first and second substituents, thereby becoming a reaction point that interacts with other molecules, thereby contributing to deterioration of the light emitting element.

Comparing Examples 1 and 7 with Comparative Examples 3 and 4, the external quantum efficiency and lifetime of Examples 1 and 7 are both improved, as compared to those of Comparative Examples 3 and 4. It is determined that such high efficiency and long lifespan properties are attributed to the first and second substituents being bonded at positions of the fused ring core as shown in the following chemical structures. Compounds 30 and 45 that are included in Examples 1 and 7 each have a structure in which an aryl group, which is a first substituent, is connected to the fused ring core at positions c1 and c2, and each have a structure in which an aryl group, which is a second substituent, is connected to the fused ring core at positions a1 and a3, wherein positions a1 to a4 correspond to the first to fourth carbon atoms as described herein. In comparison, Comparative Compounds X-3 and X-4, which are respectively included in Comparative Examples 3 and 4, have a structure in which an aryl group is connected to positions corresponding to c1 and c2, and an alkyl group is connected to positions corresponding to a1 and a3, but there are no significant improvements in luminous efficiency and element lifespan as in Examples 1 and 7. This is determined to be due to the fact that an alkyl group, rather than a second substituent such as an amine group, aryl group, heteroaryl group, or the like, is bonded to at least one of positions a1 to a4, which reduces stability as compared to the Example Compounds in which the second substituent is included. As a result, it can be seen that the Comparative Example Compounds are likely to deteriorate when applied to an element, and thus, have degraded efficiency and lifespan properties as compared to those of the Examples.

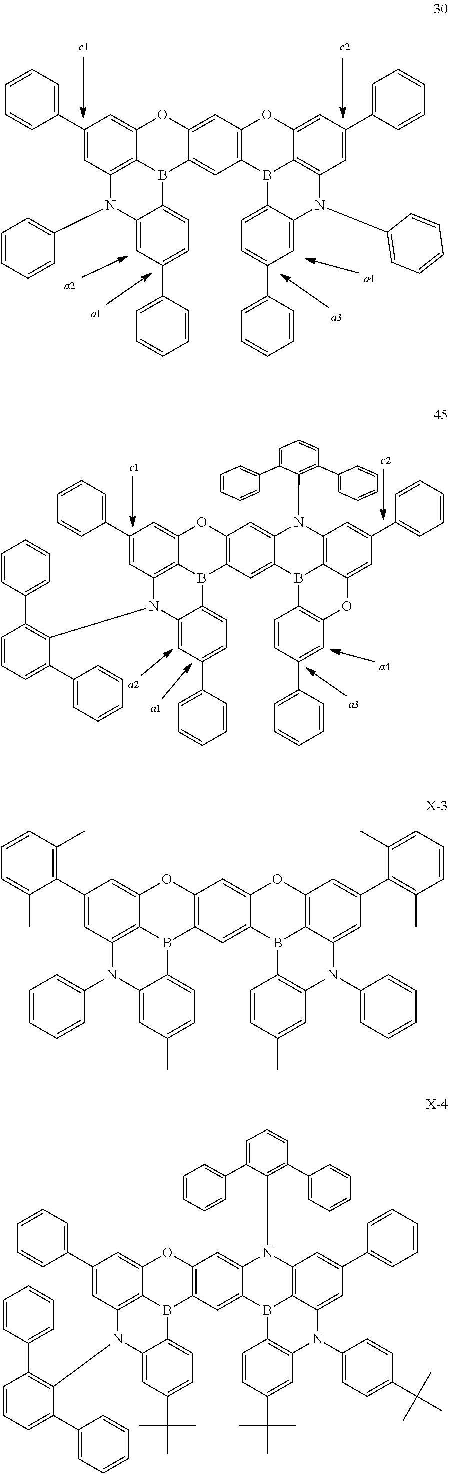

Referring to Comparative Examples 5 and 6, the external quantum efficiency and lifespan thereof are both degraded as compared to the Examples. Comparative Example Compound X-5 included in Comparative Example 5 has a structure in which a substituent is bonded at positions corresponding to c1 and c2, but also has a structure in which hydrogen atoms are connected to the first to fourth carbon atoms, and thus does not include the second substituent as defined herein, thereby having degraded stability. Thus, when applied to a light emitting element, it can be confirmed that the efficiency and lifespan thereof are both degraded. Compared to Comparative Example Compound X-5, despite having a structure in which an aryl group is bonded at positions corresponding to a1 and a3, thereby having a second substituent bonded to at least one of the first to fourth carbon atoms, efficiency and lifespan properties of Comparative Example Compound X-6 included in Comparative Example 6 are not significantly improved. This is determined to be the result of degradation in stability due to the fact that an amine group or a carbazole group, rather than a first substituent of an alkyl group or an aryl group, is bonded at positions corresponding to c1 and c2. Thus, if a carbazole group or an amine group is a substituent bonded at positions corresponding to c1 and c2 as in Comparative Example Compounds X-5 and X-6, the carbazole group or the amine group may be first decomposed in the material, and as a result, the luminous efficiency and lifespan properties may be degraded.

Referring to Comparative Example 8, the external quantum efficiency and lifespan of Comparative Example 8 are both degraded as compared to the Examples. Comparative Example Compound X-8 included in Comparative Example 8 has a structure in which a second substituent is present but not bonded at positions corresponding to any of positions a1 to a4, which correspond to the first to fourth carbon atoms as described herein, thereby having degraded stability. Thus, when applied to a light emitting element, it can be confirmed that the efficiency and lifespan thereof are both degraded. By contrast, the Example Compounds may exhibit excellent stability due to the bonding positions of the first substituent and the second substituent, and thus, may contribute to high efficiency and long lifespan of the light emitting element.

Referring to Comparative Example 9, the external quantum efficiency and lifespan of Comparative Example 9 are both degraded as compared to the Examples. In comparison to the Example Compounds, Comparative Example Compound X-9 included in Comparative Example 9 corresponds to a compound in which all four heteroatoms included in the fused ring core are nitrogen atoms. A compound in which all four heteroatoms, which are ring-forming atoms of the fused ring core, are all nitrogen atoms in the fused ring core containing boron, as in Comparative Example Compound X-9, is prone to oxidation as compared to the Example Compounds, and as a result, material stability may be degraded. By contrast, the Example Compounds may exhibit excellent molecular stability since the fourth heteroatom among four heteroatoms does not contain a nitrogen atom, and thus, may contribute to high efficiency and long lifespan of the light emitting element.

A light emitting element according to an embodiment may exhibit improved element properties with high efficiency and long lifespan.

A fused polycyclic compound according to an embodiment may contribute to high efficiency and long lifespan of a light emitting element by being included in a light emitting layer of the light emitting element.

A display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
a light emitting layer disposed between the first electrode and the second electrode, wherein
the light emitting layer includes a first compound represented by Formula 1: 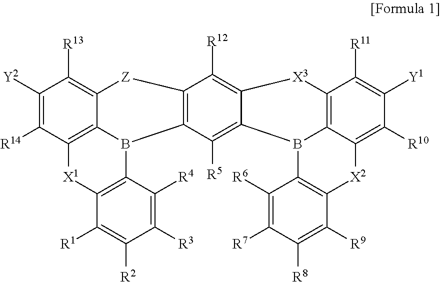
wherein in Formula 1,
X¹, X², and X³ are each independently O, S, Se, C(R¹⁵)(R¹⁶), P(R¹⁷), Si(R¹⁸)(R¹⁹), C═O, C═S, or N(R²⁰),
Y¹ and Y² are each independently a substituted or unsubstituted alkyl group having 1 to 20 carbon atoms or a substituted or unsubstituted aryl group having 6 to 30 ring-forming carbon atoms,
Z is O, S, Se, C(R²¹)(R²²), P(R²³), Si(R²⁴)(R²⁵), C═O, or C═S, and
R¹ to R²⁵ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or form a ring by being bonded to an adjacent group,
except that:
if Y¹ and Y² are each an alkyl group, then R¹ to R²⁰ are not bonded to an adjacent group to form a ring; and
at least one of R¹, R², R⁸, and R⁹ is each independently a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

2. The light emitting element of claim 1, wherein the first compound is represented by one of Formula 2-1 to Formula 2-4: 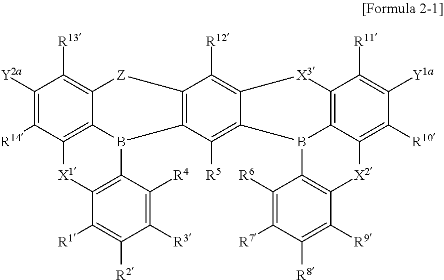 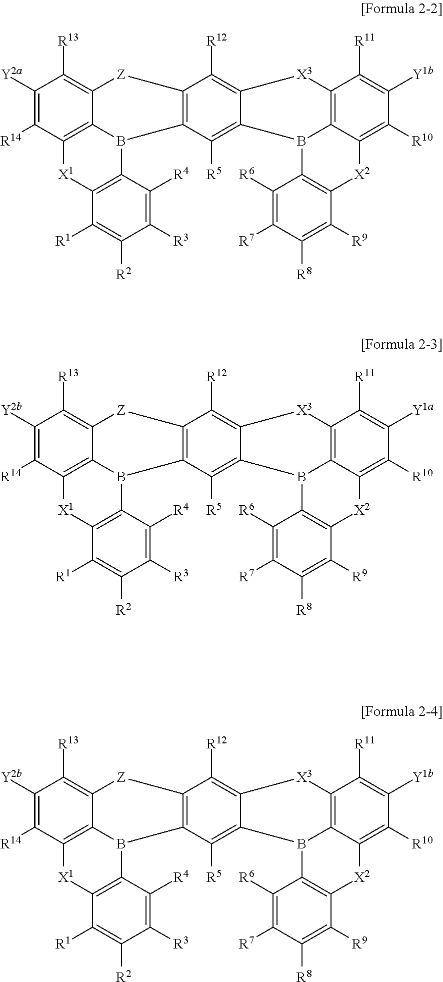
wherein in Formula 2-1 to Formula 2-4,
Z, X¹ to X³, and R¹ to R¹⁴ are the same as defined in Formula 1
Y^{1a} and Y^{2a} are each independently a substituted or unsubstituted alkyl group having 1 to 20 carbon atoms, and
Y^{1b} and Y^{2b} are each independently a substituted or unsubstituted aryl group having 6 to 30 ring-forming carbon atoms, and
wherein in Formula 2-1,
X^{1′}, X^{2′}, and X^{3′} are each independently O, S, Se, C(R^{15′})(R^{16′}), P(R^{17′}), Si(R^{18′})(R^{19′}), C═O, C═S, or N(R^{20′}), and
R^{1′} to R^{20′} are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

3. The light emitting element of claim 1, wherein the first compound is represented by one of Formula 3-1 to Formula 3-6: 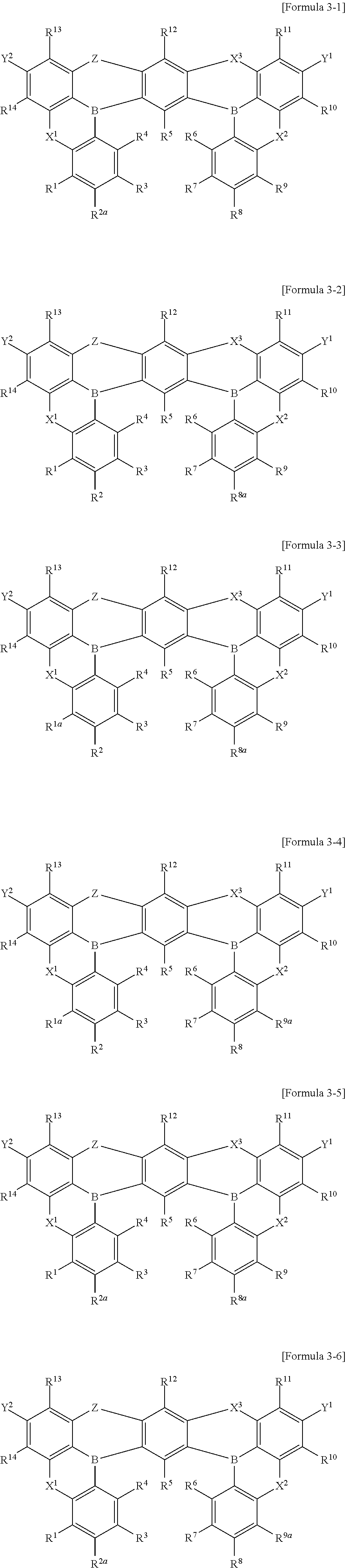
wherein in Formula 3-1 to Formula 3-6,
R^{1a}, R^{2a}, R^{8a}, and R^{9a} are each independently a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms, and
Z, X¹ to X³, Y¹, Y², and R¹ to R¹⁴ are the same as defined in Formula 1.

4. The light emitting element of claim 1, wherein the first compound is represented by Formula 4: 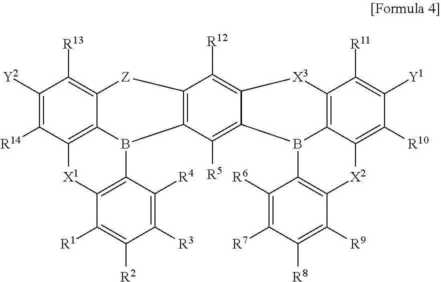
wherein in Formula 4,
X¹ to X³, Y¹, Y², and R¹ to R¹⁴ are the same as defined in Formula 1.

5. The light emitting element of claim 1, wherein the first compound is represented by one of Formula 5-1 to Formula 5-3: 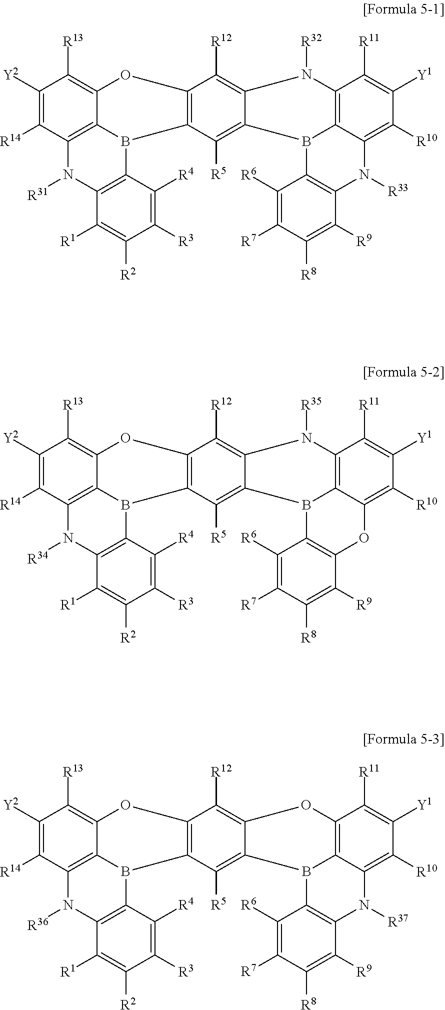
wherein in Formula 5-1 to Formula 5-3,
R³¹ to R³⁷ are each independently a substituted or unsubstituted aryl group having 6 to 30 ring-forming carbon atoms or a substituted or unsubstituted heteroaryl group having 2 to 30 ring-forming carbon atoms, and
Y¹, Y², and R¹ to R¹⁴ are the same as defined in Formula 1.

6. The light emitting element of claim 1, wherein the first compound is represented by Formula 6: 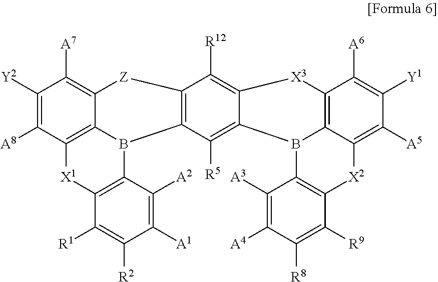
wherein in Formula 6,
A¹ to A⁸ are each independently a hydrogen atom or a deuterium atom, and
Z, X¹ to X³, Y¹, Y², R¹, R², R₅, R⁸, R⁹, and R¹² are the same as defined in Formula 1.

7. The light emitting element of claim 1, wherein Y¹ and Y² are each independently a substituted or unsubstituted alkyl group having 2 to 10 carbon atoms or a substituted or unsubstituted aryl group having 6 to 15 ring-forming carbon atoms.

8. The light emitting element of claim 1, wherein
at least one of R¹, R², R⁸, and R⁹ is each independently a substituted or unsubstituted arylamine group, a substituted or unsubstituted phenyl group, a substituted or unsubstituted biphenyl group, or a substituted or unsubstituted carbazole group, and
the remainder of R¹, R², R⁸, and R⁹ are each independently a hydrogen atom or a deuterium atom.

9. The light emitting element of claim 1, wherein the light emitting layer further comprises:
at least one of a second compound represented by Formula HT-1, a third compound represented by Formula ET-1, and a fourth compound represented by Formula D-1: 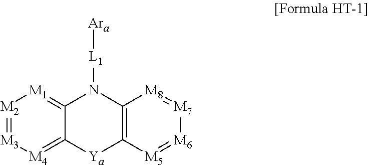
wherein in Formula HT-1,
M₁ to M₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Arₐ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or form a ring by being bonded to an adjacent group; 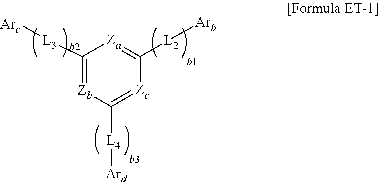
wherein in Formula ET-1,
at least one of Zₐ to Z_{c} is each N,
the remainder of Zₐ to Z_{c} are each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 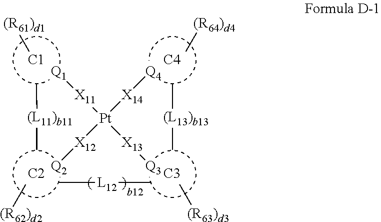
wherein in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
X₁₁ to X₁₄ are each independently a direct linkage or *—O—*,
L₁₁ to L₁₃ are each independently a direct linkage, *—O—*, *—S—*, 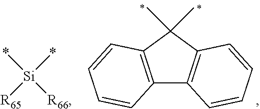
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted an alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

10. The light emitting element of claim 1, wherein the first compound comprises at least one compound selected from Compound Group 1:

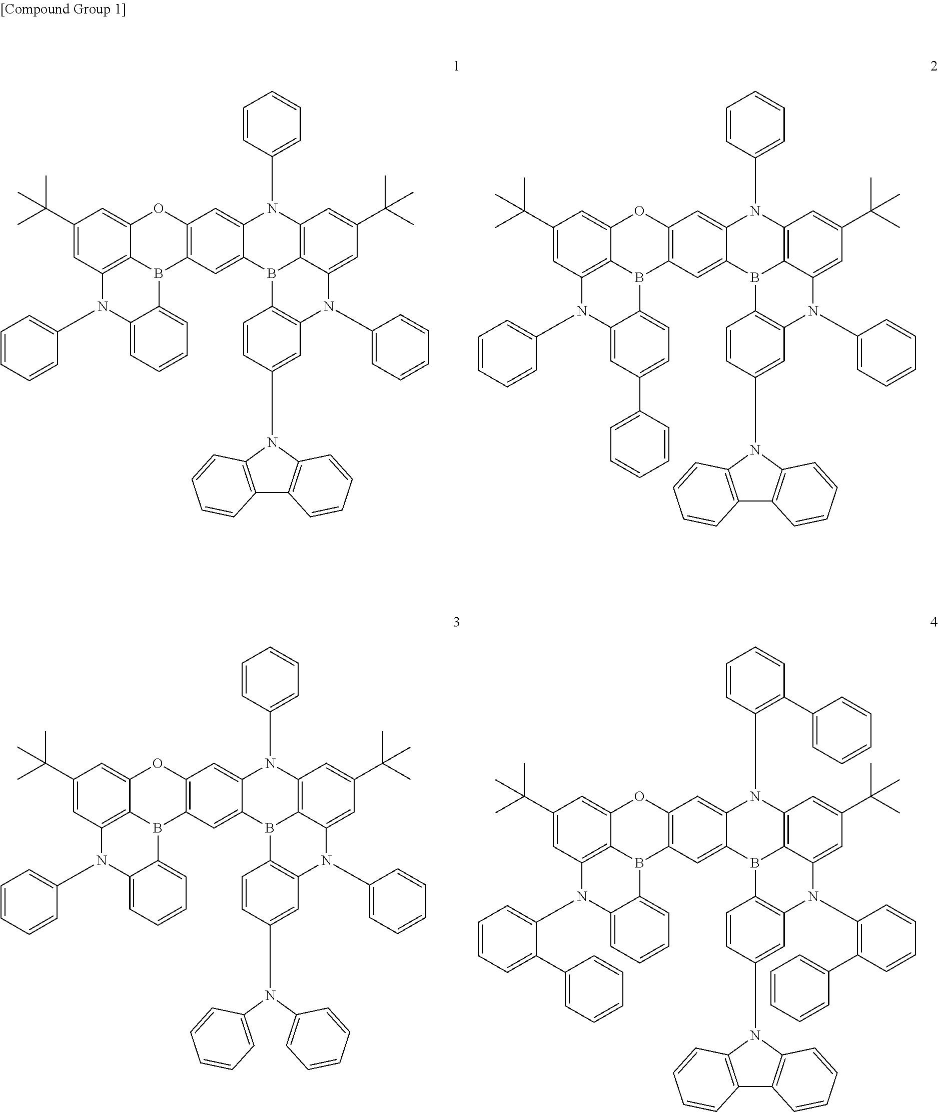

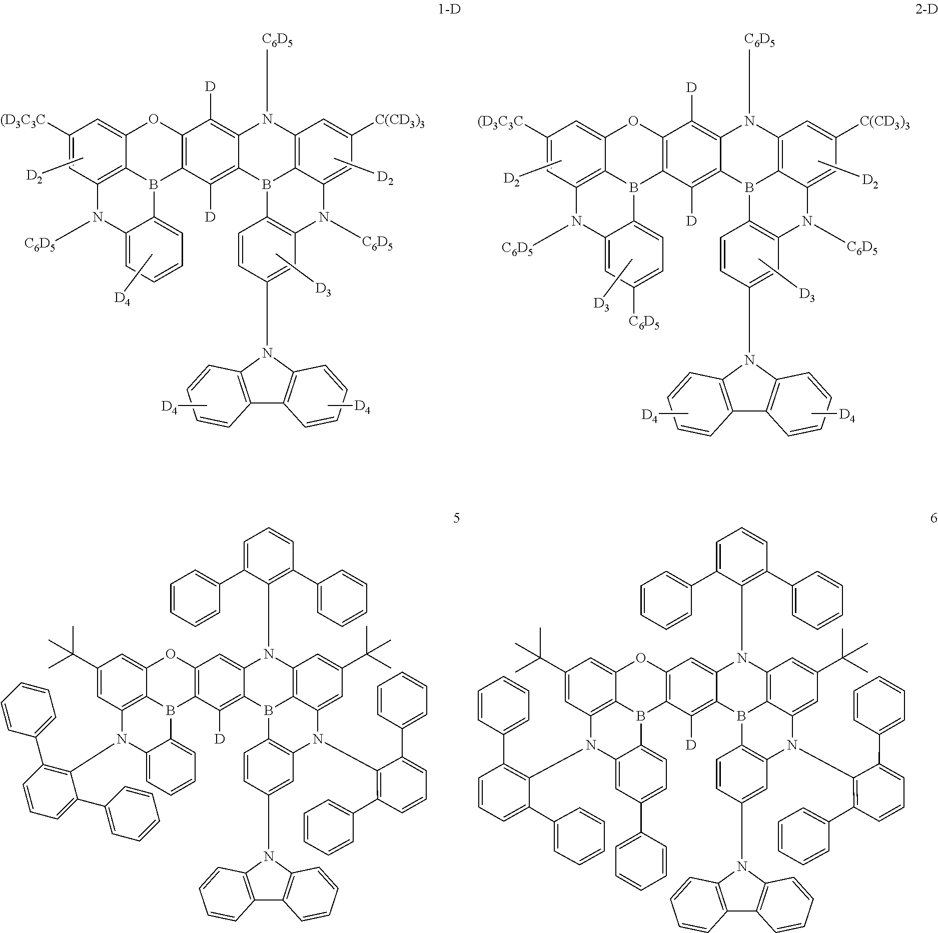

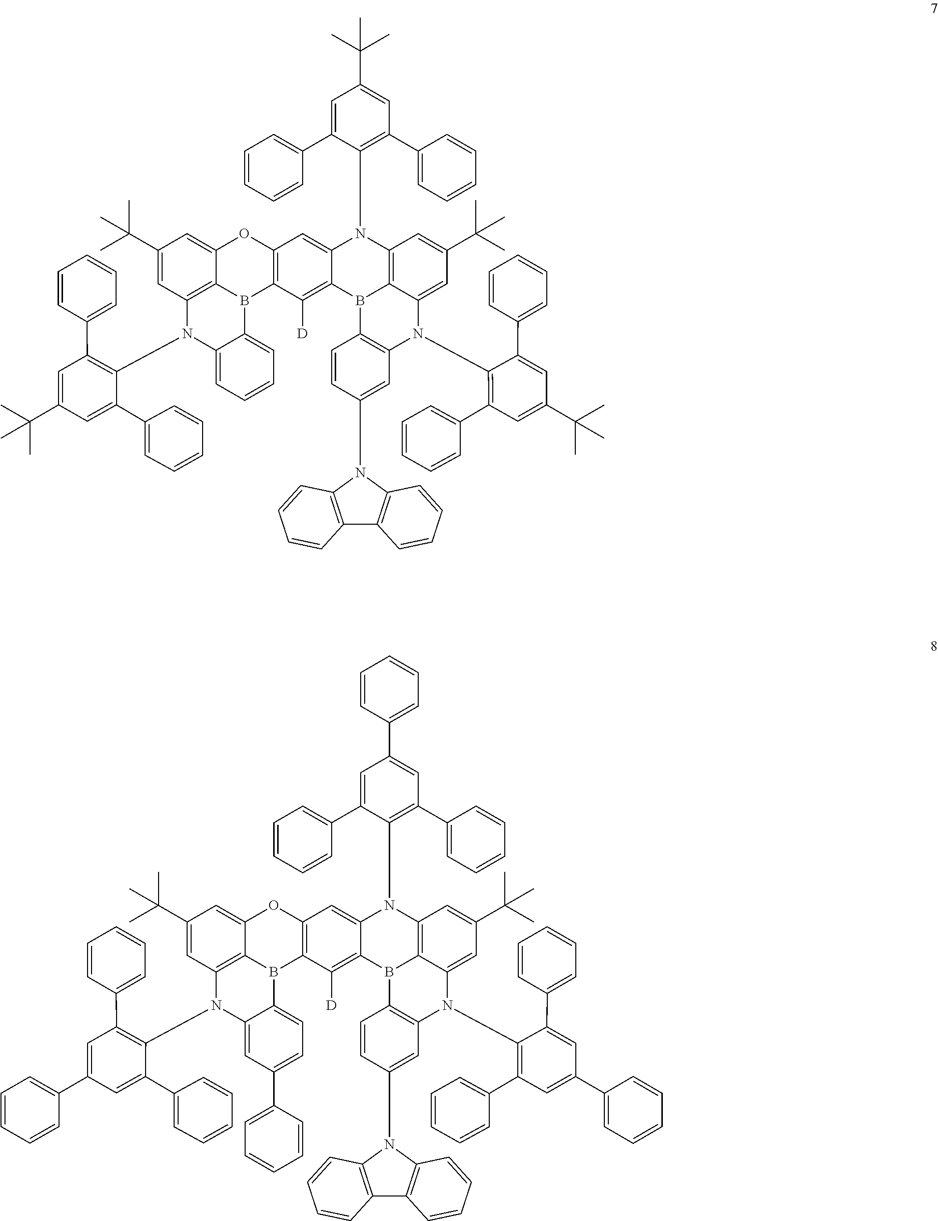 [SMILES: [2H]c1c2c(cc3c1B1c4ccc(-n5c6ccccc6c6ccccc65)cc4N(c4c(-c5ccccc5)cc(C(C)(C)C)cc4-c4ccccc4)c4cc(C(C)(C)C)cc(c41)N3c1c(-c3ccccc3)cc(C(C)(C)C)cc1-c1ccccc1)Oc1cc(C(C)(C)C)cc3c1B2c1ccccc1N3c1c(-c2ccccc2)cc(C(C)(C)C)cc1-c1ccccc1 ; [2H]c1c2c(cc3c1B1c4ccc(-n5c6ccccc6c6ccccc65)cc4N(c4c(-c5ccccc5)cc(-c5ccccc5)cc4-c4ccccc4)c4cc(C(C)(C)C)cc(c41)N3c1c(-c3ccccc3)cc(-c3ccccc3)cc1-c1ccccc1)Oc1cc(C(C)(C)C)cc3c1B2c1ccc(-c2ccccc2)cc1N3c1c(-c2ccccc2)cc(-c2ccccc2)cc1-c1ccccc1]

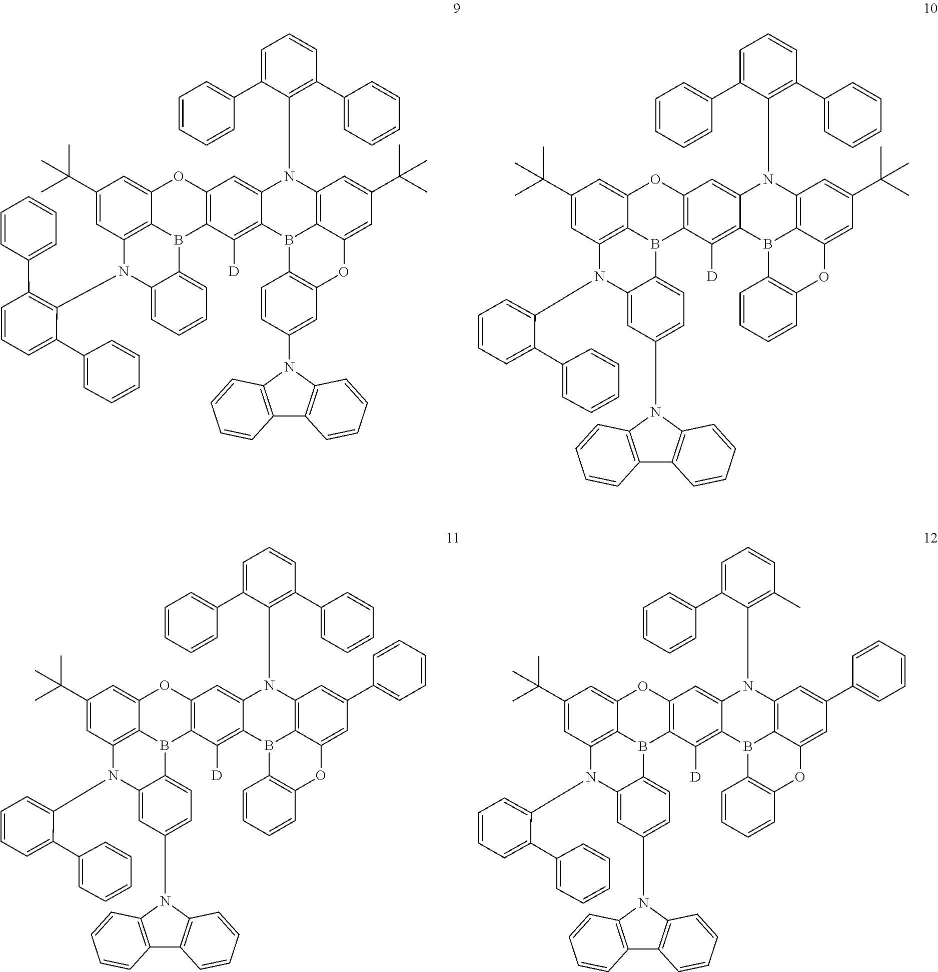

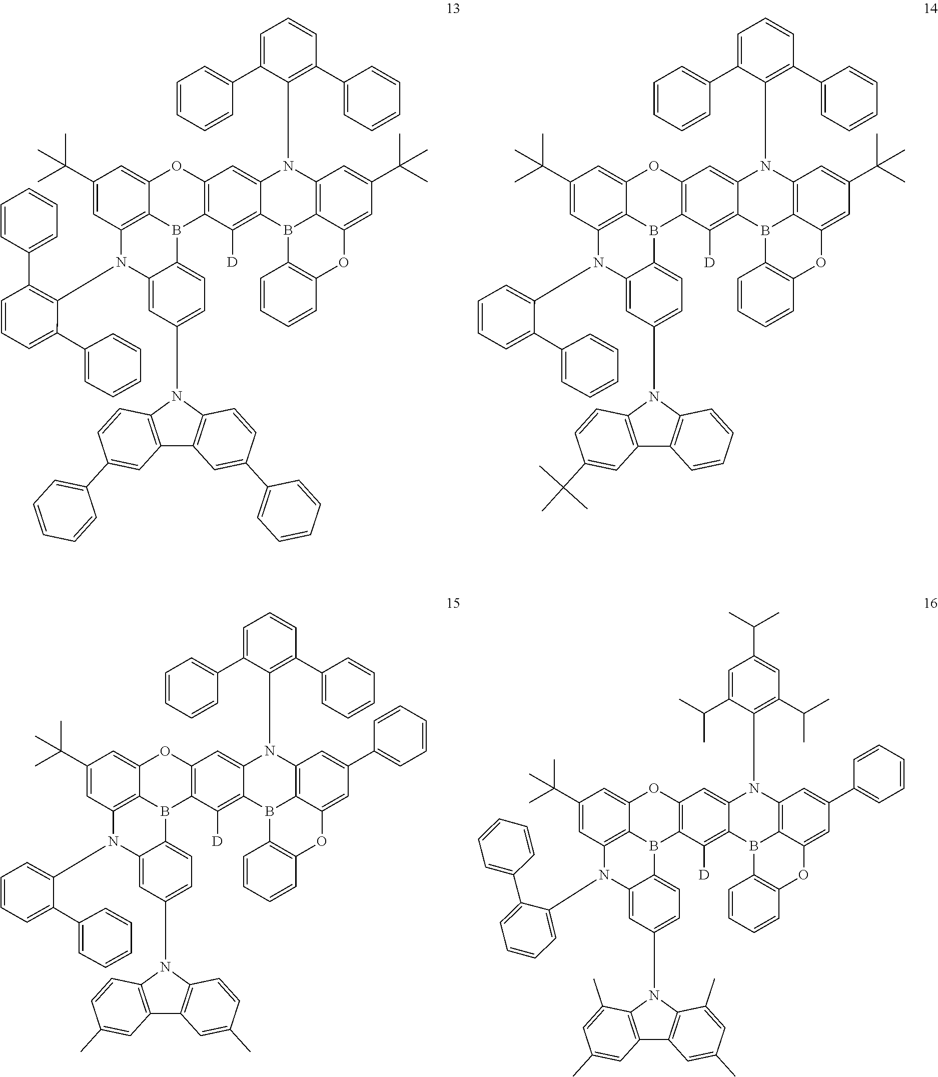

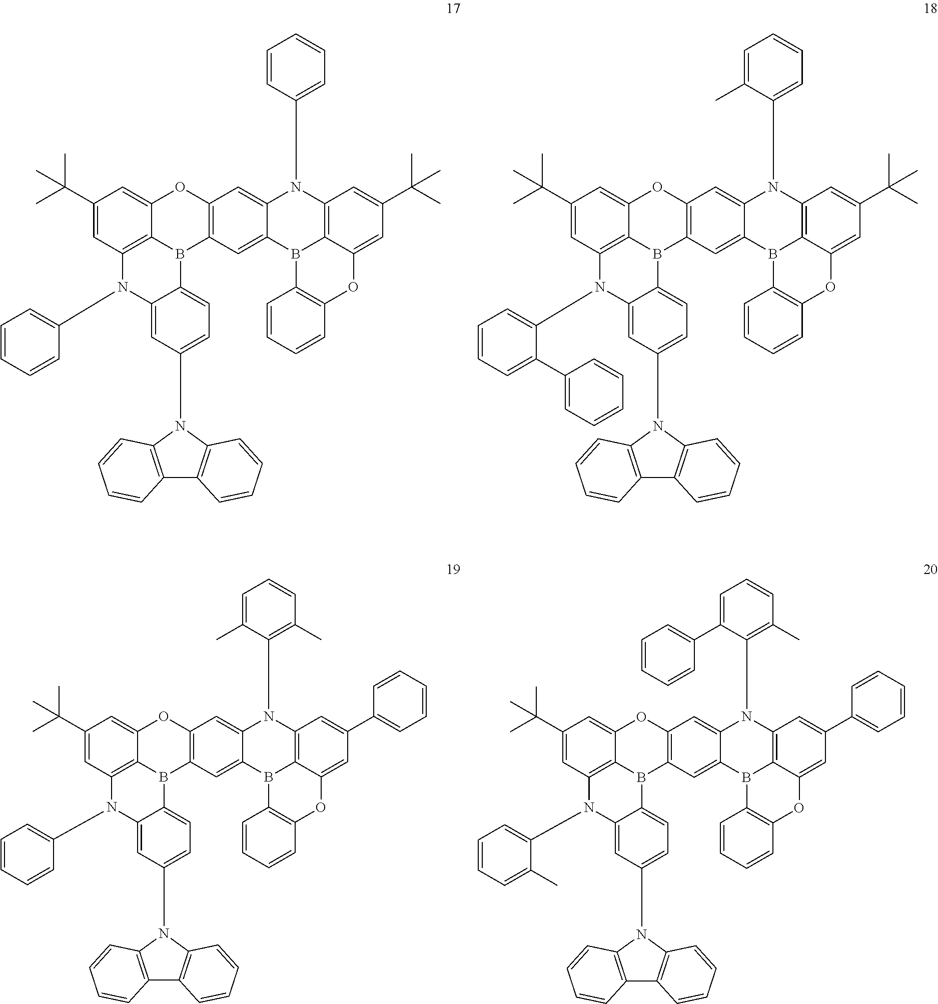

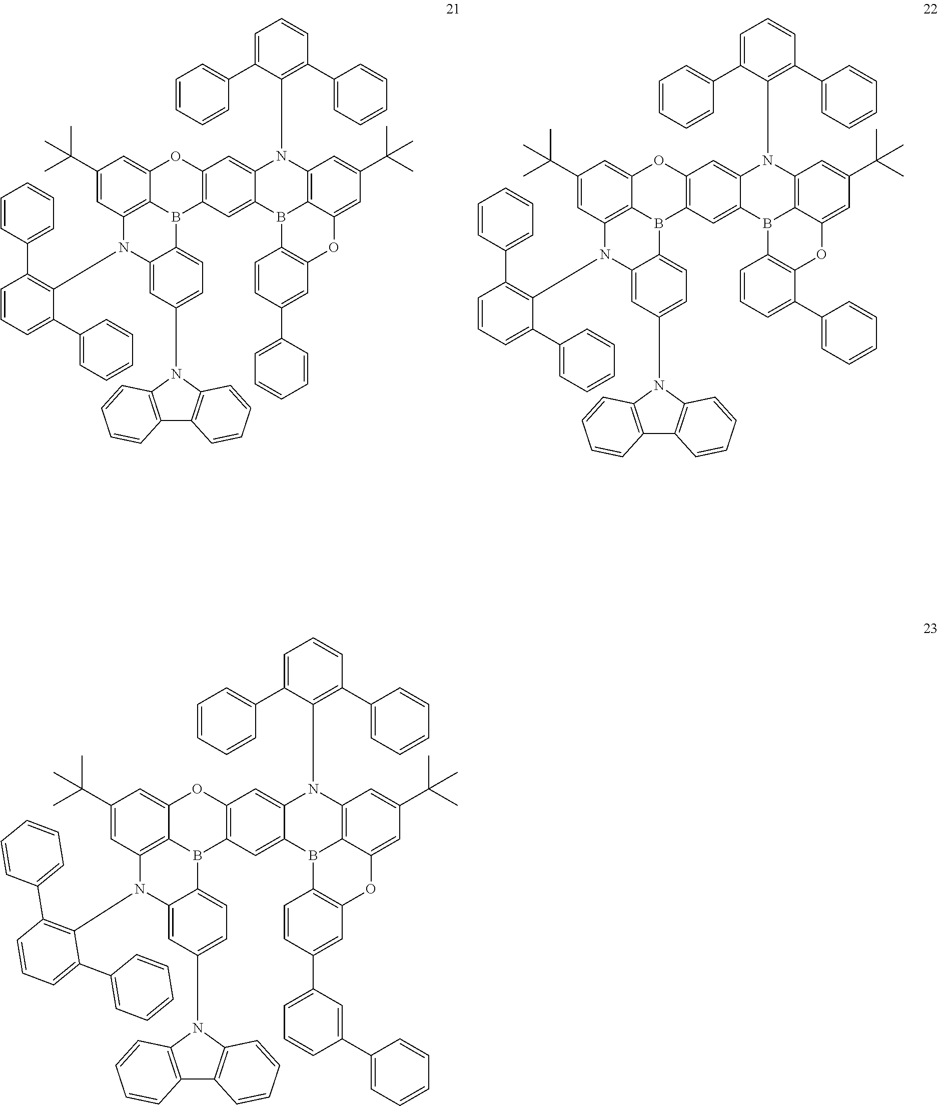

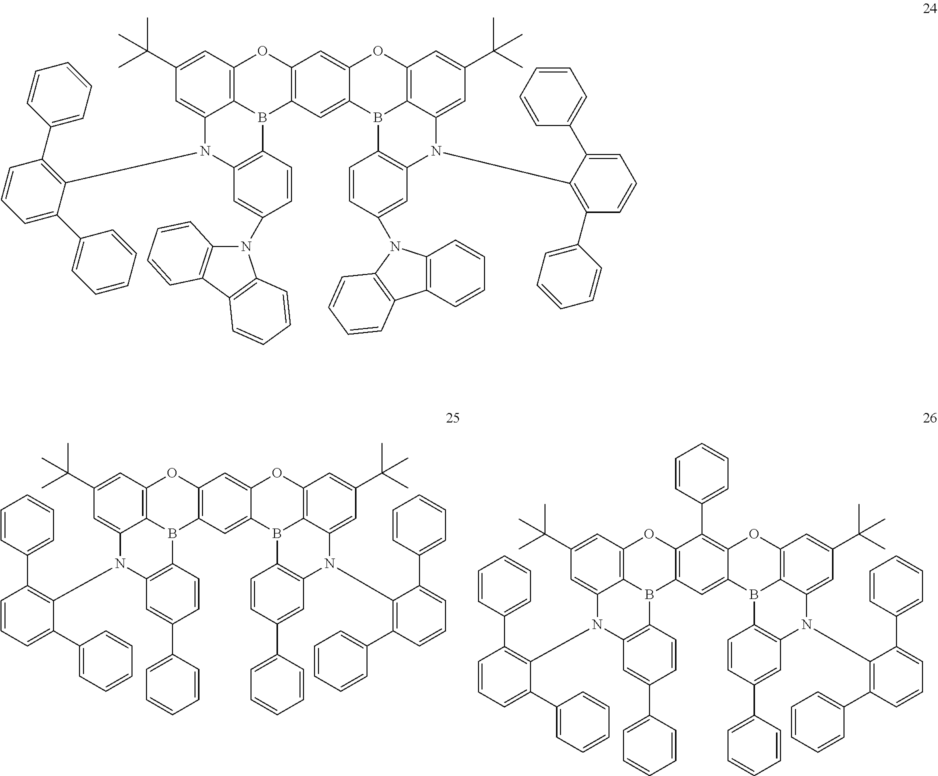

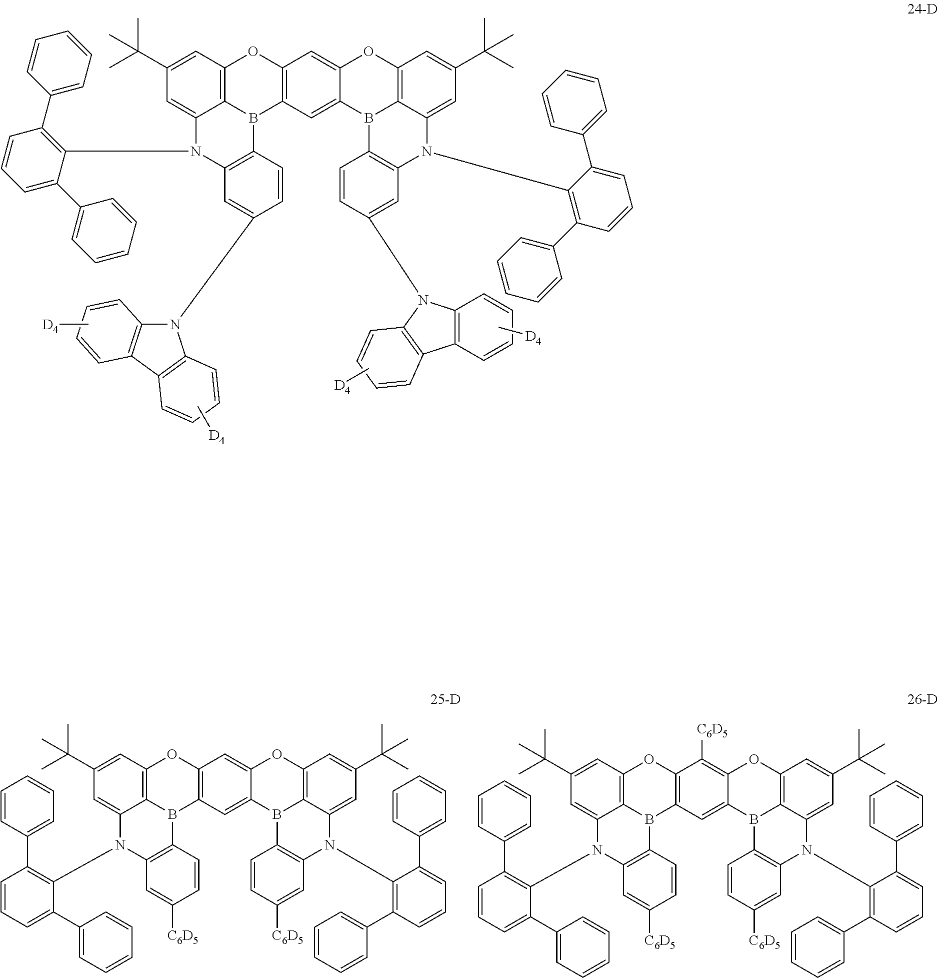

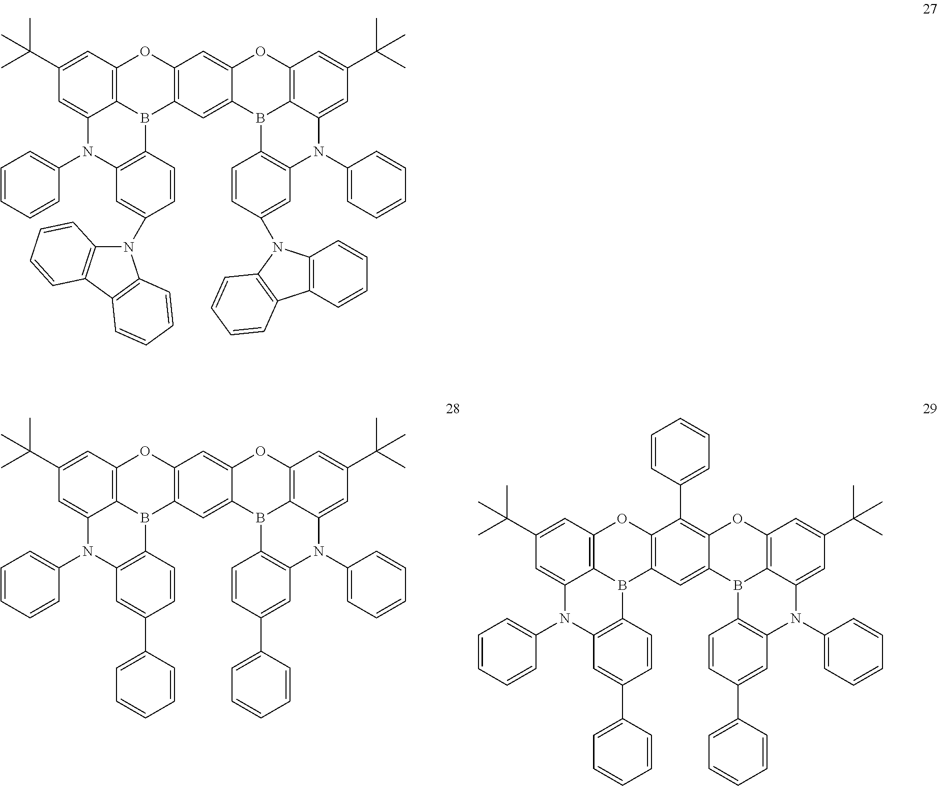 [SMILES: CC(C)(C)c1cc2c3c(c1)N(c1ccccc1)c1cc(-n4c5ccccc5c5ccccc54)ccc1B3c1cc3c(cc1O2)Oc1cc(C(C)(C)C)cc2c1B3c1ccc(-n3c4ccccc4c4ccccc43)cc1N2c1ccccc1 ; CC(C)(C)c1cc2c3c(c1)N(c1ccccc1)c1cc(-c4ccccc4)ccc1B3c1cc3c(cc1O2)Oc1cc(C(C)(C)C)cc2c1B3c1ccc(-c3ccccc3)cc1N2c1ccccc1 ; CC(C)(C)c1cc2c3c(c1)N(c1ccccc1)c1cc(-c4ccccc4)ccc1B3c1cc3c(c(-c4ccccc4)c1O2)Oc1cc(C(C)(C)C)cc2c1B3c1ccc(-c3ccccc3)cc1N2c1ccccc1]

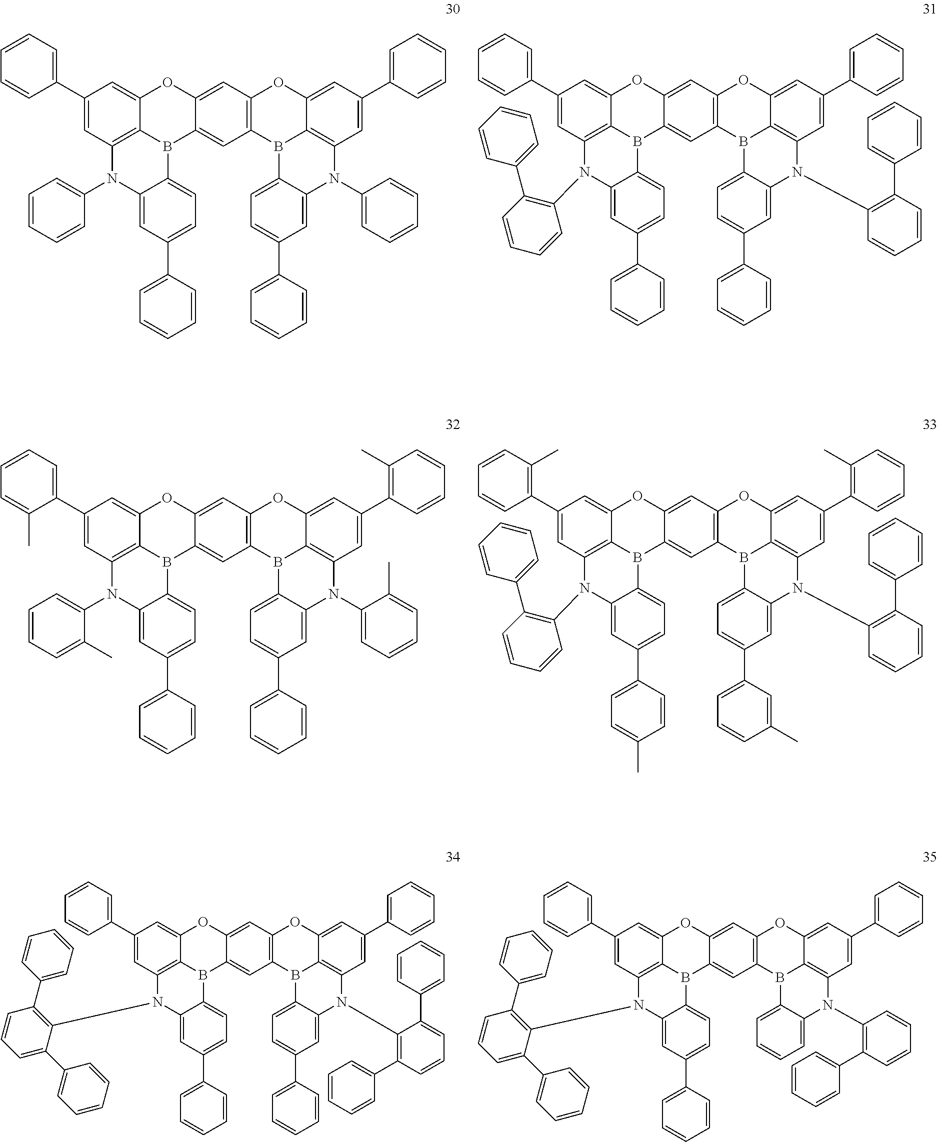

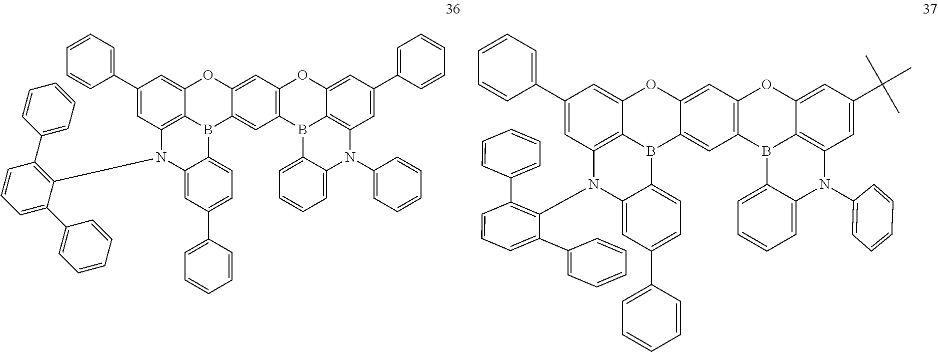

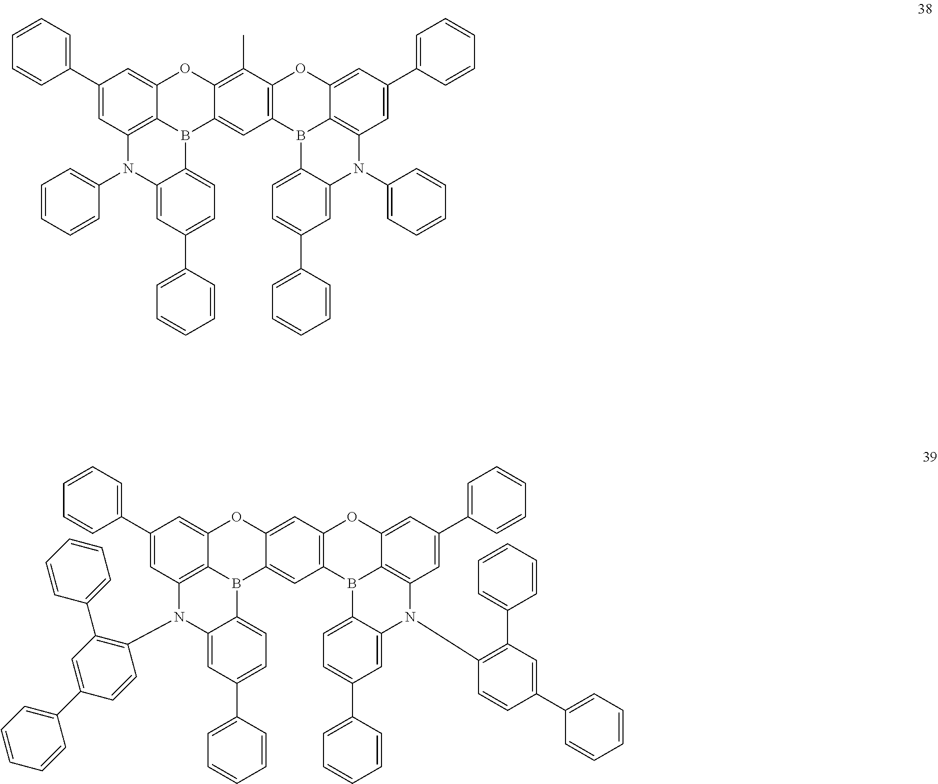 [SMILES: Cc1c2c(cc3c1Oc1cc(-c4ccccc4)cc4c1B3c1ccc(-c3ccccc3)cc1N4c1ccccc1)B1c3ccc(-c4ccccc4)cc3N(c3ccccc3)c3cc(-c4ccccc4)cc(c31)O2 ; c1ccc(-c2ccc(N3c4cc(-c5ccccc5)ccc4B4c5cc6c(cc5Oc5cc(-c7ccccc7)cc3c54)Oc3cc(-c4ccccc4)cc4c3B6c3ccc(-c5ccccc5)cc3N4c3ccc(-c4ccccc4)cc3-c3ccccc3)c(-c3ccccc3)c2)cc1]

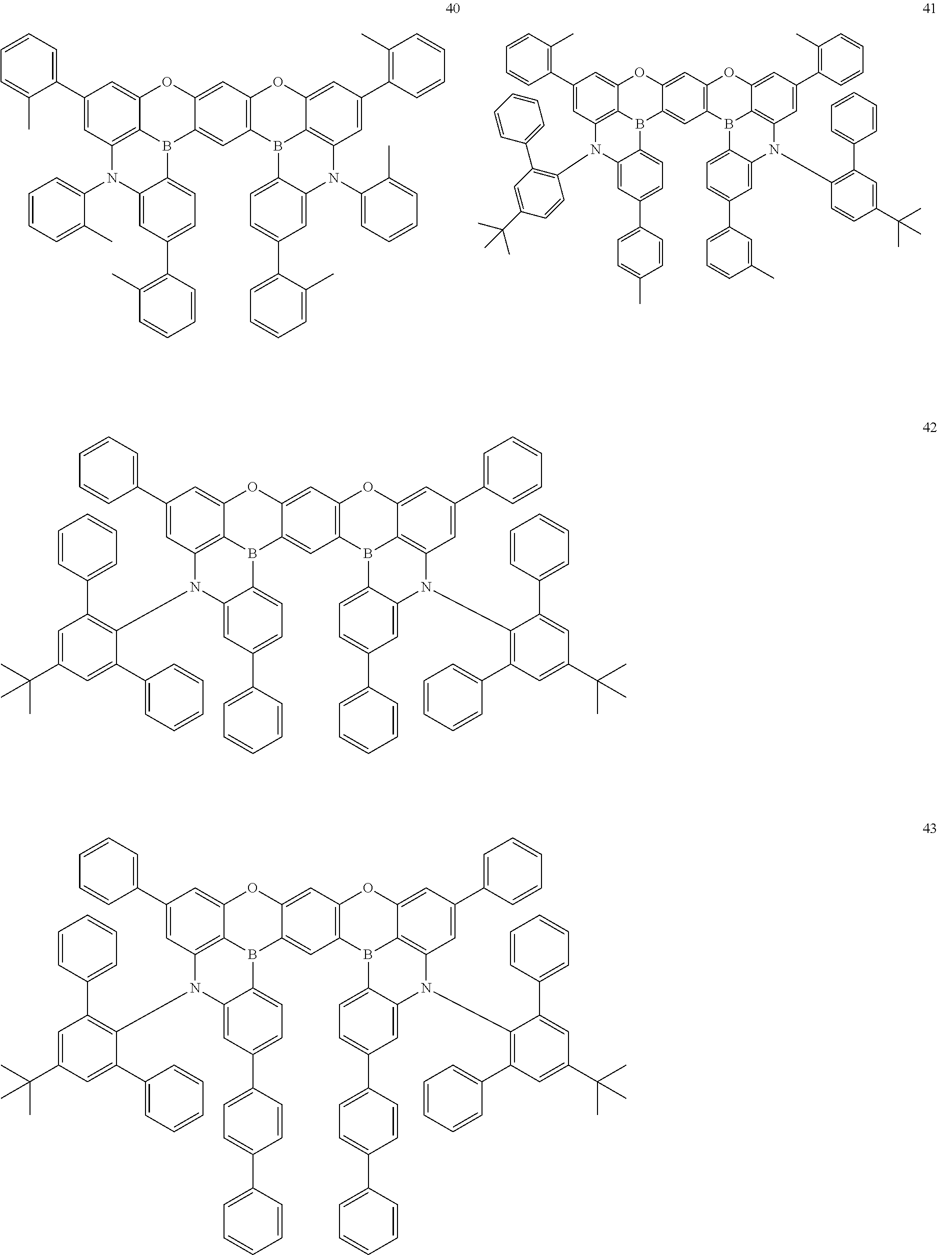

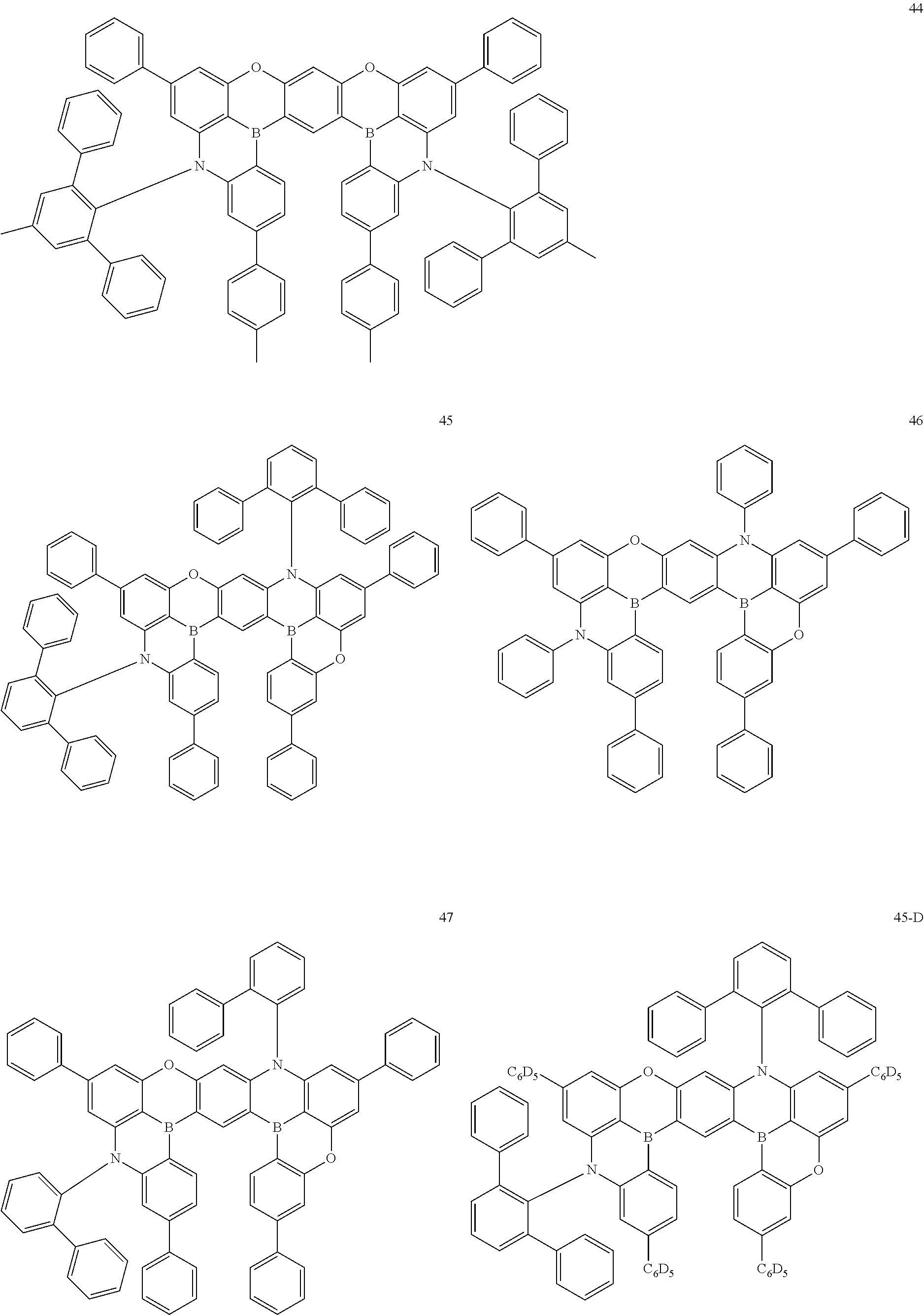

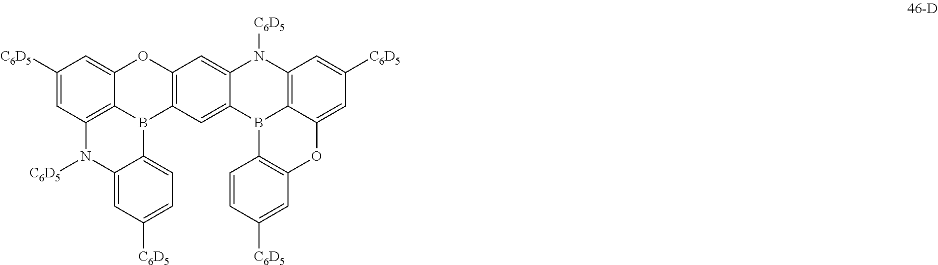

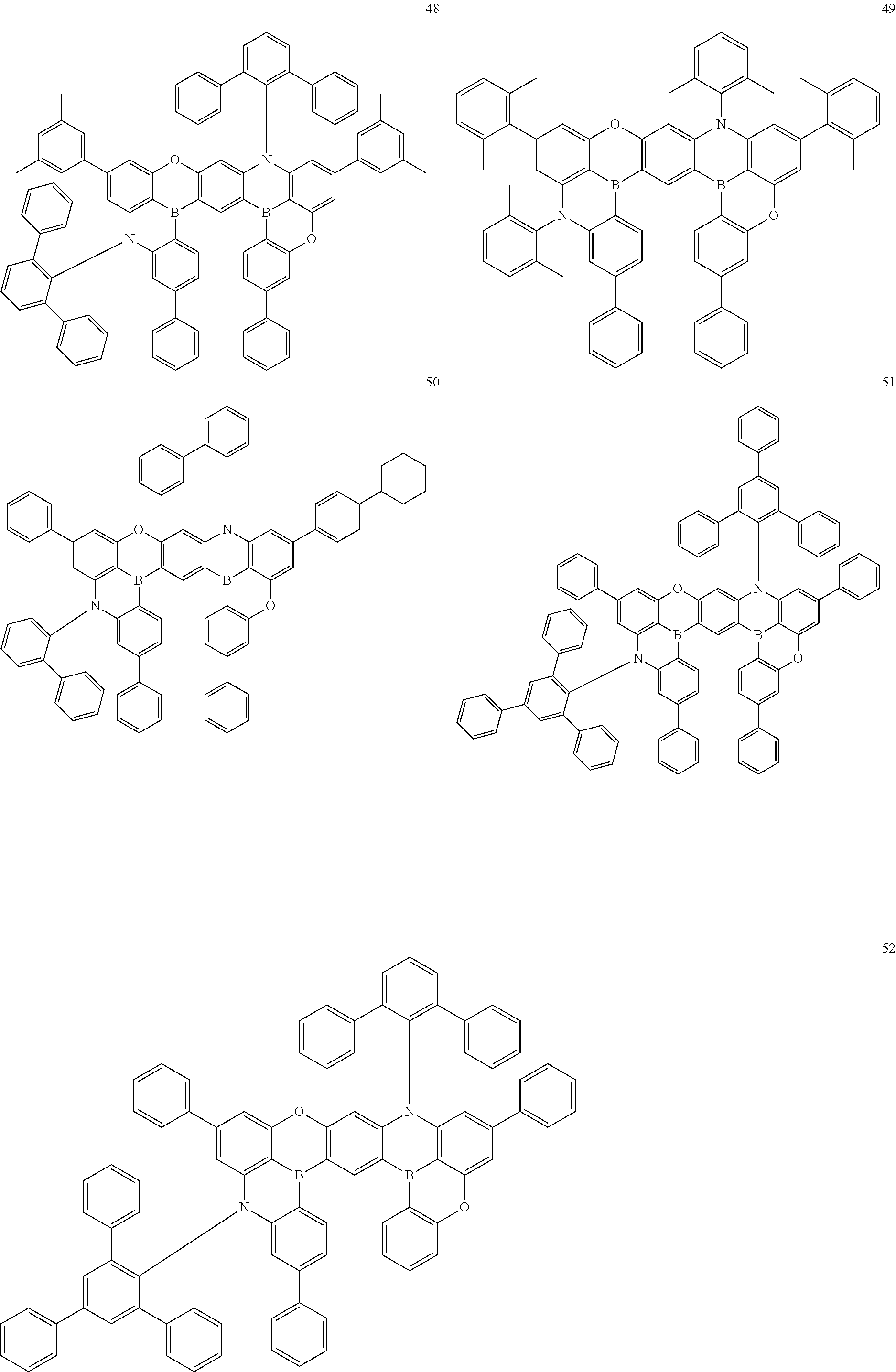

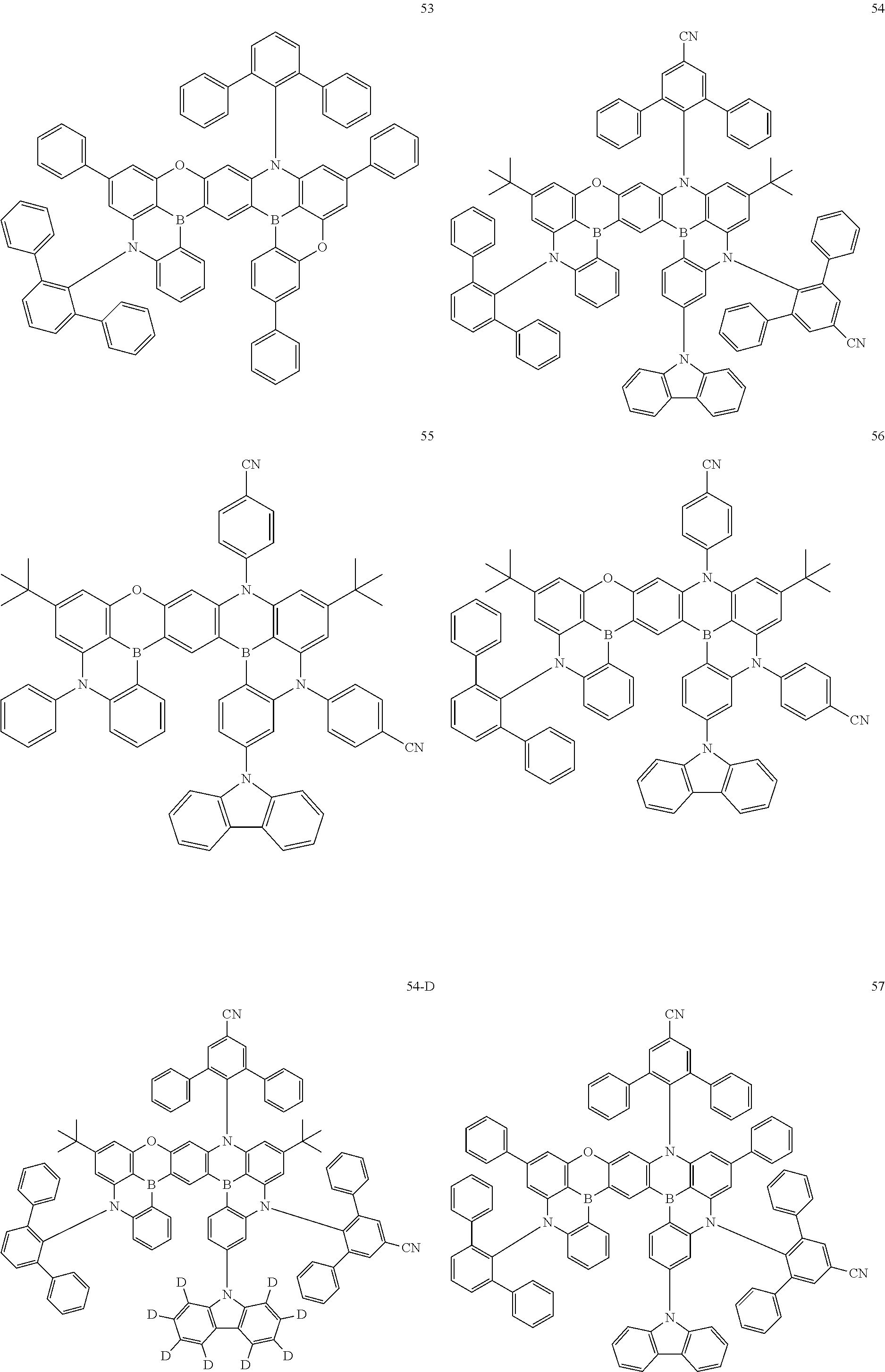

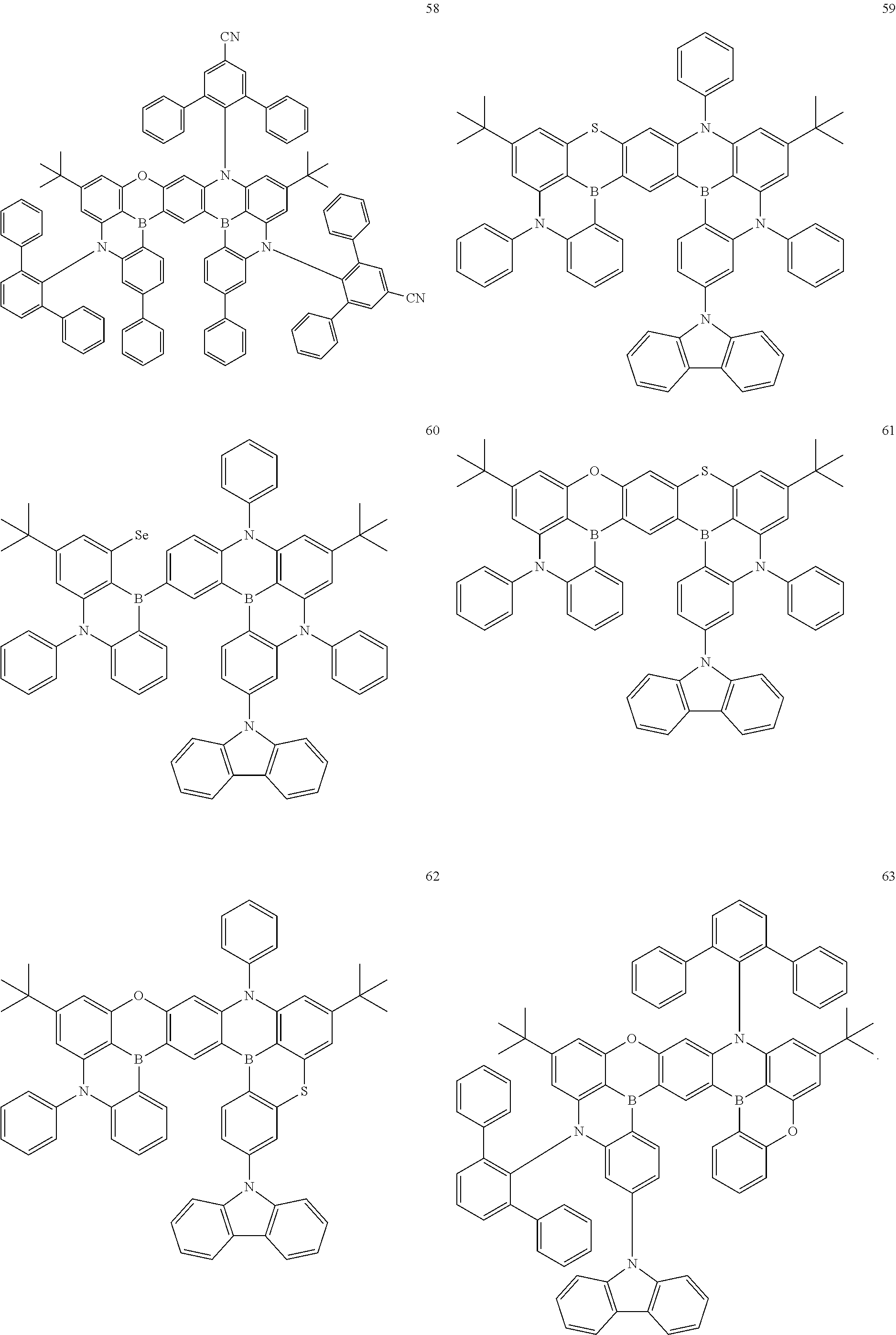

11. A display device comprising:
a circuit layer disposed on a base layer; and
a display element layer disposed on the circuit layer, the display element layer including a light emitting element, wherein
the light emitting element includes:
a first electrode;
a second electrode disposed on the first electrode; and
a light emitting layer disposed between the first electrode and the second electrode, and
the light emitting layer includes a first compound represented by Formula 1: 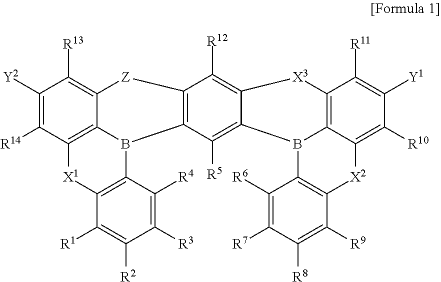
wherein in Formula 1,
X¹, X², and X³ are each independently O, S, Se, C(R¹⁵)(R¹⁶), P(R¹⁷), Si(R¹⁸)(R¹⁹), C═O, C═S, or N(R²⁰),
Y¹ and Y² are each independently a substituted or unsubstituted alkyl group having 1 to 20 carbon atoms or a substituted or unsubstituted aryl group having 6 to 30 ring-forming carbon atoms,
Z is O, S, Se, C(R²¹)(R²²), P(R²³), Si(R²⁴)(R²⁵), C═O, or C═S, and
R¹ to R²⁵ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or form a ring by being bonded to an adjacent group,
except that:
if Y¹ and Y² are each an alkyl group, then R¹ to R²⁰ are not bonded to an adjacent group to form a ring; and
at least one of R¹, R², R⁸, and R⁹ is each independently a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

12. The display device of claim 11, wherein
the light emitting element further comprises a capping layer disposed on the second electrode, and
the capping layer has a refractive index equal to or greater than about 1.6, with respect to light in a wavelength range of about 550 nm to about 660 nm.

13. The display device of claim 11, further comprising:
a light control layer disposed on the display element layer, wherein
the light emitting element emits a first color light, and
the light control layer includes:
a first light control unit including a first quantum dot that converts the first color light into a second color light having a longer wavelength range than the first color light;
a second light control unit including a second quantum dot that converts the first color light into a third color light having a longer wavelength range than the first color light and the second color light; and
a third light control unit that transmits the first color light.

14. The display device of claim 13, further comprising:
a color filter layer disposed on the light control layer, wherein
the color filter layer includes:
a first filter that transmits the second color light;
a second filter that transmits the third color light; and
a third filter that transmits the first color light.

15. A fused polycyclic compound represented by Formula 1: 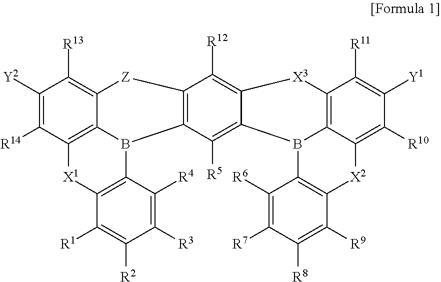
wherein in Formula 1,
X¹, X², and X³ are each independently O, S, Se, C(R¹⁵)(R¹⁶), P(R¹⁷), Si(R¹⁸)(R¹⁹), C═O, C═S, or N(R²⁰),
Y¹ and Y² are each independently a substituted or unsubstituted alkyl group having 1 to 20 carbon atoms or a substituted or unsubstituted aryl group having 6 to 30 ring-forming carbon atoms,
Z is O, S, Se, C(R²¹)(R²²), P(R²³), Si(R²⁴)(R²⁵), C═O, or C═S, and
R¹ to R²⁵ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or form a ring by being bonded to an adjacent group,
except that:
if Y¹ and Y² are each an alkyl group, then R¹ to R²⁰ are not bonded to an adjacent group to form a ring; and
at least one of R¹, R², R⁸, and R⁹ is each independently a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms.

16. The fused polycyclic compound of claim 15, wherein the fused polycyclic compound represented by Formula 1 is represented by one of Formula 2-1 to Formula 2-4: 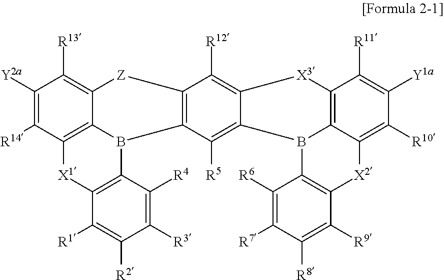 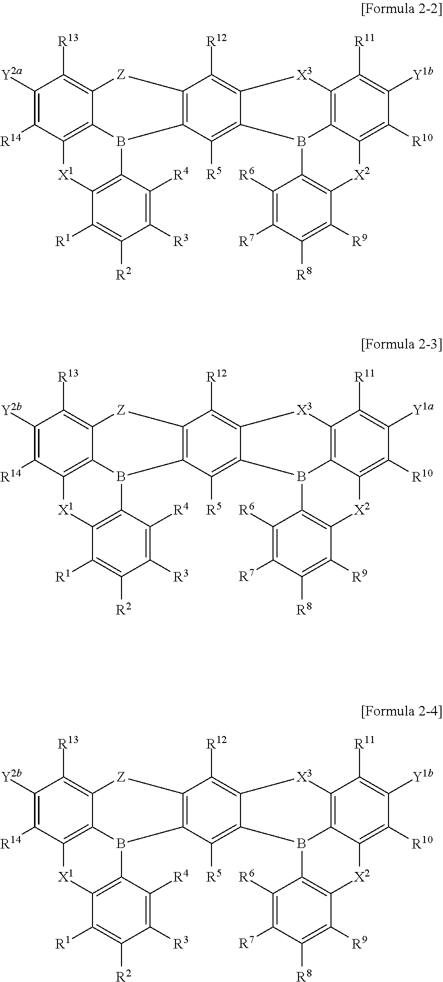
wherein in Formula 2-1 to Formula 2-4,
Z, X¹ to X³, and R¹ to R¹⁴ are the same as defined in Formula 1,
Y^{1a} and Y^{2a} are each independently a substituted or unsubstituted alkyl group having 1 to 20 carbon atoms, and
Y^{1b} and Y^{2b} are each independently a substituted or unsubstituted aryl group having 6 to 30 ring-forming carbon atoms, and
wherein in Formula 2-1,
X¹, X^{2′}, and X^{3′} are each independently O, S, Se, C(R^{15′})(R^{16′}), P(R^{17′}), Si(R^{18′})(R^{19′}), C═O, C═S, or N(R^{20′}), and
R^{1′} to R^{20′} are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted acyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

17. The fused polycyclic compound of claim 15, wherein the fused polycyclic compound represented by Formula 1 is represented by one of Formula 3-1 to Formula 3-6: 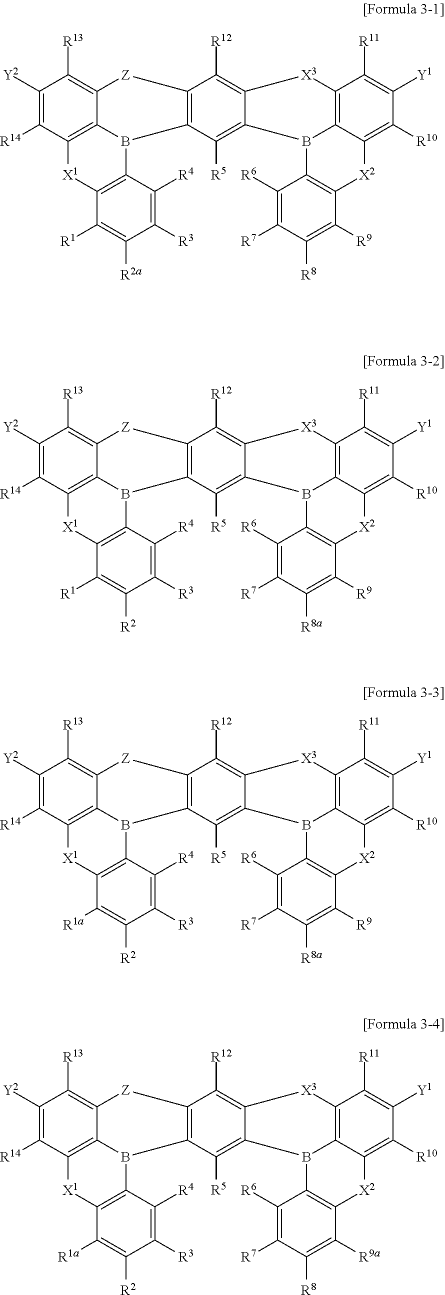 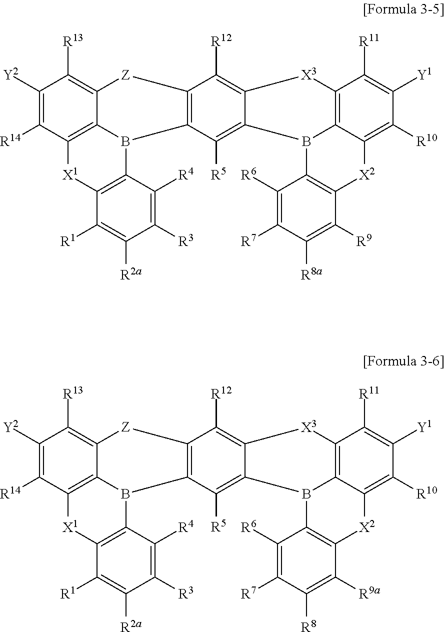
wherein in Formula 3-1 to Formula 3-6,
R^{1a}, R^{2a}, R^{8a}, and R^{9a} are each independently a substituted or unsubstituted amine group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms, and
Z, X¹ to X³, Y¹, Y², and R¹ to R¹⁴ are the same as defined in Formula 1.

18. The fused polycyclic compound of claim 15, wherein the fused polycyclic compound represented by Formula 1 is represented by Formula 4: 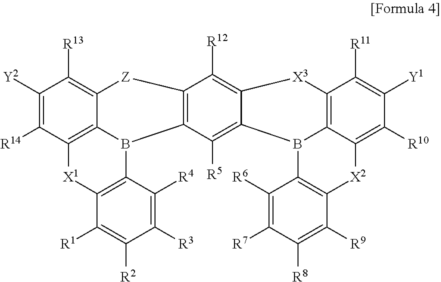
wherein in Formula 4,
X¹ to X³, Y¹, Y², and R¹ to R¹⁴ are the same as defined in Formula 1.

19. The fused polycyclic compound of claim 15, wherein the fused polycyclic compound represented by Formula 1 is represented by one of Formula 5-1 to Formula 5-3: 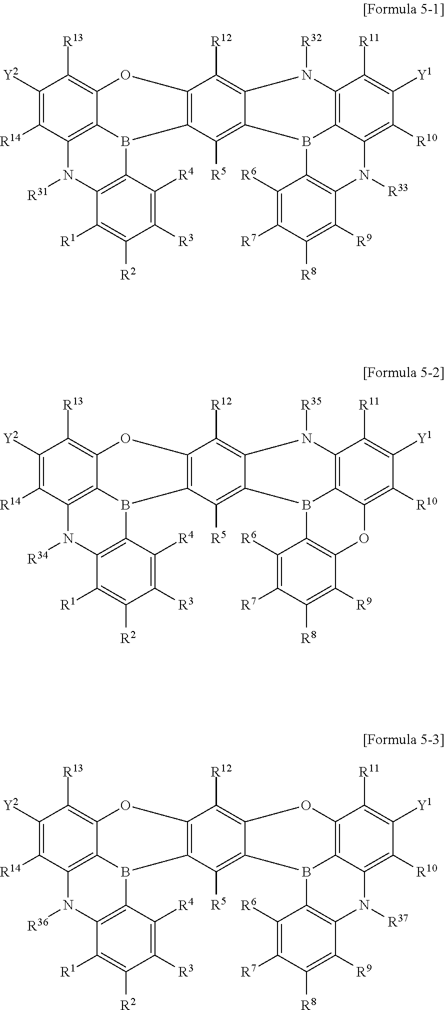
wherein in Formula 5-1 to Formula 5-3,
R³¹ to R³⁷ are each independently a substituted or unsubstituted aryl group having 6 to 30 ring-forming carbon atoms or a substituted or unsubstituted heteroaryl group having 2 to 30 ring-forming carbon atoms, and
Y¹, Y², and R¹ to R¹⁴ are the same as defined in Formula 1.

20. The fused polycyclic compound of claim 15, wherein the fused polycyclic compound is selected from Compound Group 1: 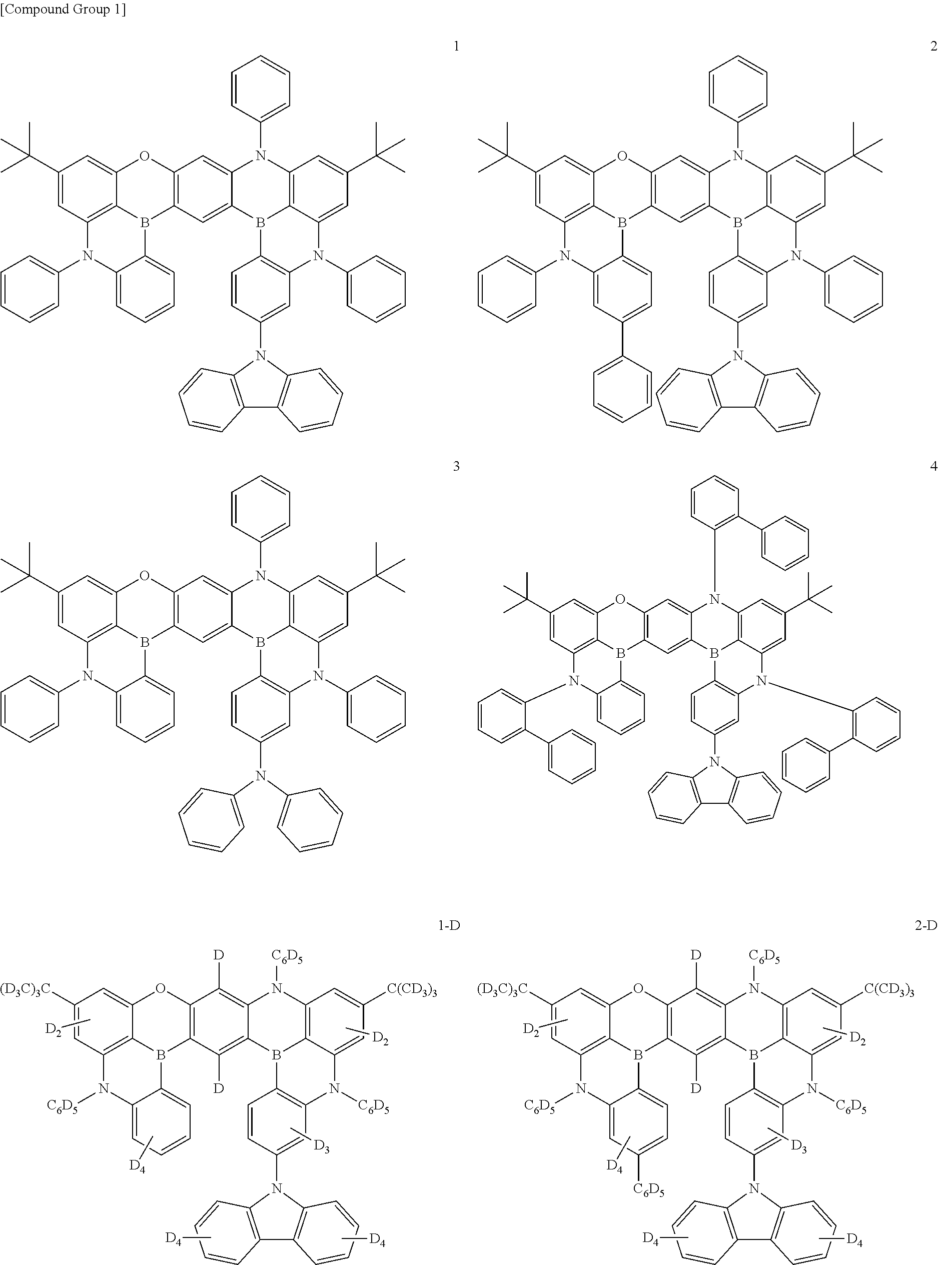 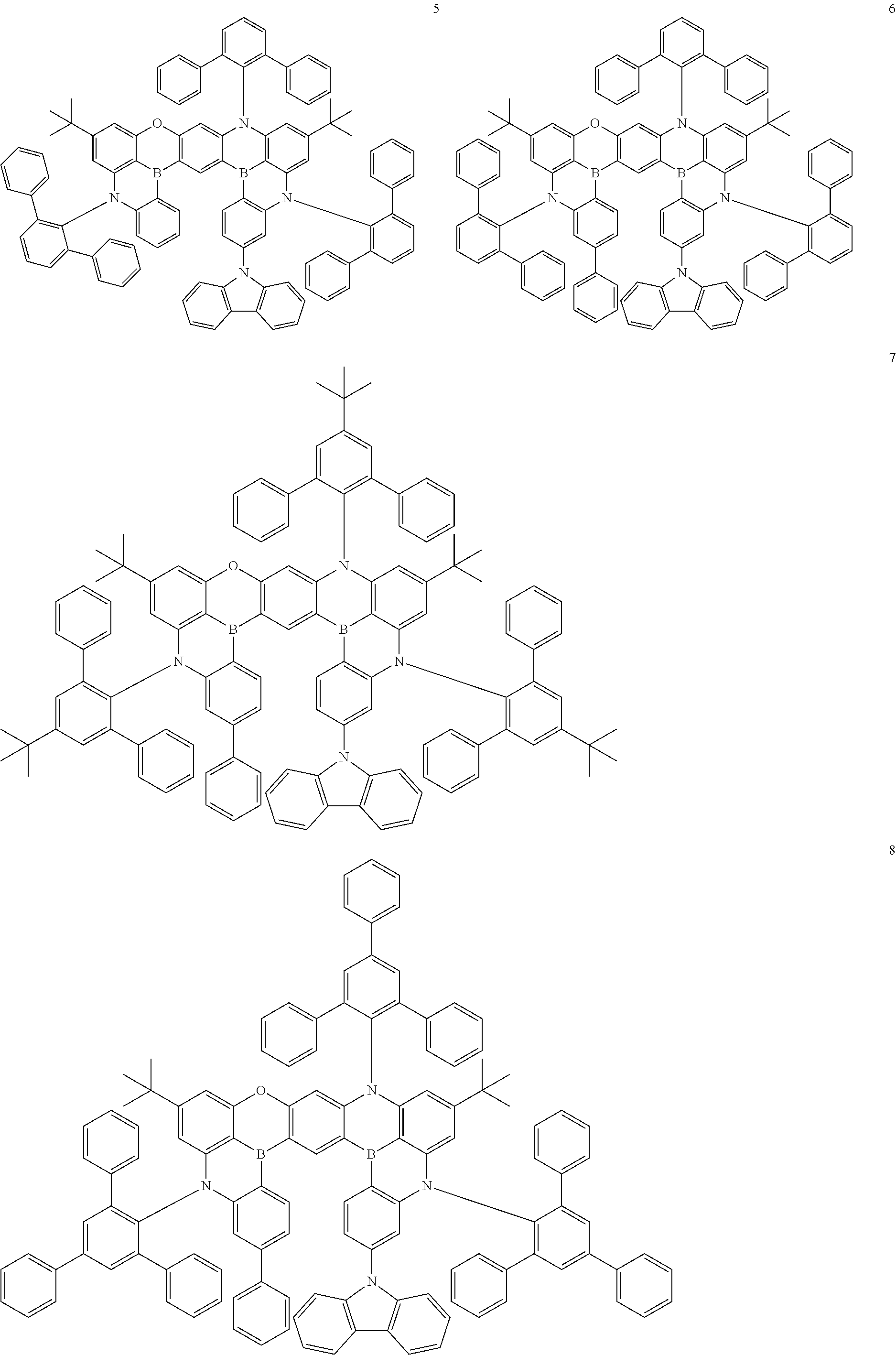 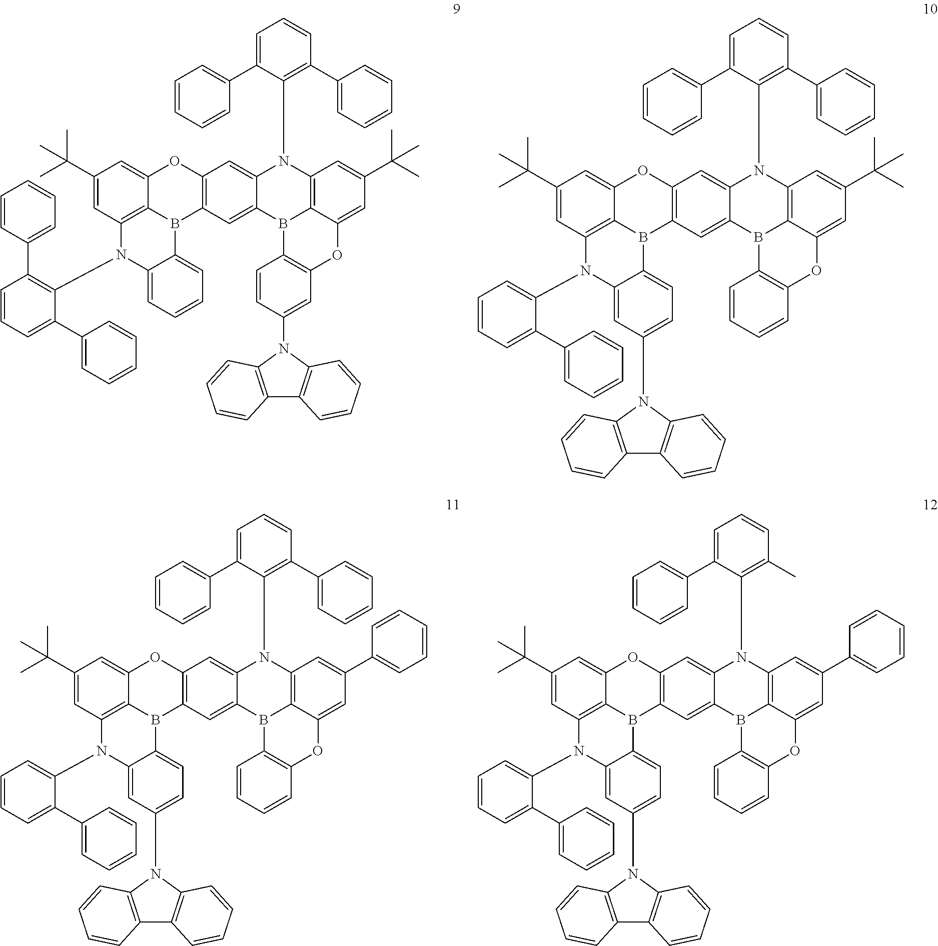 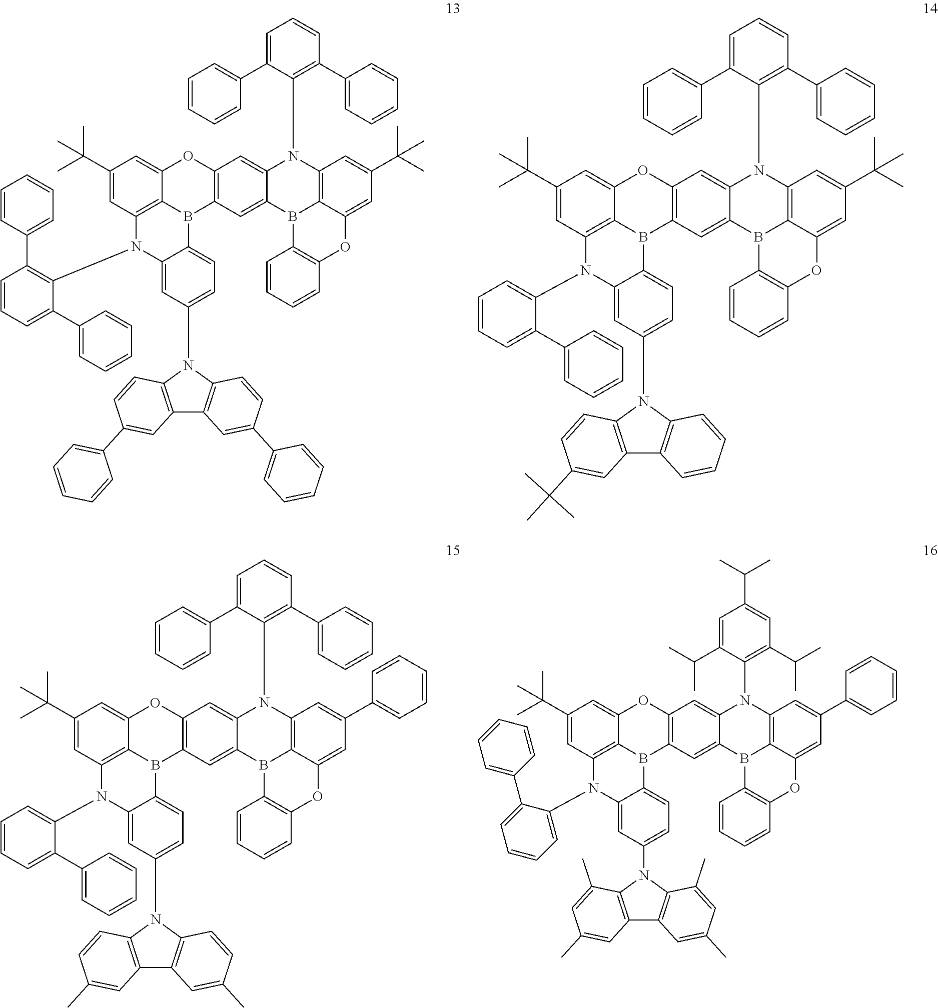 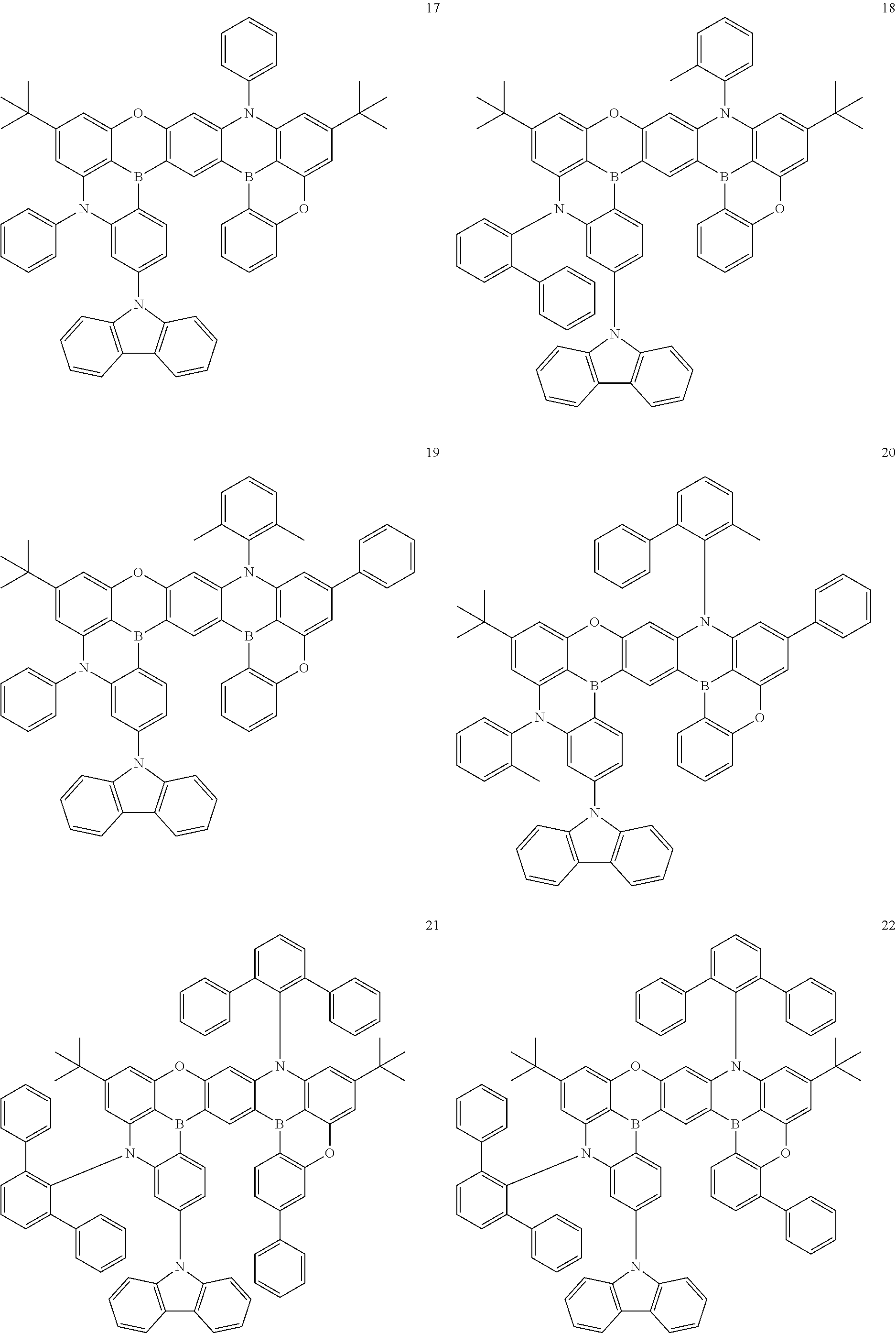 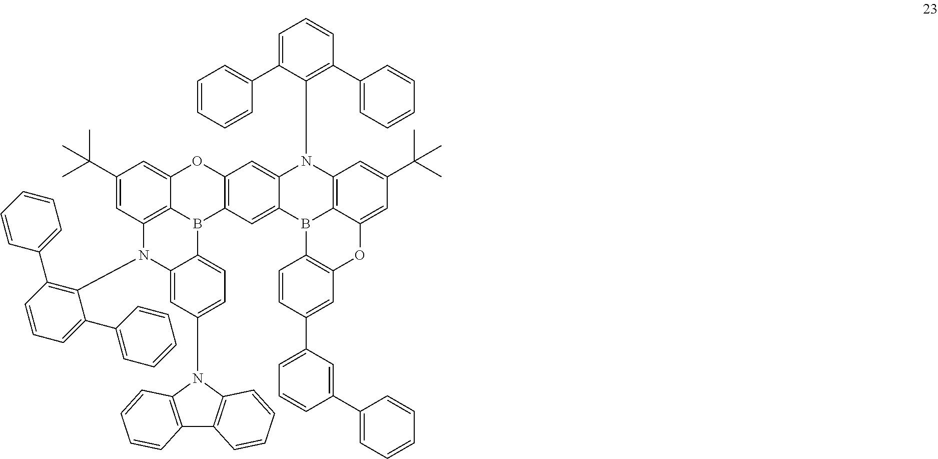 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccc(-c3cccc(-c4ccccc4)c3)cc1O2] 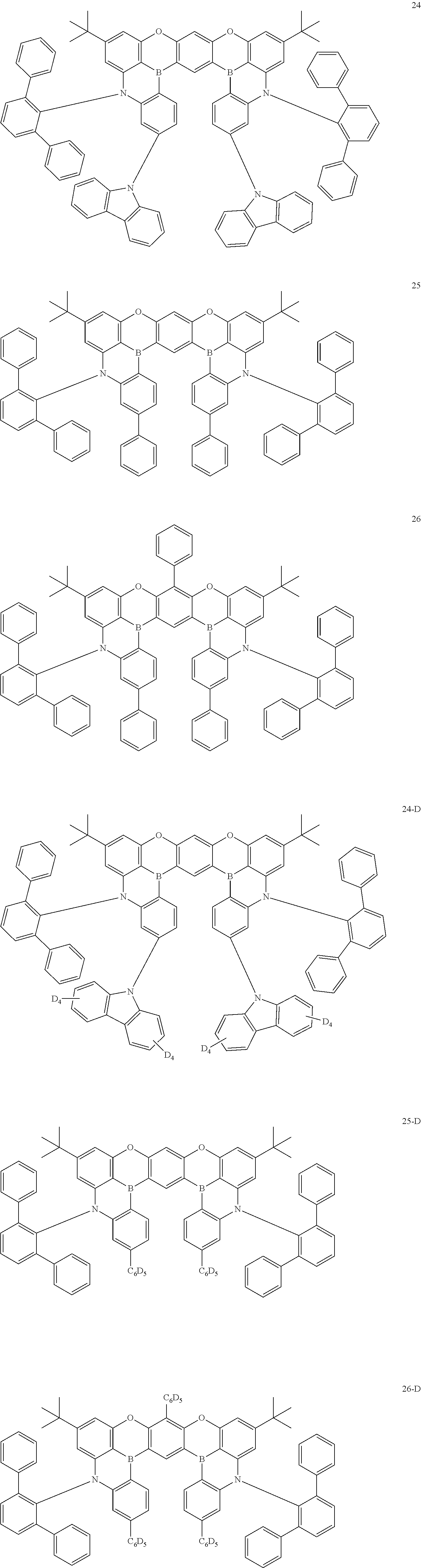 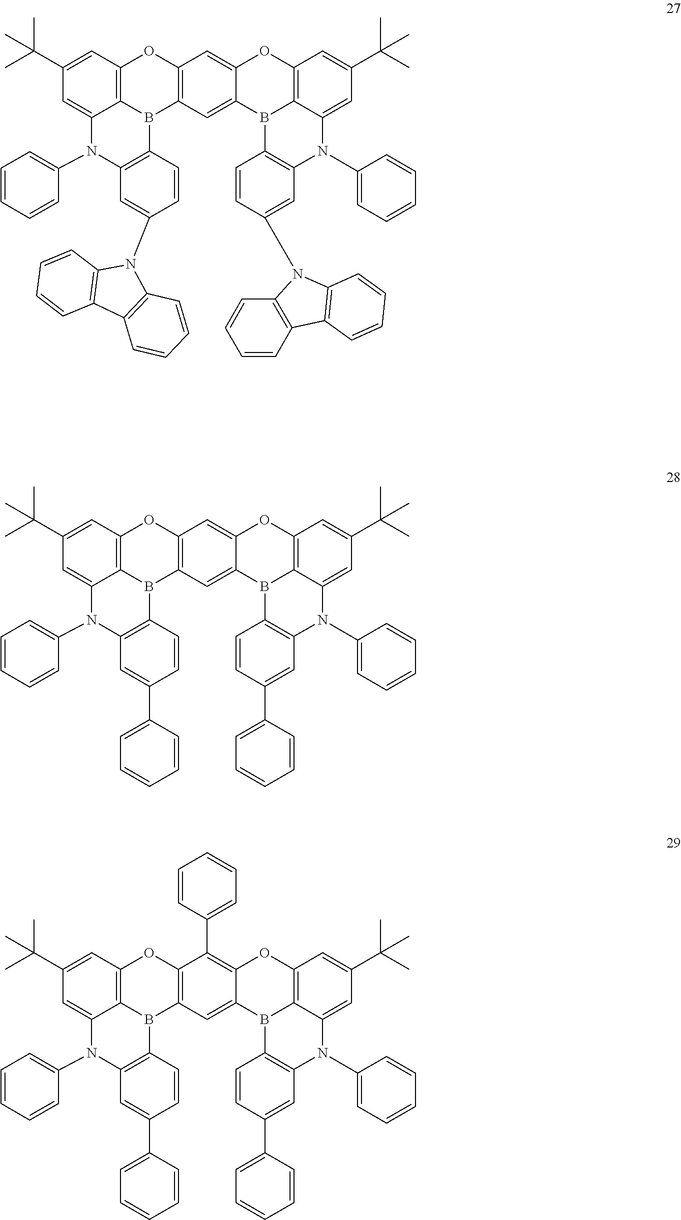 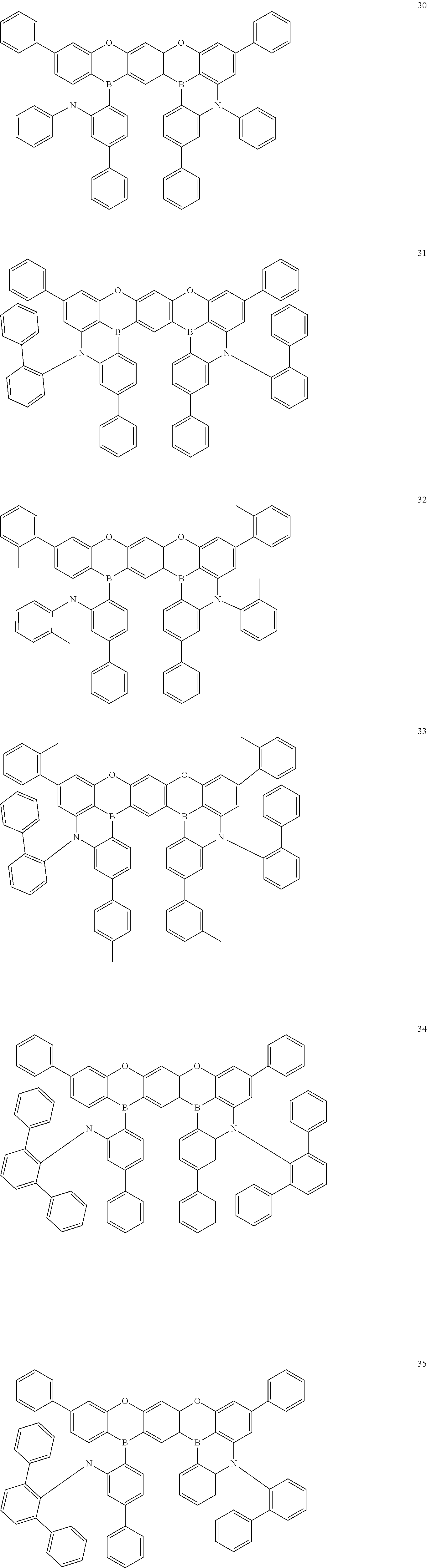 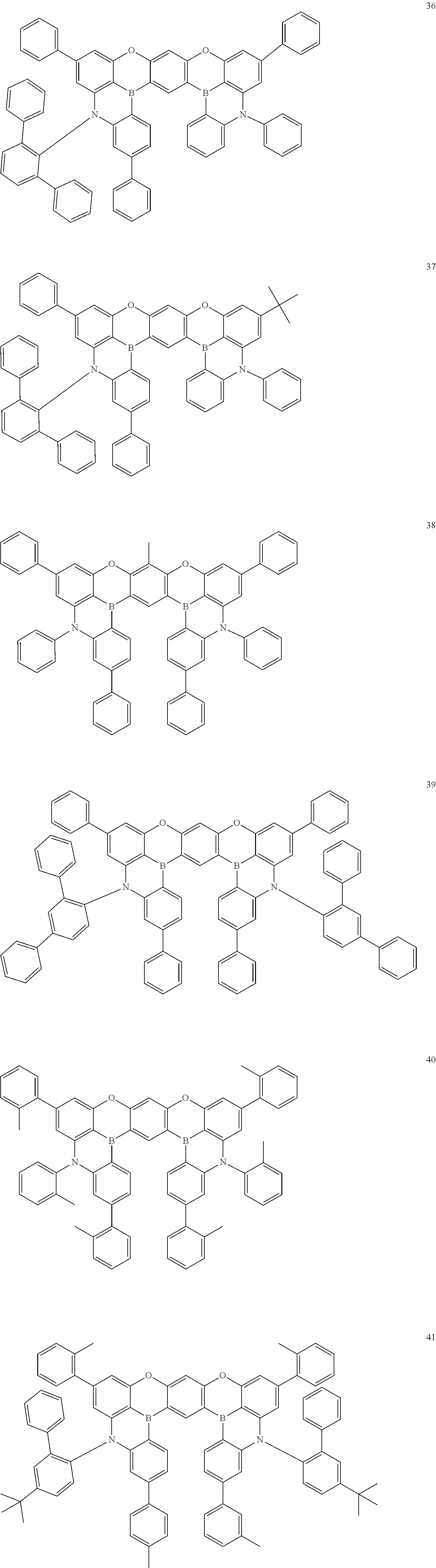 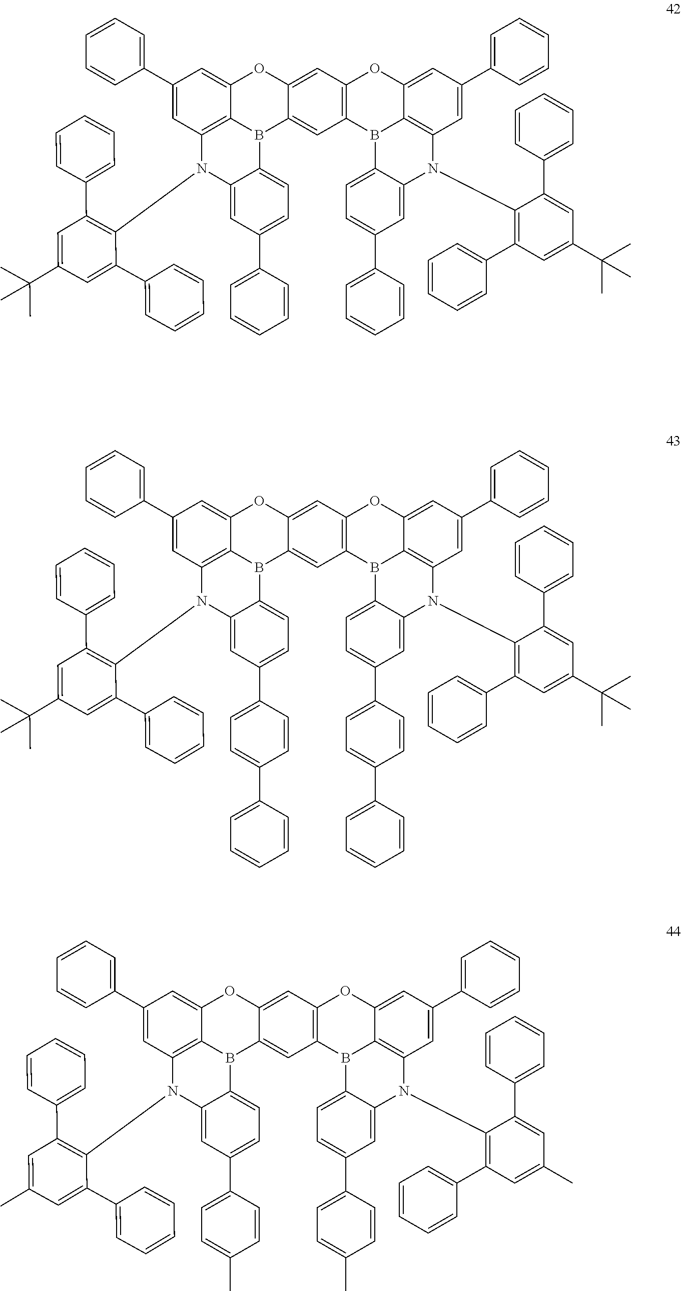 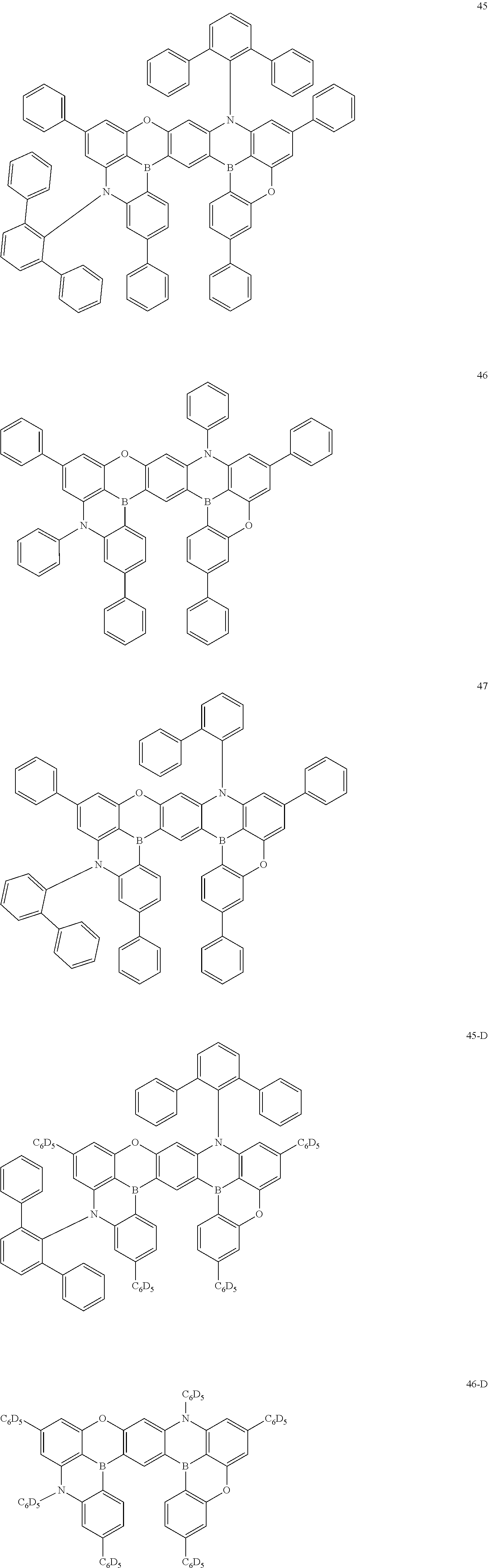 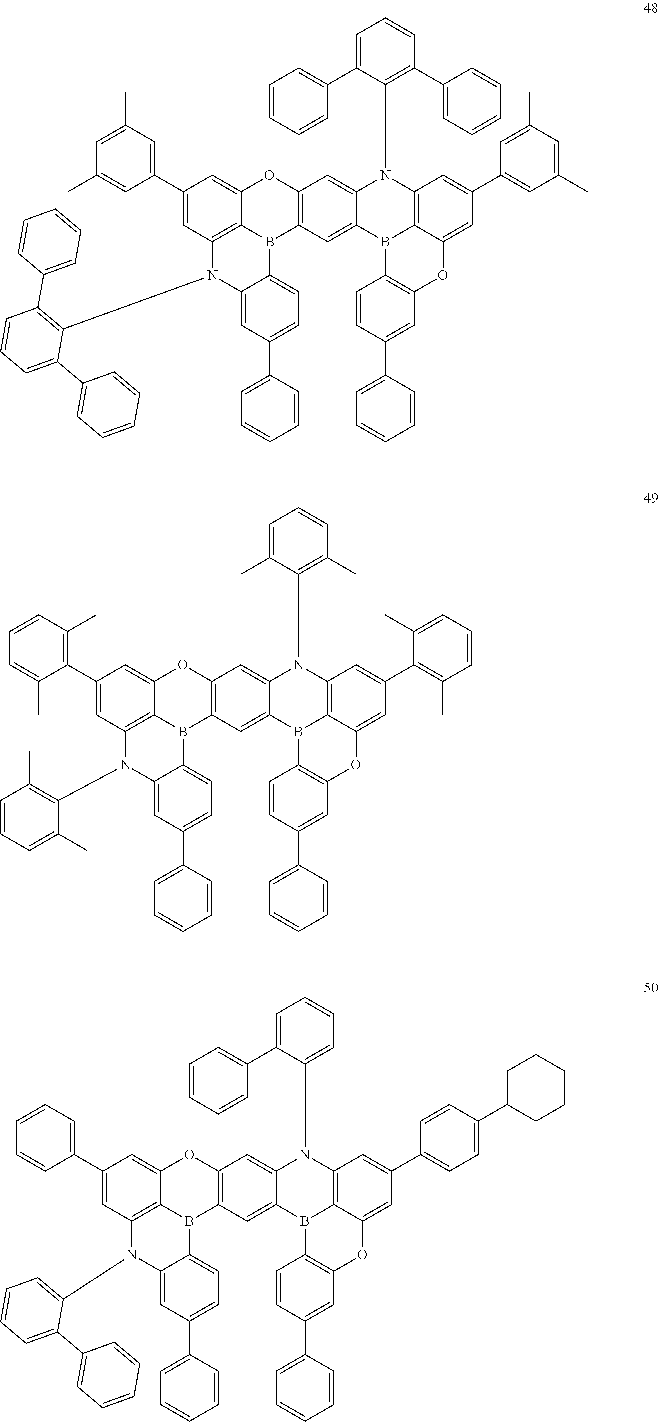 [SMILES: Cc1cc(C)cc(-c2cc3c4c(c2)N(c2c(-c5ccccc5)cccc2-c2ccccc2)c2cc(-c5ccccc5)ccc2B4c2cc4c(cc2O3)N(c2c(-c3ccccc3)cccc2-c2ccccc2)c2cc(-c3cc(C)cc(C)c3)cc3c2B4c2ccc(-c4ccccc4)cc2O3)c1 ; Cc1cccc(C)c1-c1cc2c3c(c1)N(c1c(C)cccc1C)c1cc(-c4ccccc4)ccc1B3c1cc3c(cc1O2)N(c1c(C)cccc1C)c1cc(-c2c(C)cccc2C)cc2c1B3c1ccc(-c3ccccc3)cc1O2 ; c1ccc(-c2ccc3c(c2)Oc2cc(-c4ccc(C5CCCCC5)cc4)cc4c2B3c2cc3c(cc2N4c2ccccc2-c2ccccc2)Oc2cc(-c4ccccc4)cc4c2B3c2ccc(-c3ccccc3)cc2N4c2ccccc2-c2ccccc2)cc1] 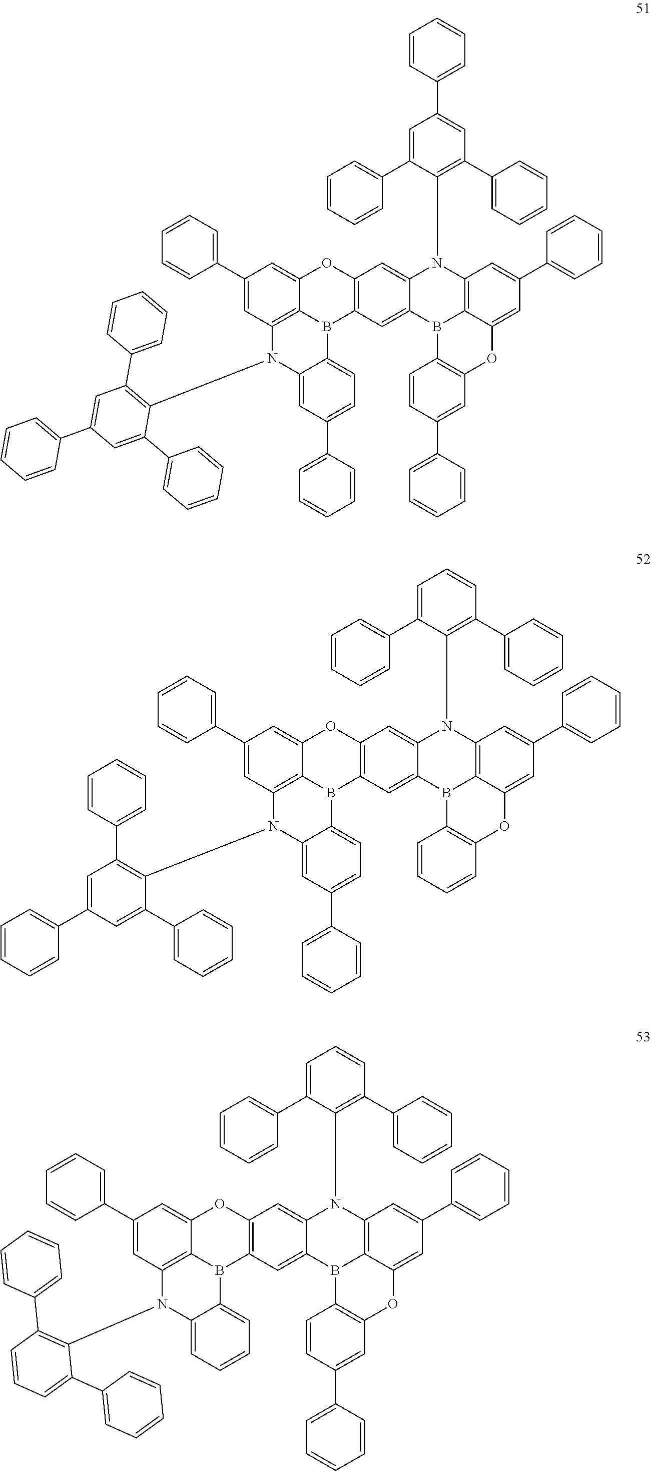 [SMILES: c1ccc(-c2ccc3c(c2)Oc2cc(-c4ccccc4)cc4c2B3c2cc3c(cc2N4c2c(-c4ccccc4)cc(-c4ccccc4)cc2-c2ccccc2)Oc2cc(-c4ccccc4)cc4c2B3c2ccc(-c3ccccc3)cc2N4c2c(-c3ccccc3)cc(-c3ccccc3)cc2-c2ccccc2)cc1 ; c1ccc(-c2cc(-c3ccccc3)c(N3c4cc(-c5ccccc5)ccc4B4c5cc6c(cc5Oc5cc(-c7ccccc7)cc3c54)N(c3c(-c4ccccc4)cccc3-c3ccccc3)c3cc(-c4ccccc4)cc4c3B6c3ccccc3O4)c(-c3ccccc3)c2)cc1 ; c1ccc(-c2ccc3c(c2)Oc2cc(-c4ccccc4)cc4c2B3c2cc3c(cc2N4c2c(-c4ccccc4)cccc2-c2ccccc2)Oc2cc(-c4ccccc4)cc4c2B3c2ccccc2N4c2c(-c3ccccc3)cccc2-c2ccccc2)cc1] 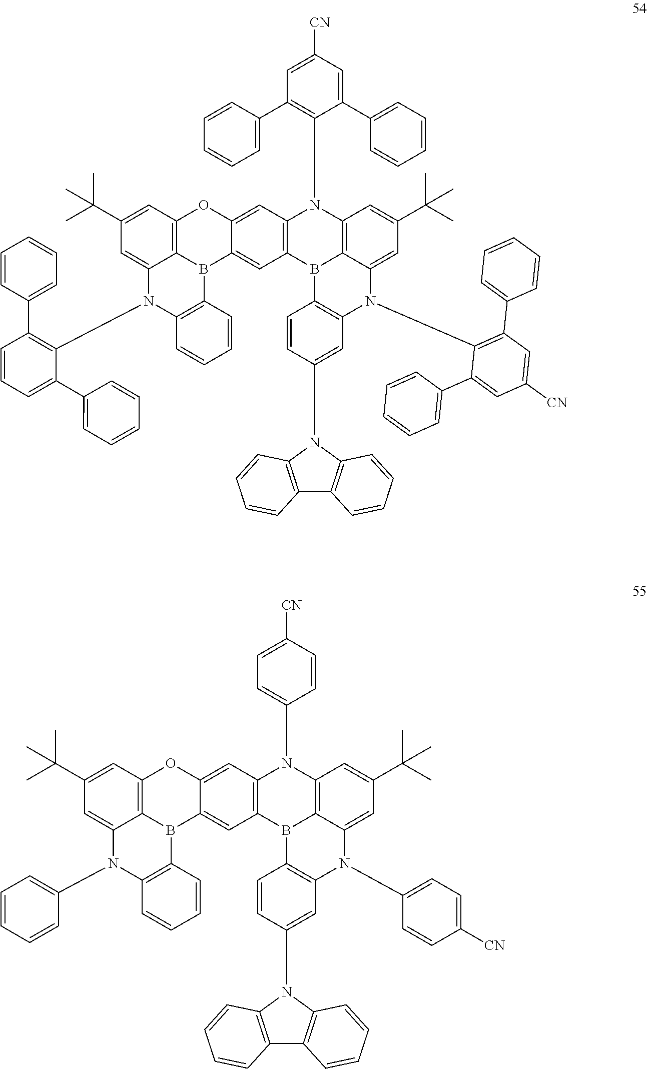 [SMILES: CC(C)(C)c1cc2c3c(c1)N(c1c(-c4ccccc4)cccc1-c1ccccc1)c1ccccc1B3c1cc3c(cc1O2)N(c1c(-c2ccccc2)cc(C#N)cc1-c1ccccc1)c1cc(C(C)(C)C)cc2c1B3c1ccc(-n3c4ccccc4c4ccccc43)cc1N2c1c(-c2ccccc2)cc(C#N)cc1-c1ccccc1 ; CC(C)(C)c1cc2c3c(c1)N(c1ccccc1)c1ccccc1B3c1cc3c(cc1O2)N(c1ccc(C#N)cc1)c1cc(C(C)(C)C)cc2c1B3c1ccc(-n3c4ccccc4c4ccccc43)cc1N2c1ccc(C#N)cc1] 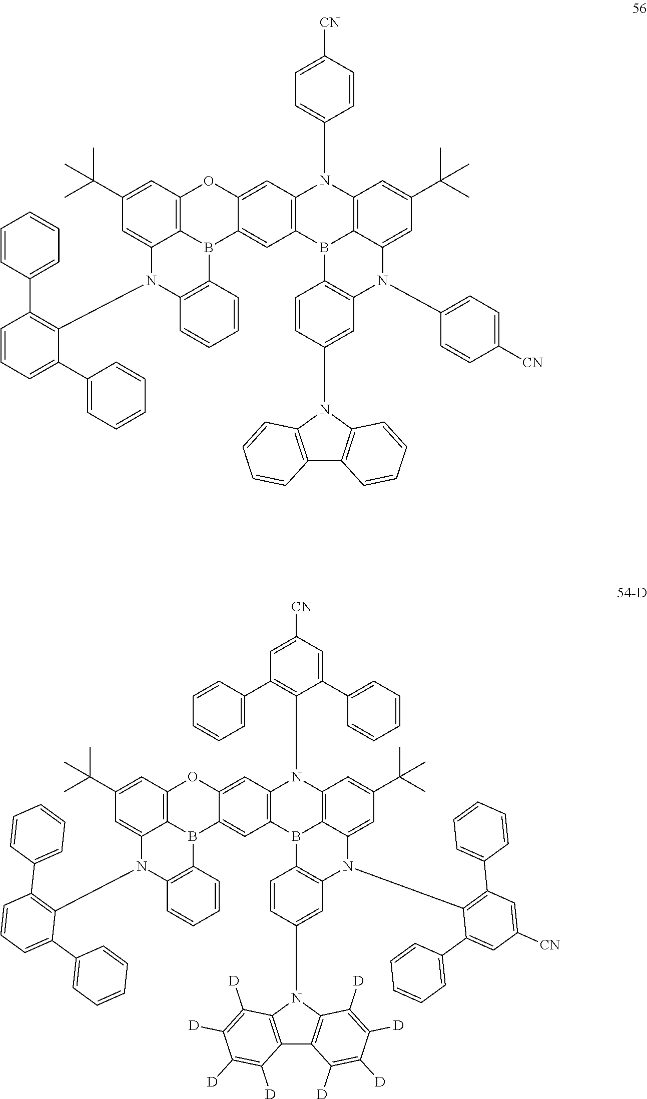 [SMILES: CC(C)(C)c1cc2c3c(c1)N(c1c(-c4ccccc4)cccc1-c1ccccc1)c1ccccc1B3c1cc3c(cc1O2)N(c1ccc(C#N)cc1)c1cc(C(C)(C)C)cc2c1B3c1ccc(-n3c4ccccc4c4ccccc43)cc1N2c1ccc(C#N)cc1 ; [2H]c1c([2H])c([2H])c2c(c1[2H])c1c([2H])c([2H])c([2H])c([2H])c1n2-c1ccc2c(c1)N(c1c(-c3ccccc3)cc(C#N)cc1-c1ccccc1)c1cc(C(C)(C)C)cc3c1B2c1cc2c(cc1N3c1c(-c3ccccc3)cc(C#N)cc1-c1ccccc1)Oc1cc(C(C)(C)C)cc3c1B2c1ccccc1N3c1c(-c2ccccc2)cccc1-c1ccccc1] 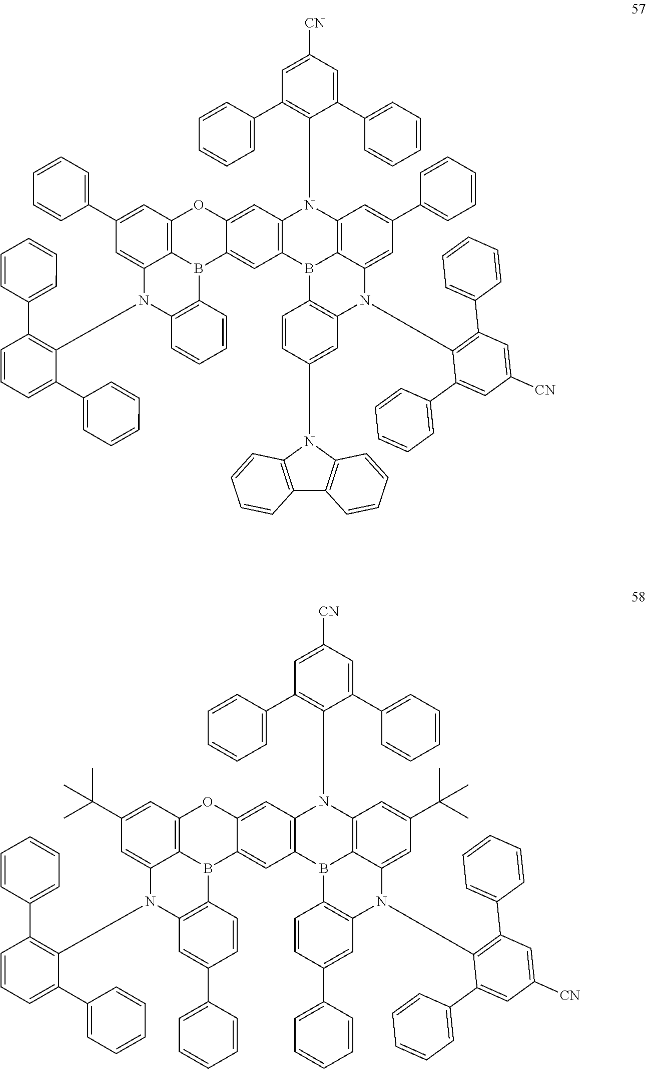 [SMILES: N#Cc1cc(-c2ccccc2)c(N2c3cc(-n4c5ccccc5c5ccccc54)ccc3B3c4cc5c(cc4N(c4c(-c6ccccc6)cc(C#N)cc4-c4ccccc4)c4cc(-c6ccccc6)cc2c43)Oc2cc(-c3ccccc3)cc3c2B5c2ccccc2N3c2c(-c3ccccc3)cccc2-c2ccccc2)c(-c2ccccc2)c1 ; CC(C)(C)c1cc2c3c(c1)N(c1c(-c4ccccc4)cccc1-c1ccccc1)c1cc(-c4ccccc4)ccc1B3c1cc3c(cc1O2)N(c1c(-c2ccccc2)cc(C#N)cc1-c1ccccc1)c1cc(C(C)(C)C)cc2c1B3c1ccc(-c3ccccc3)cc1N2c1c(-c2ccccc2)cc(C#N)cc1-c1ccccc1] 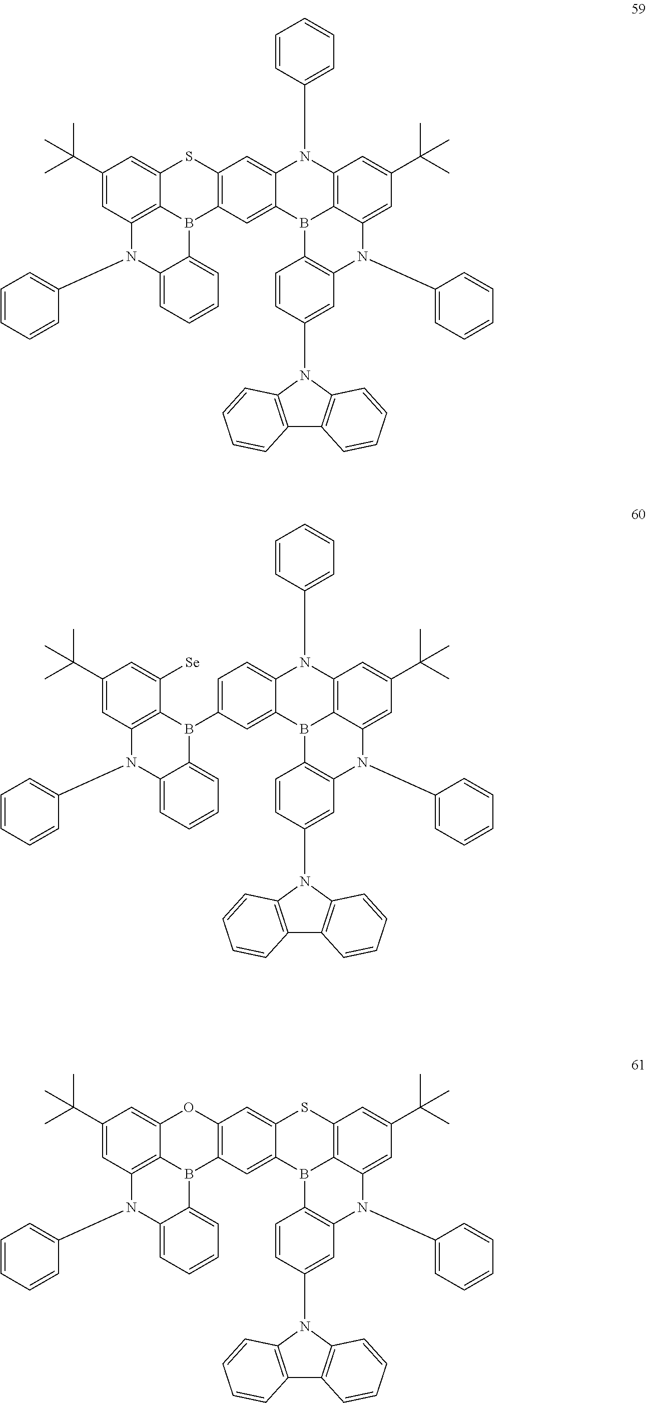 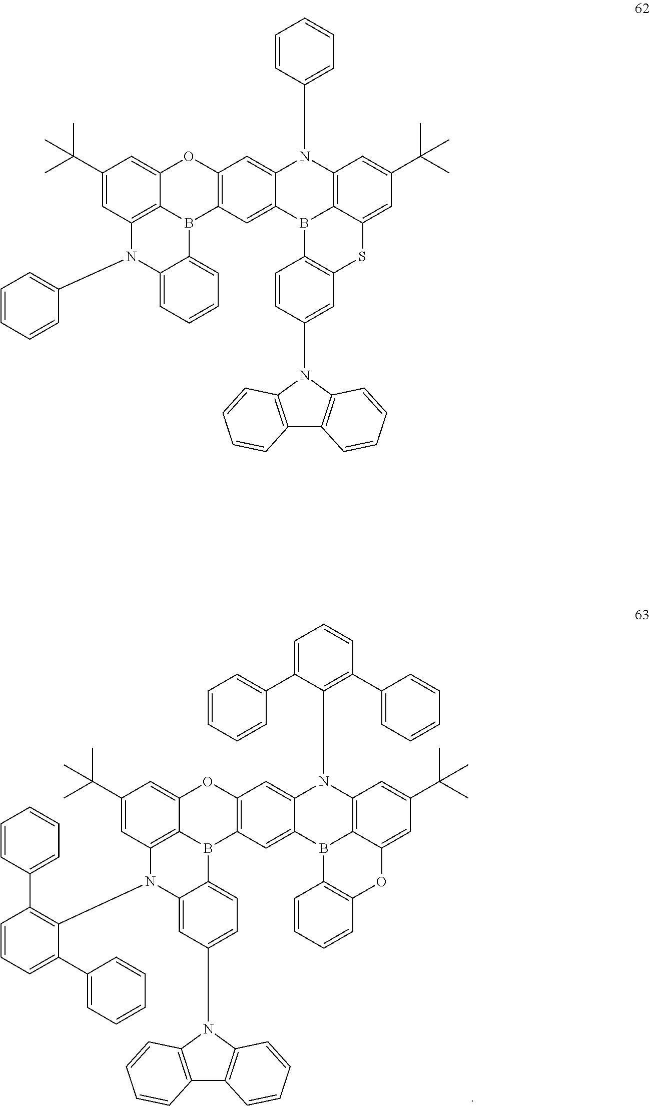 [SMILES: CC(C)(C)c1cc2c3c(c1)N(c1ccccc1)c1ccccc1B3c1cc3c(cc1O2)N(c1ccccc1)c1cc(C(C)(C)C)cc2c1B3c1ccc(-n3c4ccccc4c4ccccc43)cc1S2 ; CC(C)(C)c1cc2c3c(c1)N(c1c(-c4ccccc4)cccc1-c1ccccc1)c1cc(-n4c5ccccc5c5ccccc54)ccc1B3c1cc3c(cc1O2)N(c1c(-c2ccccc2)cccc1-c1ccccc1)c1cc(C(C)(C)C)cc2c1B3c1ccccc1O2]
